(19) United States
(12) Patent Application Publication
(10) Pub. No.: US 2013/0228221 A1
(43) Pub. Date: Sep. 5, 2013

(54) MANUFACTURING METHODS AND STRUCTURES FOR LARGE-AREA THIN-FILM SOLAR CELLS AND OTHER SEMICONDUCTOR DEVICES

(71) Applicant: SOLEXEL, INC., Milpitas, CA (US)

(72) Inventors: Mehrdad M. Moslehi, Los Altos, CA (US); Pawan Kapur, Burlingame, CA (US); Karl-Josef Kramer, San Jose, CA (US)

(73) Assignee: Solexel, Inc., Milpitas, CA (US)

(21) Appl. No.: 13/869,928

(22) Filed: Apr. 24, 2013

Related U.S. Application Data
(63) Continuation-in-part of application No. 13/731,112, filed on Dec. 31, 2012.
Application No. 13/731,112 is a continuation-in-part of application No. 13/807,637, filed on Mar. 25, 2013.
Application No. 13/807,637 is a continuation-in-part of application No. 13/204,626, filed on Aug. 5, 2011.

(51) Int. Cl. H01L 31/0224; H01L 31/18

(52) U.S. Cl. CPC H01L 31/022441; H01L 31/18
USPC 136/256; 438/98

(57) ABSTRACT

Fabrication methods and structures relating to multi-level metallization for solar cells as well as fabrication methods and structures for forming back contact solar cells are provided.

### CROSS-REFERENCE TO RELATED APPLICATIONS

This application claims priority to U.S. Provisional Patent Application Ser. No. 61/637,831 filed Apr. 24, 2012, which is hereby incorporated by reference in its entirety.

### FIELD

The present disclosure relates in general to the fields of photovoltaics and semiconductor microelectronics. More particularly, the present disclosure relates to the methods, architectures, and apparatus related to high-efficiency back-contact crystalline silicon photovoltaic solar cells.

### BACKGROUND

Currently, crystalline silicon (both multi-crystalline and mono-crystalline silicon) has the largest market share in the photovoltaics (PV) industry, currently accounting for about 85% of the overall global PV market share. Although moving to thinner crystalline silicon solar cells is long understood to be one of the most potent and effective methods for PV cost reduction (because of the relatively high material cost of crystalline silicon wafers used in solar cells as a fraction of the total PV module cost), utilizing thinner crystalline wafers is hampered by the problem of thin wafers being extremely fragile, mechanical breakage during wafer handling and cell processing, and the resulting production yield losses caused by thin and fragile silicon wafers. Other problems include inadequate light trapping in the thin cell structure because silicon is an indirect bandgap semiconductor material and absorption of longer wavelength red and infrared photons (particularly those in the wavelength range of about 900 nm to 1150 nm) requires relatively long optical path lengths—often much larger than the wafer thickness itself. Further, using known designs and manufacturing technologies it is often difficult to balance the requirement of high mechanical yield and reduced wafer breakage rate with high manufacturing yields in PV factories in a cost effective manner.

Relating to substrate (semiconductor absorber) thickness, for current crystalline silicon wafer solar cells, moving even slightly thinner than the current thickness range of 140 μm to 200 μm starts to severely compromise mechanical yield during cell and module manufacturing. This is particularly a big challenge for larger cell sizes such as 156 mm×156 mm and 210 mm×210 mm cells (compared to the smaller 125 mm×125 mm cells). Thus, manufacturable solutions directed to process very thin solar cell structures, such as with cell semiconductor absorbers thinner than about 100 μm down to micron-size-scale and submicron thickness, often must utilize a cell process during which the cell is fully supported by a either a temporary and/or a permanent host carrier throughout the process flow, or a cell process which utilizes a novel self-supporting, stand-alone, substrate with an accompanying structural innovation. This structural innovation must allow the cell substrate to be extremely robust against breakage in high throughput solar cell and module factories. Examples of the latter are the novel 3-Dimensional honeycomb and pyramidal structures formed with crystalline silicon thin films.

On the cell architecture side, back-junction/back contacted monocrystalline semiconductor (such as monocrystalline silicon) solar cells are conducive to very high efficiency. This is primarily because there is no metal shading associated losses on the front side as well as no emitter on the front which helps result in a high blue response. Moreover, the use of n-type base enables much higher minority carrier lifetime compared to p-type base, as well as no Light-Induced Degradation (LID). In addition, the back-contact/back-junction cell with n-type base may use well-established silicon nitride frontside passivation and anti-reflection coating layer with positive fixed charges in the passivation layer (or layer stack) comprising silicon nitride providing for improved frontside surface passivation with reduced Frontside Surface Recombination Velocity (FSRV) enabled by field-assisted passivation. Further, backside metal may be made thicker and with a higher area coverage (e.g., well over 90%) to ensure very low series resistance (or very high metal interconnect electrical conductivity) without worrying about the trade-off with shading that is often a consideration for front contacted cells. Back contacted/back junctions cells are, in particular, highly conducive to being combined with very thin (e.g., solar cell substrates for at least two distinct reasons. Firstly, high-efficiency back contacted/back junction cells have a stringent requirement of having minority carrier diffusion length (known as L_{eff}) at least 5× (by a factor of at least approximately 5) the thickness of the substrate (or the active crystalline semiconductor absorber). A very thin (e.g., with crystalline semiconductor layer thickness less than about 80 microns and more preferably less than about 50 microns) solar cell substrate enables this requirement without demanding a very high bulk substrate lifetime or a very high quality material, thus, can be done in practice on a cheaper starting material having eliminated the most stringent substrate quality requirements. This indirectly gives a further cost advantage: the quality of the material can be relaxed in addition to it being thinner. A second reason is related to the process flow which enables fabrication of the back contact/back junction cells (will be discussed further in the following sections). Because back contacted cell architecture and related process flow may be catered to have all high temperature process steps (i.e., any cell process steps with process temperatures in the range of approximately 400° C. to ˜1150° C.) on one side of the cell, the requirement for a carrier of the thin substrate when it is going through processing on the other sides are considerably eased. Thus, using a very thin substrate (e.g., with crystalline semiconductor layer thickness less than about 80 microns and more preferably less than about 50 microns) in conjunction with a back-contacted/back-junction architecture may represent an ideal solar cell combination.

In the past, there have been attempts in solar PV R&D to use carriers such as glass for thin substrates; however, these carriers have suffered from serious limitations including relatively low maximum processing temperatures in the case of soda lime glass (or most other non-silicon foreign materials), with the processing temperatures being limited to well below approximately 400° C.—which potentially may compromise the solar cell efficiency. There have also been attempts to make small area (for example, cell areas well below 10 cm²) thin cells which do not have serious breakage concerns (while they still suffer from the thermal processing limitations, including limitation of process temperatures to well below approximately 400° C.); however, large cell areas (areas well above 100 cm²) are often required for commercial viability through cost-effective manufacturing.

### BRIEF SUMMARY

Therefore, a need has arisen for fabrication methods and designs relating to metallization for solar cells. In accordance with the disclosed subject matter, methods, structures, and apparatus for multi-level metallization of solar cells are provided. These innovations substantially reduce or eliminate disadvantages and problems associated with previously developed solar cells.

According to one aspect of the disclosed subject matter, fabrication methods and structures relating to multi-level metallization of solar cells are described. In one embodiment, a back contact solar cell comprises a substrate having a light receiving frontside surface and a backside surface for forming patterned emitter and base regions. A first electrically conductive metallization layer is patterned on the backside base and emitter regions. An electrically insulating layer is formed on the first electrically conductive metallization layer and a second electrically conductive metallization layer is formed on the electrically insulating layer. The second electrically conductive metallization layer is connected to the first electrically conductive metallization layer through conductive via plugs formed in the electrically insulating layer.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, nature, and advantages of the disclosed subject matter may become more apparent from the detailed description set forth below when taken in conjunction with the drawings in which like reference numerals indicate like features and wherein:

FIG. 1 is a diagram illustrating solar cell processing carrier combinations;

FIG. 2 is a cross-sectional diagram of a back contact solar cell embodiment;

FIG. 3 is a diagram illustrating ex-situ emitter process flow embodiments;

FIG. 4 through 8 are back contact solar cell manufacturing process flows using an epitaxial substrate;

FIGS. 9A through L are cross-sectional diagrams after processing steps of a back contact solar cell;

FIGS. 10 through 21 are back contact solar cell manufacturing process flows using epitaxial substrate;

FIGS. 22 through 35 are back contact solar cell manufacturing process flows using a cleaved substrate;

FIGS. 36 through 45 are back contact solar cell manufacturing process flows using a bulk wafer;

FIG. 46 is a back contact solar cell manufacturing process flow for a selective emitter;

FIG. 47 is a cross-sectional diagram of a cell resulting from the flow of FIG. 46;

FIG. 48 is a back contact solar cell manufacturing process flow;

FIG. 49 is a cross-sectional diagram of a cell resulting from the flow of FIG. 48;

FIG. 50 is a back contact solar cell manufacturing process flow;

FIG. 51 is a cross-sectional diagram of a structure with retrograde resist sidewalls;

FIGS. 52 through 57 are top views of solar cell backplane embodiments after various processing steps;

FIGS. 58 and 59 are back contact solar cell manufacturing process flows for heterojunction cells;

FIG. 60 is a cross-sectional diagram of a solar cell with a heterojunction architecture;

FIGS. 61A through C are back contact solar cell manufacturing process flows using an epitaxial substrate;

FIGS. 62A through G are top view and cross-sectional views of a back contact solar cells after backplane processing steps;

FIGS. 63A through D are cross sectional diagrams of a pluto structure after certain processing steps;

FIGS. 64A through F show various aspects, cross-sectional and top views and process flows, of a four-layer backplane oasis structure;

FIGS. 65A through D are top views of various cell backplane metal finger designs;

FIG. 66 is a top view of backplane embodiment;

FIG. 67 show cross-sectional diagrams of an oasis structure;

FIGS. 68A through C are cross-sectional diagrams of a hybrid structure;

FIGS. 69 and 70 show cross-sectional diagrams of a immersion contact bonding structure embodiments;

FIG. 71 is a back contact solar cell manufacturing process flow;

FIG. 72A shows process flows for manufacturing pluto backplane structures;

FIG. 72B shows process flows for manufacturing oasis backplane structures;

FIGS. 73A through J show cross-sectional diagrams of a cell during fabrication steps of a pluto embodiment of back contact solar cell process flow;

FIGS. 74A through D show a top view (FIG. 74A) and cross-sectional diagrams of a cell during fabrication steps of a oasis embodiment of back contact solar cell process flow;

FIG. 75 shows cross-sectional diagrams of an oasis structure two step lamination using a predrilled dielectric sheet;

FIG. 76 shows cross-sectional diagrams of an oasis structure single step lamination using a predrilled dielectric sheet;

FIGS. 77A through D are cross-sectional diagrams of a pluto-hybrid structure during back contact solar cell formation.

FIGS. 78 through 80 are diagrams illustrating example multi-level metallization embodiments for interdigitated back contact solar cells;

FIGS. 81 through 83 are cross sectional diagrams of a back contact solar cells with a backside multi-level metallization designs;

FIG. 84 is a graph showing design related calculation results for power loss as a function of metal 1 design;

FIG. 85 is a graph showing the relative sensitivity of the number of M2 backplane orthogonal fingers to metallization pitch and M1 base-to-emitter metal width ratio;

FIG. 86 is a graph showing the thickness of on-cell aluminum metal (M1) vs. the number of backplane orthogonal aluminum-metal-foil fingers pairs (M2) at absolute cell efficiency loss of 0.25% (60 mW);

FIG. 87 is a graph showing the thickness of on-cell aluminum metal (M1) vs. the number of backplane orthogonal aluminum-metal-foil fingers pairs (M2) at absolute cell efficiency loss of 0.50% (120 mW);

FIG. 88A is a solar cell manufacturing process flow using epitaxy on a template;

FIG. 88B is a solar cell manufacturing process flow using wafer based cells with an optional absorber thinning;

FIG. 88C is a solar cell manufacturing process flow showing subsequent cell processing steps for the flows of FIGS. 88A and 88B;

FIG. 89 is a solar cell manufacturing process flow using wafer based cells with texturization prior to backplane lamination;

FIG. 90 is a solar cell manufacturing process flow using wafer based cells with thermal oxide front surface passivation;

FIG. 91 is a cross-sectional diagram of on-cell back contact structures after formation of doped emitter and base contact regions and a patterned first layer metal;

FIG. 92 is a top view of a solar cell backside a first level and second level metallization pattern embodiment;

FIG. 93 a cross-sectional diagram of a homojunction back contact solar cell;

FIG. 94 a cross-sectional diagram of a heterojunction back contact solar cell;

FIGS. 95A and 95B are solar cell manufacturing process flow for epitaxial based and wafer based heterojunction solar cells;

FIG. 96 is a solar cell manufacturing process flow for epitaxial based and wafer based solar cells with homojunction emitters;

FIG. 97 is a solar cell manufacturing process flow showing subsequent cell processing steps for the flows of FIGS. 95 and 96;

FIGS. 98A through 101B2 are cross-sectional diagrams showing a large-area thin-film semiconductor device formation using porous silicon seed and release layer followed by epitaxial silicon growth for a back contact back junction solar cell embodiment;

FIG. 102 is a process flow embodiment for a back-junction back-contact monocrystalline silicon solar cell;

FIG. 103 is a process flow embodiment for a back-junction back-contact monocrystalline silicon solar cell;

FIGS. 104 and 105 are specific process flows for back contact back junction solar cells using the cleaving technique coupled with a backplane;

FIGS. 106 and 107 are representative process flows for manufacturing large area thin crystalline silicon, back contact/back junction solar cells using porous silicon and epitaxial growth;

FIG. 108 is a cross-sectional diagram showing the schematic of a solar cell which has an emitter on the backside and base contact on the front side;

FIG. 109 is a process flow for the formation of a large-area thin-film semiconductor device, specifically a back-junction front-contact monocrystalline silicon solar cell using epitaxy;

FIG. 110 is a process flow for the formation of a large-area thin-film semiconductor device, specifically a back-junction front-contact monocrystalline silicon solar cell using cleavage;

FIGS. 111 through 113 are process flow embodiments for an epi cell with front-contact base and back-junction/back-contact emitter;

FIG. 114 is a cross-sectional diagram of a front junction and front contact solar cell;

FIGS. 115 and 116 are process flows for the formation of a large-area thin-film semiconductor devices, specifically front-junction, front-contact monocrystalline silicon solar cells; and

FIG. 117 is a process flow for an epi cell with front-contact emitters.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

And although the present disclosure is described with reference to specific embodiments, such as crystalline silicon and other fabrication materials, one skilled in the art could apply the principles discussed herein to other materials, technical areas, and/or embodiments without undue experimentation.

The disclosed subject matter provides various structures and manufacturing methods for high-efficiency back-junction/back contacted solar cells specifically using thin crystalline semiconductor absorbers such as monocrystalline silicon with the cell absorber layer (or substrate), preferably ranging in thickness from about less than one micron (1 μm) up to about one hundred microns (100 μm), and even more particularly ranging in thickness from about one micron (1 μm) to about fifty microns (50 μm). The cell structures and manufacturing methods provided also apply to thicker crystalline semiconductor substrates or absorbers, ranging in thickness from about 100 μm to about 200 μm (which also includes the thickness range for more conventional CZ or FZ wafer thicknesses). The crystalline solar cell substrates may be formed either using chemical-vapor-deposition (CVD) methods including epitaxial growth (such as atmospheric-pressure epitaxy) or other crystalline silicon material formation techniques (including but not limited to the so-called kerfless slicing or exfoliation methods utilization proton implantation, metal-stress-induced exfoliation, or laser). Various embodiments of manufacturing methods as it pertains to all aspects of processing very thin crystalline semiconductor solar cell substrates may be extended to other types of materials and to wafer based approaches, including kerfless cleavage methods such as the implantation-assisted wafer cleavage methods. Key attributes of various cell embodiments provided include substantially reduced semiconductor (e.g, silicon) material consumption, very low manufacturing cost, high cell efficiency, and relatively high energy yield, thus, improved solar photovoltaic module performance. Specifically, this stems from the combinations of the unique cell design architectures and manufacturing methods of this invention, which entail manufacturing back junction/back contacted solar cells using thin crystalline semiconductor layers, yielding very high conversion efficiency on thin crystalline semiconductor substrates, yielding very low cost. While the variety of disclosed embodiments may be applied to various crystalline semiconductor materials (such as silicon, gallium arsenide, germanium, etc.), preferred embodiments for monocrystalline silicon are provided (which also apply to the other monocrystalline semiconductors including gallium arsenide, germanium, gallium nitride, etc.).

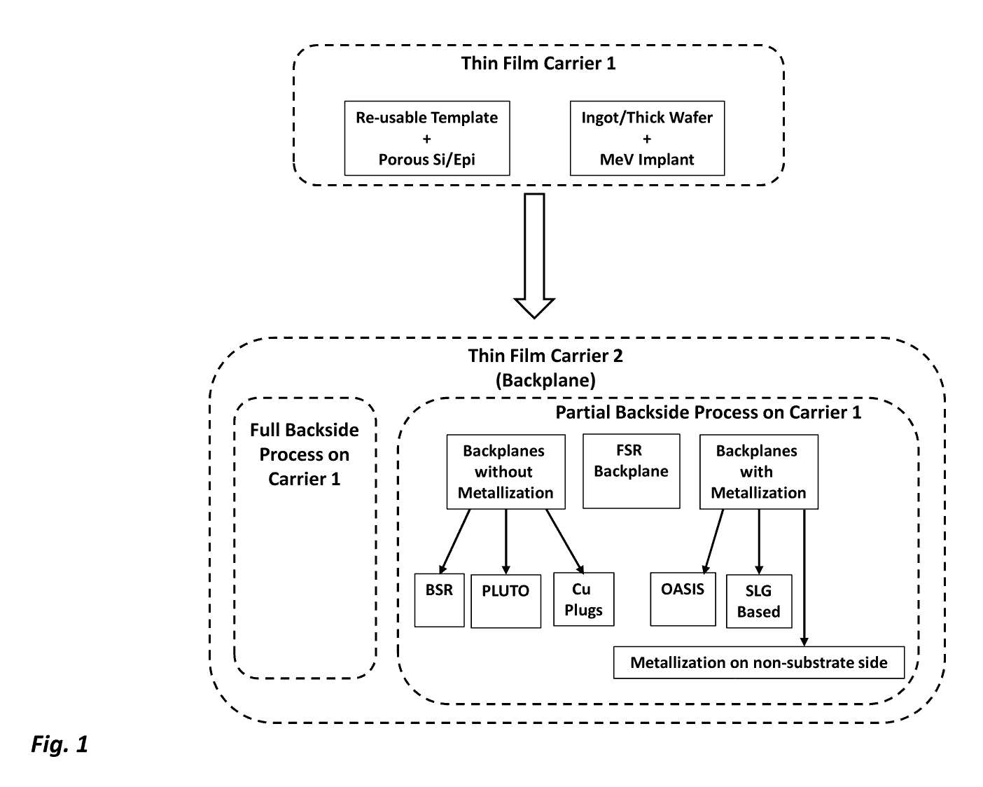

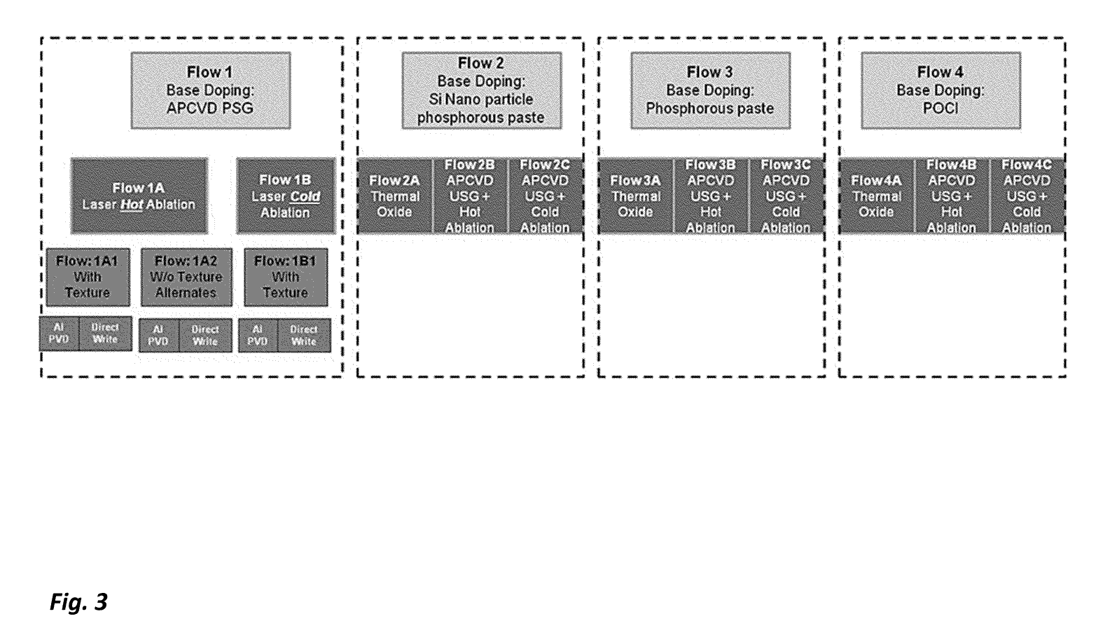

The disclosed subject matter provides innovations particularly pertaining to very thin crystalline solar cells (from about 1 micron up to 150 microns, and more preferably cell absorbers in the thickness range of about 1 micron to about 50 microns) with the back junction/back contact architecture. First, novel very thin (thickness range of 1 micron to 150 microns) back contacted/back junction crystalline silicon cell structures are provided. Secondly, methods for manufacturing back contacted/back junction crystalline silicon cell structures are provided. Thirdly, methods for supporting thin substrates (using Carriers) while they have being processed through the line and while they are deployed in the field are provided. Various combinations of these three categories create a myriad set of structures, process flows, and thin cell support carriers. FIG. 1 is a graphical flowchart showing the various thin film carrier combinations, comprising temporary Thin-Film Carrier 1 and permanent Thin-Film Carrier 2, disclosed herein. FIG. 1 shows the two classes of carriers whose varied combination constitute the novel structures and methods for manufacturing very thin back contacted/back junction crystalline semiconductor solar cells and specific embodiments which are disclosed herein. The two classes of carriers comprise first carrier and second carrier. Options for different cell fabrication process flows once the carriers 1 and 2 are established are also provided herein, including in FIG. 3. Note that, it is possible to have any of the process flows paired with most carrier 1 and carrier 2 combinations

The final structures obtained using these unique combinations are back-contact solar cells. Importantly, although this disclosure provides many unique sets of set of structures, process flows, and thin cell support carriers, it is understood that not all sets of possible process flows based are explicitly covered by this document, and the ones which are not covered are implied based on the cell design and process flow architectures disclosed herein. Several process flows and alternative embodiments are provided with detail herein allowing one with skill in art to combine various disclosed aspects.

This disclosure provides various host carrier methods and structures used for supporting the thin semiconductor (such as thin monocrystalline silicon) cell. We start by first addressing the category pertaining to handling and supporting thin film silicon substrate (henceforth, TFSS) through its manufacturing and permanently reinforcing it—this is shown as Thin Carrier 1 and Thin Film carrier 2 in FIG. 1.

High manufacturing yield is a pre-requisite for commercially viable thin silicon solar technology. Very thin solar cells (from about 1 micron up to 150 microns, and more preferably cell absorbers in the thickness range of about 5 microns to about 60 microns) discussed in this document are fully and continually supported throughout the cell handling and processing to maintain high manufacturing yield and for commercial viability. This means that thin cells are never processed or handled without either temporary or permanent support attachments (also called substrate carriers). These thin semiconductor cells are also permanently supported (and reinforced) once assembled in the photovoltaic modules for installation and operation in the field to maintain mechanical resilience, reliability, and high yield during module lamination/packaging, field installation, and field operation. Because both sides of the solar cell need to be accessed and processed (to complete the cell backside and sunnyside), in general, two carriers are required for TFSS (in order to always support the thin semiconductor substrate throughout handling, processing, and final module packaging): one for processing each face of the solar cell. The carriers must satisfy several important criteria: firstly, they should be cost-effective (i.e., very low cost per cell or very low cost per peak watt). Their combined amortized cost should be less than the cost of the silicon in the thin cell that they save (compared to the traditional wafer-based solar cells). Secondly, at least one of the carriers should be able to withstand relatively high temperature processing (particularly at temperatures in the range of approximately 300° C. up to as much as 1150° C.) required in manufacturing of high-efficiency solar cells, without any complications due to mismatch in coefficient of thermal expansion (CTE) and/or due to undesirable impurities being introduced into the cell. In addition, if only one of the carriers is able to support high temperature cell processing (i.e., high-temperature processing to form the cell substrate itself using CVD epitaxy as well as to complete the cell backside device structure as required), the process flow should be such that all the necessary high temperature processing steps are on this high-temperature-capable carrier (which will serve as temporary reusable carrier). As mentioned before these particular criteria are highly favorable to back contacted/back junction cell, hence, truly enabling high efficiency back-contact, back-junction thin cells. Thirdly, at least one of the carriers should preferably be able to withstand wet processing and final cell metallization required for manufacturing solar cells. An example of a key wet processing step includes silicon front surface random pyramid texturing etch in diluted and heated alkaline (comprising KOH and/or NaOH and/or TMAH) solutions. Fourthly, once the first side (preferably the cell backside for the back-contact/back-junction cell processing) is partially or fully processed, the carrier (which serves as temporary reusable carrier) should be such that the thin cell (Thin Film Semiconductor Substrate: TFSS) may be easily detached or lifted off from the carrier on demand with high yield and with the TFSS layer transferred to the other carrier in conjunction with the lift-off detachment process (attached on the side which was processed first, preferably the cell backside for back-contact cell) for processing of the second side. Subsequently, in the case, where the first side (preferably the cell backside) was only partially processed, the remaining process steps (for instance, such as completion of the final cell metallization) can be completed using, for example, various embodiments detailed below. Preferably within the embodiments of this invention, the high-temperature-capable temporary carrier and the high-temperature processing steps precede the permanent carrier as well as the wet processing and final cell metallization steps. Moreover, starting with the formation of the thin-silicon substrate using CVD epitaxy till the pre-lift-off attachment of the permanent carrier to the TFSS layer, all the process steps performed on the TFSS while on the temporary carrier are preferably dry processing steps (no wet processing on the temporary carrier other than a wet porous silicon process step prior to the formation of the TFSS layer by CVD epitaxy). Furthermore, the cell contact metallization is preferably performed after formation of the cell contacts and prior to the attachment of the permanent carrier and prior to the lift-off separation of the TFSS layer from the temporary reusable carrier or template.

Supporting Carrier #1 (i.e., Reusable Template) for TFSS.

For the combination of TFSS with back contact/back junction architecture two choices for the first carrier are disclosed, henceforth carrier 1. These options are shown in FIG. 1 under carrier 1. In the remaining document Sunnyside of the Back contact/back junction cell will be interchangeably referred to as the cell “frontside”, while the non-sunny side will be interchangeably called the cell “backside”.
1. The first disclosed option for carrier 1 is a relatively thick (preferably in the thickness range of about 0.2 mm to 2 mm) semiconductor (e.g., preferably mono-crystalline silicon for high-efficiency mono-crystalline silicon solar cells) wafer (with wafer area in the range of 150 cm² up to over 2,000 cm²), which may also serve as a reusable template (hence amortizing cost over many template reuse cycles). Large area thin solar cell substrates, with desirable cell areas, for instance, square-shaped cell dimensions of 156 mm×156 mm (this size may be scaled up to at least 210 mm×210 mm or even larger sizes up to 300 mm×300 mm and 450 mm×450 mm), are first manufactured using epitaxial semiconductor (epitaxial silicon) growth on top of a reusable crystalline semiconductor template, and are subsequently dislodged. The reusable template can be substantially planar or in a different embodiment have pre-structured 3-dimensional pre-pattern. This document focuses on the substantially planar template, although various embodiments can be applied to the pre-structured templates with random structure or patterned regular structure 3D features. It may be reused several times (preferably at least 10's of times) for epi (epitaxial silicon) growth, which amortizes its cost over the reuse cycles. After its useful reuse life, the reusable template can be ultimately recycled to make new templates through CZ crystal growth and wafer slicing. The TFSS is released from the reusable template using a sacrificial release layer which in one preferred embodiment may be a porous silicon layer, preferably with at least with two different porosities (a higher porosity buried release layer and a lower porosity seed layer) or a graded porosity. The reusable template, since it is preferably a relatively thick (preferably in the range of about 0.2 mm to 2 mm) silicon wafer, is capable of withstanding relatively high processing temperatures (e.g., up to about 1150° C. or even higher) without any CTE mismatch issues with the subsequent TFSS and without any contamination concerns, satisfying one of the key criteria for carrier 1, outlined above. The template can be in various sizes such as 156 mm, 165 mm, 200 mm, 300 mm or 450 mm (or any diametric or side dimensions in the range of about 100 mm to several hundred mm, at least up to 450 mm), shapes, such as round or square or polygon, and thicknesses capable of going through full or partial solar cell process without cracks or breakage, with template thickness of about at least 200 μm (and as thick as about 2 mm or even thicker). The second criterion for carrier 1, related to cost effectiveness is accomplished by reusing and amortizing the template cost over a plurality of TFSS fabrication cycles (as well as by using unpolished templates if necessary or desired). Finally, this carrier also satisfies the aforementioned carrier criteria of being conducive to the high-yield detachment of the TFSS with high repeatability and consistency. This is accomplished by preceding the epitaxial growth of TFSS with formation of a porous silicon layer (serving as an epitaxial seed layer and subsequent release layer) between the template and the TFSS, preferably using a wet electrochemical etch process in a liquid comprising HF and IPA (or HF and acetic acid, or HF mixed with another suitable material). The porosity of the porous silicon layer is catered and spatially adjusted in depth (by using a lower porosity top layer and a higher porosity buried bottom layer) to accomplish the dual purpose of i) transferring the crystallinity of template with high fidelity during the epitaxial process, and ii) yet be able to provide very high yield detachment and release on demand from the template. The cell release may be accomplished using processes such as mechanical release (MR) or sonicated mechanical release in a liquid (SMR), or another suitable method, resulting in lift-off detachment of the TFSS layer after its attachment or lamination to the permanent carrier 2.
2. The second disclosed option for carrier 1 can be a reusable thick wafer or an ingot. The detachment of the TFSS may be accomplished using a high-implantation-energy such as an MeV (mega-electron volt) proton (hydrogen ion) implant and separating thin slices from the host wafer or ingot.

When the porous silicon/epi technique on the host carrier is compared with the thick wafer/ingot and implant induced separation technique several trade-offs can be identified. The wafer/ingot with implant has the advantage of not needing porous silicon and epitaxial growth and the accompanying reactors (however, it has dependency on polysilicon feedstock and ingot growth). On the other hand it needs rather expensive MeV proton implantation capital equipment and high energy consumption to operate the implanters. The quality of silicon can be high depending on the cost of the ingot and it can potentially also allow wet processing. A downside is that because the ingot may have <111> orientation in order to eliminate the need for excessively high proton implantation doses, the wafer may rely on more-expensive and damage-producing dry texturing as opposed to the standard wet texturing. The porous silicon/epi combination has the advantage that it is compatible with standard alkaline wet texturing and the substrate doping can be modulated/graded to whatever is conducive for high efficiency requirements. Also, very thin silicon cell substrates (down to about one micron) are possible using a porous silicon/epi manufacturing method and the doping profile can be engineered and adjusted during the epitaxial growth process (not possible for the thin silicon layers produced by proton implantation).

Supporting Carrier #2 for TFSS: Backplane.

The second carrier, in the specific context of back contacted/back junction cells should preferably satisfy several criteria. An obvious one is that it must support the TFSS through the remaining process steps. Secondly, it should protect the prior processing on the side where it is attached (backside for our specific architecture), while the other side (frontside) is being processed. This requires that the second carrier preferably be relatively immune or resistant to the wet chemistry that is used during processing of the frontside (particularly and primarily the wet chemistry used to clean and texture the TFSS sunnyside). Thirdly, it may or may not have high-conductivity metallization layer (preferably comprising aluminum and/or copper) as its integral part. For the case where it does have metallization, in addition to being a carrier (preferably a very low cost permanently attached carrier), it provides metallization which seamlessly attaches to the metal on the cell with low resistance. Finally, though not as high a priority, it should have thermal processing capability sufficient for achieving excellent frontside passivation (therefore, preferably at least up to a temperature of about 180° C. and more preferably at least up to a temperature of about 250° C. or even 300° C.) without producing cracks in TFSS due to any CTE mismatch with silicon and without degradation of the carrier material. This second carrier attached to the solar cell backside henceforth, will be identified as the solar cell “Backplane.”

Several backplanes embodiments are disclosed herein and outlined in FIG. 1 under the Thin Film Carrier 2 heading. It is important to note that any of the several options outlined for carrier 2 in FIG. 1 may be used in conjunction with either of the two carrier 1 options, which are discussed above, that is, any carrier 2 embodiment be used with either the Reusable template/epi/porous silicon option or with the Ingot (or thick wafer)/Implant option.

Carrier 2 (the backplane) may be divided into two broad classes (FIG. 1): The first category, “Full Backside Process on Carrier 1” is where carrier 2 is attached only after all the required processing on the side where it attaches (backside) is completed on carrier 1. In a back contact/back junction cell this might entail finishing all non-sunny side (backside) processing steps including patterned dopant diffusions, contact opens, and full backside contact metallization. No further processing is required on this side, except in some cases, where electrical access to the final cell metallization is required. The second category, “Partial Backside Process on Carrier 2” is where carrier 2 is attached after only partial processing on the backside is finished. Although, this document focuses on the latter category with partial processing and discusses several sub-groups that are possible within this paradigm, it is understood that a variation entailing full processing per the first category is implicit and within the scope of this invention.

One of the driving forces behind the partial processing paradigm on the non-sunny side (i.e., cell backside) is to ensure that if potentially deleterious materials (including lifetime degrading materials), such as copper, are part of the backside processing, they do not contaminate carrier 1, which can be reused for carrying other TFSS (hence, preventing the risk of metallic cross contamination in the production line). This prevents cross contamination in the manufacturing line and the resulting efficiency degradation (hence enabling high-yield template reuse without the risk of cross contamination to the cells). Thus, an idea behind partial processing on the non-sunny side is to introduce the potentially lifetime-degrading materials and processes (such as high-conductivity copper plating metalliation) after the TFSS is detached and released from carrier 1, hence, eliminating the risk of cross contamination.

Three sub-categories of backplanes within the partial processing paradigm are shown in FIG. 1. In the first case, referred to as front surface reinforcement, “FSR”, the TFSS is released from the template using a temporary carrier attached on the partially processed backside. Subsequently, the frontside cell processes such as texture and passivation are carried out with the temporary backside carrier supporting the TFSS. The temporary carrier is choose by the ease of release of the TFSS and may utilize known methods, such as electricity (ex. Mobile electrostatic chuck, MESC), mobile vacuum chuck, MOVAC, or a temporary adhesive which is released upon heating or upon UV exposure. The remaining backside steps (for example, copper metallization) are performed by transferring the TFSS from the temporary backside support to the optically transparent permanent front side reinforcement (for example, a low-cost EVA encapsulant/glass combination), thus freeing up the backside for remaining processing (for example remaining metallization steps). A specific requirement of the front side reinforcement being that it does not degrade light transmission and coupling beyond the degradation usually incurred due to module level packaging. Thus, EVA/glass based reinforcement or the like is preferred, although, other material sets are also possible (such as EVA with a clear front fluoropolymer sheet made of ETFE).

The second and third subcategories, “Backplanes without Metallization” and “Backplanes with Metallization,” of backplanes with partial backside processing are characterized by backplanes which are permanent (in contrast with aforementioned FSR). A difference between these two categories is that the “Backplanes without Metallization” do not have thick metallization integrated or embedded in their structure; rather, this metallization is put on toward the back-end after the frontside (sunny-side) is processed. Whereas, “Backplanes with Metallization” have a thick second level of metallization (for instance, a patterned metal foil) integrated into the backplane. The thick metallization layer on the backplane connects to the thin metallization layer on the TFSS, forming the second layer of interconnects, and may also contain busbars. This thick high-electrical-conductivity metallization layer (preferably made of aluminum and/or copper) decreases resistance for back-contacted cells.

This disclosure details three particular embodiments within the “Backplanes without Metallization” subcategory of backplanes. Importantly, this should not be construed as limitation of this paradigm to these three embodiments. The first case is called Back Surface Reinforcement or “BSR.” In this process flow, the TFSS is released from the template (the first carrier) using a permanent backside reinforcement. The permanent backside reinforcement only partially covers the backside, thus allowing processing on the backside through the open areas, after front side processes are completed also with the BSR support. A structural example of this is a backplane made in a grid pattern with a substantially large open area between the grids providing access to the backside for last several processing steps on the non-sunny backside.

The second embodiment of a permanent “Backplanes without Metallization” is a design known as acronym “PLUTO.” In this process flow, a simple and cheap backplane material (e.g., a relatively low-CTE Pre-preg material comprising a mixture of resin and fibers) is attached to the TFSS, while it is attached to the first carrier. The backplane attachment may be a direct bonding/lamination (if material has adhesive in it) or use an intermediate adhesive layer, for example a dielectric adhesive (DA) which may be printed using means such as screen printing (or applied using a spray coater or a roller coater). The pre-preg assembly/material choices should be such that they meet the following criteria:
a. The released TFSS/Pre-preg assembly should be relatively stress and crack-free with very little bow.
b. The backplane should maintain crack-free properties and should not induce stress cracks in the TFSS, while going through subsequent processing steps such as frontside texturing (e.g., using hot KOH) and PECVD passivation processes.
c. The backplane should be relatively resistant to the chemicals used during frontside processing such as texturing and post-texture surface cleaning (and any possible pre-texture silicon etch).
   After all frontside processing is completed using the PLUTO backplane, access holes (100's to 1000's of holes) are drilled, preferably using a high-productivity laser drilling tool, through the backplane (such as a pre-preg material) and remaining cell metallization is finished, preferably either by plating or using a combination of screen printing of a patterned electrically conductive seed paste and attachment of a pre-patterned metal foil layer (comprising aluminum and/or copper). These holes provide access to the underlying on-cell patterned metal which was formed while the TFSS was on the template (specific examples will be illustrated during the subsequent discussion on process flows). The drilling of holes may be accomplished using a myriad of laser and mechanical methods, in a specific example this can be accomplished using a fast throughput CO2 laser. Requirements for the drilling technique include fast throughput, no damage to the TFSS or the underlying metal on the TFSS, a reliable way to clean the laser opened contacts (if necessary) to have low resistance electrical access to the underlying metal on the TFSS, and proper alignment of the holes to the underlying metal. Subsequent to the laser drilling the rest of the metallization (comprising a second level of metal) may be finished using several method including plating (both electroless and/or electroplating), direct thick metal write techniques such as flame spray, attaching a cheap bread-board with metallization to the backplane, attaching metal foil fingers after screen printing of a patterned conductive seed paste, or having the metallization as part of the module assembly in approaches such as monolithic module assembly (MMA). A slight modification process includes an embodiment in which the pre-preg has pre-drilled holes prior to its attachment/lamination to the TFSS (to eliminate the risk of laser-drilling-induced damage to the TFSS) and is protected by another easily removable cheap thin material layer or sheet (such as a thin Mylar sheet or another suitable material). In this embodiment, the removable protective sheet will be preferably removed after completion of the sunnyside cell processing (including at the wet texture and PECVD passivation processes), and prior to completion of the final cell metallization (or prior to module assembly in the case of MMA).

The third embodiment, “Cu Plugs,” of a permanent “Backplanes without Metallization” of FIG. 1 is a design with a slight modification of the aforementioned so-called PLUTO embodiment. And although, specifically identified with a metal as a naming convention, this approach should not be construed to be limited to copper as the electrically conductive material. In this case, the backplane has an additional layer backing compared to PLUTO. For example, the backplane may consists of glass or other harder solid backsheet materials (e.g., anodized Al) with a pliant attachment material such as an encapsulant PV-FS Z68 (from DNP Solar), also called Z68 in short, or Ethylene Vinyl Acetate (EVA). The backsheet may have pre-drilled holes, but the underlying attachment material serves as a sealant to protect the TFSS metal from being chemically attacked during frontside processing (such as during frontside wet alkaline texturing). After texture and passivation processes, the sealant material is opened up through the pre-drilled holes in the backsheet (for example soda lime glass, SLG). This may be performed using a myriad of methods such as laser drilling or mechanical punching. Once these holes are opened, a continuous seed metal layer is deposited either using a direct write scheme such as metal ink/paste printing (using s stencil printer, screen printer, inkjet printer, or aerosol jet printer), or PVD (e.g., plasma sputtering), or electroless plating. The metal is then thickened by plating and isolated between p and n type diffusion contact metals on top of the backsheet. Various known plating and isolation processes may be used including, for example a screen print resist, then blanket plating of metal, then etch back the resist and use the plated metal as the mask to etch the underlying thin seed metal layer. Alternatively and preferably in our embodiments, a patterned electrically conductive paste is formed by direct write on the backplane, such as with screen printing of a suitable paste (e.g., paste containing copper or nickel or another suitable conductor). Then, the final metallization is completed using direct plating (e.g., such as copper plating) on the patterned plating seed (hence, eliminating the need for sacrificial resist and resist strip and seed etch-back processes).

Another embodiment uses a single sided or a dry frontside texturing process so that the need to protect the partially processed backside is obviated and all access points can be pre-opened (using laser drilling or mechanical drilling or punching) either before attachment of the backplane or before processing the frontside.

The “Backplanes with Metallization” subcategory of backplanes, as shown in FIG. 1 with partial backside processing, are characterized by backplanes which are permanent and have integrated metallization. Three embodiments of the “Backplanes with Metallization” are disclosed in detail in FIG. 1: Ahown with acronyms OASIS, SLG-based (soda lime glass), and “Metallization on non substrate side” (backplanes with metallization facing away from the TFSS). In two embodiments, OASIS and SLG-based, the backplane-integrated metal faces the TFSS during its lamination/bonding to the TFSS, while in the third embodiment, “Metallization on non substrate side,” the metallization of the backplane faces away from the TFSS.

The OASIS backplane embodiment has several components. First, it consists of a metallic backplate which may or may not also serve as the metallization layer. This metallization layer, which in a particular embodiment is patterned into inter-digitated fingers with busbars, may be made, for example, from Al foils or solderable aluminum foils. The Al foils may be pre-coated or pre-plated with nickel and Sn (or a Sn solder alloy) to provide better adhesion of the conductive vias which connect the second level of interconnects to the first level of interconnects on the TFSS. The backplate may be protected from chemical attack on the top by a suitable protective layer such as Z68, EVA or prepreg or another suitable polymeric/plastic cover sheet. These layers are ultimately opened up to provide access for the testing and module connections from the top. During lamination of the patterned metal to the EVA or Z68 like material, substantial planarity must be accomplished by exploiting the flow of the attachment material such that the final assembly should be substantially planar from both top and bottom. At the planar bottom of this assembly, the connection of the Al foil metal to the underlying TFSS metal is made using selective conductive posts or vias in the dielectric layer which has gaps to accommodate the electrically conductive vias. The conductive vias (henceforth conductive epoxy or CE) and the dielectric material (henceforth dielectric epoxy or DE) in the preferred embodiment are screen printed on either the TFSS or on the backplane. CE material requirements include cost effectiveness, highly conductive, it may be screen printable in a preferred embodiment, and that it attaches with low contact resistance to both the overlying backplane metal and the underlying TFSS metal. DE material requirements include cost effectiveness, that it is a non-electrically-conductive dielectric, it may be screen printable in a preferred embodiment, and it adheres well to both the overlying backplane material (both metal and the EVA or Z68 dielectric encapsulant) and the underlying TFSS materials consisting of both TFSS metal and dielectric. For example, the OASIS backplane may have a myriad of variations based on choices in the following categories:
a. Backplate material in the backplane: examples include aluminum foils, Al foils coated with Sn, or glass (different kinds of glasses including the soda lime glass), or other polymeric materials. The requirement is that the backplate material should give the strength and rigidity to the backplane to carry the TFSS. It should also be such that during subsequent thermal processes, it does not induce cracks in the TFSS because of thermal expansion coefficient mismatch.
b. Patterned Metallization material: examples include Al foils which may be coated with other metals to make them conducive for low contact resistance attachment to the electrically conductive vias. In another example, these may be pre-coated Al foils. In one embodiment the metallization material may be the same as the backplate material or it could be attached to the backplate material using adhesive. The thickness of the metallization is dictated by strength requirement if it is the same as the backplate and the resistance requirements.
c. Pattern Design of the metallization: Options primarily consist of the number and hence the width of inter-digitated fingers that are used. The widest width and the least number of fingers that is used may be determined by the largest tolerable resistance (without degrading Fill Factor) on the TFSS metal line between conductive via posts. A second consideration which falls under pattern design is whether the metal foils have additional functionality. For example, they can be designed to give a partial spring-like action, which may be accomplished, for example, either by having them physically separated within each finger or by partially cutting them in a snake-like pattern; however, various designs are possible. The spring-like functionality is geared toward providing the metal foils to expand and contract freely such that they do not rupture the CE or the TFSS due to thermal expansion coefficient mismatch.
d. The choice of the dielectric and the conductive connection material: criteria for selection of these materials are already discussed above.
e. Method of depositing the CE and the DE materials: in one preferred embodiment these are screen printed. This print can be either on the TFSS or on the backplane.
f. Orthogonal vs. Parallel Design: Whether the backplane metallization (second level metal or M2) is parallel or orthogonal to the on-cell TFSS metallization (first level metal or M1) is dictated by several considerations. The orthogonal backplane (M2 fingers orthogonal or cross-cut or perpendicular to M1) has an advantage that the width of the lines on the backplane (or the width of M2 fingers) can be independent, in general, and specifically, much wider than the M1 fingers. This helps in making this metallization much coarser and with less strongent alignment requirements than M1. However, precaution needs to be taken to ensure that orthogonal lines do not short. Thus, the dielectric material has to have good coverage. Parallel design restricts the pitch and dimensions of the backplane metal (M2) to be the same as the on-cell TFSS metal (M1) design. This design on the cell is in general fairly tight and, in turn, is dictated by several device considerations including reduced base resistance, reduced electrical shading, etc.
g. Access scheme of the foil busbars for the module connections: For example, this may be through through-holes through the protective layer or may be a wrap around where the Al foils are wrapped around to the top of the backplane, and protected for example by a laminated polymer during processing of the frontside and contact access to the foils is enabled at the end of the process.

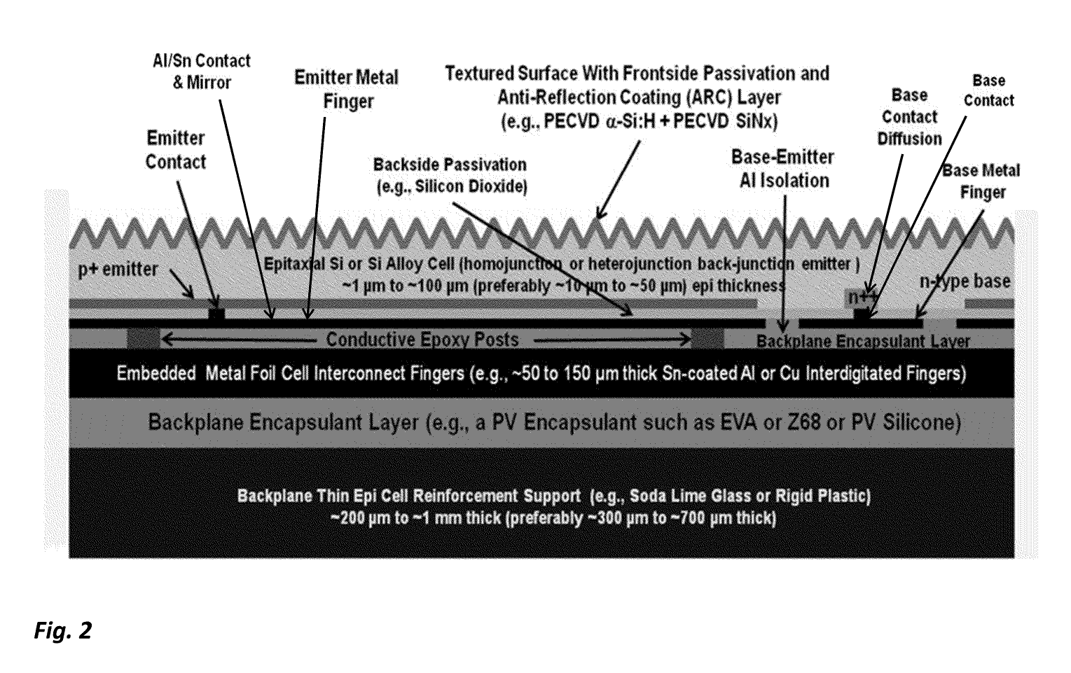

FIG. 2 is a diagram of a cross section of an SLG-based back contact solar cell embodiment. The soda-lime glass or SLG based embodiment as disclosed herein is a subcategory of the so-called OASIS backplane, where the backplate material is a soda lime glass sheet—as shown in FIG. 2. This is attached to the Sn-coated (or solder alloy coated) Al foil metallization using Z68 (or another suitable encapsulant) material. The Al foils wrapped around the glass to have the busbars on top of the glass backplane, and thus are sealed with the protective z68 on the sides as well. The “Metallization on non substrate side” back contact solar cell embodiment has the integrated metallization of the backplane on the side facing away from the TFSS.

Specific examples in which these backplanes may be fit into process flows for forming back contact solar cells are outlined in the manufacturing methods below.

### General Structures and Methods for TFSS-Based Back Junction/Back Contacted Solar Cells

The above discussion pertained to the choices and combinations pertaining to first and second (backplane) carriers for ensuring high processing/manufacturable yield for TFSS back junction/back contacted solar cells. The following section deals with manufacturing methods and process flows for an entire TFSS based solar cell with these carriers. While depicting process flows, in several cases, the backplane is abstracted. This abstraction may be replaced by any of the several backplane options that were discussed in the above sections. In addition, the combination of the backplane with specific flows may either be used with the template/Porous Silicon (PS) based carrier 1 or the Ingot (or Thick Wafer)/implant based carrier 1. Specific flows pertaining to these two cases will be shown. FIG. 1 shows process flow options and their relations to carrier 1 and carrier 2; however again it should be noted that the process flows in FIG. 1 or the following process flows are descriptive examples and should not be used in a restricted sense. Further, these exemplary process flow embodiments should be interpreted as being able to be used with the myriad backplane options as well as any of the two carrier 1 options. A noted exception to this is that in-situ emitter based process flows may not be used with Ingot (or Thick Wafer)/implant carrier 1 option.

Ex-Situ Vs. In-Situ Emitter.

The process flows shown FIG. 1 may be further categorized into two broad categories of process flows: Ex-situ emitter where the emitter is not formed as an integral part of the epitaxial growth process and is produced after the TFSS is manufactured using techniques such as atmospheric pressure chemical vapor deposition (APCVD) epitaxial growth. And in-situ emitter which is appropriate for the carrier 1 template/porous silicon option and is grown as part of the silicon epitaxial growth of the TFSS (hence, eliminating the need for subsequent formation of emitter). This disclosure focuses on the embodiments with ex-situ emitter formation; however, in-situ emitter based flows may also be applicable in some instances by one skilled in the art. With respect to the aforementioned options of ex-situ and in-situ emitter, the following considerations should be noted.
1. The ex-situ boron doped p+ emitter is formed after the in-situ phosphorous based n-type epitaxial substrate is grown using epitaxy. The patterned ex-situ emitter is formed preferably using the combination of APCVD BSG (glass doped heavily with boron), laser ablation of BSG, followed by drive-in of the emitter.
2. The ex-situ emitter eliminates the risk of epitaxial auto-doping during high-volume manufacturing of solar cells, which is present in the case of in-situ emitter.
3. The ex-situ emitter eliminates the need for pulsed picoseconds laser ablation of silicon to isolate base with the emitter (or to form the patterned emitter and base regions).

### General Structural and Manufacturing Method Attributes Shared by the Process Flows.

Specific examples of a class of final back junction/back contacted solar cell structure and methods for manufacturing are detailed below. Note, that the structures and methods are not limited to these specific examples. A wider range of examples may be derived using the aforementioned general carrier methods by those skilled in the related art. For those specific structure and methods detailed herein, identified common attributes include:

1. Common Structural attributes in the disclosed process embodiments:
a. About 25 μm (microns) to 50 μm epi thickness. More generally, this range can be 5 μm to conventional thicknesses of around 200 μm.
b. Phosphorous based n-type base doping. In general, this can be other n-type dopant material (for instance, arsenic or antimony or indium) as well as a p-type base such as, but not limited to that formed by boron or gallium doping.
   2. Common Manufacturing Method attributes in the disclosed process embodiments:
a. The processes on carrier 1 (either template of thick wafer/ingot) include:
   i. APCVD-based processes are preferably used in conjunction with furnace anneal to form the ex-situ emitter. APCVD, in general, has both boron silicate glass (BSG) and phosphorous silicate glass (PSG). However, other substitutes for APCVD PSG are also possible and discussed.
   ii. As mentioned above, in another embodiment relevant to the template/porous silicon (PS) first carrier, the ex-situ APCVD emitter may be replaced by epitaxial-based in-situ emitter followed by laser based silicon ablation to isolate the base from the emitter area.
   iii. Pulsed pico-second based laser ablation pattern for emitter-base isolation, emitter and base contacts, and busbarless Al fingers on the cells. In a generic case, the pattern may be defined by other lasers such as nanosecond (ns) laser. In addition, the Al (or aluminum alloy such as Al—Si) fingers on the cell may be of arbitrary design conducive for better cell performance. This includes, but is not limited to, several mini-cells (on a single substrate) with their own busbars connected at a level above the on-cell metallization levels, such as at the backplane.
   iv. An anneal step with optional oxidation, which takes care of both driving and activation of the BSG dopant (and PSG, if present), as well as creating the thermal oxide based back surface passivation. In a preferred embodiment this is done in the same step, however, if need be, in general may be broken down into separate steps. In addition, this may be done either in a tube based or an in-line thermal processing furnace.
   v. A metal 1 deposition step, which may be a vacuum based deposition such as physical vapor deposition (PVD) such as plasma sputtering or evaporation or ion beam deposition, which is then followed by a laser ablation, such as a pulsed picosecond laser ablation step, for patterning said metal 1 layer. Alternatively, the metal 1 (M1) deposition step may entail the direct-write printing, using for instance ink jet, screen printing, stencil printing, or aerosol jet printing to deposit directly a patterned metal ink or paste on the processed TFSS backside.
   vi. If the carrier 1 is a template/Porous Silicon (PS), a preferred process method embodiment is to not use wet processing on it after (between epitaxial growth till completion of the lift-off separation of TFSS attached to carrier 2) because of the risk of TFSS lifting or bubbling prematurely. However, this should not be interpreted in the limiting sense. The disclosed subject matter includes the general case where it is possible to do wet processing or semi-wet processing, for instance, through the use of etching vapors such as HF vapors to remove dielectric films such as the silicate glasses.
   vii. On carrier-1 lamination of backplane and the release of the TFSS from carrier-1 while attached to carrier-2.
b. The processes on carrier 2 (Backplane)
   i. Post-release wet etch for removing quasi mono-crystalline silicon (QMS) layer arising from the processed porous silicon layer. This also includes using wet processing to texture the front surface. In a preferred embodiment, these wet steps are performed in a single step using KOH-based (or NAOH-based) etch chemistry. However, if needed, in general they can be broken down in two separate steps with both steps using KOH based chemistry or the QMS removal step using TMAH-based or a separate KOH-based (or NAOH-based) chemistry. There is also the possibility of just doing QMS removal without texture with either KOH or TMAH (KOH may be advantageous for lower cost reasons). And instead of wet texture either use dry texture based on laser or plasma processing, or no texture and use other means to effectively couple-in broad-band sunlight—these “other” means may rely on dispersed nano-particles such as dielectric particles, or silver or gold particles.
   ii. If texturing is involved, a post texture surface cleaning process is a critical step for back junction/back contacted cell. This cleaning step enables formation of a high quality front-surface passivation layer following the cleaning process. A specific cleaning chemistry for this purpose may be based on HF/HCl chemistry and/or ozonated HF chemistry, although more expensive alternates such as the so-called RCA clean can also be used. Performing a diluted HF dip post texture clean and just before passivation is also critical to get lower front surface recombination velocities (hence, higher quality passivation). For the case of an organic backplane material such as prepreg or prepreg with an underlying additional adhesive layer and with a marginal integrity of the backplane during the texture and post texture clean processes, an additional process step prior to the deposition of the passivation layer or layers such as a-Si or a-SiOx (amorphous silicon oxide) plus Silicon nitride is disclosed which is to use a reduced pressure or atmospheric pressure plasma or a stream of radicals (such as hydrogen radicals and/or ions) to remove both organic residue redeposited from the backplane material as well as native oxide. Such processes may be preferably integrated in the initial stage of the passivation tool (such as the PECVD passivation) or alternatively be performed off-line.
c. Low temperature front surface passivation and ARC layer that meets the required device specifications. In general, this includes a passivation layer which is deposited at a temperature which can accommodate processing with the chosen backplane is adequate. The allowable maximum temperature of passivation is dependent on the ability of backplane to withstand this without cracking TFSS, without degradation of the backplane material, and/or compromising the solar cell fill factor and other reliability related parameters. A good passivation is expected at temperatures in the range at or above about 150° C. for PECVD SiN. One example is to use PECVD of thin amorphous silicon (deposited using PECVD at a substrate temperature in the range of about 150° C. to 200° C.) followed by a low temperature SiN deposition (preferably at the same temperature as amorphous silicon or amorphous silicon oxide). More generally, a good passivation must have a very low interface trap density with silicon and the polarity of charge which repels the minority carriers away from the front surface. For the n-type material, this embedded charge needs to be a stable positive charge. A subsequent thermal anneal either in a forming gas, a neutral, or vacuum or other suitable ambient at a suitable time after the passivation may be beneficial for improving the passivation quality. Such thermal anneal may be performed at a temperature equal to or higher than the PECVD passivation temperature (up to about 300° C. depending on the thermal stability and CTE-match of the backplane material).
d. Access to backplane metal and its busbars. The specifics of this depends on the type of the backplane. If the backplane is the kind (discussed above) which has integrated or embedded metal foil metallization then the choices are either a pre-made through hole (which would be covered during wet processing) or a wrap around bus bar opening (which would be covered during wet processing). For the backplanes where the backplane metallization is a final processing step, access is not an issue.
   FIG. 3 is a diagram showing for ex-situ emitter process flow embodiments in accordance with the disclosed subject matter. The process flows are divided into four categories Flow 1 through 4 which are distinguished by the differences in the way the base contact is made. All the flows shown in FIG. 3 may be used with either the template/porous silicon carrier 1 or with the bulk wafer Ingot/implant Carrier 1, and with any backplane option outlined in this disclosure.

### Flow Option 1:

This process flow uses APCVD PSG to make the base doping. PSG layer is deposited and phosphorus is driven in either using a batch furnace anneal or using pulsed nanosecond laser hot ablation of the PSG layer (in the latter case, to dope the underlying TFSS and to ablate the PSG layer for base contact opening).

### Flow Option 2:

This process uses screen printed (or stencil printed) silicon nanoparticle phosphorous or silicon nanoparticle phosphorous ink applied by inkjet (or aerosol jet) printing. This will be followed by a thermal anneal.

### Flow Option 3:

This option uses screen printing of the phosphorous paste or phosphorous ink applied by inkjet printing. This is followed by thermal anneal in a batch furnace equipment to drive in the dopant.

### Flow Option 4:

This process uses Phosphorous Oxychloride POCl3 as the starting phosphorous dopant material (process is preferably performed in a POCl3 tube furnace). It requires post diffusion phosphorus glass wet etch or HF vapor etch.

Sub-categories of the four flow option categories of FIG. 3 are detailed below.
Flow Option 1: APCVD PSG based base doping.

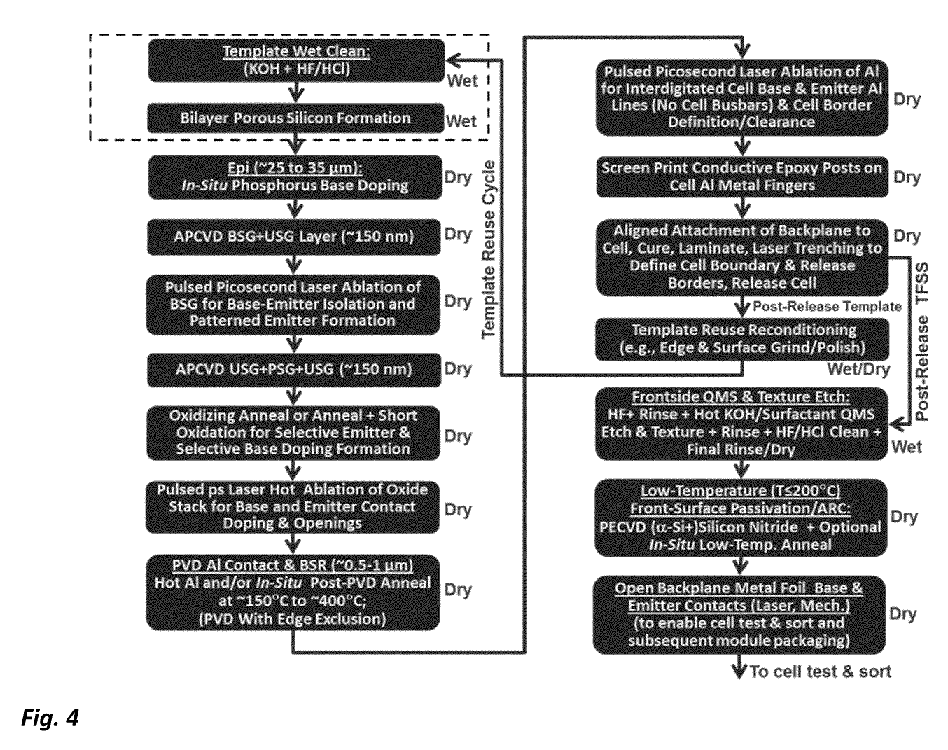

There are two sub-categories in this class: a) Hot ablation using pulsed ns laser processing to drive base and emitter contact using laser (and to concurrently open the base and emitter contact holes), b) Cold ablation (preferably using pulsed ps laser processing) where furnace anneal makes the base contact diffusion regions. FIG. 4 is a process flow using hot laser ablation (preferably using pulsed ns laser processing) with selective emitters for manufacturing thin back junction/back contacted solar cells with two carriers (corresponding to flow option 1A1 in FIG. 3). The process starts with cleaning of a mother template crystalline silicon wafer. In one example this could be a 200 mm diameter, 200 μm to 1.2 mm thick semiconductor standard wafer. In another example, this can be a 165 mm side full square, 200 μm to 1.2 mm thick crystalline silicon wafer. The template is cleaned using, for example, chemistries such as KOH, and acids such as HF, HCl or combinations thereof (HF/HCl), and/or a chemistry comprising ozonated HF. The cleaning can also be performed using any other chemical cleans known for cleaning metallic and organic impurities. Another example is RCA clean; however, RCA clean is more expensive for solar cell manufacturing purposes. The cleaning is followed by bilayer or multi-layer (at least two different porosities) porous silicon formation using electrochemical etching (preferably in HF/IPA). The first layer (or the top layer) formed is a low porosity layer (for example, this can be a layer with a porosity in the range of, but not limited to, 15-40%). This is followed by the second layer (buried layer) with a higher porosity (for example, this can be a layer with a porosity in the range of, but not limited to, 45-70% porosity) which is formed underneath so that it is closer to the template and separates the lower porosity layer from the template. Other configurations such as monolayer or trilayer or graded-porosity porous silicon are also possible, in general, as long as the layers facilitate several key requirements including: an excellent top epitaxial seed layer to enable formation of a good quality epitaxial silicon layer on top of the low porosity porous silicon layer, a reliable and high release yield due to on-demand breaking of the high porosity layer for TFSS lift-off separation from the template, and no premature release or bubbling of the TFSS from the template carrier during the on-template processing steps (preferably but not limited to the all-dry on-template processing steps after formation of TFSS till lift-off separation). The porous silicon formation process is followed by a drying step and then hydrogen pre-bake and epitaxial silicon growth, preferably in the thickness range of about 5 μm to about 50 μm. Both the hydrogen prebake and epitaxial growth process are preferably performed in the same An integral part of the growth process is the selection of the pre-bake condition. During the hydrogen pre-bake process step (preferably in-situ prebake in the epitaxial growth reactor), not only the pre-bake removes the native oxide and other potential surface contaminants, is also causes a reflow and solid phase diffusion of silicon such that the surface pores of the porous silicon seal at the surface of the low porosity layer (due to the driving force caused by reduction of the surface energy of low-porosity porous silicon), hence, producing an excellent epitaxial seed layer for subsequent epitaxial growth of a high quality TFSS layer. This, in turn, facilitates better epitaxial growth and formation of high-quality in-situ-doped TFSS layer with high minority carrier lifetimes. The epitaxial growth process is then followed by BSG deposition, preferably using an in-line atmospheric-pressure CVD (APCVD) reactor. The BSG layer ultimately serves as the boron source for forming the emitter regions by thermal diffusion of boron from BSG into the underlying TFSS using thermal anneal. Although, 150 nm thickness is shown in FIG. 4, this may be adjusted per requirements of the back mirror and emitter doping. In practice, the BSG thickness may be in the range of about 50 nm up to 250 nm and the BSG layer may be capped with an undoped layer of oxide (with an undoped glass thickness in the range of about 10 nm to 100 nm). The BSG layer deposition is followed by picoseconds (ps) pulsed laser ablation of the BSG layer, this laser ablation stops at silicon, thus does not damage the underlying silicon (negligible heat-affected zone compared to pulsed ns laser ablation). The ablated area ultimately becomes the base part of the device—where the emitter will not be diffused and the doped base contact regions will be exposed. Depending on the device design, this area fraction (fraction of base openings) can range from about 3% up to about 20% (corresponding to emitter area ratio in the approximate range of 80% to 97%). Larger emitter area fractions are preferred for higher cell efficiencies and this is enables through the use of pulsed ps laser processing. A very large opening, thus a large fraction of base results in minority carrier having to travel larger distances to get to the emitter. This results in more recombination dragging down the cell conversion efficiency (also known as electrical shading). The narrower size of the width of the opening is limited by being able to align and put base diffusion and contact areas inside this area. The laser ablation of the BSG isoptionally followed by APCVD of undoped silicate glass (USG), followed by PSG/USG, thus forming a trilayer. The underlying USG layer, depending on its thickness, controls the extent of phosphorous diffusion during anneal. A thicker USG layer will prevent phosphorous diffusion, and will result in a true separated junction (where emitter and base diffusion regions do not touch) with no back surface field (henceforth, BSF). A BSF layer can help increase the open circuit voltage of the device (Voc). If the underlying USG layer is thin (or not deposited at all), some phosphorous diffuses into the TFSS surface region during the thermal annealing step. This, in turn, results in both a BSF formation as well as a so-called abutted junction cell structure. The phosphorous and Boron concentrations, respectively in the PSG and BSG layers, are controlled to yield the appropriate doping concentrations the in emitter and the base regions. Depending on the cell design requirements, these dopant concentrations in the BSG and PSG layers may be in the range of about 2% up to 7%. After USG/PSG/USG is deposited (after the pulsed ps laser ablation direct patterning process), the device is then processed through a multi-functional furnace anneal step where there may be both an inert anneal in a nitrogen (or inert gas) ambient as well as an optional oxidizing anneal, optionally followed by a low-temperature in-situ gettering anneal (preferably performed in the temperature range of about 550° C. to 650° C. to getter metallic contaminants such as iron), optionally followed by a lower temperature in-situ forming gas anneal (in the temperature range of about 400° C. to 500° C.). The goal is to optimize the conditions of these in-situ anneal steps within the same multi-functional furnace anneal process recipe such that a good quality back surface oxide passivation, desirable phosphorus and boron dopant drive-ins and dopant activation, gettering of metallic impurities and further improvement of the backside passivation properties are accomplished in a single tool. It can also be advantageous to have a thin layer of aluminum oxide Al2O3 at the immediate back surface, as it tends to enable the incorporation of a negative charge, which in turn repels electrons, the emitter minority carriers, from that surface and is capable of providing very good surface passivations in that region. Such Al2O3 layer can be deposited in situ and as a first step in the same APCVD tool used for deposition of the BSG layer. Flows incorporating Al2O3 are disclosed later in this disclosure.

As shown in FIG. 4, the anneal step is followed by picosecond pulse laser ablation to open contacts (Other types of lasers such as pulsed ns lasers can also be used). However, a special laser ablation processes called hot laser ablation can be used which performs the dual role of not only opening the contacts to both emitter and base but at the same time rapidly driving in the respective dopants into TFSS silicon surface in the contact open area. Thus, base contacts are formed through the USG/PSG layer with phosphorous driven from PSG into silicon (where PSG is in contact with silicon), whereas, the emitter contacts are formed through USG/PSG/USG/BSG stack and Boron is driven in (from the BSG layer where it is in contact with silicon or separated from silicon only with an ultrathin layer of Al2O3). Hot ablation processing is able to create highly doped n+ and p+ contact areas under where the metal will eventually make contact with silicon (for base and emitter contact metallization). This is desirable for both decreasing contact resistance and for reducing recombination velocity at the metal contact. Thus, locally high dopant regions may be created, while maintaining lightly doped regions (dictated by the anneal) such as a more lightly doped emitter region (desirable for higher cell efficiency) under the passivation and away from the contact regions. This ensures an independent optimization of doping concentrations in regions close to the contact from regions away from contacts and enables effective formation of a selective emitter and base which in turn is beneficial for higher Voc, better infrared quantum efficiency, and higher overall cell efficiency

Laser hot ablation is followed in one embodiment for metal 1 by physical vapor deposition (PVD) based deposition of a thin aluminum or Al—Si layer (such as with plasma sputtering or evaporation). This aluminum (Al) layer serves the function of both back surface reflector (BSR) in conjunction with the backside passivation dielectric stack as well as is instrumental in making a good electrical contact to the device base and emitter regions. The contact resistance of Al (or Al doped with Si) PVD to both the doped emitter and the base contact regions is critical. The PVD process may also be done either as a hot PVD (depositing the Al layer while the cell substrate is heated to a temperature in the approximate range of 150° C. to 450° C., or a post PVD anneal may be performed between 150° C. to 450° C. if needed. This is to ensure better contact resistance (hence, higher fill factor) as well as take advantage of a better passivation in presence of Aluminum (Al anneal) and H2 from the APCVD layers (effectively performing a forming gas anneal to improve the backside passivation and to improve the cell Voc). Subsequently, other PVD metal layers may be deposited depending on the needs of the adhesion, reflectivity requirements and laser metal isolation requirements. In one rendition, combination of NiV (or Ni) and Sn can also be sputtered as second and third layers on top of Al using PVD and in situ after sputter deposition of Al. The function of this metal stack with a top layer of Sn will be to ensure that the adhesion of the backplane metal or M2 is not compromised (hence, improving the cell fill factor and long-term reliability). In a variation of this stack, the Al/NiV/Sn stack can be annealed below the melting point of Sn to give a solder like anneal between Sn and NiV. Subsequently, pulsed picoseconds laser is used to isolate and pattern both base and emitter metal areas. A typical design is interdigitated finger design. In a preferred embodiment, no busbars and only interdigitated fingers are defined on the cell for M1. This minimizes electrical shading under the busbar and increases cell efficiency. However, other embodiments with busbars as well as with other designs such as mini-cells can be defined with the metal ablation laser process. In general, the specific dimensions including pitch of emitter/base lines is dictated by several device design considerations including, but not limited to, base and emitter diffusion resistance. PVD could entail vacuum sputtering, vacuum evaporation, ion-beam deposition (IBD), atmospheric arc spray and other thermal physical vapor coating methods. In a different and less preferred embodiment, screen printing of resist, followed by etch can also be used to isolate base and emitter patterns. However, there is a risk in this approach due to performing wet processing on template (for metal etching and resist stripping wet steps).

In another variation of the metallization process, instead of using PVD metal (which includes vacuum techniques such as sputtering, evaporation etc), prevalent metal screen printed approach can be used. This approach has the advantage of not using vacuum process which tends to be both expensive as well as present the danger of dislodging the epi substrate prematurely from the mother template due to the delamination pressure from the porous silicon interface while the cells are in vacuum. In the metal screen printed embodiment, in general, a base and an emitter metal is screen printed (this may be a single screen print process using a single aluminum paste material) and fired to make metallization contact to the emitter and base diffusion regions, where the base and emitter diffusions are created using several possible techniques, one of which is described above and several others will be detailed subsequently. The rest of the process flow remains similar. The screen printed metal or metals can be either co-fired or sequentially fired, and may be the same for base and emitter or be dissimilar. Further, the screen printed metals may be fritted, lightly fritted, or frit-less (such as a suitable fritless aluminum paste). Specific examples of this process may entail screen printing a frit-less Al metal paste on both emitter and base and co-firing using the same process step. The M1 metal pattern will depend on the underlying cell design; however, in general, it can include segmented metal lines to reduce wafer level stress and to reduce the risk of microcrack formation in TFSS. Another example of this process could entail screen printing and firing Ag for the phosphorous contact, while screen printing and firing Al for the base contact. These screen printed lines or fingers can be continuous or segmented. In this rendition, if it is segmented on the base, the PSG may be deposited selectively in the base area, thus, creating pockets of base contact doping. Subsequently, the Ag metal may be fired through the doping sources (PSG in this case) to create contacts within the base pockets. This approach can have efficiency advantage by ensuring much smaller base contact minority carrier recombination, hence improving both Voc and Jsc of the solar cell. It also obviates the need for opening base contact using laser process. This segmented metal design is possible only because of the versatility of the backplane. The backplane allows a vertical draw of current while summing it at the backplane layer. In case there is difficulty in providing backplane level connection at the same tight pitch as the Ag metal segmentations (which may be dictated by other device constraints), a continuous metal can be screen printed (for example Al) on top of Ag segments at the same time that the emitter metal is printed. Care has to be taken to ensure that this metal (Al) does not penetrate through the PSG oxide which may be avoided using the right choice of the metal paste.

Although, not explicitly mentioned in the following sections dealing with other variations of the process flow, it is understood that the direct write metal screen printed option can be utilized in lieu of the PVD metal option for the subsequently discussed process flows as well.

In the specific embodiment shown in FIG. 4, the next step is to screen print conductive material (as an example, an epoxy material) on to the patterned metal lines on a cell. If necessary, a dielectric adhesive layer may also be printed to protect the cell from shunting. This is understood to be an option, if necessary, for all the process flows discussed subsequently that involve a conductive adhesive (although, not explicitly shown in the process flow Figures). This is followed by alignment, attachment and lamination of the backplane to the metal lines. In a separate embodiment, the screen print of the conductive and/or dielectric material may be performed on the backplane metal. Subsequently, the backplane assembly with the conductive material may be aligned and attached to the metal lines on the template. The advantage of printing conductive epoxy on the backplane is that there is no screen print step on the template, which ensures a complete contact free processing on the template and increases mechanical yield. The challenge is that the alignment becomes more stringent.

And although several types of backplanes were discussed in the earlier section, the two embodiments are detailed as follows:
a. Face to Face Bond: A thick interconnect stack, made with patterned Al foil of thickness preferably between 50 μm to 300 μm, helps conduct the electrical current laterally without much resistive losses. The conductive foil is attached to the backplane which may be either glass or plastic using a PV qualified, compliant encapsulant material, for example, but not limited to Z68. The Al foil, Z68, and the backplane material (for example glass or plastics) is referred to as the backplane assembly. The assembly is attached to the template using the aforementioned conductive epoxy such that the interdigitated pre-patterned foil pattern attaches face down on to the template. In the following two configurations the dimension of the Al foil patterns may be different. In the first configuration the Al foil lines are parallel to the patterned lines on the template. In the second configuration the backplane Al lines are orthogonal to the metal lines on the template. In orthogonal case, to avoid shorting of the emitter and base lines only alternate template metal lines make contact to the overrunning backplane foil lines in a checkerboard cross-points pattern. The orthogonal configuration may be advantageous as it allows the backplane lines or fingers (M2 fingers) to be wider and less in number, making its manufacturing manageable and also reduce its cost. The parallel lines have to conform to the pitch/dimensions of the on-template metal lines, which, in turn, are restricted by device design. In a thin cell case, this pitch is further limited because of a high sheet resistance of the base for a thin cell. Several precautions are suggested to ensure that there is no shorting between the orthogonal lines at the crossing junctions where no contacts to M1 are desired. This may be ensured by flowing the Z68 or another suitable dielectric encapsulant material under the Al foil during lamination. The flow can be enhanced if the Al foil is perforated. Another way to avoid the risk of shunting with the orthogonal configuration is to dummy print dielectric (non-conductive) posts in the negative checkerboard pattern. This ensures that at the cross-points, where the contacts are not desired, the over-running Al foils are supported by the non-conductive posts, and consequently, it does not sag to touch the on-template metal line.
   The current still needs to be drawn out to the top of the backplane from the face down side. Following are two general schemes for this: firstly, to wrap the Al foil around the edge of the backplane on to the other side (henceforth, Wrap-around Busbars). Risks with this scheme include difficulty in protecting the wrapped foil during some of the subsequent steps. In the second scheme, a few through holes are drilled and current is accessed at these locations from the underlying foil. Several ways to create these holes are disclosed herein.
b. A second configuration of the backplane does not have any Al foil. The backplane assembly consists of only the backplane material (most likely a polymeric or plastic material, or possibly glass) and Z68 or like material. A polymeric or plastic material sheet may be advantageous over rigid glass because it is easier/cheaper to drill more holes through it, and it also makes the resulting solar cells flexible or semi-flexible (hence, also enabling lower cost flexible module packaging of the cells). The challenge with polymeric or plastic backplane is that the subsequent steps with plastic may require capping the temperature to a lower values (for instance, no more than ˜150° C. up to 300° C.) as it has a higher CTE mismatch with silicon compared to glass (unless made with embedded low-CTE fibers or particles). The holes are drilled only through the backplane, but not through Z68. During subsequent wet and dry processing, the Z68 cover protects the underlying device. Finally, Z68 is opened and the module assembly is used to directly draw current from the underlying cell. This renders the cell cost to be dramatically cheaper, while requiring a somewhat more complex assembly process in the module.

Although, the process flow remains similar with either of the backplane embodiments discussed above, the Al foil configuration is detailed in the remaining process flows. Backplane assembly is attached to the cell/template (FIG. 4) and is laminated and cured. This is followed by a laser trench to define cell boundary and release boundary. Subsequently, a mechanical release is performed using available techniques such as mechanical release (MR) or sonicated mechanical release (SMR).

After release, the template is cleaned and send back for reuse for porous silicon and epi for the next Reuse. The TFSS attached to the backplane assembly (which is the second and the permanent carrier) is now cleaned on the QMS (or porous silicon) side and textured. In one specific embodiment, this may be performed in one shot using hot KOH based chemistries such as KOH/SCD or KOH/IPA combination (wherein KOH may be replaced with NaOH). This is followed by post texture clean which in one case can be done using HF/HCl combination. Subsequently, the TFSS is taken for its final process step on the sunny-side which is deposition of the (hydrogenated) SiNx ARC and passivation layer. Because of the presence of backplane assembly, the maximum temperature of this process is limited to a low value which may be in the range of 150° C. to 300° C. depending on the choice of the backplane material. A method by which a satisfactory passivation may be achieved at low temperature for back contacted cells is discussed in an earlier passivation. It suffices to mention that this will involve excellent cleaning post texture and deposition of a thin (e.g., 3 nm to 10 nm) amorphous silicon (a-Si) or amorphous silicon oxide layer before SiN. The SiN preferably has to be rich in positive charges to repel the positively charged minority carrier holes away from the surface and reduce surface recombination

The final step in the process flow of FIG. 4 is to open the access holes in the Z68 material through the already existing holes in the backplane. This is for vertically drawing out (or in) the emitter and base current from the Al foil. In one specific embodiment, the through-access holes in Z68 are created using hot solder material which burns through the Z68 material, making contact to the underlying Al foil. Subsequently, the solder can be used for module assembly. In another embodiment, the Z68 (or another suitable encapsulant) material can be exposed to a quick radiation (potentially IR), which pulls it back and opens the access point to Sn or solder alloy. In yet another configuration, the holes are drilled either only in Z68 or in both glass and Z68 at the end using laser. In yet another configuration, the holes are drilled through both Z68 and glass at the time of backplane assembly, but the underlying device is now protected through from the texture bath using the single sided texture tools or by a temporarily tagging Z68 on top of the holes.

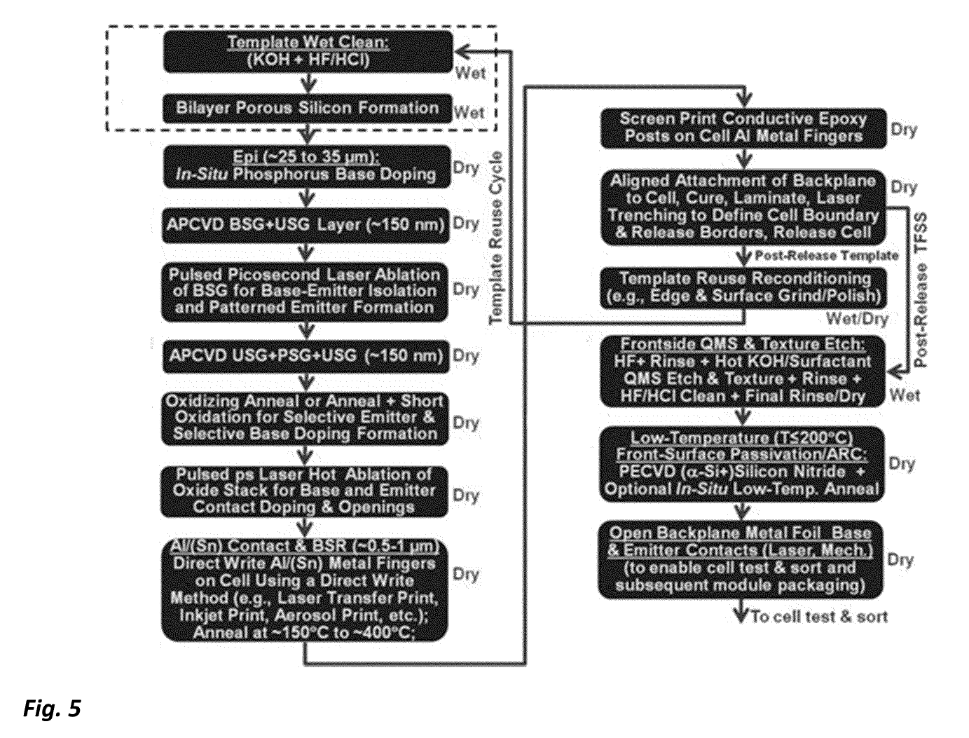

FIG. 5 is a representative selective emitter and hot ablation process flow of this invention similar to that depicted in FIG. 4 except using direct metal write techniques (corresponding to flow option 1A1 in FIG. 3). Direct write techniques can eliminate the need for the PVD metal deposition and the subsequent laser metal isolation steps. As a variation of the process flow shown in FIG. 4, the PVD metal deposition followed by laser metal isolation may be replaced by any of the numerous direct metal write techniques. These may include, but are not limited to screen printing of one or more metal pastes, inkjet/aerosol printing of one or more metal based inks and laser transfer printing. These direct metal write techniques may subsequently be followed by higher temperature anneals.

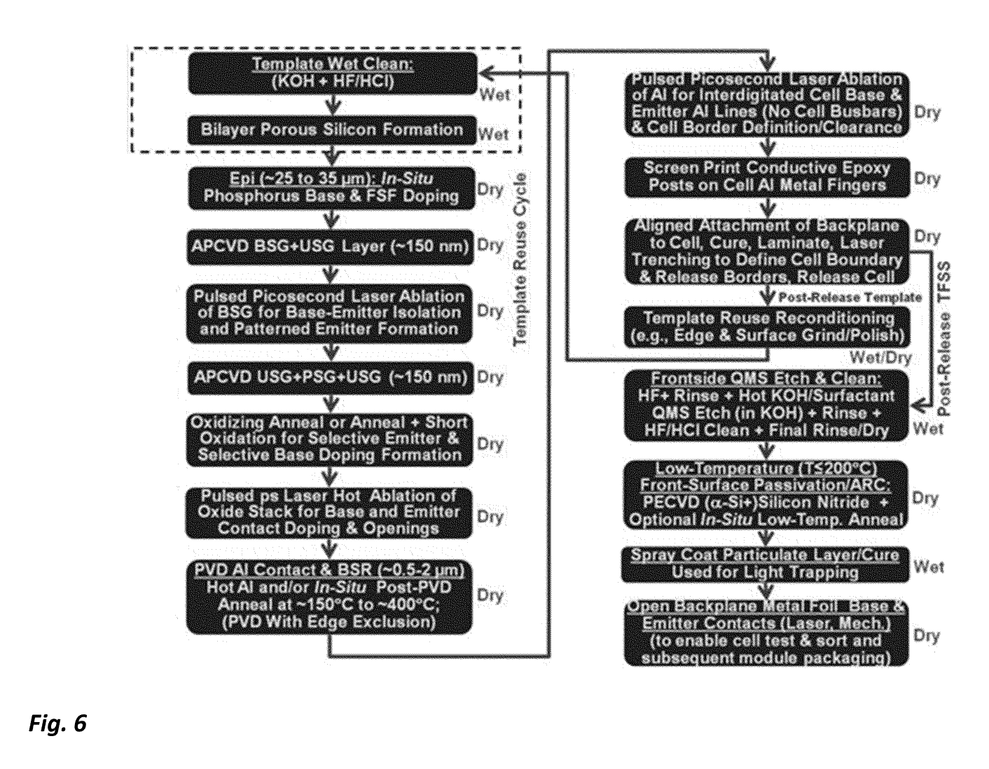

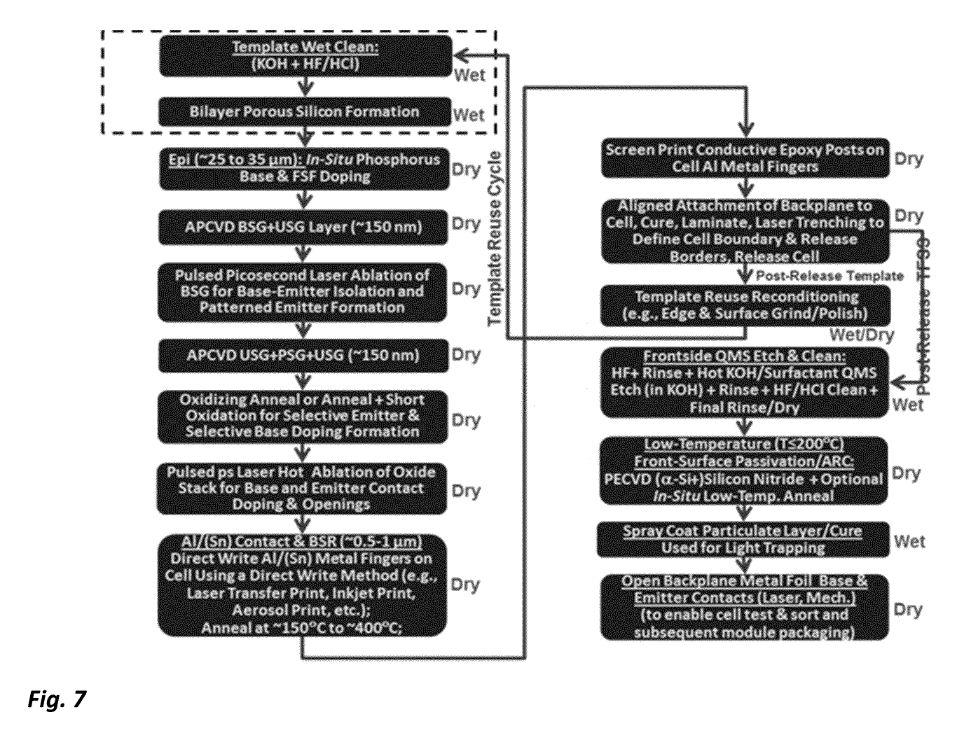

FIG. 6 and FIG. 7 are two selective emitter and hot ablation process flows paralleling FIG. 4 and FIG. 5, respectively, with a difference that the flows detailed in FIGS. 6 and 7 allows formation of an in-situ front surface field (FSF) during epitaxial silicon growth by eliminating texture on the front side. Thus, FIGS. 6 and 7 correspond to flow option 1A2 in FIG. 3. An advantage of the FSF is that it helps reduce base resistance, increase Voc by reducing the front surface recombination velocity (reduced FSRV). An idea behind this no texture flow is to protect the in-situ-doped front surface field. After doing QMS removal (small amount of silicon removal from the front), the flow moves directly to passivation without performing texture. The function of texture in terms or light trapping is accomplished by an additional subsequent step following the front passivation. These steps entail depositing, in one instance spray coating, a suitable dielectric or metallic particulate layer and curing.

FIG. 6 shows PVD metal stack deposition while FIG. 7 shows direct write metal techniques. FIG. 6 depicts the process flow with PVD metal deposition which has an in-situ front surface field achieved using a textureless process. Light trapping is achieved using particulate layer on the front side of the cell. FIG. 7 depicts direct metal write instead of the PVD metal plus laser isolation methods shown in FIG. 6.

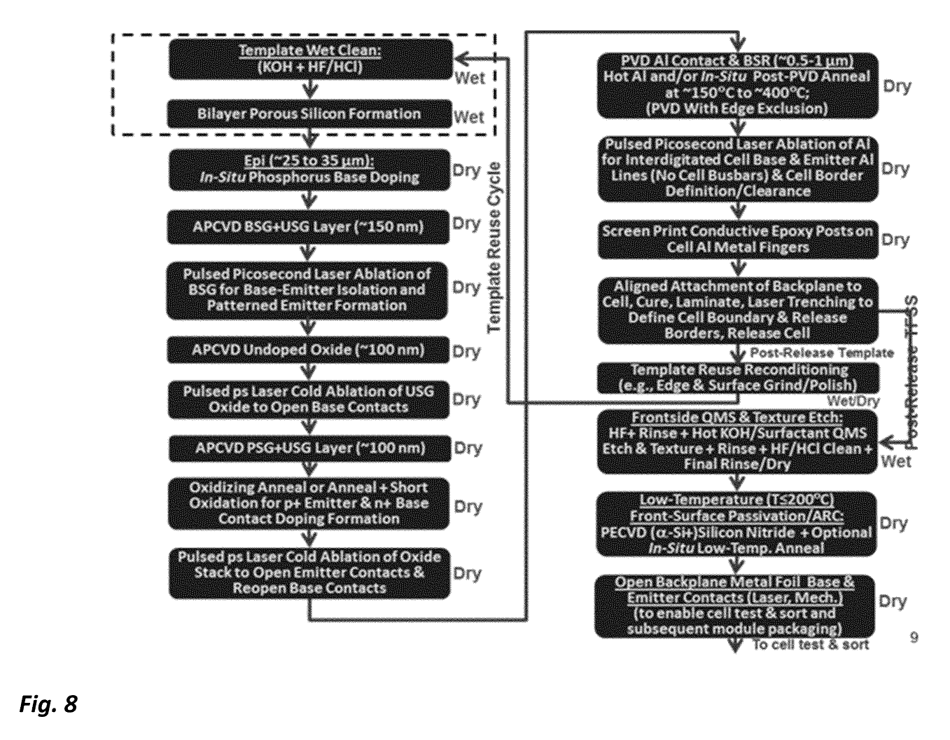

FIG. 8 is an embodiment of a process flow corresponding to flow option 1B in FIG. 3. This flow is similar to the flow outlined in FIG. 1 with variations discussed above, except for one difference—the flow in FIG. 8 uses cold ablation (preferably using pulsed ps laser) instead of hot ablation. The backend steps are similar to Flow Option 1A in FIG. 4 with a few modifications of the initial on-template steps. The process of cold ablation may modify a few steps on the template. As shown, the flow is identical up to laser ablation of the BSG layer to isolate emitter and base diffusion areas. This laser step is followed by deposition of APCVD USG layer only instead of a USG/PSG/(USG) stack (as may be used in the case of hot ablation process). Subsequently, USG layer is ablated using laser ablation process to create phosphorous doping opening. This is followed by the PSG/USG (with USG cap on top of PSG) stack deposition. Now, the thermal oxidizing anneal and drive is performed. This ensures the formation of the emitter junction, formation of the base doping in silicon, and back surface passivation with thermal oxide. The next step is to open emitter and base contacts using cold pulsed ps laser ablation. A difference from hot ablation is that in the case of cold pulsed ps laser ablation the laser does not have the concurrent burden of driving the dopant in (this has already been done for both base and emitter using high temperature anneal). The laser only opens contacts and stops at silicon with negligible damage to silicon. Although cold laser ablation may be considered an easier manufacturing process, hot ablation holds at least two advantages. First, it reduces the number of steps by two which can provide cost savings. Second, it requires only aligning the base contact to the emitter/base isolation area while the cold ablation requires aligning first the USG open area to the emitter/base isolation area and then aligning the base contact to the USG open area. For a given alignment capability and contact sizes, cold ablation will require starting with wider emitter/base isolation area. Subsequent process steps shown in the flow FIG. 8 are similar to the flows previously depicted.

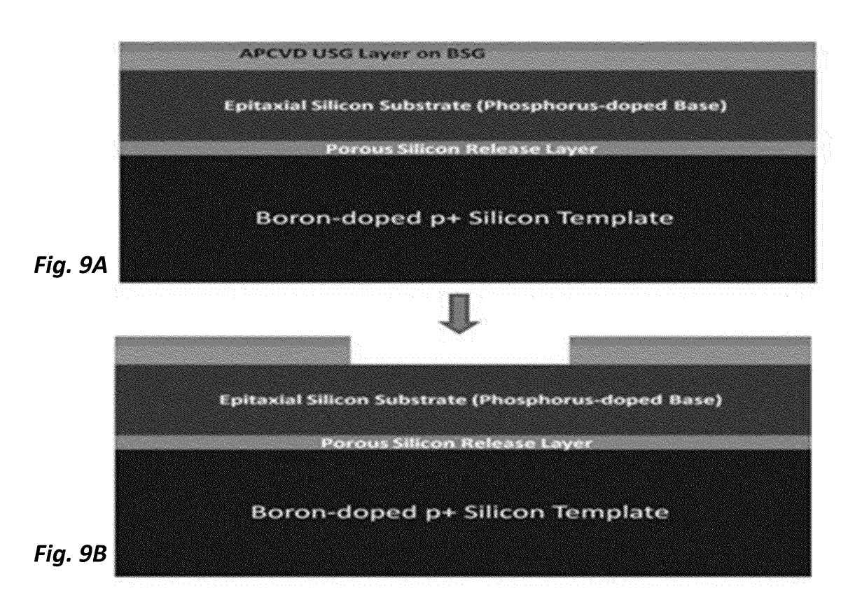

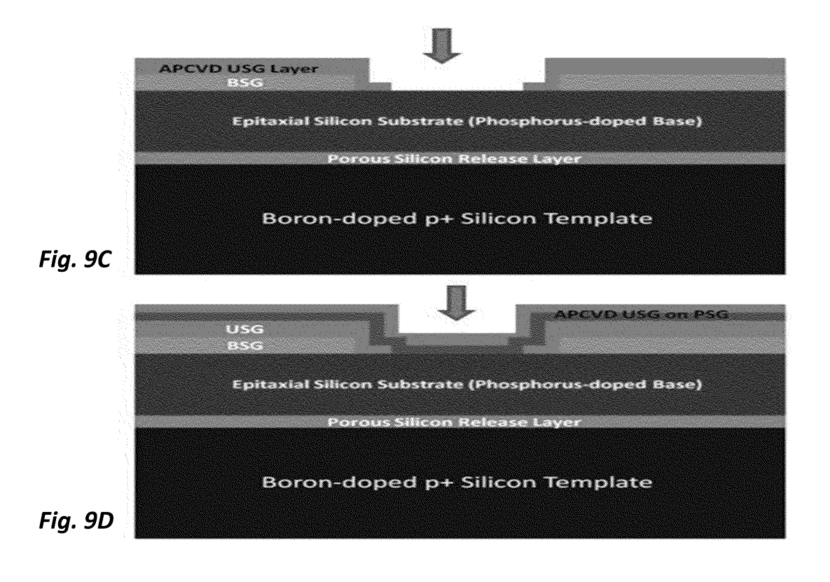

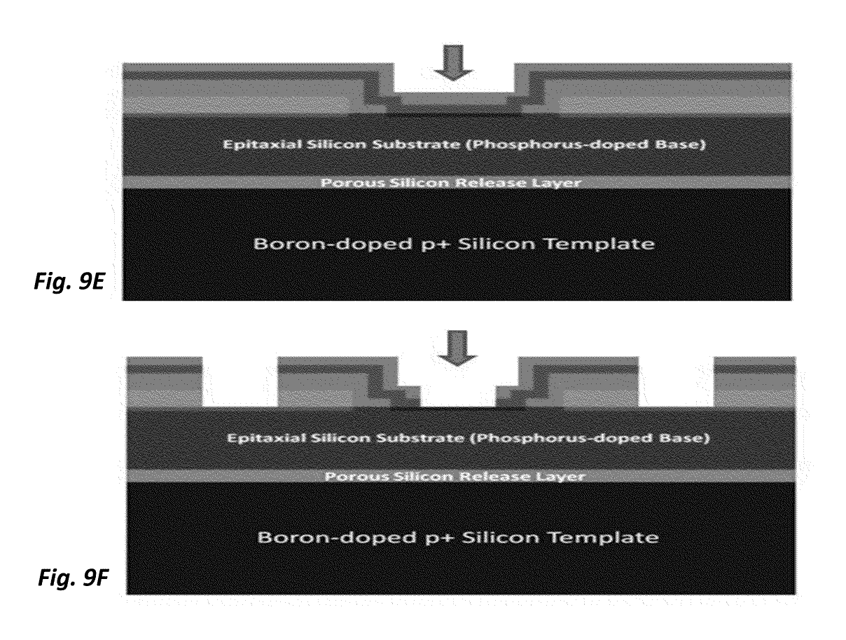

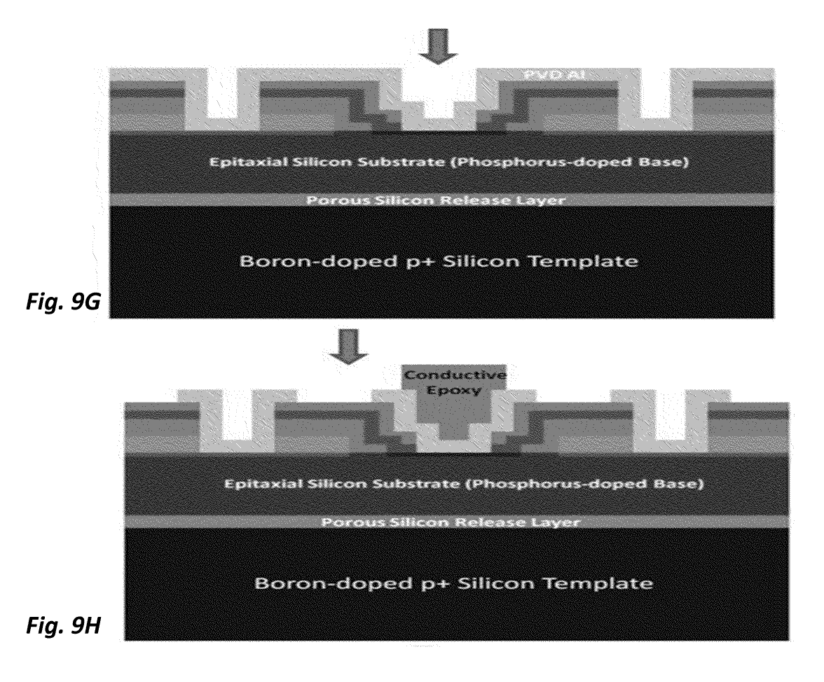

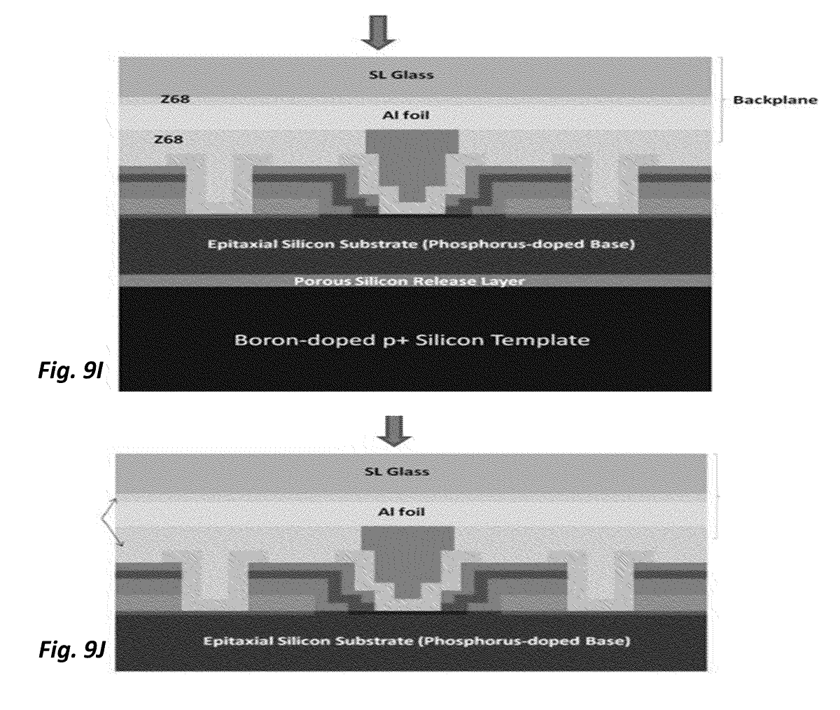

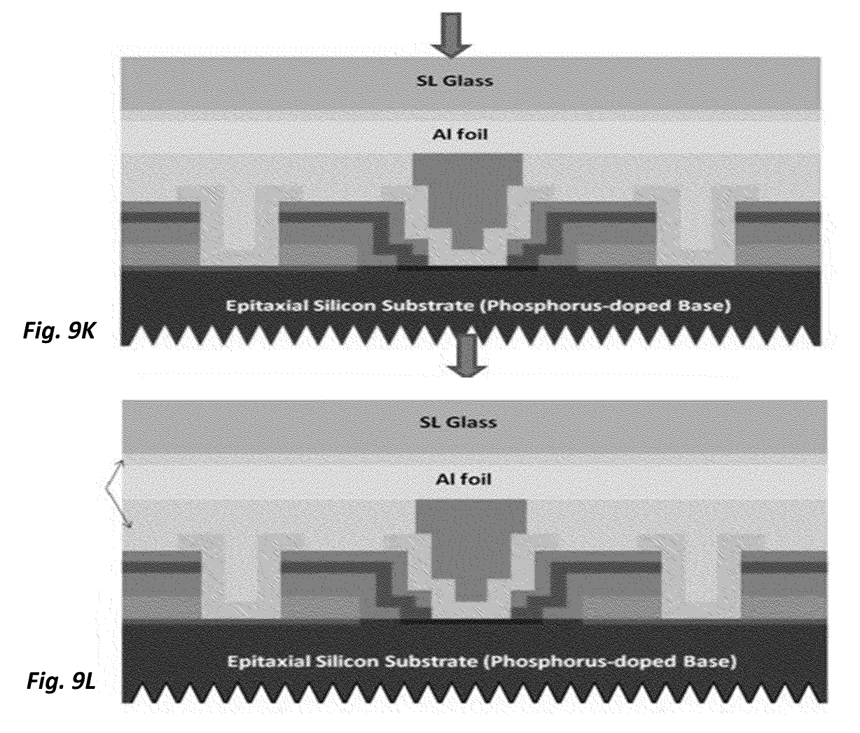

FIGS. 9A-L are cross-sectional diagrams depicting major fabrication steps of the cold ablation flow of FIG. 8. (corresponding to flow option 1B in FIG. 3). FIG. 9A shows the USG/BSG (with USG can on top of BSG) deposition steps, FIG. 9B shows the USG/BSG laser ablate steps, FIG. 9C shows the USG deposition steps, FIG. 9D shows the USG/PSG/(USG) deposition steps, FIG. 9E shows the oxidizing anneal/dopant drive-in deposition steps, FIG. 9F shows the laser cold ablate and contact open steps, FIG. 9G shows the PVD Al (or Al/NiV/Sn or another suitable stack comprising an underlayer of Al and an overlayer of a suitable solder alloy) deposition steps, FIG. 9H shows the laser metal ablate plus epoxy print steps, FIG. 9I shows the backplane attachment steps, FIG. 9J shows the cell/template release steps, FIG. 9K shows the QMS (remnant of porous silicon residues on the TFSS) removal and texturing steps, and FIG. 9L shows the low temperature front surface passivation steps.

### FIG. 3 Flow Option 2: Silicon Nanoparticle Phosphorous Based Base Doping.

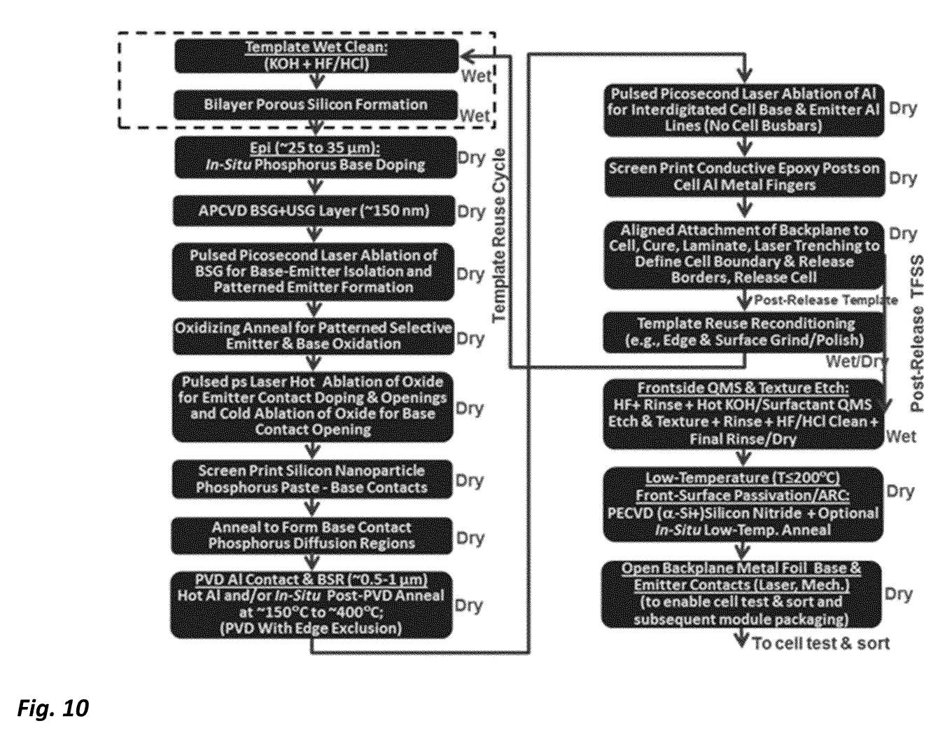

FIG. 10 outlines a process flow for silicon nanoparticle phosphorous based base doping (paste or ink). The backend of the process flow starting with Al PVD as well as the front end of the flow consisting of template clean/porous silicon/epi/APCVD BSG/USG depositions, and laser ablation of BSG stack are previously disclosed, see FIG. 4 and FIG. 8. Of the three described sub-variations of flow option 2 (options 2A, 2B, and 2C), option 2A and 2B use hot ablation and option 2C uses cold ablation. FIGS. 10, 11, and 12 depict the entire process flow for option 2A, 2B, and 2C of FIG. 3, respectively.

FIG. 10 representing option 2A shows that post BSG laser ablation, an oxidizing anneal is performed in a thermal furnace anneal tool. This is a multi-functional process and has at least a dual purpose of forming the emitter by driving boron from BSG into silicon as well as forming a thermal oxide layer in the area where BSG was ablated which serves as a passivation for what will ultimately become the base region. This is followed by hot laser ablation of the emitter area to form selective emitter similar to the process described in flow option 1A. At the same time cold ablation is used in the base area to open oxide for base doping contact. Subsequently, silicon nanoparticle based phosphorous paste is screen printed or is dispensed using other ways such as injecting, in the base contact open areas. Subsequently, the paste is annealed to drive the base doping. This is followed by identical process flow to option 1 (along with all its variations) starting at PVD Al.

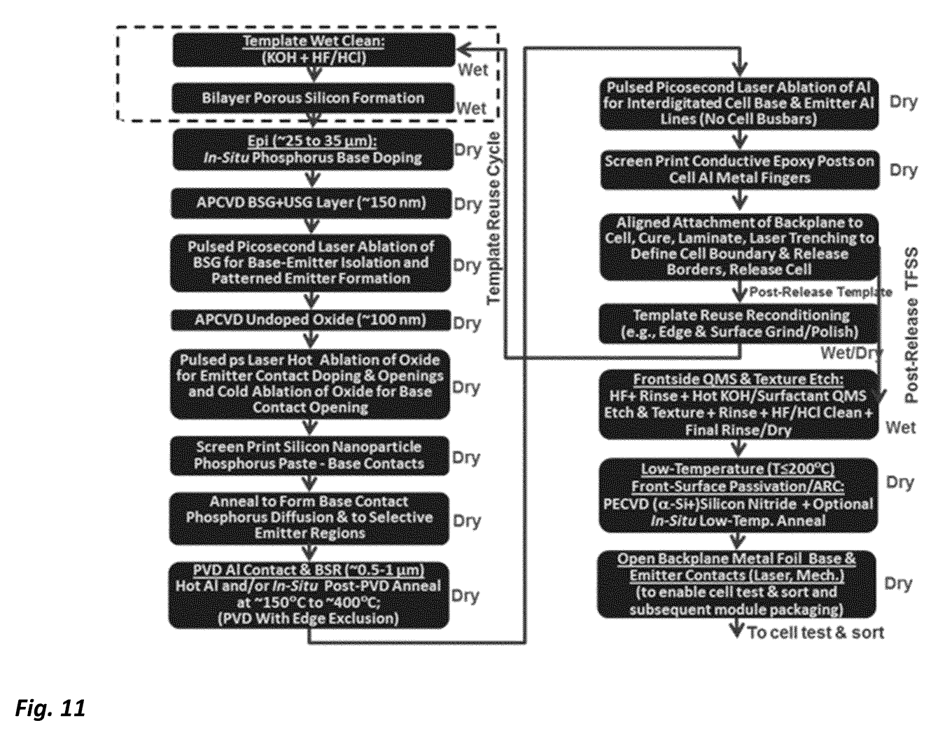

FIG. 11 shows flow option 2B with hot ablation and silicon nanoparticle phosphorous paste or ink using two APCVD tools. In option 2B (FIG. 11), post BSG laser ablation, APCVD is used to deposit USG (instead of thermal oxide in option 2A). This is followed by hot ablation of the emitter and cold ablation of USG for base contact open. Subsequently, screen printing or inkjetting of phosphorous based silicon nanoparticles (paste or ink) is performed. This is followed by a thermal anneal to form base contact as well as the selective emitter. Subsequent processing may be identical with variations to flow option 1.

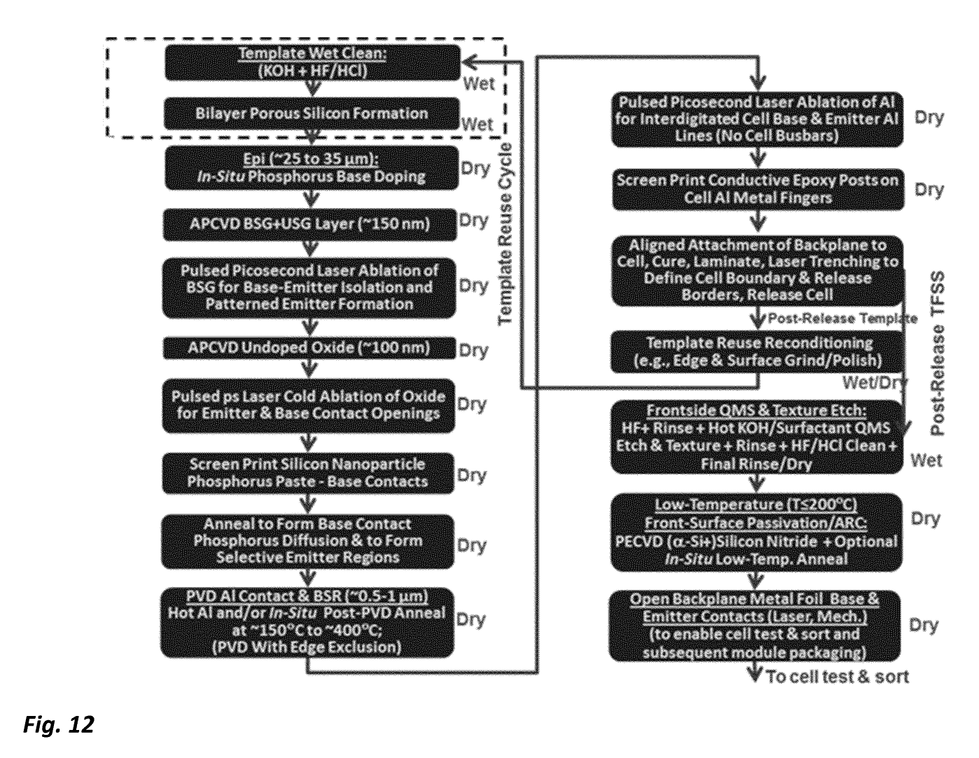

Option 2C (FIG. 12) is the cold ablation flow. FIG. 12 shows flow option 2C with cold ablation with silicon nanoparticle paste for phosphorous doping. Here, post BSG laser ablation, APCVD is used to deposit USG just as in option 2B. However, this is followed by base and emitter contact open using cold ablation. Subsequently, nanoparticle phosphorous paste is applied in the base area (again by either screen printing of a paste or inkjet printing of an ink) and is annealed. The annealing action drives the emitter and forms the base doping area. Subsequent processing may be similar to that previously disclosed.

Note that, in all the options with silicon nanoparticles (flow option 2 in FIG. 3), since the paste is silicon nanoparticle based there is no need to open the base contact again after the paste is applied. Hence, the metal may be put down directly on this cured paste. And if needed, the flow can be modified to accommodate opening the area before putting PVD Al.

### Flow Option 3 of FIG. 3: Phosphorous Paste Based Base Doping.

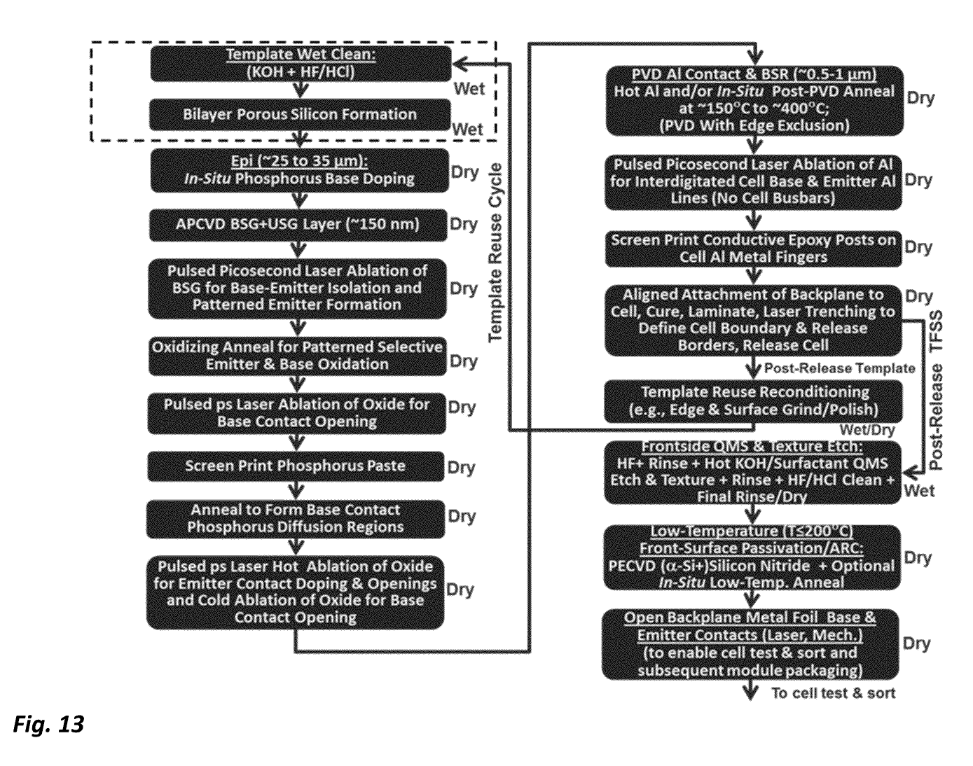

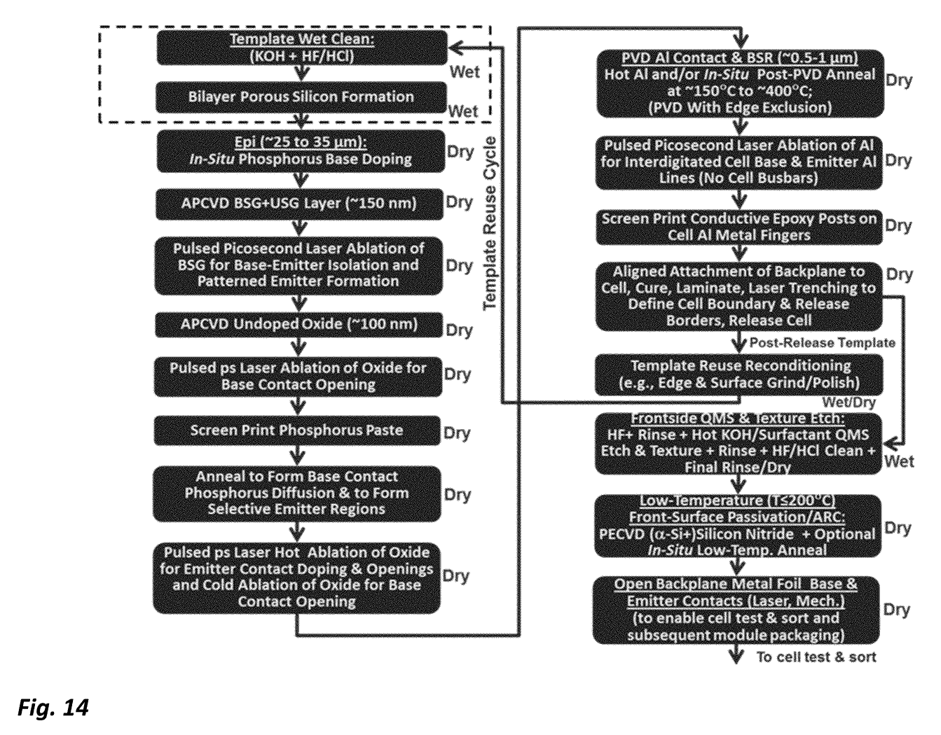

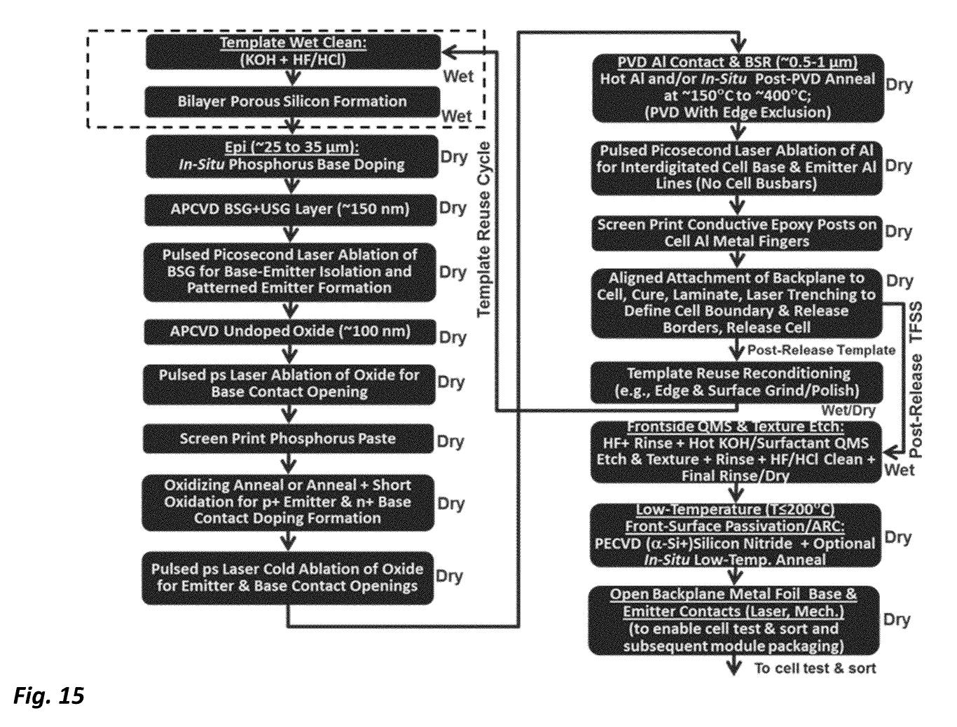

Here the difference compared to previous flows is that the base contact is formed using the commercially available phosphorous pastes. All process steps before up to laser ablation of BSG stack and after and including Al PVD may remain the same as option 1. There are three phosphorous paste based base doping variations shown, in FIGS. 13, 14, and 15 corresponding to flow options 3A, 3B, and 3C of FIG. 3 respectively. In many ways these three sub options mirror the three sub-options for the nanoparticle paste previously discussed with minor differences. FIG. 13 (flow option 3A) and FIG. 14 (flow option 3B) use hot ablation while FIG. 15 (option 3C) is cold ablation process. Additionally, as shown FIG. 13 (flow option 3A) uses one APCVD, while FIG. 14 (flow option 3B) and FIG. 15 (option 3C) use two APCVD tools.

In option 3A (FIG. 13), post BSG ablation there is an oxidizing anneal for emitter formation as well as for base area passivation using thermal oxide—similar to flow option 2A. Subsequently, laser ablation is used to open only base contacts with cold ablation—different from flow option 2A. This step is followed by screen printing (or any other way of dispensing phosphorous paste for direct write, such as inkjet printing), followed by an annealing to drive the base contact phosphorous diffusion regions. Subsequently, hot ablation of the emitter and cold ablation of base area is performed to make selective emitter and base contacts. All steps following this starting from PVD Al are previously disclosed.

Option 3B (FIG. 14) has APCVD USG deposition after BSG ablation, followed by pulsed ps laser (or pulsed fs laser which can be used instead of pulsed ps laser whenever cold ablation is required in any of the process flows of this invention) cold laser ablation of USG to open base contacts. Just as in option 3A, this is followed by screen printing of phosphorous paste and drive and anneal of phosphorous base contact as well as emitter areas. This is followed by hot ablation of emitter and cold ablation of the base to reopen the contact in the base through the phosphorous paste. All steps starting Al PVD following this are previously disclosed.

Option 3C (FIG. 15) uses APCVD USG after BSG ablation. This is followed by ablation of USG for base opening, followed by screen printing of phosphorous paste, followed by an oxidizing anneal and/or anneal to form emitter, base doping, as well as a passivation. This is followed by cold ablation of emitter and base areas to open contacts. Subsequently, starting Al PVD all steps are previously disclosed.

### Flow Option 4: POCl3 Based Base Doping.

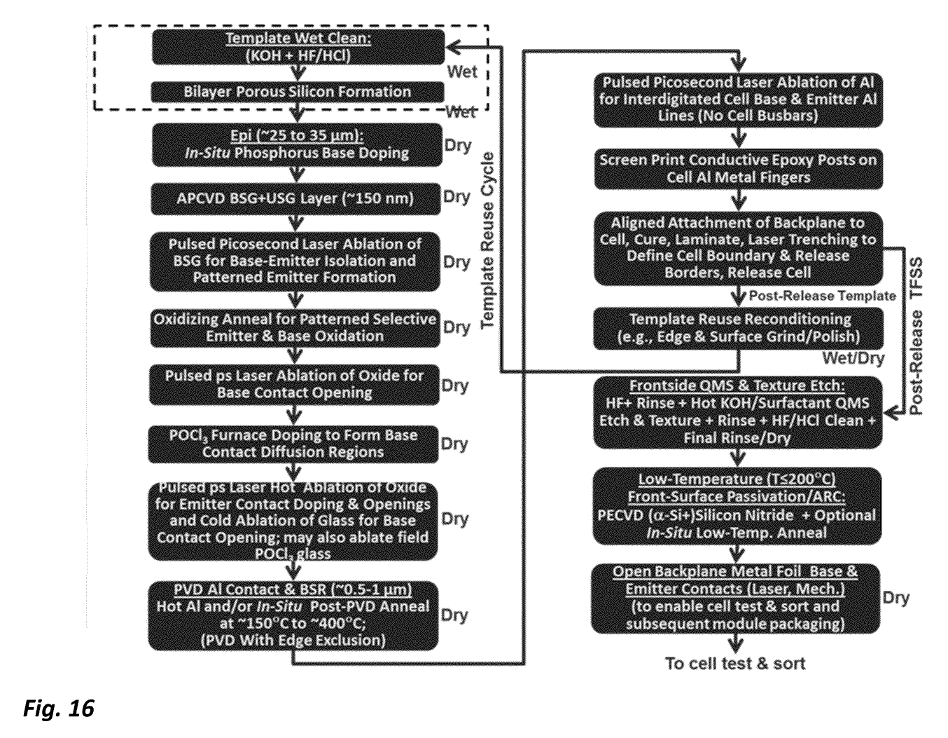

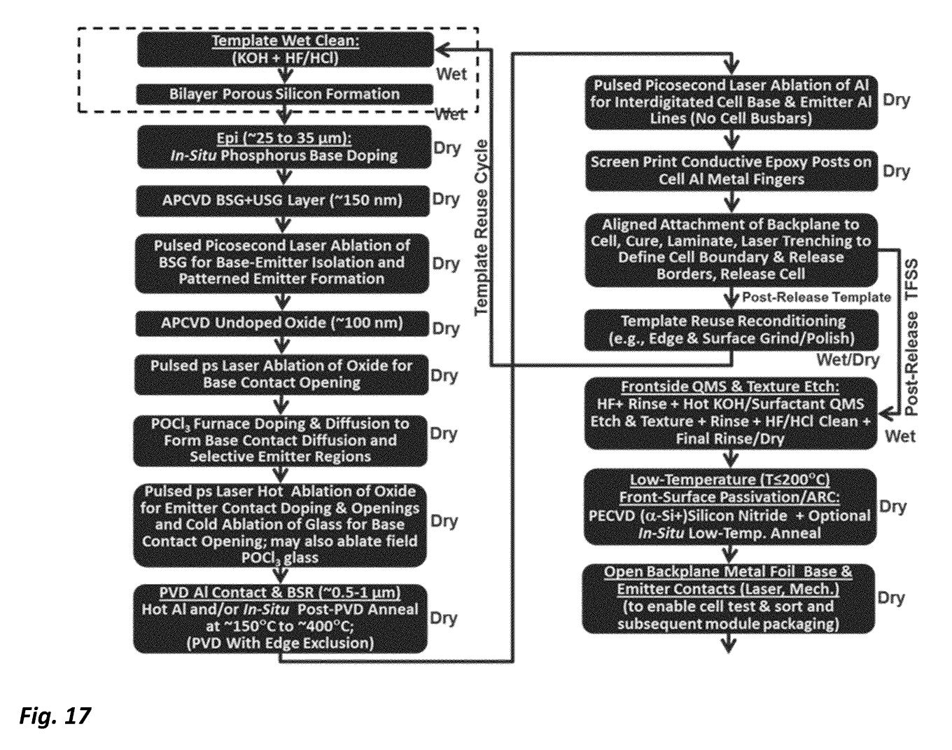

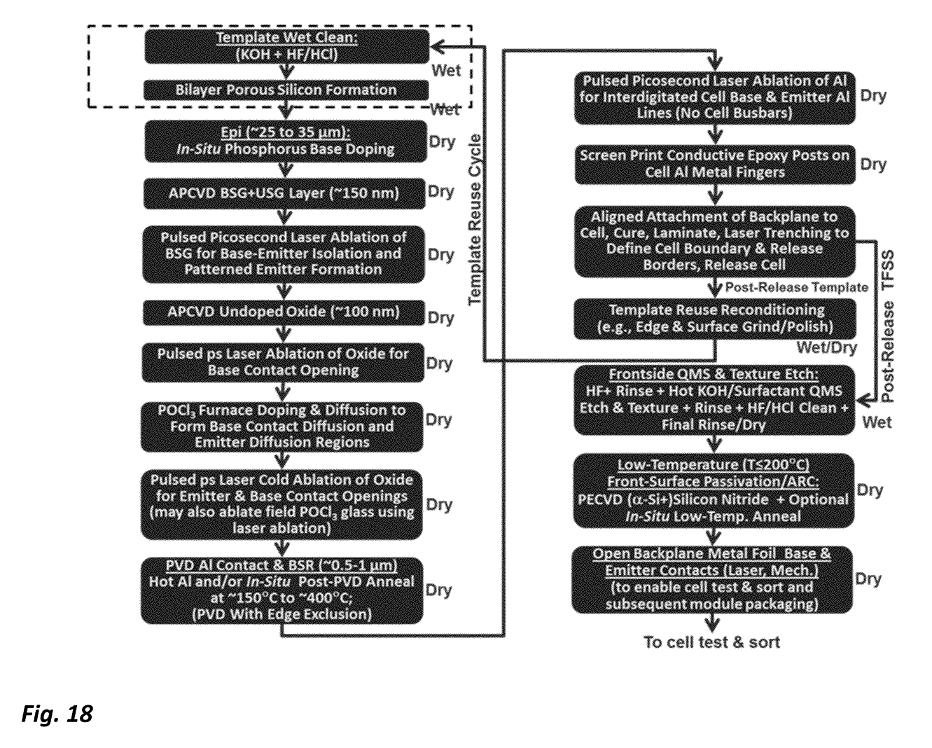

FIGS. 16, 17, and 18 are a set of flows using furnace POCl3 (phosphorus oxychloride) doping for base doping. As shown, all steps up to including BSG laser ablation as well as all steps post and including Al PVD may be the same as previously disclosed. There are three POCl3 based base doping variations shown, in FIGS. 16, 17, and 18 corresponding to flow options 4A, 4B, and 4C of FIG. 3 respectively. FIG. 16 (flow option 4A) and FIG. 17 (flow option 4B) use hot ablation while FIG. 18 (option 4C) is cold ablation process. Additionally, as shown FIG. 16 (flow option 3A) uses one APCVD, while FIG. 17 (flow option 3B) and FIG. 18 (option 3C) use two APCVD tools.

In option 4A (FIG. 16), laser ablation of BSG stack is followed by an oxidizing anneal in a batch furnace which drives the emitter at the same time and forms a passivating thermal oxide in the base region. This is followed by cold ablation of thermal oxide for base contact open which is followed by POCl3 furnace doping to form base contact diffusion regions. Subsequently, hot ablation is used for emitter contact open, and cold ablation to go through the POCl3-formed glass in the base area. It is also conceivable that the laser is used to ablate all POCl3-formed glass, which may be desirable from the back mirror perspective. This is followed by Al PVD as previously disclosed.

In option 4B (FIG. 17), APCVD oxide is deposited instead of thermal oxide anneal. This is followed by cold laser ablation of USG material to form base contacts. This is followed by POCl3 doping, which takes care of both forming base diffusions as well as driving the emitter regions into silicon. Subsequently, hot ablation is used for emitter contact opening and drive to form selective emitter, where cold ablation is used to go through the POCl3 glass material and open base contacts. This is followed by the standard process starting at PVD Al.

In option 4C (FIG. 18), instead of thermal oxide, APCVD of USG is used to create blocking of POCl3. This is followed by cold ablation of USG for base contact open and POCl3 process. The POCl3 process not only forms base contacts, but also simultaneously diffuses the emitter. This is followed by a cold ablation of both emitter and base contact opens. The remaining process flow remains as before.

Minimum cell process flow. This section describes a variation of the process flows described as option 1 above (using PSG for making base contact). In this variation, several steps are combined and the CE print step is eliminated to use a reduced number of tools for creating the high-efficiency, back contact thin cell. A defining attribute of these minimum steps flows is that the screen printing of conductive epoxy is eliminated by using a low-temperature solder alloy (e.g., 58% Bi-42% Sn with 138° C. solder melting point, or Bi-45% Sn-0.33% Ag with a melting point of 140-145° C.), formed both as an overlayer on top of the cell Al metal/mirror as well as on the backplane metal fingers with a pre-formed pin grid array on the metal fingers. Once the backplane is aligned and placed on the cell, the backplane pin grid array is solder attached to the cell during the thermal lamination process.

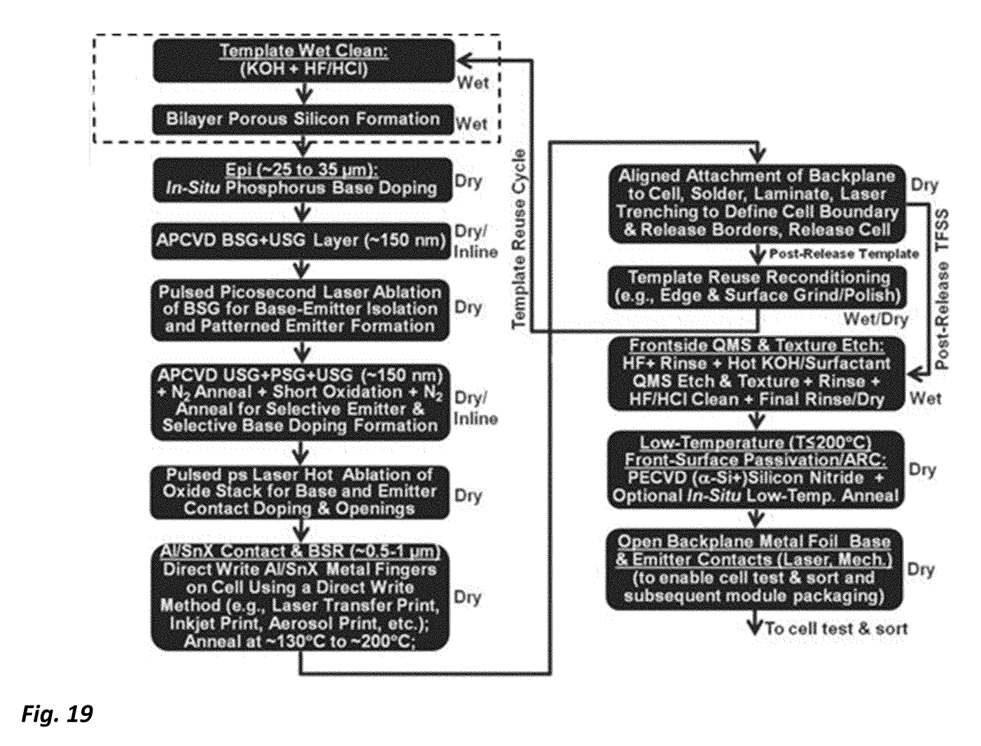

FIG. 19, a hot ablation direct writing process, depicts a first embodiment of a minimum steps process flow with the following noted attributes: two APCVD process steps used, has a texturing process, uses PSG and hot ablation to form base diffusion, selective emitter formed using laser, has a direct metal write process such as screen print, inkjet, aerosol print, laser transfer print, and direct solder bonding without CE screen print.

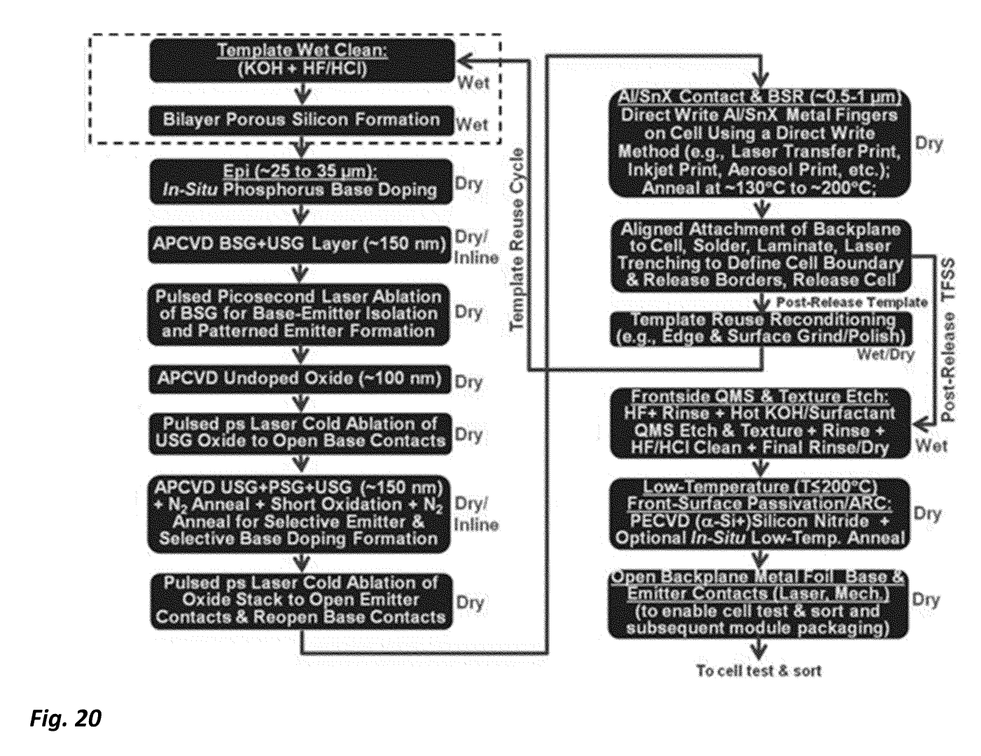

FIG. 20, a cold ablation direct writing process, depicts a second embodiment of the minimum process flow. It retains the common attributes of FIG. 19 of solder attachment as well as direct metal write to eliminate a few process steps. However, it differs from the FIG. 19 flow in that it does not rely on hot ablation and has three APCVD steps.

Non Epi Bulk Thin Substrate Process Flows.

Previously, two types of carrier 1 examples were disclosed. The first type of carrier 1 uses a template and the second type of carrier 1 is a thicker wafer or ingot from which thin CZ or FZ slices are cleaved or exfoliated using a myriad of available techniques, including hydrogen ion implantation. The following section describes the cell level process flows utilizing backplane innovation in conjunction with the wafer cleaving approach to obtain a thin silicon substrate. Proton implant based cleaving produces <111> textured substrates, which would preferably require dry texturing. The embodiments show proton implant cleavage/slicing of ultrathin substrates (e.g., about 1 μm to 80 μm thick substrates separated/cleaved from much thicker reusable wafers, e.g., wafers or bricks which are several mm or several cm thick).

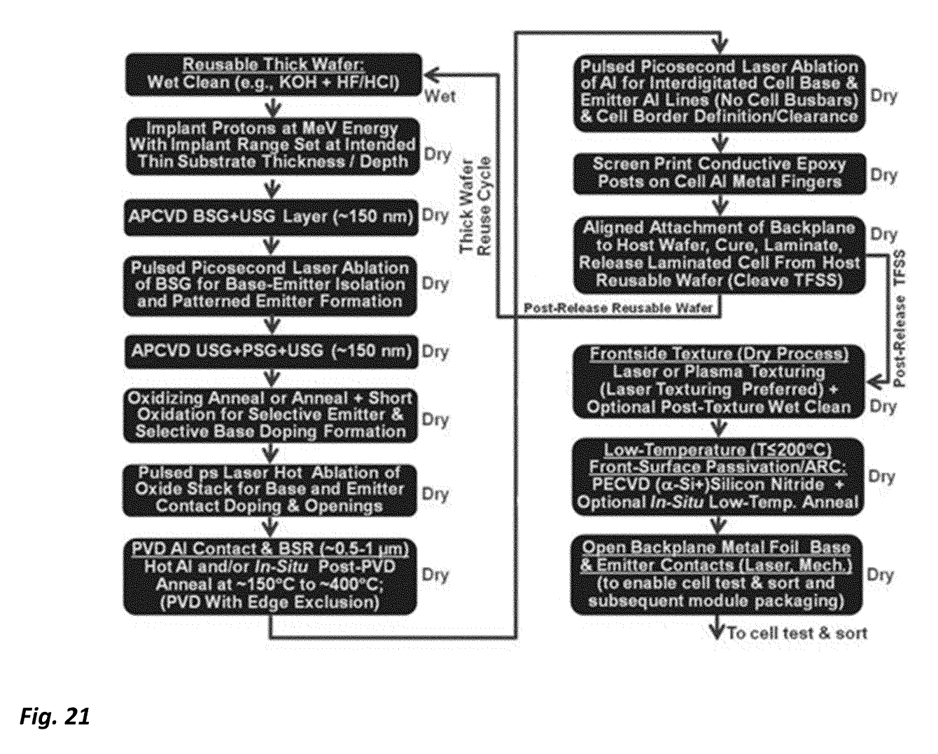

FIG. 21 shows the first process flow using a wafer cleaving approach to obtain a thin silicon substrate. The process flow parallels the flow 1A1 described in FIG. 4 (which uses a reusable template for carrier 1) except for the initial steps which are used to create the substrate. The specific attributes of this flow are: uses two APCVD processes (base contact diffusion formed using APCVD PSG and hot laser ablation), cell front-surface texturing which may be performed on planar or pre-textured templates with or without in-situ Front-Surface Field (FSF) phosphorus doping, metal deposition which may be performed using vacuum sputtering, vacuum evaporation, atmospheric arc/thermal spray coating, etc. The first step is to start with a reusable, thick wafer.

In FIG. 21, first the wafer is implanted with MeV proton implants, with the implant energy setting the substrate thickness. Following this step of substrate creation, the steps shown are similar to the flow shown in FIG. 4 until the backplane attachment step. After backplane attachment the wafer is released from the thick wafer from the cleave created by the implant. This is followed by a dry texturing process, which may be performed either using the laser or a dry plasma process, since it is a <111> surface. An optional post texture clean may subsequently be performed—previous embodiments using a reusable template did not necessarily require a dry texture process also. As shown in FIG. 21, after dry texturing passivation and backplane access steps are performed.

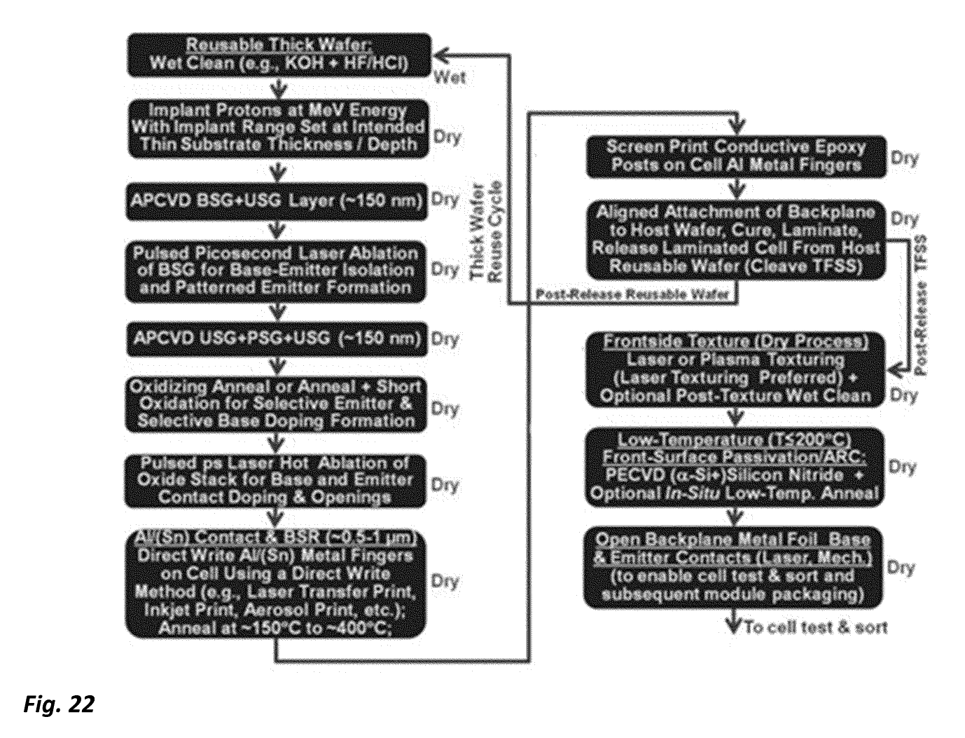

FIGS. 22 through 35 show several variations and examples of the process flow outlined in FIG. 21 for back contact thin crystalline solar cells using proton implanted and cleaved thin silicon cells. The variations mirror similar flows described using the Reusable PS/Epitaxial TFSS on template process flows. Four categories of process flows are similar to the flow options in FIG. 3—these four categories are distinguished from each other on the bases of the method used to create the base diffusion area. The first category, including the flow of FIG. 21, uses PSG layer to create the base diffusion areas; the second category uses silicon nano particles; the third category uses phosphorous paste; and the forth category uses POCl process to create base diffusion regions.

FIGS. 22 through 26 show flows belonging to the PSG based doping category. Each of these process flows may be characterized by the following attributes listed directly thereafter.

FIG. 22 corresponds to flow option 1A1 of FIG. 3, and may be characterized by the following attributes:
Thin substrate formed by slicing/cleaving from reusable thick wafer or brick or ingot piece (e.g., after MeV proton implant); the thin substrates are typically (111) oriented substrates (to facilitate cleavage with reasonable proton implantation doses), requiring dry laser or plasma texturing
Includes selective emitter without added process steps (using hot ablation process)
Uses two APCVD processes
Base contact diffusion formed using APCVD PSG & hot laser ablation
Includes cell front-surface texturing
May be performed on planar or pre-textured templates with or without in-situ Front-Surface Field (FSF) phosphorus doping
Same as flow 1A1 but with direct write process for interdigitated cell metal (e.g., Al or Al/Sn or Al/NiV/Sn) fingers
Metal deposition may be performed using a direct write process such as screen printing, laser transfer printing, inkjet printing, aerosol printing.

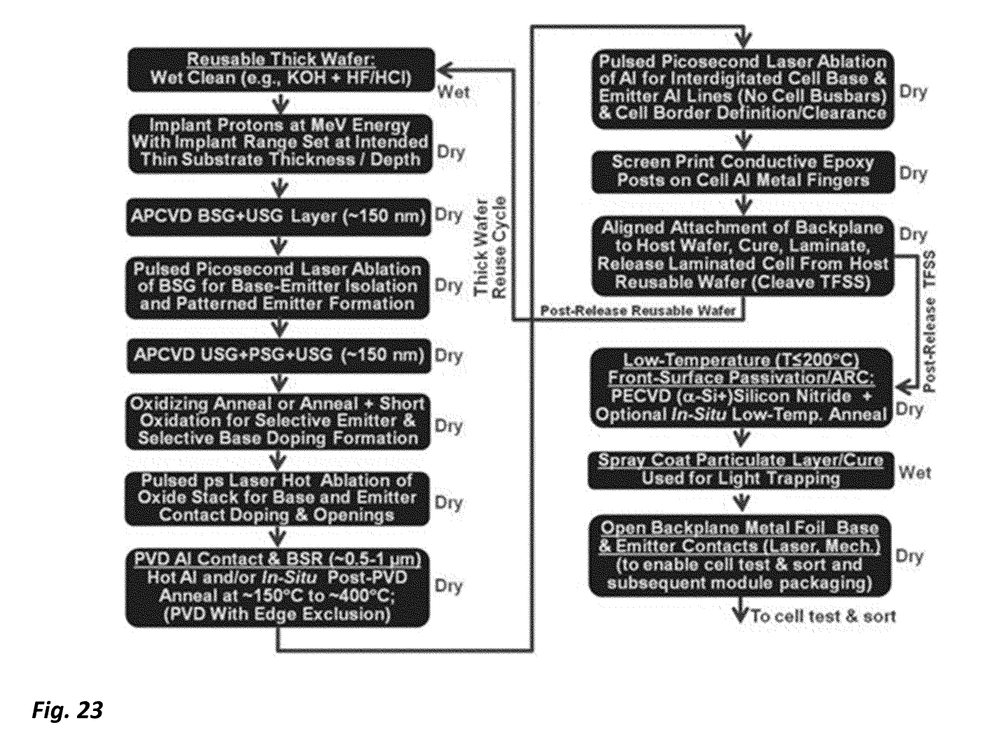

FIG. 23 corresponds to flow option 1A2 of FIG. 3, and may be characterized by the following attributes:
Thin substrate formed by slicing/cleaving from reusable thick wafer or ingot piece (e.g., after MeV proton implant); the thin substrates are typically (111) oriented substrates, requiring dry laser or plasma texturing
Includes selective emitter without added process steps (using hot ablation process)
Uses two APCVD processes
Base contact diffusion formed using APCVD PSG and hot laser ablation
No cell front-surface texturing (textureless)—instead light trapping is assisted by coating a particulate light trapping layer (such as a dielectric or metallic particulate)
Includes Front-Surface Field (FSF) phosphorus doping
Metal deposition may be performed using plasma sputtering, vacuum evaporation, atmospheric arc/thermal spray coating, etc.

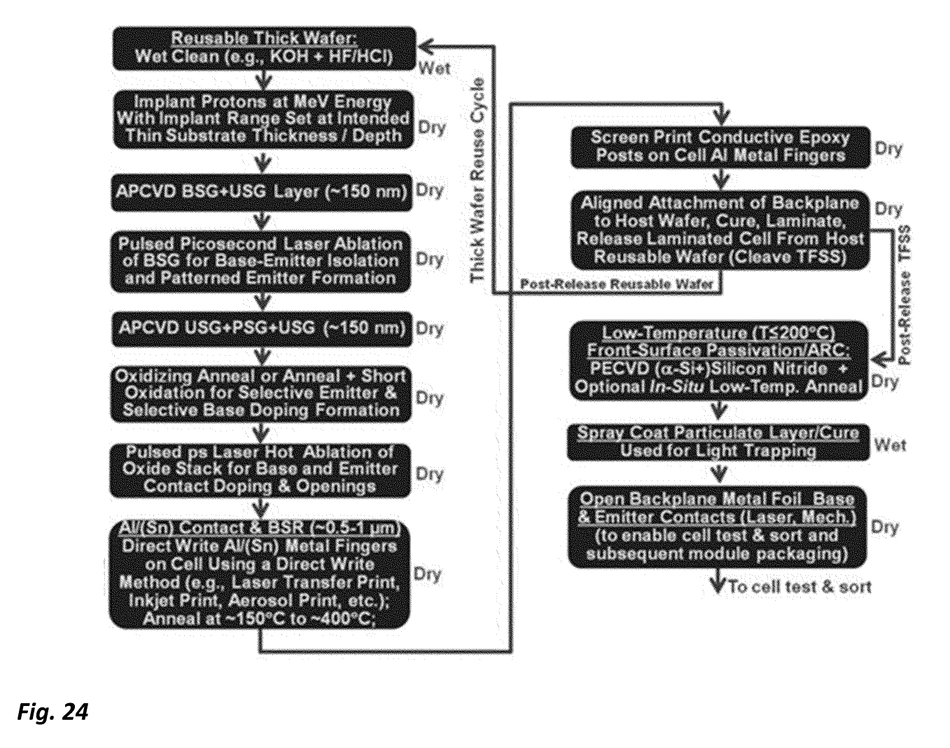

FIG. 24 corresponds to flow option 1A2 of FIG. 3, and may be characterized by the following attributes:
Thin substrate formed by slicing/cleaving from reusable thick wafer or ingot piece (e.g., after MeV proton implant); the thin substrates are typically (111) oriented substrates, requiring dry laser or plasma texturing
Includes selective emitter without added process steps (using hot ablation process)
Uses two APCVD processes
Base contact diffusion formed using APCVD PSG and hot laser ablation
No cell front-surface texturing (textureless)—instead light trapping is assisted by coating a particulate light trapping layer
Includes Front-Surface Field (FSF) phosphorus doping
Metal deposition may be performed using a direct write process such as screen printing, laser transfer printing, inkjet printing, aerosol printing, etc.

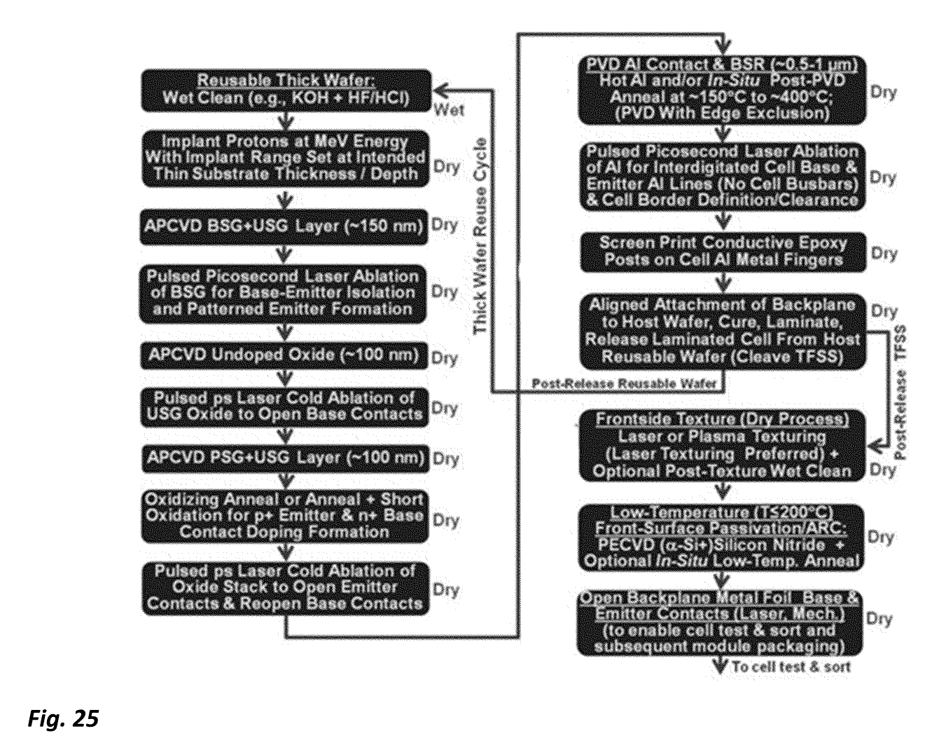

FIG. 25 corresponds to flow option 1B of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses three APCVD processes
Base contact diffusion formed using APCVD PSG and furnace anneal
Metal deposition may be performed using plasma sputtering, vacuum evaporation, atmospheric arc/thermal spray coating, etc

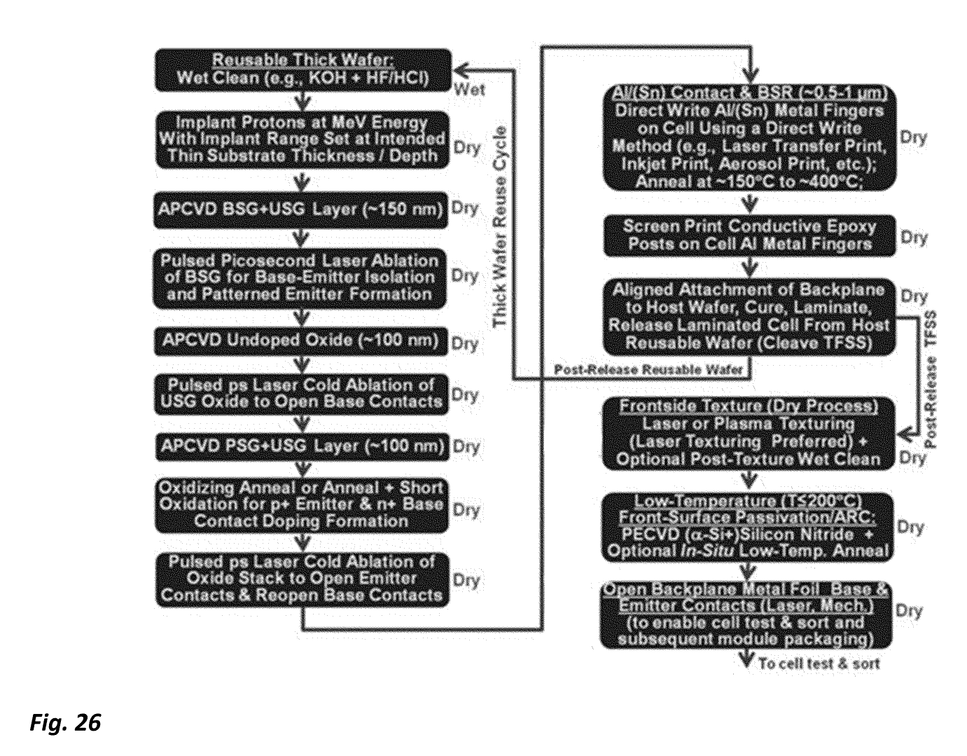

FIG. 26 corresponds to flow option 1B of FIG. 3, and may be characterized by the following attributes:
Thin substrate formed by slicing/cleaving from reusable thick wafer or brick or ingot piece (e.g., after MeV proton implant); the thin substrates are typically (111) substrates, requiring dry laser or plasma texturing
Includes selective emitter without added process steps (using hot ablation process)
Uses three APCVD processes
Base contact diffusion formed using APCVD PSG and furnace anneal
Metal deposition may be performed using a direct write process such as laser transfer printing, inkjet printing, aerosol printing, etc.

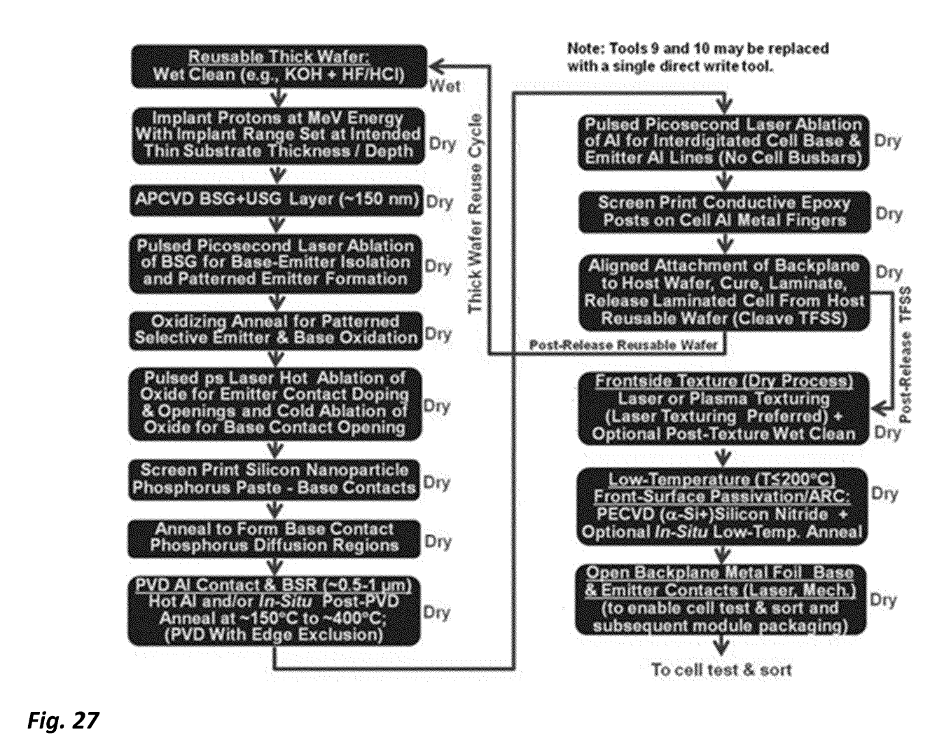

FIG. 27 corresponds to flow option 2A of FIG. 3, and may be characterized by the following attributes:
Thin substrate formed by slicing/cleaving from reusable thick wafer or ingot piece (e.g., after MeV proton implant); the thin substrates are typically (111) substrates, requiring dry laser or plasma texturing
Includes selective emitter without added process steps (using hot ablation process)
Uses only one APCVD process step
Base contact diffusion formed using screen printed or inkjet printed silicon nanoparticle phosphorus paste

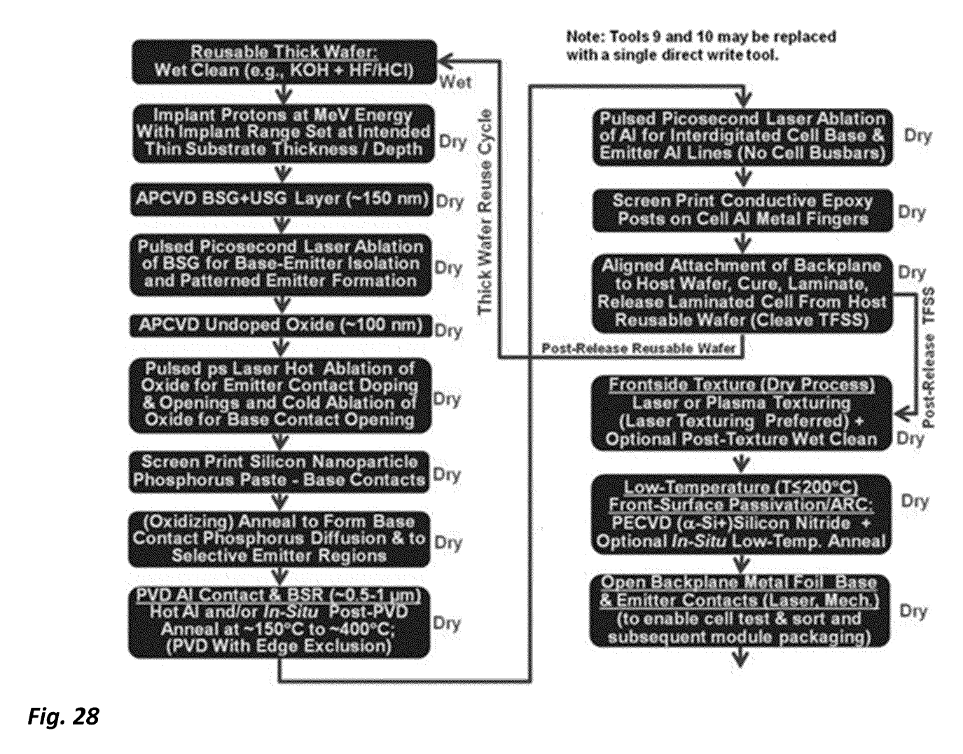

FIG. 28 corresponds to flow option 2B of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses two APCVD process steps
Base contact diffusion formed using screen printed or inkjet printed silicon nanoparticle phosphorus paste

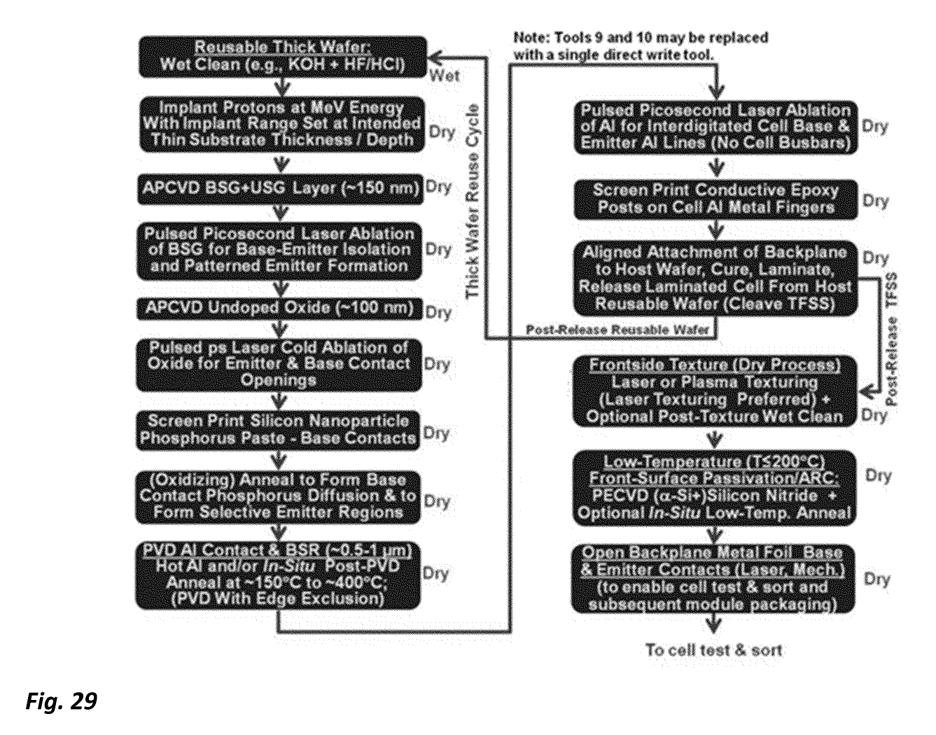

FIG. 29 corresponds to flow option 2C of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
No hot ablation process and no selective emitter
Uses two APCVD process steps
Base contact diffusion formed using screen printed or inkjet printed silicon nanoparticle phosphorus paste

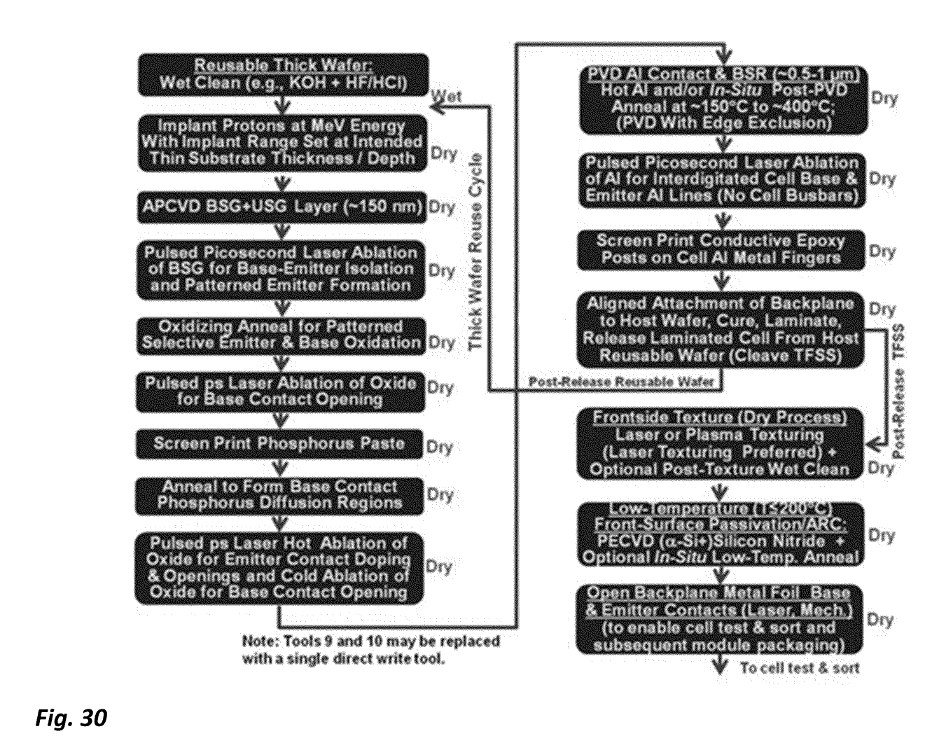

FIG. 30 corresponds to flow option 3A of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses only one APCVD process step
Base contact diffusion formed using standard commercial phosphorus paste (e.g., applied by screen printing)

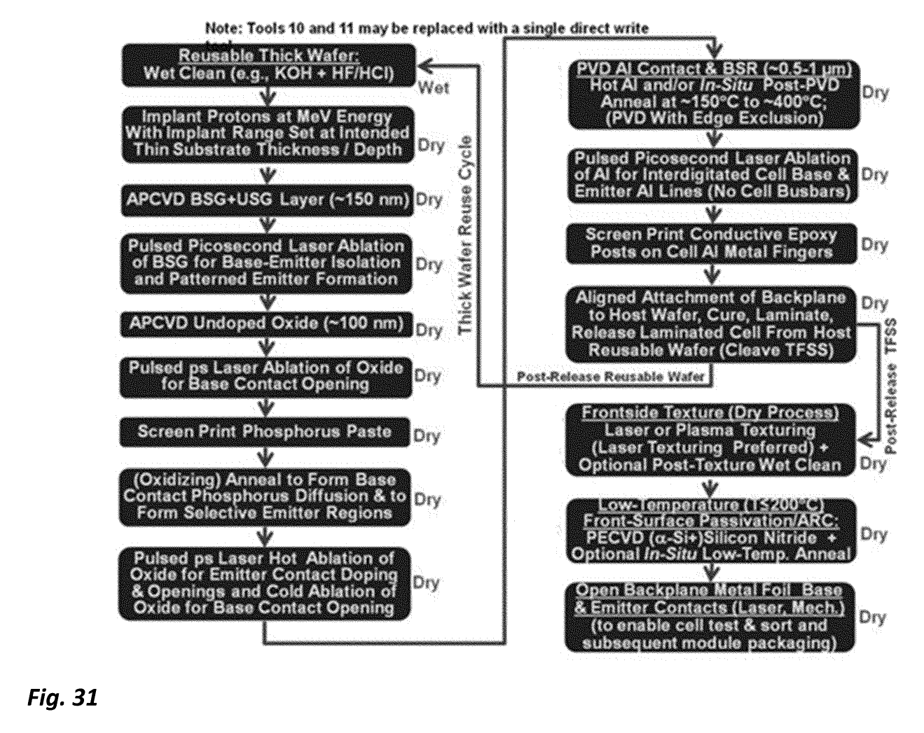

FIG. 31 corresponds to flow option 3B of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses two APCVD process steps
Base contact diffusion formed using standard commercial phosphorus paste (e.g., applied using screen printing)

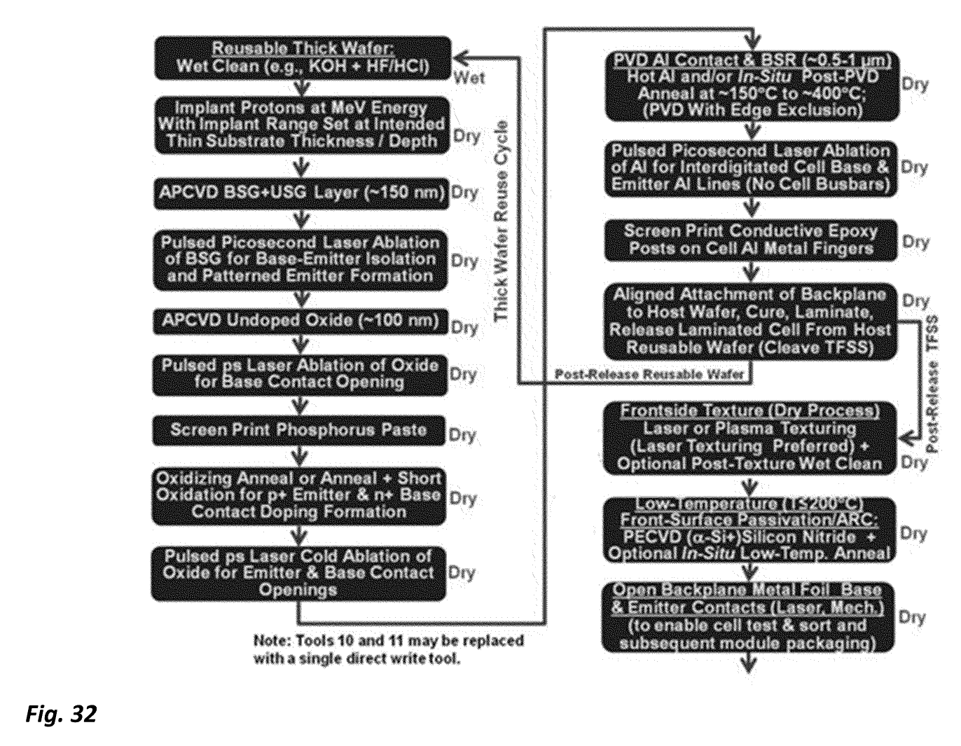

FIG. 32 corresponds to flow option 3C of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
No hot ablation process and no selective emitter
Uses two APCVD process steps
Base contact diffusion formed using standard commercial phosphorus paste (e.g., applied using screen printing)

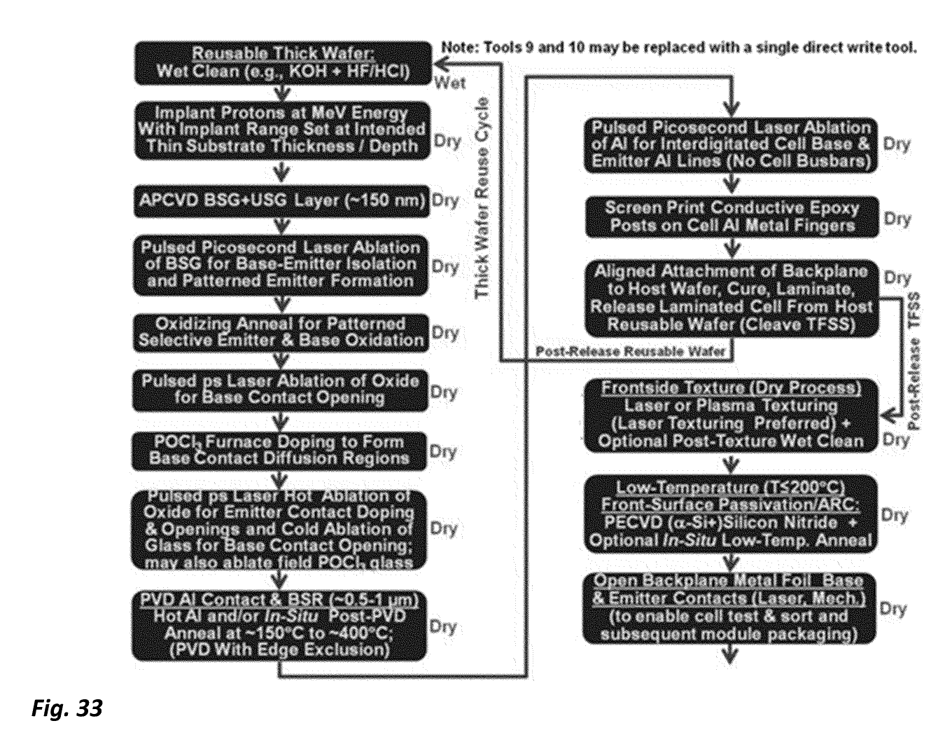

FIG. 33 corresponds to flow option 4A of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses only one APCVD process step
Base contact diffusion formed using POCl₃ furnace doping

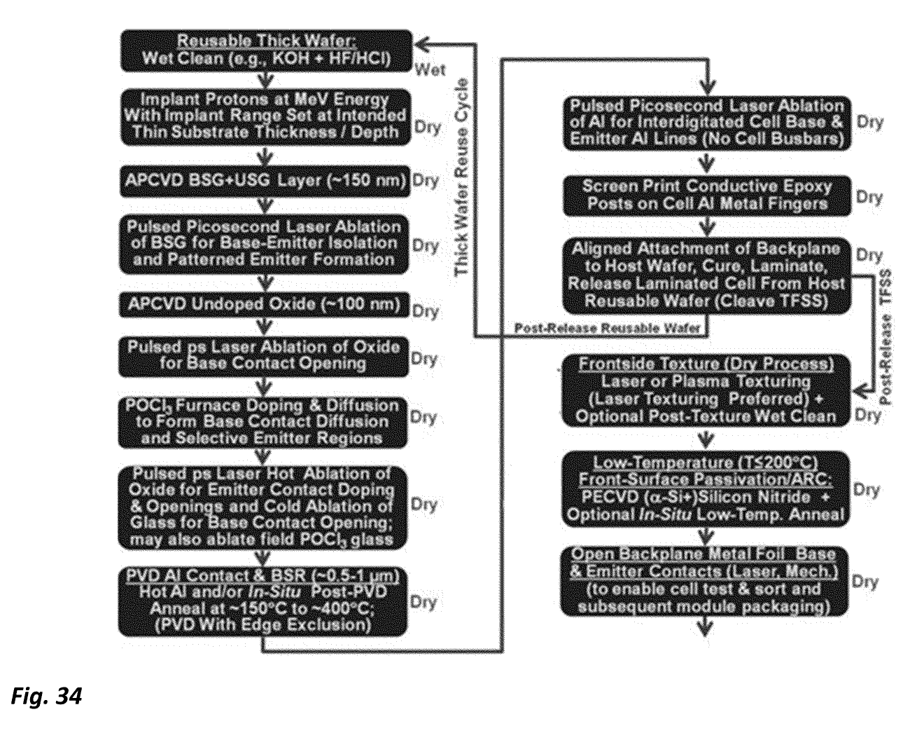

FIG. 34 corresponds to flow option 4B of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
Includes selective emitter without added process steps (using hot ablation process)
Uses two APCVD process steps
Base contact diffusion formed using POCl₃ furnace doping

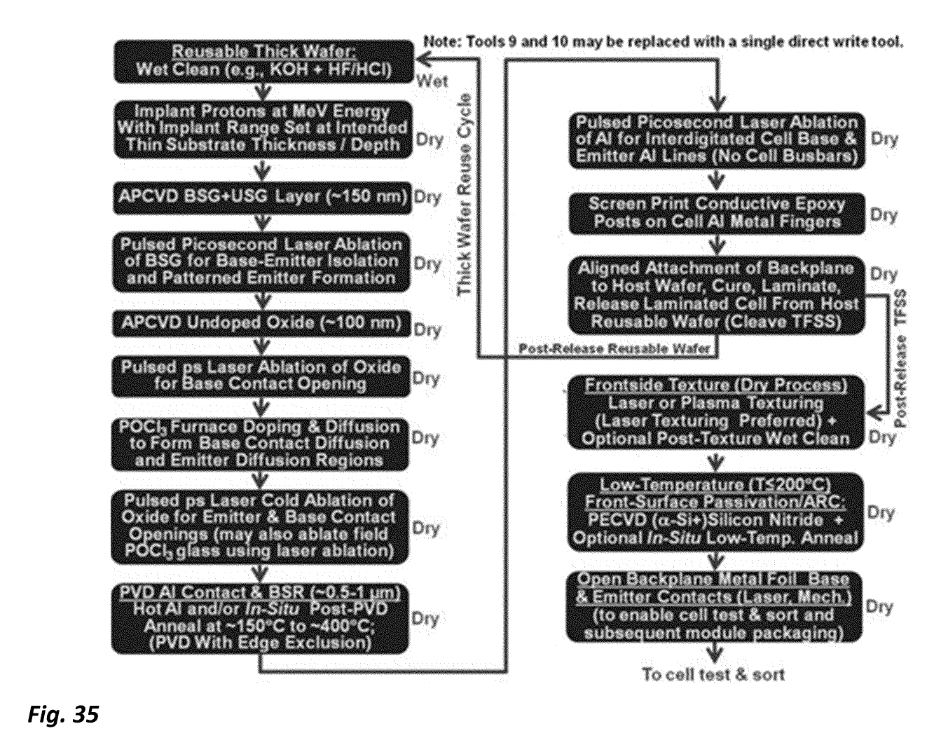

FIG. 35 corresponds to flow option 4C of FIG. 3, and may be characterized by the following attributes:
Thin substrate formed by slicing/cleaving from reusable thick wafer or brick or ingot piece (e.g., after MeV proton implant); the thin substrates are typically (111) oriented substrates, requiring dry laser or plasma texturing
No hot ablation process and no selective emitter
Uses two APCVD process steps
Base contact diffusion formed using POCl₃ furnace doping

Specific Process Flows for Bulk CZ and FZ Wafers Using Backplane Technology.

In this category of flows representative back contacted/back junction process flows for bulk CZ (Czochralski) and FZ (Float Zone) wafers using backplane technology are detailed. Among distinguishing factors includes insertion of backplane and also the extensive use of pico-second laser processes for direct pattern definition. Although, not explicitly mentioned, if desired, the backplane technology may be used on the bulk FZ and CZ wafers to thin them down by etching to form much thinner cell absorbers, which may be useful when cheap bulk wafers are desired that may not render very high lifetimes. These cheaper, relatively lower lifetime wafers may also be of p-type bulk doping. Although, all the process flows depicted are examples of wafers with the preferred doping which is n-type base (bulk) doping.

Five categories of flows are detailed below—each category having two subcategories. Subcategories are distinguished by the method which is used to deposit and pattern metal on the cell. In the first sub-category, analogous to the previously described flows in this document, PVD along with laser based metal isolation processes are used to obtain patterned base and emitter metals. In the second sub-category, a direct patterned metal write technique is used in lieu of the PVD/laser isolation steps. Full process flows of the five main categories are detailed in the figures and descriptions; however, the categories may be defined according to the following characteristics:

CZ/FZ Option I: PSG based front surface field (FSF) which is formed before texture.
CZ/FZ Option II: POCl3 based FSF which is formed before texture. The process has no POCl3 glass deglaze step.
CZ/FZ Option III: POCl3 based FSF with the POCl3 glass deglaze.
CZ/FZ Option IV: PSG based FSF formed after texture.

### CZ/FZ Option V: No FSF

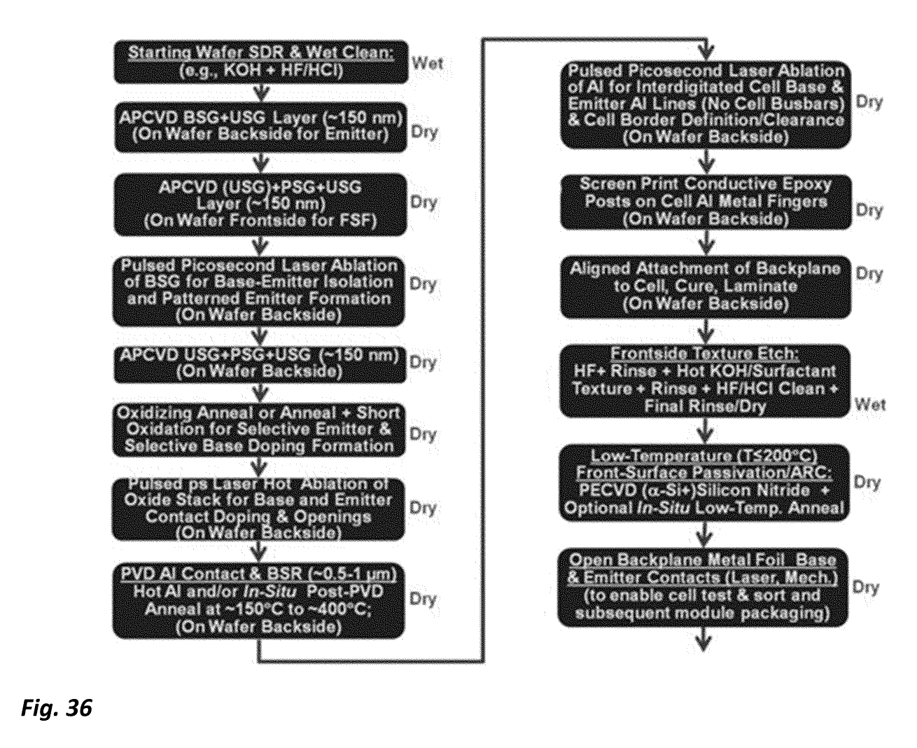

FIG. 36 corresponds to CZ/FZ Option I, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for frontside FSF as well as backside base contact diffusion
Pre-texture FSF formation
In-Line backplane attachment
Metal deposition may be performed using plasma sputtering, vacuum evaporation, atmospheric arc/thermal spray coating, etc.

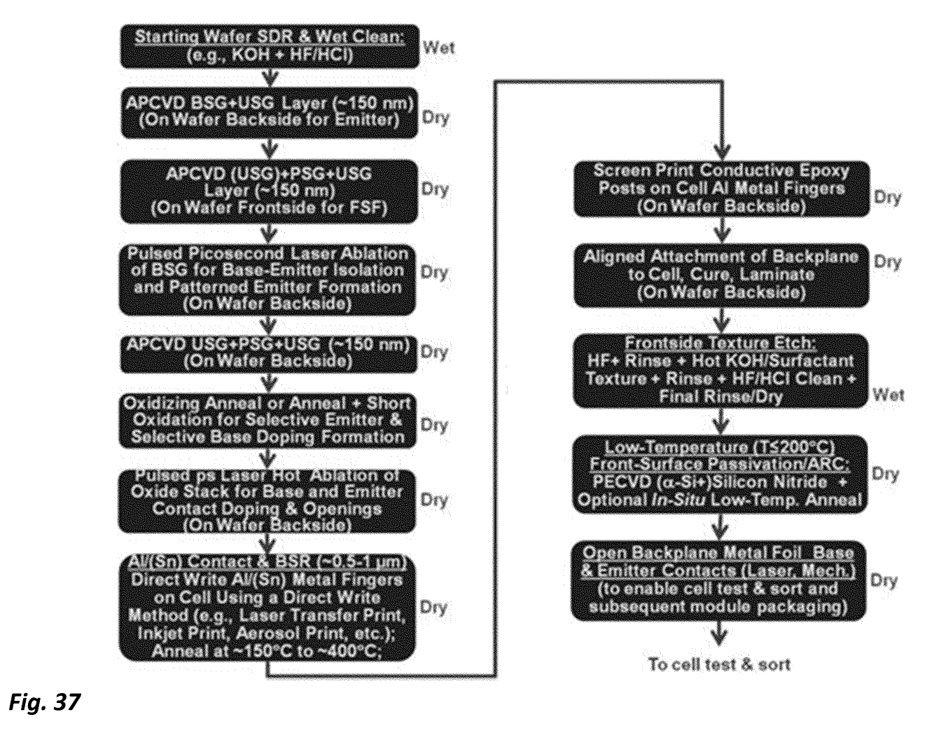

FIG. 37 corresponds to CZ/FZ Option I, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for frontside FSF as well as backside base contact diffusion
Pre-texture FSF formation
In-Line backplane attachment
Metal deposition may be performed using a direct write process such as laser transfer printing, inkjet printing, aerosol printing, etc.

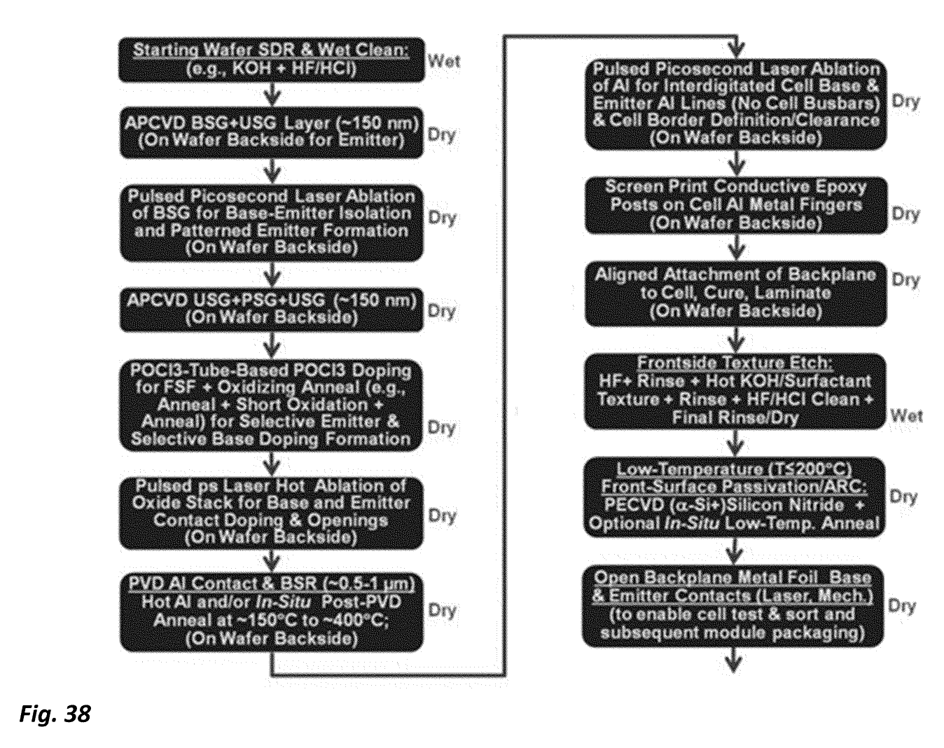

FIG. 38 corresponds to CZ/FZ Option II, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used only for backside base contact diffusion
POCl3-tube-based anneal used to concurrently or sequentially anneal and oxidize
No POCl3 glass deglaze
Pre-texture FSF formation
Metal deposition may be done using vacuum sputtering, vacuum evaporation, atmospheric arc/thermal spray coating, etc.

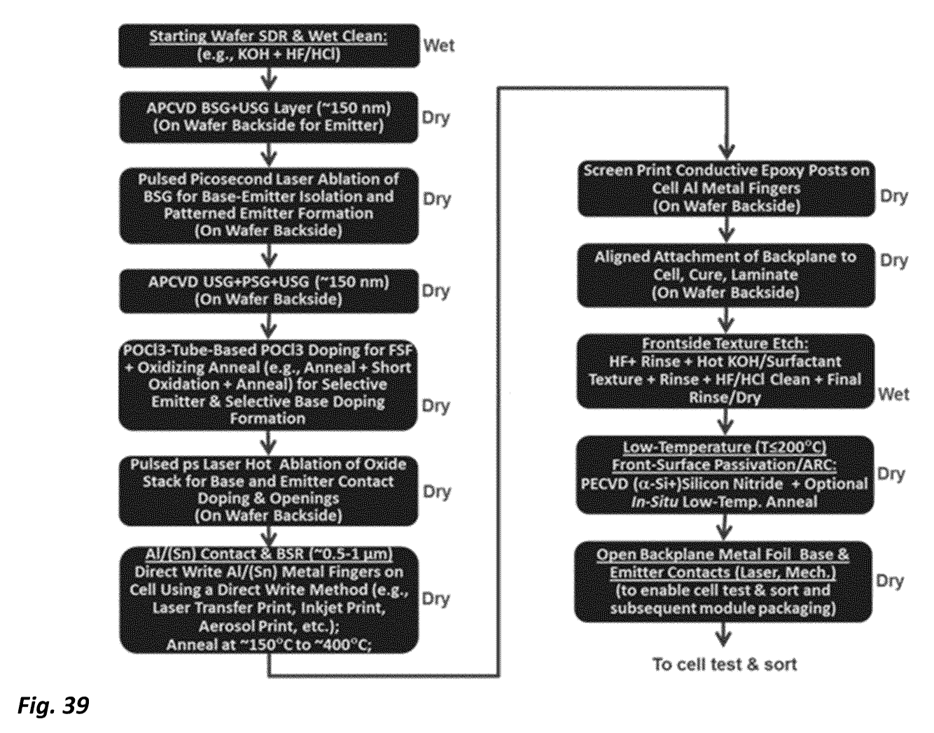

FIG. 39 corresponds to CZ/FZ Option II with main attributes similar to FIG. 38 except the direct write for metal, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used only for backside base contact diffusion
POCl3-based furnace anneal used to concurrently or sequentially anneal and oxidize
No POCl3 glass deglaze
Pre-texture FSF formation
Metal deposition may be performed using a direct write process such as screen printing, laser transfer printing, inkjet printing, aerosol printing, etc.

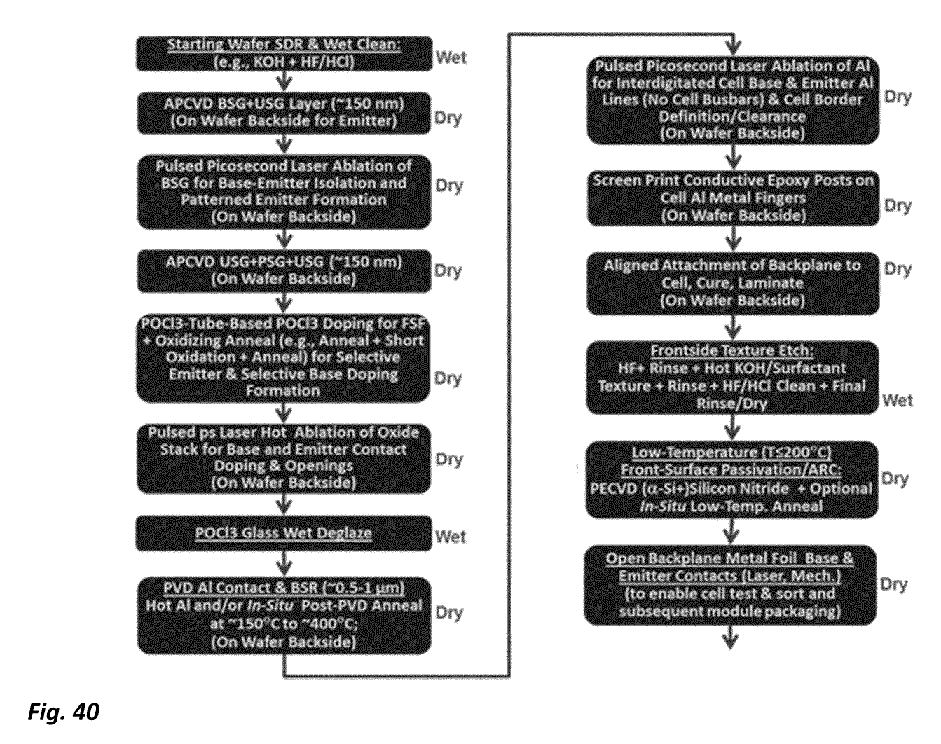

FIG. 40 corresponds to CZ/FZ Option III, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used only for backside base contact diffusion
POCl3-based furnace anneal used to concurrently or sequentially anneal and oxidize
With POCl3 glass deglaze
Pre-texture FSF formation
Metal deposition may be performed using plasma sputtering, vacuum evaporation, atmospheric arc/thermal spray coating, etc.

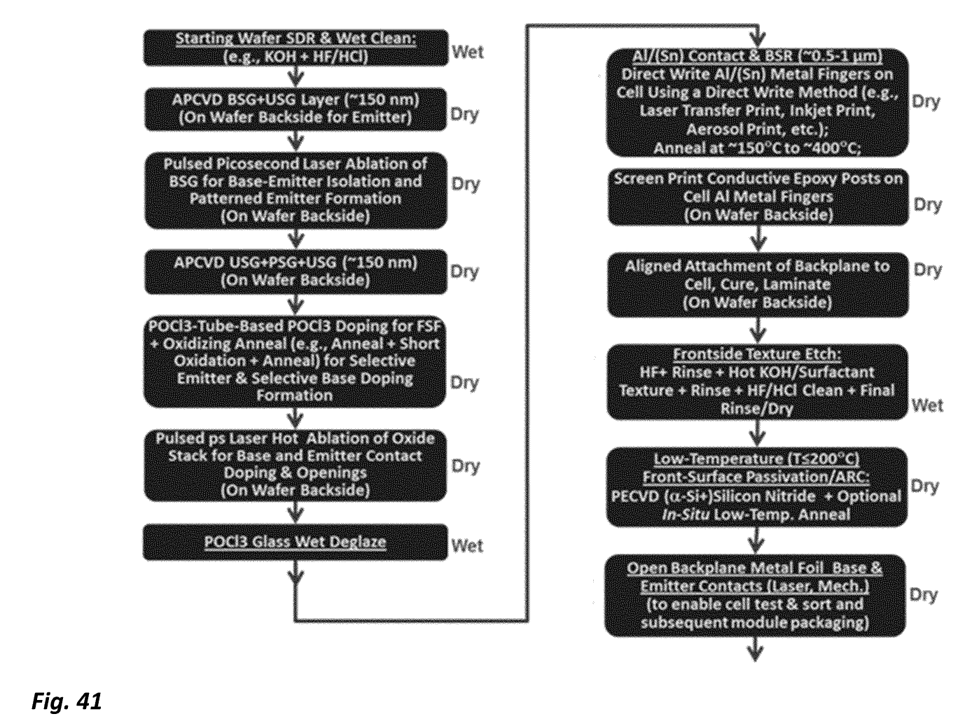

FIG. 41 corresponds to CZ/FZ Option III, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used only for backside base contact diffusion
POCl3-based furnace anneal used to concurrently or sequentially anneal and oxidize
With POCl3 glass deglaze
Pre-texture FSF formation
Metal deposition may be performed using a direct write process such as screen printing, laser transfer printing, inkjet printing, aerosol printing, etc.

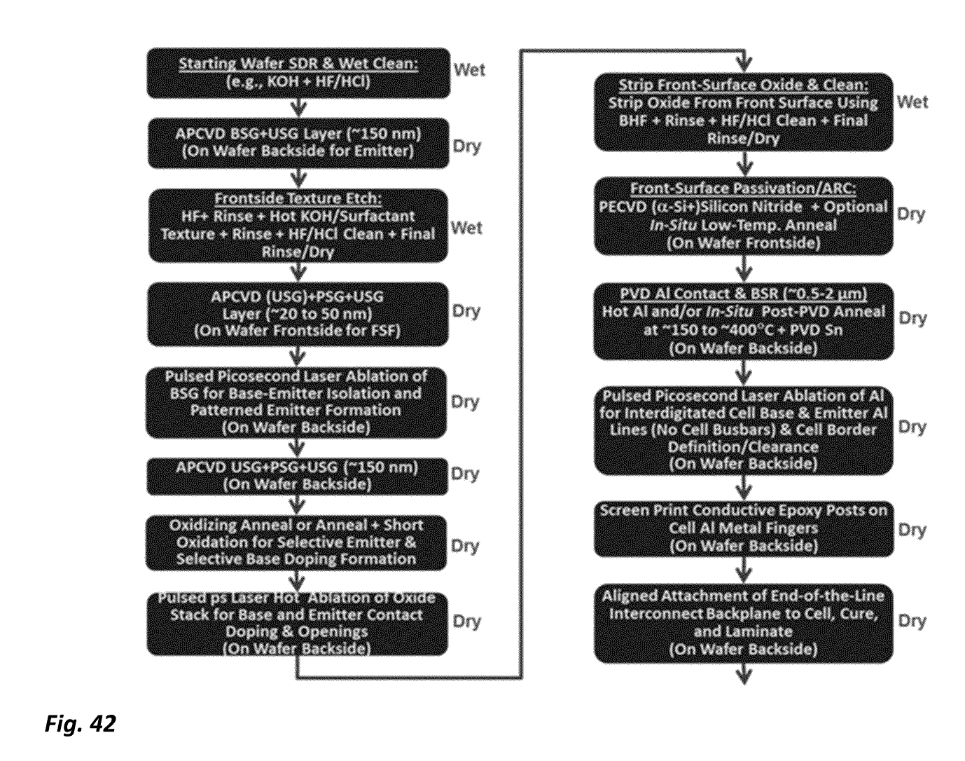

FIG. 42 corresponds to CZ/FZ Option IV, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for frontside FSF as well as backside base contact diffusion
Post-texture FSF formation
Metal deposition may be performed using plasma sputtering, vacuum evaporation, atmospheric arc/thermal spray coating, etc.

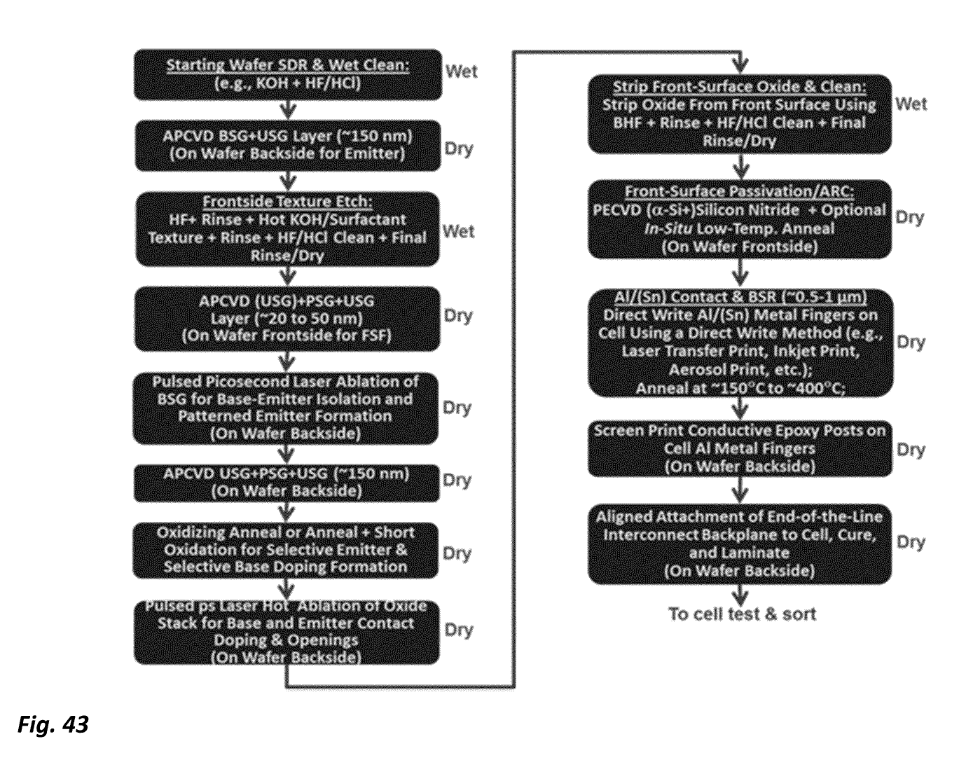

FIG. 43 corresponds to CZ/FZ Option IV, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for frontside FSF as well as backside base contact diffusion
Post-texture FSF formation
Metal deposition may be performed using a direct write process such as screen printing, laser transfer printing, inkjet printing, aerosol printing, etc.

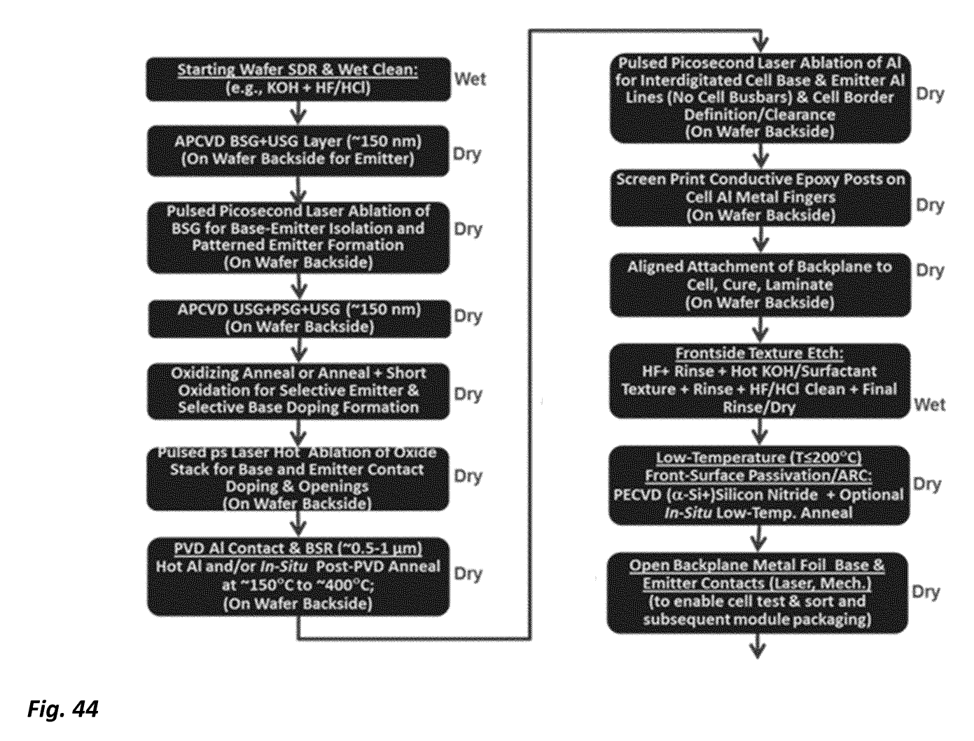

FIG. 44 corresponds to CZ/FZ Option V, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for backside base contact diffusion
No FSF
Metal deposition may be performed using plasma sputtering, vacuum evaporation, atmospheric arc/thermal spray coating, etc.

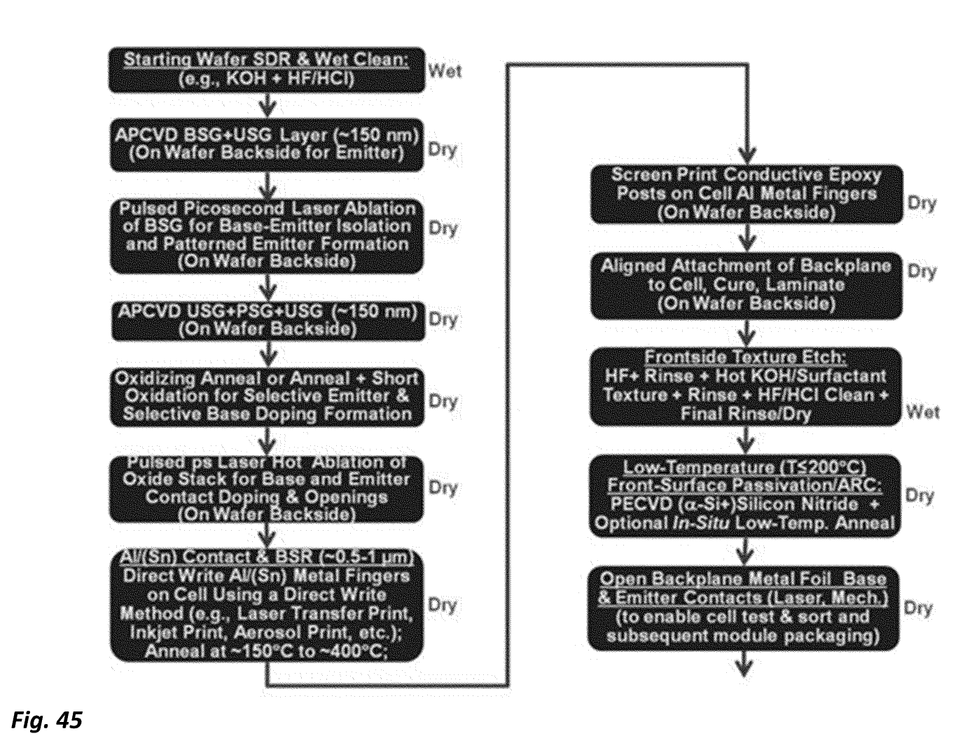

FIG. 45 corresponds to CZ/FZ Option V, and may be characterized by the following attributes:
Includes selective emitter without added process steps (using hot ablation process)
Separated Base-Emitter Junction
Uses two APCVD processes
Base contact diffusion formed using APCVD PSG and hot laser ablation
APCVD PSG used for backside base contact diffusion
No FSF
Metal deposition may be performed using a direct write process such as screen printing, laser transfer printing, inkjet printing, aerosol printing, etc.

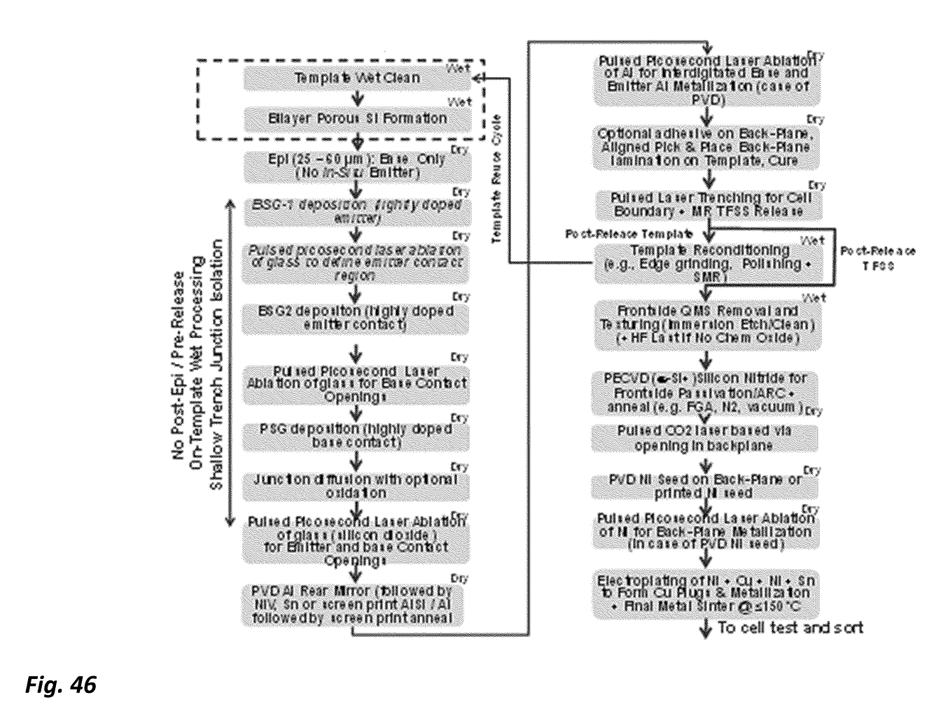

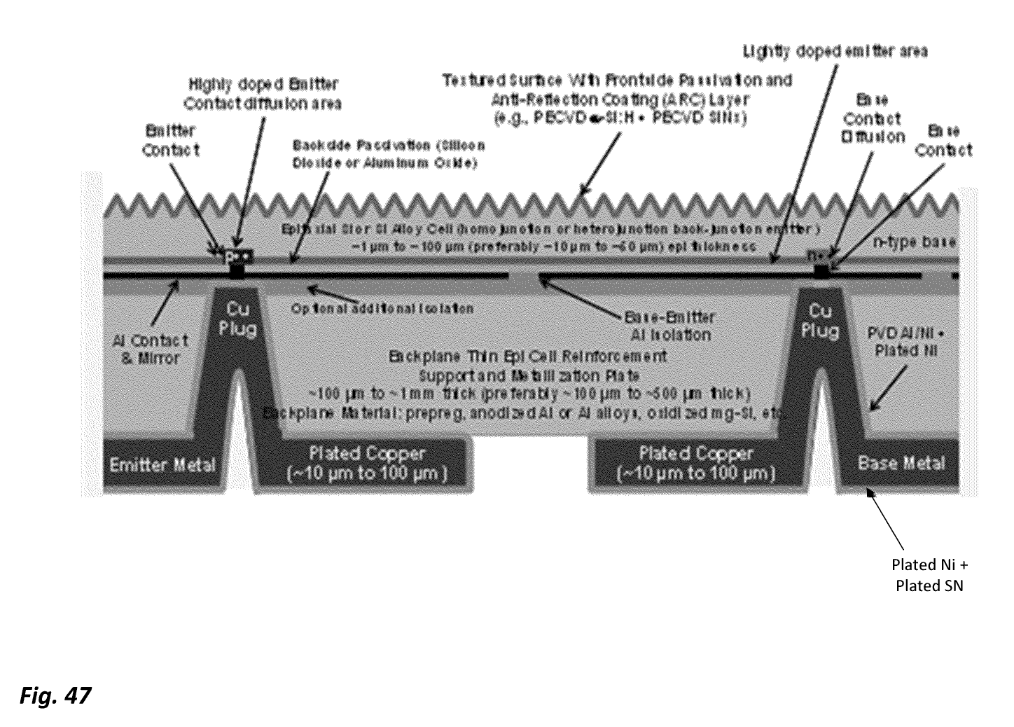

In addition to the flow family 1B outlined in FIG. 3, it is also possible and desirable to generate a selective emitter structure on the back side by the use of two separate BSG layer depositions, together with an additional cold pulsed ps (or fs) laser ablation step. This selective emitter structure using APCVD layers and laser ablation is applicable as a variation of all previously described structures and flows, be they on absorber layers generated from epitaxially deposited films, from CZ wafer or from otherwise processed absorber layers such as those cleaved using high energy such as MeV implantation and splitting. FIG. 46 shows a cell process flow to generate selective emitter structure (with lighter emitter junction doping and heavier emitter contact doping concentrations) using an additional BSG layer and picosecond laser ablation patterning. FIG. 47 is a diagram showing the cross section of the resulting cell structure from the flow of FIG. 46, the cell containing a selective emitter formed by two BSG depositions with different diffused sheet resistances.

As seen in FIG. 46, starting with a cleaned template the porous silicon bilayer or layer structure is formed. A lightly n-type doped epitaxial film (in-situ base doping typically in the range of about 5×10¹⁴ cm⁻³ to 1×10¹⁸ cm⁻³, thickness between about 5 μm and 100 μm) is deposited. The base phosphorus doping concentration may be varied based on a pre-specified profile during the epitaxial growth process (again, preferably in the range of about 5×10¹⁴ cm⁻³ to 1×10¹⁸ cm³). As outline previously, the doping is optionally done using more than one doping level to implement optimized doping, for instance, to achieve both high Voc (high minority carrier lifetime) and high fill factor (reduced parasitic base resistance). Such optimized doping may consist of a front surface field where a higher doping close to the sunny side surface of the device is implemented. However, it may also be advantageous to have a lower doping in that regime, which in turn can also lead to a better front surface recombination velocity but from a different effect. That effect is believed to be due to the band lineup at the surface with respect to the band position of interface states and which renders such interface states less severe.

After epitaxial silicon layer deposition, a first BSG layer is deposited with a rather low concentration of boron to later provide a lightly doped emitter in the bulk of the back surface region. This process is followed by laser ablation (preferably picosecond laser) of the area where the emitter contact is to be formed. This and the subsequent structuring processes can advantageously contain parallel lines across the structure. Areas of emitter contacts and base contacts are aligned in an alternating interdigitated pattern. In certain zones, namely in the zones where later in the process the busbars are located on the metal 2 layer (second metal deposition), it may be advantageous to deviate from the linear, parallel, interdigitated base and emitter contact pattern. This deviation is employed to drastically reduce the electrical shading that is otherwise experienced underneath each busbar. Next the second BSG layer is deposited with a comparatively higher concentration of boron, such as to provide the highly doped emitter contact region (e.g., with p++ doping). Subsequently, the area for the base contact is laser ablated, preferably using a picosecond laser. Next, a PSG layer is deposited, to serve as the precursor for the phosphorus doped base contact. Subsequently, the dopants are driven in during a multi-functional high temperature process step which optionally can contain a neutral ambient such as nitrogen, optionally followed by an oxidizing ambient such as oxygen or water steam (and furthermore, optionally comprising backend lower temperature gettering and finally forming gas anneal). The junctions are now driven in. Contact can subsequently be made by laser ablation in the contact area, preferably using picosecond laser. Next, the metal 1 (first metal deposited and metal positioned closest to cell) is deposited and structured, either using PVD of for instance a stack of Al, Ni or NiV and Sn, followed by patterning using for instance, picosecond laser ablation, or by screen printing, aerosol printing, ink jet or otherwise printing one or more layers of aluminum containing paste. The aluminum paste may be selected to contain in a first layer some silicon to reduce spiking into the junctions upon subsequent annealing, or other spike reducing agents. In a second layer, also attributed to the structure of metal 1, the paste or ink can be selected to contain a suitable grain structure to harmonize well with the later via access hole drilling which is employed to make contact between metal 1 and metal 2. Other selection criteria are the optimized conductivity to have a low line resistance within metal 1 (M1). Especially for the lower ink or paste it is also crucial to select the correct paste for a low contact resistance to both the base and the emitter. Where desired, different pastes or inks, even containing different metals, may be employed to make the contact to the baser contact diffusion versus to the emitter contact diffusion. For example, the initial metal 1 layer can be a thin layer of ink such as nickel ink which can be deposited very locally in the contact regions and then turned into a silicide by heating, preferably in a self limiting process. However, the subsequent layer of metal 1 be treated at low enough temperatures to provide the lowest resistivity phase of the respective silicide formed. It is to be noted that in order to facilitate a good process window for later via access hole laser drilling while at the same time keeping metal 1 consumption (thickness) and cost per cell in check, it may be advisable to locally print thicker aluminum metal paste pads underneath the designated via holes areas, while printing a much thinner aluminum paste elsewhere on the cell to form the continuous or segmented fingers. This design may be formed, for example, by printing additional metal paste material in the area of the via hole (hence, double screen printing of the metal paste) or also by increasing the line width in the area of the via hole for better alignment tolerance or by combinations of the former and the latter.

It is to be noted that all flows and structures described in this disclosure may, in alternative embodiments, use printing processes for metal 1 paste such as ink jet, aerosol or screen printing, although PVD followed by picosecond (or fs) laser ablation patterning is explicitly mentioned as the method for metal 1 deposition. Subsequent to paste or ink printing, the pastes or inks can be suitably baked and annealed. Next, the backplane can be attached, for instance, but not limited to lamination of a suitable low-CTE prepreg material, or by first screen printing and heat or radiation treatment, such as by UV radiation, of another adhesive filler, optionally between the metal 1 spaces in order to planarize the surface prior to the backplane lamination. If such an additional adhesive is used, the backplane material, such as prepreg, can be laminated to the relatively planarized surface structure afterwards.

The lamination material, such as prepreg, may be smaller in extent than the template side dimension for instance a few millimeters on each side. For instance, for a standardized 156 mm×156 mm final cell it may be advantageous to have a lamination material just larger, for instance about 158 mm×158 mm, and a template just larger than that, for instance about 165 mm×165 mm.

After the lamination, in the area just outside the lamination region an ablated trench of silicon can be cut partially or fully through the epitaxial film with a laser, preferably a nanosecond UV laser, or alternatively employing thermal laser separation, a process where locally an area is heated using a travelling laser beam and subsequently cooled, using a trailing jet of mist, water or other coolant such as helium, thereby creating a cleaving front which can be terminated in the region of the release layer, formed by the porous silicon and thereby at the interface between the epitaxial layer and the template.

Following such preparation, the laminated reinforced thin film solar substrate (TFSS) may be released from the template, preferably by a pulling process, a peeling process, a pull-peeling process or through the support of sonication, such by either immersing the TFSS and template stack in an ultrasonic bath or by adding ultrasonic energy to a dry release station with the capability of applying vacuum to both sides of the stack, or by vacuum oscillation or by a combination of the above. After release of the TFSS the remaining template undergoes a process in which the area outside of the active released area is stripped of remaining epitaxial material, by grinding it off, by the use of water or other liquid pressure, by chemical removal or by a combination of the above. Subsequently, the template is cleaned and inspected and then fed back into circulation, for another round of porous silicon formation, epitaxial film deposition and so on.

The released TFSS is then trimmed to size, preferably using one or a combination of several lasers, for instance a UV or green nanosecond laser. Such trimming to size can also contain a partial ablation trench just inside of the edge boundary, to make the structure less prone to propagation of microcracks from the outside of the device. After trimming the TFSS is then textured, for instance using an alkaline texture chemistry, such as KOH with a suitable additive, followed by a post texture clean, for instance using HF and HCl, and finishing with a hydrophobic surface (for instance, using an HF-last cleaning step). Next, the TFSS receives the front side passivation, for instance by deposition of a-Si or a-SiOx, followed by ARC layer deposition, such as Silicon nitride (SiN), all preferably performed using PECVD.

The silicon nitride also contributes to the front side passivation by providing hydrogen as well as a positive charge to repel the base minority carriers. Either during the deposition or at a later step such as end of the line, the passivation layer and interface may be annealed, for instance, using a forming gas or a neutral ambient or in vacuum, to improve passivation. Such anneal may be performed at a temperature in the range of about 200° C. up to the maximum temperature allowable by the backplane material, as well as ensuring no crystallization of amorphous silicon (or silicon oxide) and ensuring formation of no microcracks. The maximum allowable temperature may be as high as about 300° C. to 350° C.

Subsequently, the backside of the wafer receives via holes, preferably drilled using a CO2 laser and stopping on or just inside the metal 1 layer. Next, the metal 2 deposition is employed, which may be arranged orthogonally to metal 1. An exception is the bus bar area if it is desired to be part of metal 2. As stated before, underneath the bus bars, metal 1 fingers as well as emitter and base regions are preferably arranged differently in order to minimize overall electrical shading from the bus bar area.

Prior to metal 2 deposition, a surface clean of the contact may be employed, such as with a sub-atmospheric or atmospheric plasma etch or cleanup to remove native oxide. For the metal 2 application, various techniques, such as those described above, may be employed, including a PVD seed which is later patterned using resist print, plating of Cu and Sn, resist strip and local seed layer etch or a pattern or unpatterned printed seed layer, such as printed nickel ink or paste (or a copper ink or paste), followed by suitable baking and subsequent copper plating. Alternatively, the metal 2 layer may also be applied using thermal spraying such as flame spraying of Al, Al with Zn, or Cu or Cu followed by Sn. The thermal spraying may be performed in lines or through a patterned mask that is periodically cleaned.

Dimensions for the metal 2 layer may be relaxed as the region access is mainly achieved by the smaller dimension metal 1 layer and metal 2 layer being arranged orthogonally to metal 1. The laminated backplane serves among other functions (such as permanent support and reinforcement) also that of the isolating dielectric between metal 1 and metal 2 layers and to provide the matrix for the via holes which provide access between the two layers (M1 and M2). Exemplary thickness dimensions for the cell of FIG. 47 include: epitaxial Si˜10 to 50 μm, backside passivation oxide 50 to 250 nm, backplane (prepreg, anodized Al alloy or oxidized metallurgical grade silicon: mg-Si)˜150 to 500 μm, sputtered (PVD) Al or printed (AlSi, Al) contact/mirror˜50 to 250 nm, plated Ni (top and bottom)˜100 to 500 nm, plated top Sn˜0.5 to 5 μm, and plated copper metal˜25 to 50 μm.

If the bus bar is not part of the cell but rather part of the module, then the geometries in the cell may be simplified and it is possible to have both metal 1 and metal 2 both completely contain parallel interdigitated fingers only, arranged orthogonally between metal 1 and metal 2.

However, another advantage of having structures in metal 1 not being completely linear is that this design allows for a recess or exclusion of the area of metal 2 coverage within the TFSS area and thereby a sealing of the edges of the TFSS during the plating process. Such sealing prevents contamination of the active absorber area with potentially detrimental metal plating solutions containing for instance Cu.

It also may be advantageous to have the interdigitated metal lines of the metal 1 layer segmented, especially in cases such as a rather thick printed metal paste. Segmentation is to be arranged such that the contact to metal 2 is still made as well so that the series resistance throughout the line does not noticeably deteriorate. When these requirements are met, for example for line segments between about 0.5 and 5 centimeter in length, then the segmentation may prevent generation of microcracks as well as excess bow and stress initiated by the shrinkage of the metal 1 lines during a paste anneal or during process steps subsequent to the metal deposition or metal paste anneal.

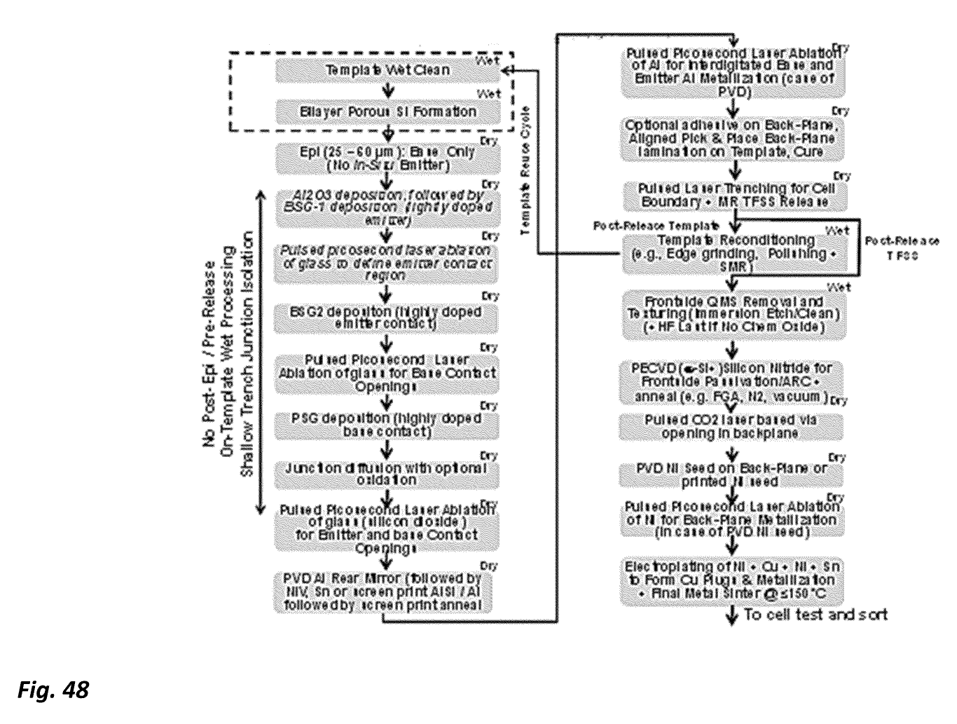

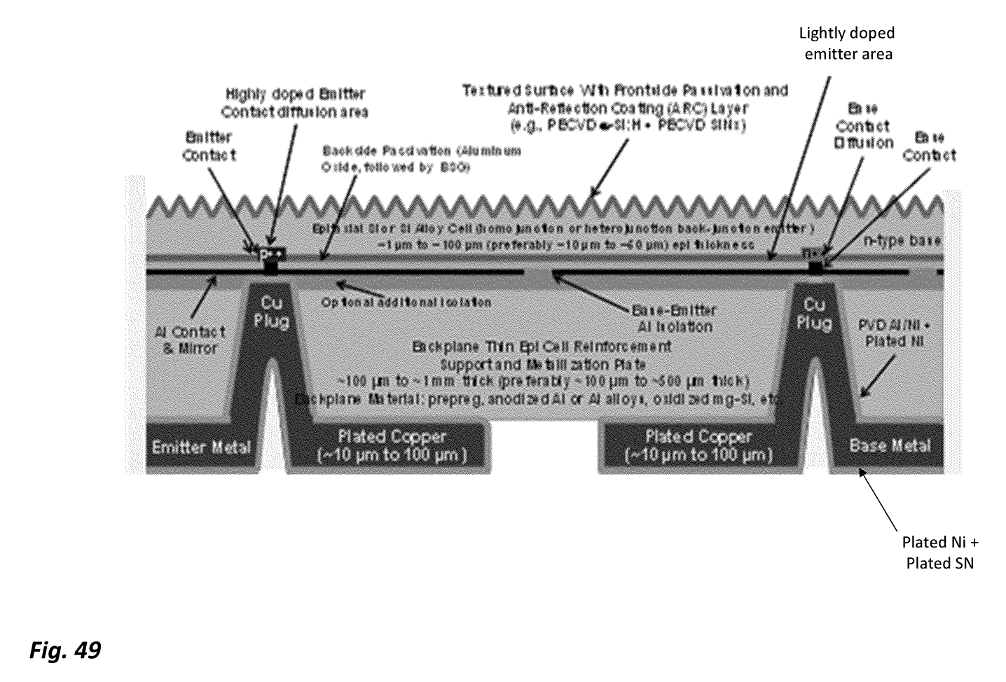

Importantly, alternative dielectrics may be formed and used on the backside of the cell. For a p-type emitter, such as a boron doped emitter, it may be advantageous to have a passivation dielectric in contact with the emitter region which provides a negative charge. Therefore, in a variation of all previously described structures and flows, be they on absorber layers generated from epitaxially deposited films, from CZ wafer or from otherwise processed absorber layers such as those cleaved using high energy such as MeV implantation and splitting, it is also possible to have material such as a thin (e.g., thickness in the range of about 5 nm to 50 nm) aluminum oxide (preferably formed by APCVD or ALD) as the first layer contacting the backside (and therefore the top of the epitaxial layer). FIG. 48 is an example process flow which incorporates the deposition of aluminum oxide as the back surface passivation of the active absorber layer and FIG. 49 is a cross-section of an example embodiment of a cell structure formed by the process shown in FIG. 48 and which incorporates deposited aluminum oxide as the back surface passivation of the active absorber layer. The cell of FIG. 49 shows aluminum oxide as the backside passivation dielectric. The aluminum oxide may preferably be deposited using an atmospheric process such as APCVD, or by atomic layer deposition (ALD). Such a layer may be deposited, preferably in the same tool, immediately prior to the deposition of the first BSG layer and emitter doping using BSG proceeds through this layer. Alternatively, the layer itself can contain boron or, less likely, enough aluminum to be activated to diffuse as a dopant and form the emitter region, especially for the selective emitter version the lightly doped emitter region. The aluminum oxide layer subsequently undergoes the same laser ablation processes that have been described above when using BSG, USG and PSG.

Exemplary thickness dimensions for the cell of FIG. 49 include: epitaxial Si˜10 to 50 μm, backside passivation oxide 50 to 200 nm, backplane (prepreg, anodized Al alloy or oxidized mg—Si)˜150 to 500 μm, sputtered (PVD) Al or printed (AlSi, Al) contact/mirror˜50 to 250 nm, plated Ni (top and bottom) ˜100 to 500 nm, plated top Sn˜0.5 to 5 μm, and plated copper metal˜25 to 50 μm.

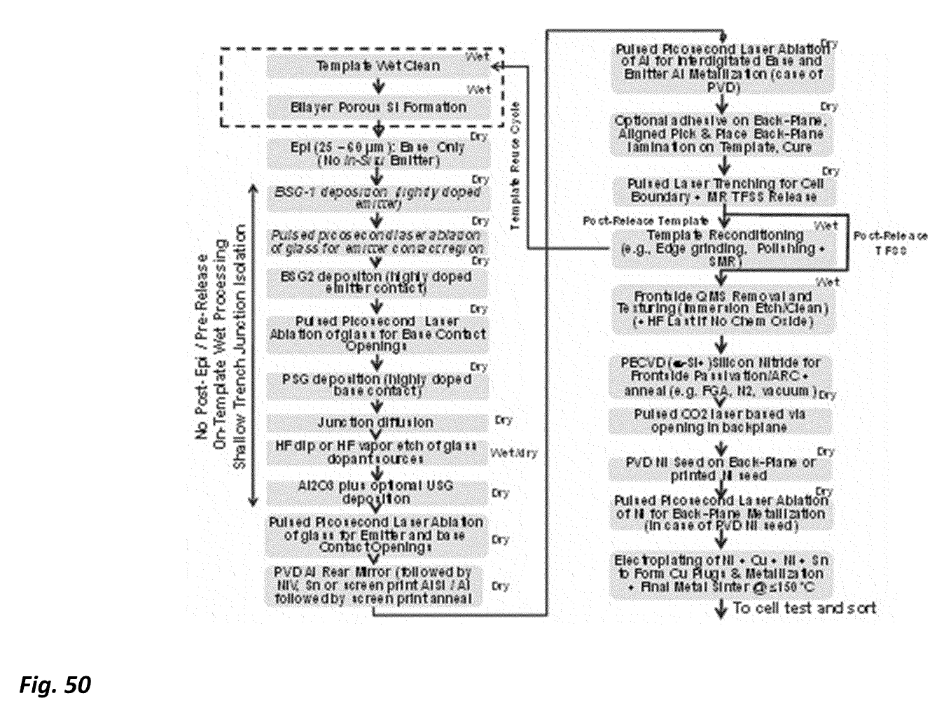

As an alternative to the above deposition sequences, it is also possible to apply the aluminum oxide at a later point in time—as shown by the flow in FIG. 50. FIG. 50 is an example of an alternative process flow which incorporates the deposition of aluminum oxide as the back surface passivation of the active absorber layer. For this flow, the aluminum oxide is deposited after removal of the doped glass layers which serve as precursors for the emitter and base contact diffusion doping.

For instance, after diffusion of the junctions using one of the above schemes which utilize BSG, PSG and USG, it is possible to strip these APCVD oxide layers, for instance using an HF dip or preferably an HF vapor etch, followed by suitable residue removal by gas stream. Then the aluminum oxide is deposited directly onto the silicon, which in turn already contains the suitable emitter and base contact diffusions. Optionally the aluminum oxide can be thick enough or capped with other deposited oxide, such as USG, in order to prevent pin hole shunting of the subsequent metal 1 deposition. Further processing proceeds as described above for all other embodiments.

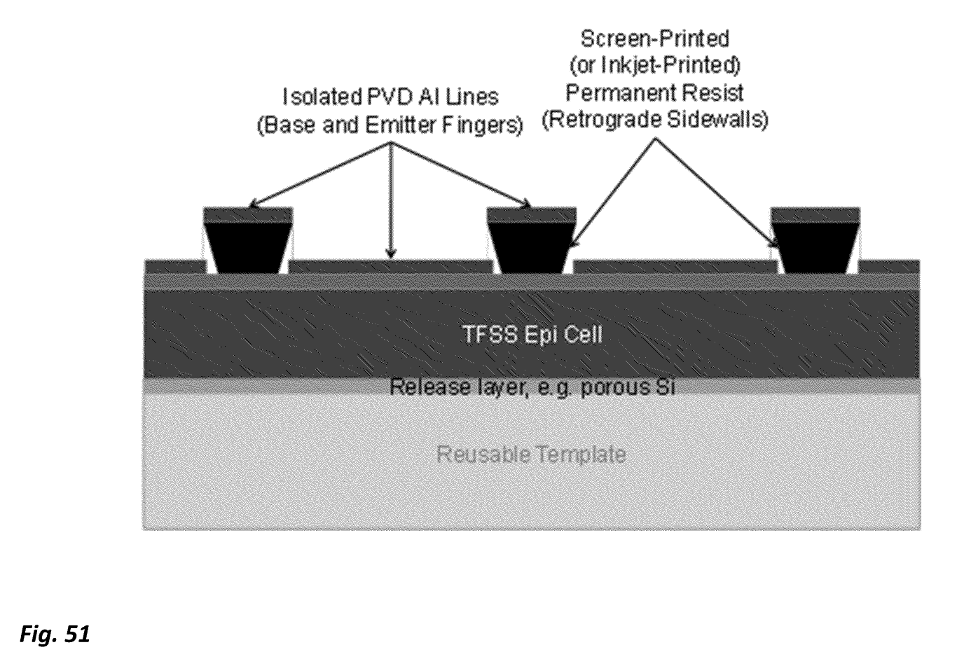

The metal 1 layer provides, in addition to electrical contact, a mirror for the photons that pass through the thin absorber layer. Therefore, a very effective mirror is advantageous for harvesting and converting a higher amount of photons by reflecting the infrared photons for improved photon trapping and energy harvesting. The area coverage of metal, as well as its specific reflectivity, play important roles for this function. In order to increase the area of coverage, deposit a thin, PVD based metal, the PVD layer on a previously patterned structure—as shown in FIG. 51. FIG. 51 is a cross-section a structure which enables the patterning and separation of a blanket deposited metal layer film, the structure providing an enhanced area of metal coverage on the back surface of a backside contacted cell. The structure of FIG. 51 consists of an overhanging structure of a material which is highly transparent to the photons to be reflected and which provides separation (electrical isolation) of the metal layer for a sufficiently line-of-sight based deposition process, such as PVD or evaporation. Such a layer also eliminates the need for laser ablation for the separation of the metal 1 layer. Cleanliness and process control are crucial for such a process in order to avoid direct shunting of adjacent emitter and base metal lines. The structure of FIG. 51 shows retrograde resist sidewalls, which may be formed by double screen printing of resist. Furthermore, optically transparent EVA or PV silicone may be used as the resist material. Alternatively, any other suitable material with long-term reliability may be used as the resist material may remain permanently in the cell and additively contribute to the rear mirror reflectance.

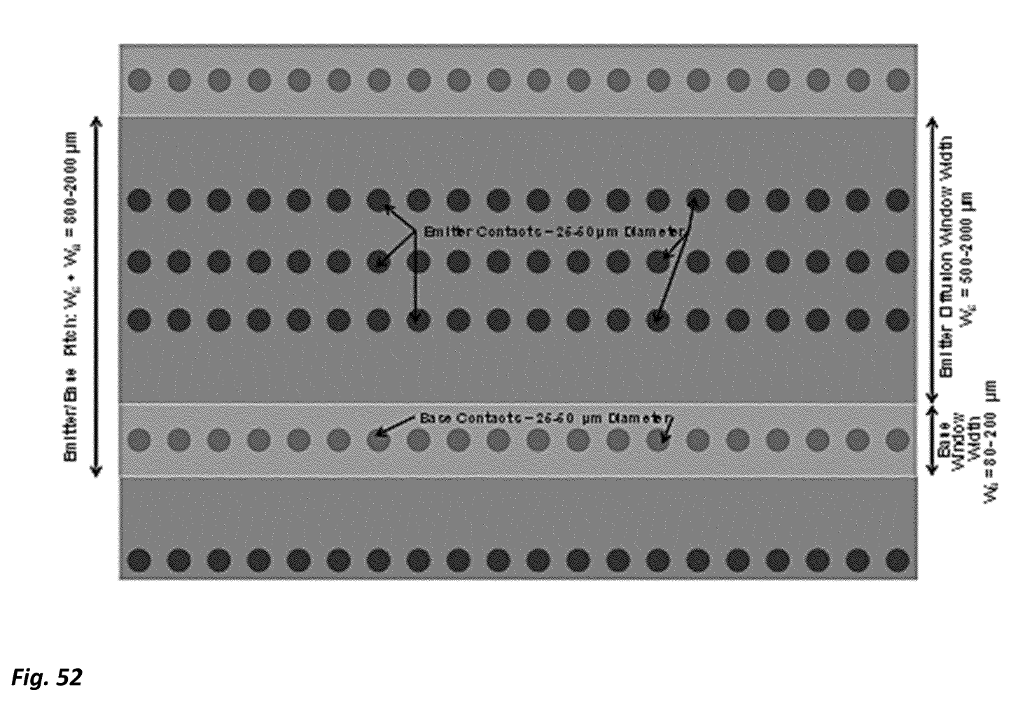

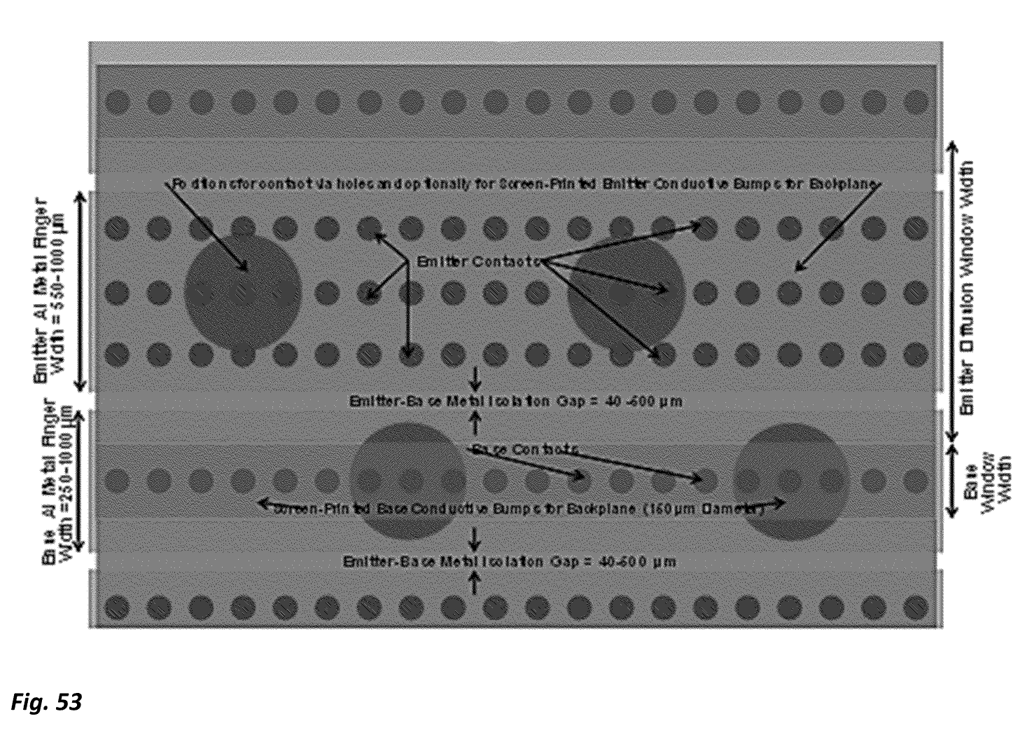

Additionally, the geometrical structure of the on-template processes may be optimized. In addition to the structures mentioned above which enable harvesting electrical current underneath the bus bar regions, there are other geometrical structures, especially for metal 1, that may be employed advantageously and which fan out underneath the bus bars which are located on metal layer 2. However, for simplicity most of the lines of emitter and base regions as well as contacts are parallel interdigitated lines—simplified structures depicted in FIGS. 52 and 53.

FIG. 52 is a top view of a cell backplane showing the layout for base contact window and emitter, including contact openings for the case of linear interdigitated emitter and base fingers. FIG. 53 is a top view of the cell backplane structure FIG. 52 including metal 1 deposition, with the addition of large round areas depicting locations for via holes in the backplane material to enable contact between metal 1 and metal 2 layers.

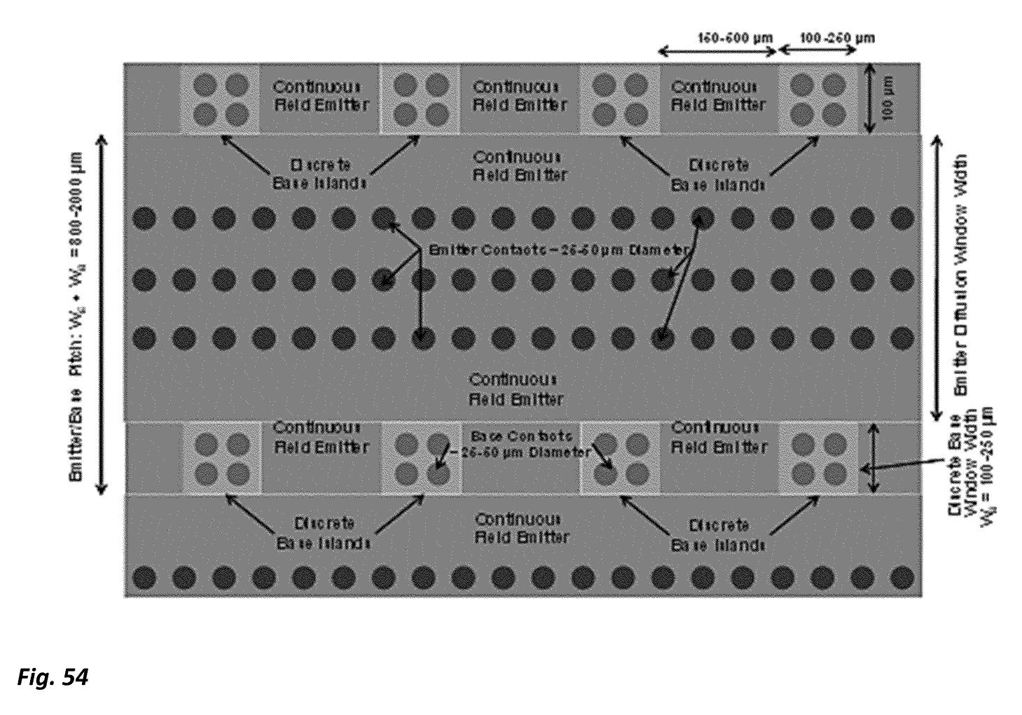

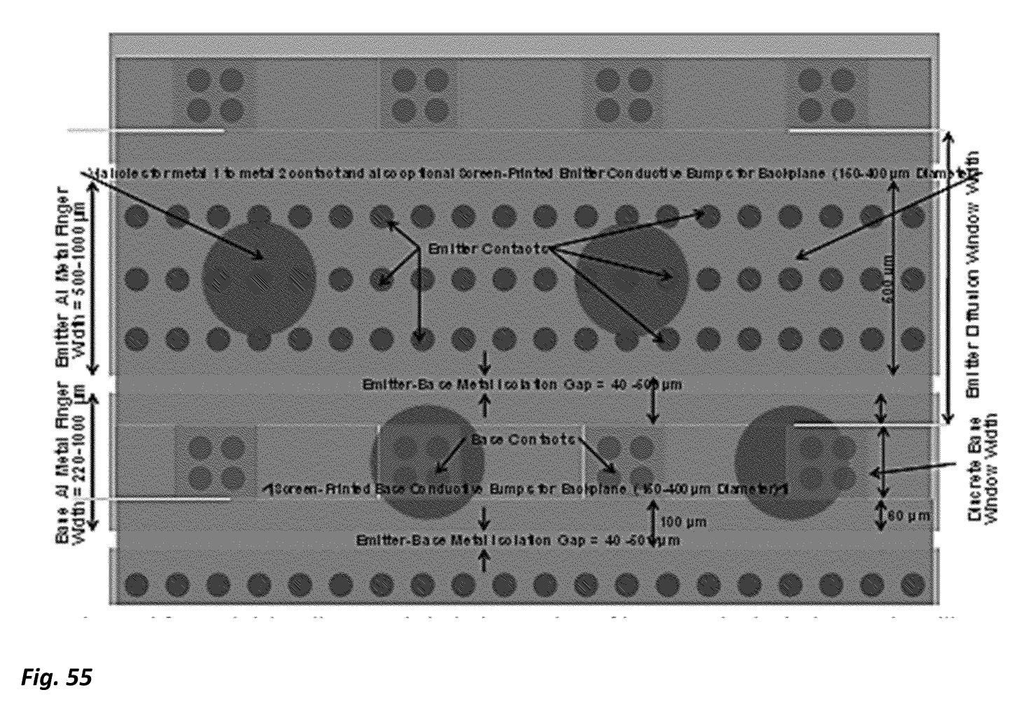

However, it is also possible to have both the base diffusion regions and the base contact opening regions laid out in the form of islands in a sea of emitter area—geometries shown in FIGS. 54 and 55. With such a layout, the electrical shading underneath the base region may be reduced. Electrical shading of the base minority carriers (holes in n-type material) occurs when the holes, rather than having to travel just vertically to the emitter region, also have to travel laterally to the emitter region. This is the case underneath the base diffusion regions. FIG. 54 is a top view of a cell backplane showing the layout for base contact window and emitter, including contact openings for the case of an array of base contact islands. FIG. 55 is a top view of a cell backplane showing the layout for base contact window and emitter, including contact openings for the case of an array of base contact islands with the presence of metal 1 lines and via hole locations. Note that no direct correlation is assumed between the location of via holes with respect to base contact islands.

When base islands are employed, the mean path of holes to travel to the emitter for current collection may be reduced, thereby increasing the hole collection efficiency. FIGS. 52 through 55 show base contact island structures in comparison to the linear structures. The base diffusion islands and the base contact hole openings have to be carefully aligned during the laser ablation processes. Such alignment and synchronization is critical for the success of these structures. The geometrical aspects of islands versus linear regions hold for all structures herein disclosed.

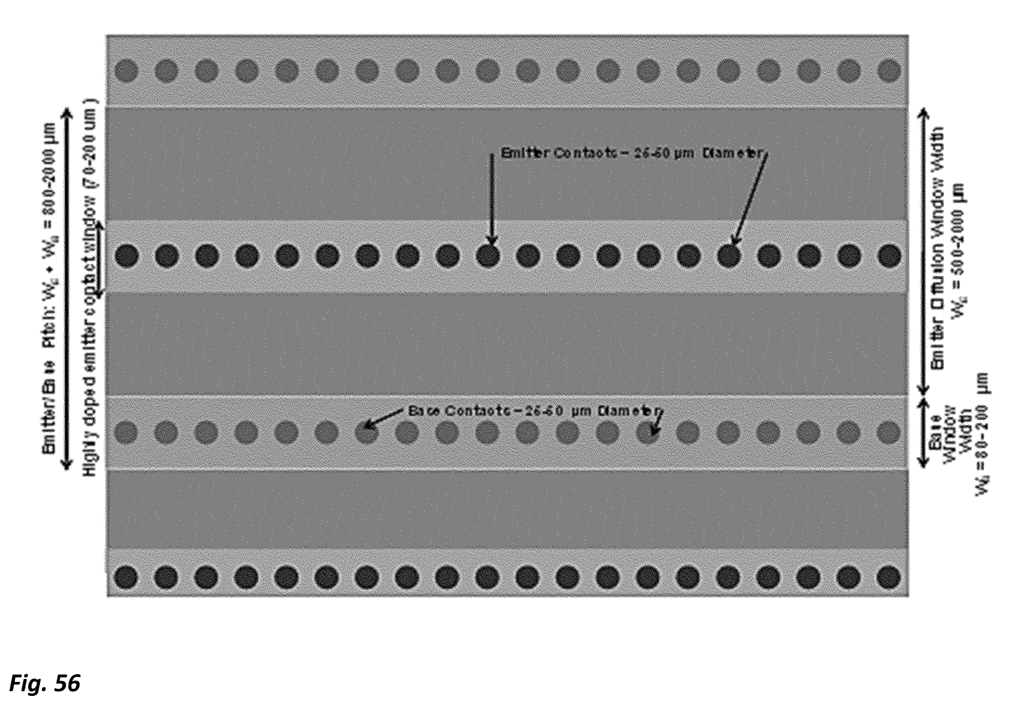

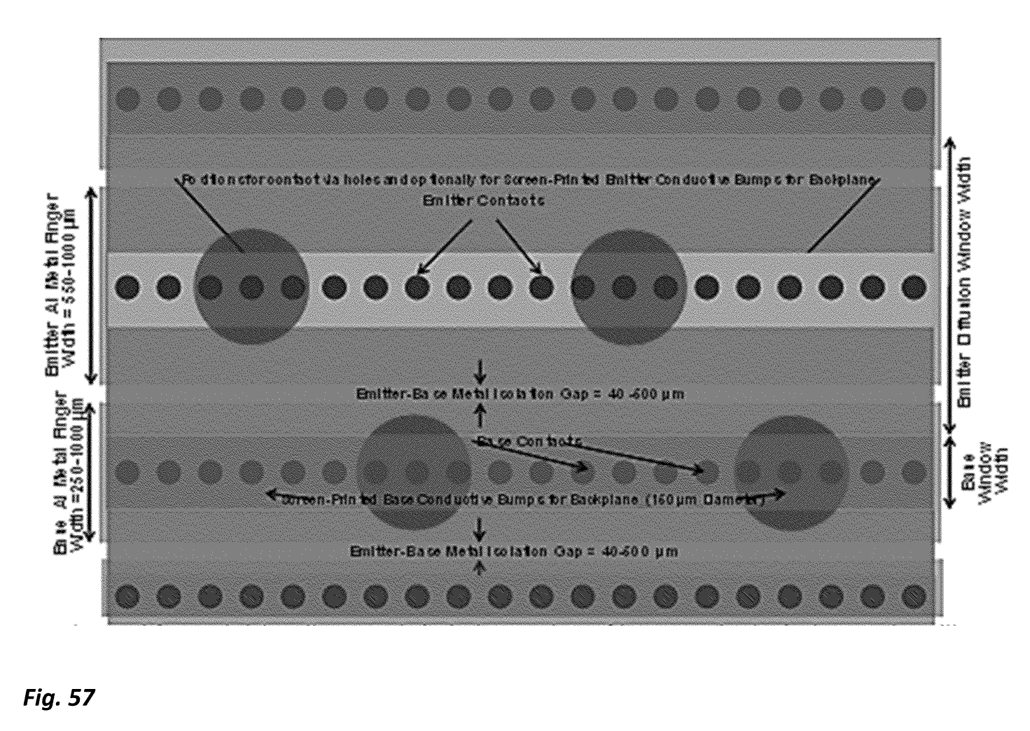

The same concepts hold true for the case of the above described selective emitter formation using two boron dopant sources, for example two different BSG layers, as described above—FIGS. 56 and 57 depict example geometries of the laser patterns for such generated selective emitters. FIG. 56 is a top view of a cell backplane showing the layout for base contact window and emitter, including contact openings for the case of linear interdigitated emitter and base fingers and selective emitter area where the emitter diffusion region of the contact to the emitter is doped higher than the emitter diffusion region away from said contact region. FIG. 57 is a top view of a cell backplane showing the layout schematics for the same selective emitter structure as FIG. 56 including metal 1 deposition. The large round areas are locations where via holes in the backplane material enable contact between metal 1 and metal 2 layers.

Similarly, in most of the presented disclosures metal 1 has been generated using PVD and subsequent laser ablation. However, all structures and methods are fully compatible and applicable as well to any direct write metal 1 application methods, such as screen printing, ink jet or aerosol jet printing and thermal or flame spraying.

Also, in most of disclosed embodiments, the annealing of the passivation has been employed in in-situ anneal methods. However, all processes and structures are also fully applicable to such conditions where the passivation anneal is carried out ex-situ at a suitable point after the passivation material deposition. Advantages to ex-situ annealing include the following: The ex-situ anneal reduces the stringency of matching the thermal expansion coefficients between all the materials involved, mainly the active TFSS absorber material, such as silicon, the backplane material, as well as the metal 1 paste material and the optional additional adhesive that is employed at least between the metal 1 lines and between the active absorber material such as silicon and the backplane laminate. When the passivation itself is done at a sufficiently low temperature, say at or below 220° C. in a sophisticated deposition tool, such as a PECVD machine, then having a subsequent anneal at a higher temperature, such as 300° C. d, can be done in a very simple tool, such as an oven, and in a simple, potentially coin stacked fashion with optional interleaves between TFSS. This sequence of processing alleviates handling concerns caused by residual CTE mismatching between the materials involved.

Heterojunctions.

Most silicon based solar cells on the market today are based on homojunctions. Heterojunctions, especially those with a wider bandgap emitter, benefit from the potential of a higher Voc and thus higher efficiency capability. Several cost effective ways for providing heterojunctions in conjunction with thin silicon cells are provided. The heterojunction is achieved mainly by the introduction of hydrogenated amorphous silicon (a-Si) in the emitter, which provides a wider bandgap when compared to crystalline silicon. One main task when processing such cells with amorphous silicon is to retain the effective process temperature after the amorphous silicon deposition below the crystallization temperature of silicon, typically below 400 deg C. In practice, deposition of amorphous Si (or silicon oxide) is done using PECVD at a temperature in the range of about 150° C. to 200° C.

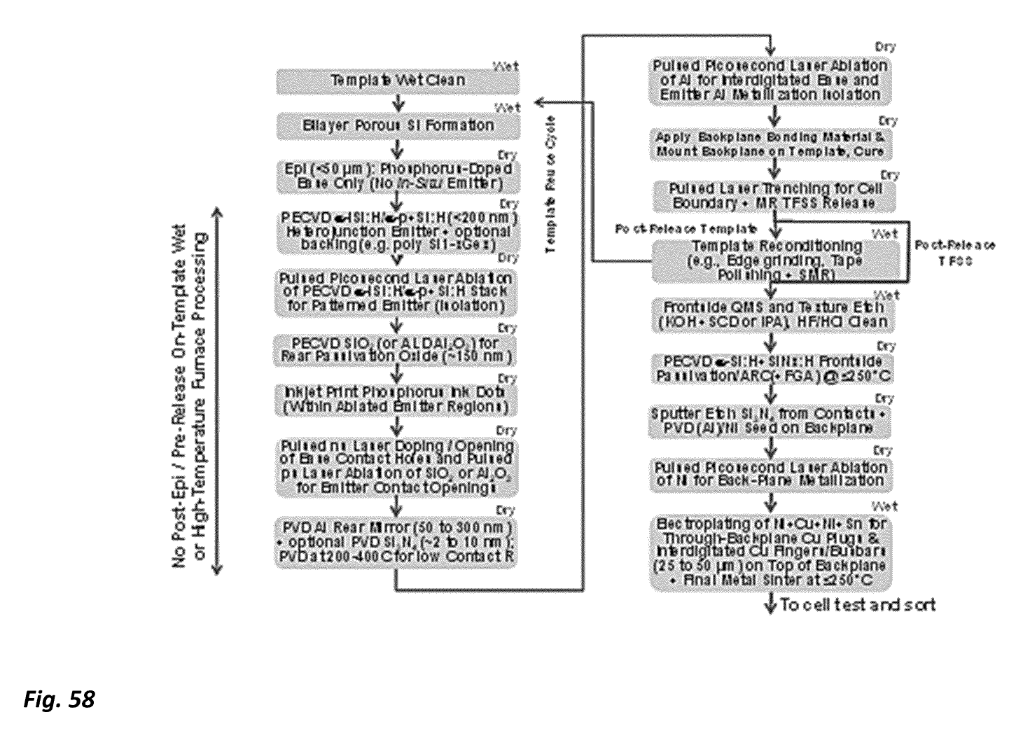

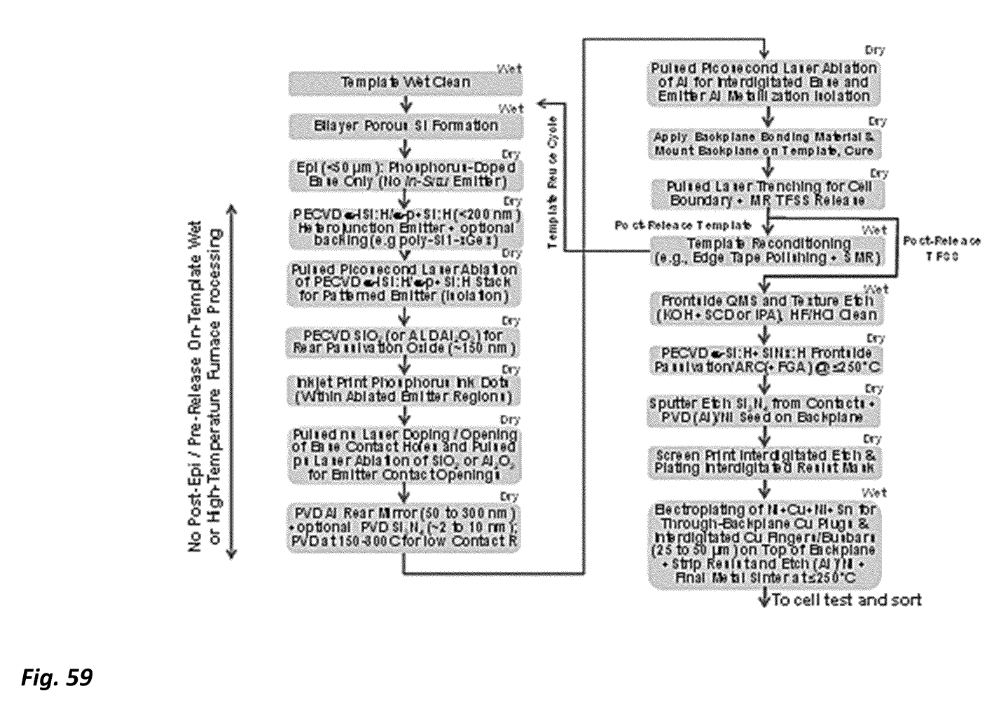

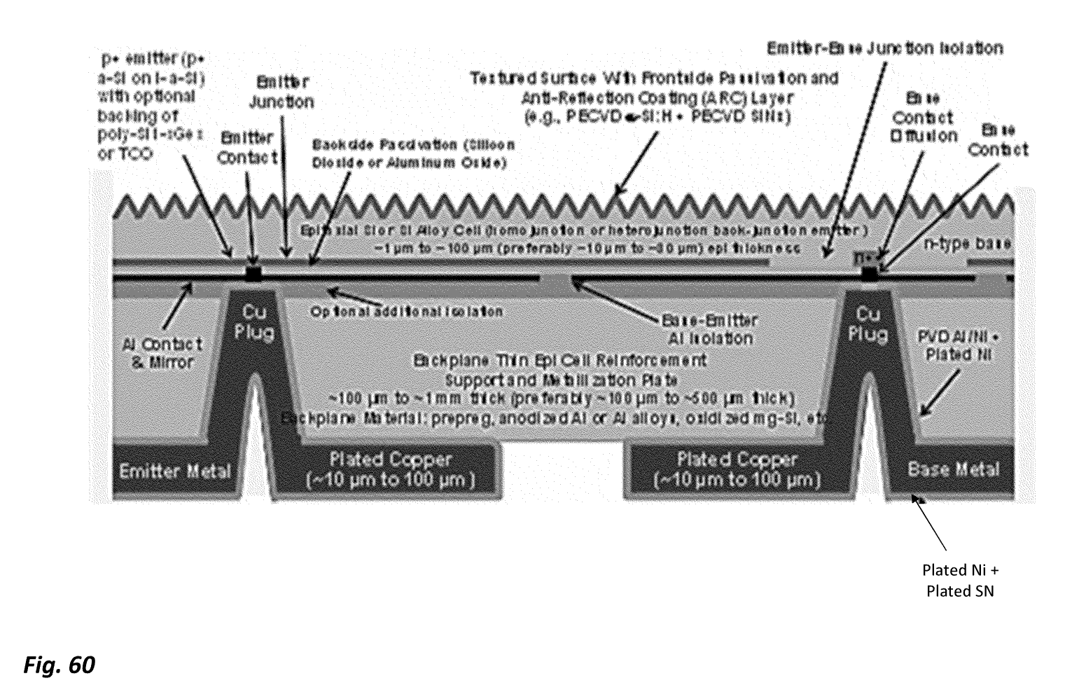

FIGS. 58 and 59 are process flow embodiments for generating a heterojunction cell (both using no furnase processing and inkjet phosphorous print), based on an a-Si emitter and based on using an epitaxially deposited thin silicon absorber structure. FIG. 60 is a diagram of a cross section of a resulting structure employing heterojunction thin silicon cell architecture using an epi based cell. The structural design of such a cell is the same for a CZ wafer based flow, with the exception that thicker silicon can also be employed. However, it is also possible to thin down the CZ silicon afterwards to a thickness with an optimized tradeoff between lifetime and absorption in the infrared, the latter being aided by a thicker absorber layer. Exemplary thickness dimensions for the cell of FIG. 60 include: epitaxial Si˜10 to 50 μm, backside passivation oxide 150 to 200 nm, backplane (prepreg, anodized Al alloy or oxidized mg-Si)˜150 to 500 μm, sputtered (PVD) Al or printed (AlSi, Al) contact/mirror˜50 to 250 nm, plated Ni (top and bottom)˜100 to 500 nm, plated top Sn˜0.5 to 5 μm, and plated copper metal˜25 to 50 μm.

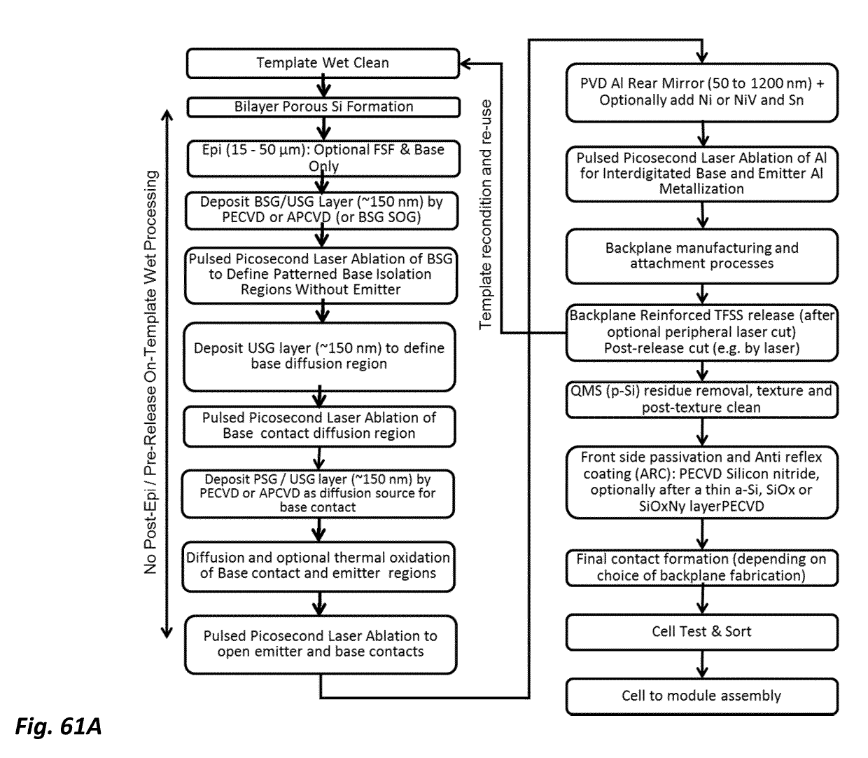

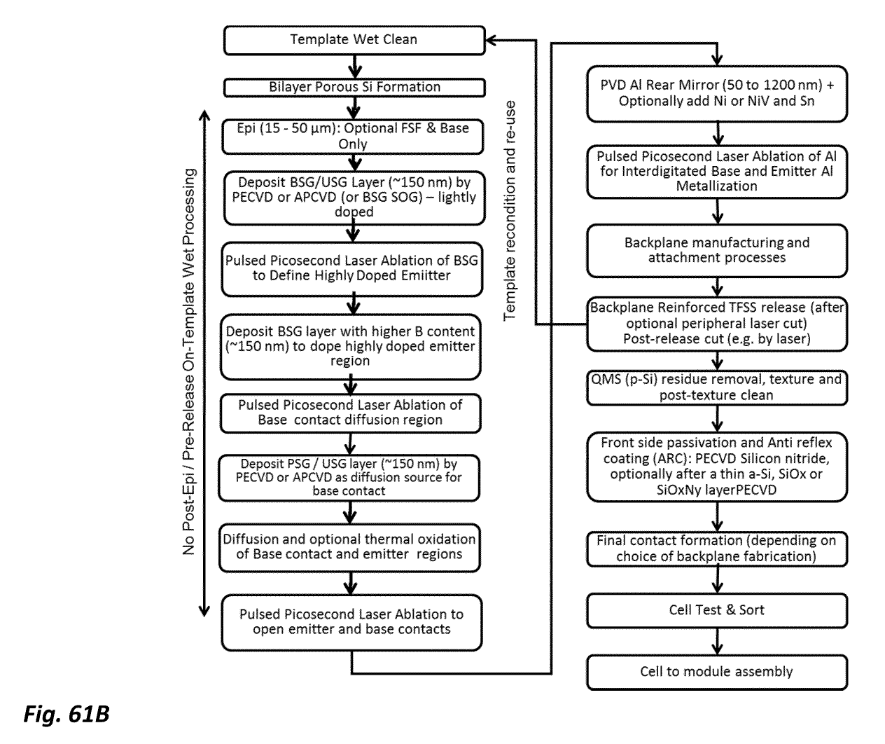

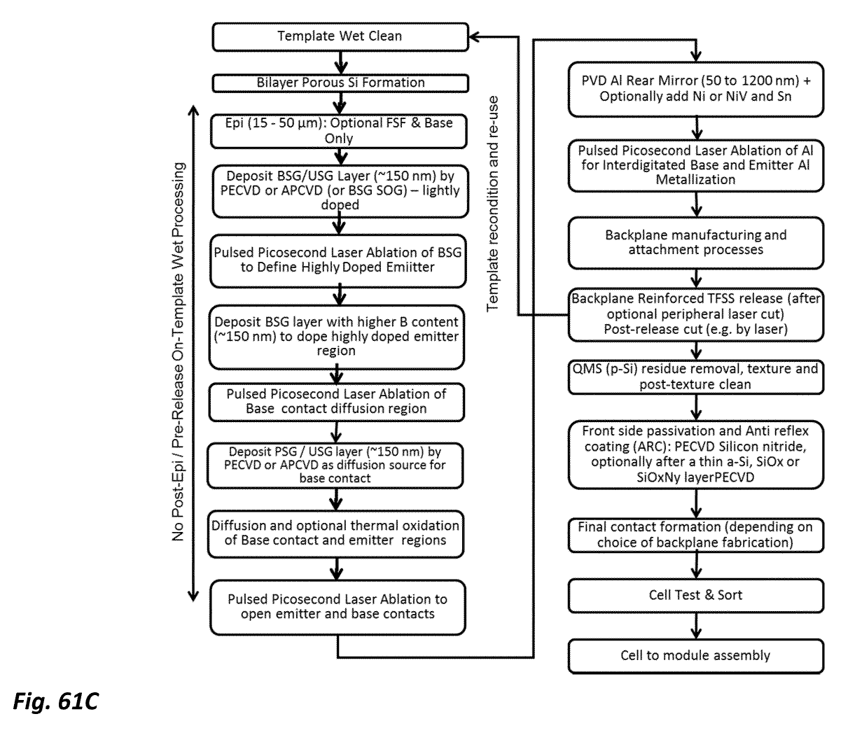

The processes are applicable to thin silicon, such as silicon generated using epitaxial deposition on top of a porous silicon layer, as well as implant/cleave based thin silicon architectures, as well as CZ wafer- and thinned CZ wafer-based cells. FIG. 61 demonstrate process flow embodiments for such embodiments. Template clean, porous silicon formation and epitaxial Si deposition of the n-type base are as in other flows. Following epitaxy, a sequence of thin (typically <200 nm thick) depositions, comprising first an intrinsic, then a p+ doped amorphous silicon (a-Si) stack. As a-Si itself tends to have a rather low conductivity, it can be required to add a backing layer deposition after the amorphous Si to help carry the current with sufficiently low resistance. Such a backing layer should be deposited at a temperature low enough to prevent a-Si from crystallizing. Example layers of such kind are layers transparent conductive oxides such as ITO or ZnO or polycrystalline alloys of silicon and germanium (Si1-xGex), which, with sufficient Ge content, can be deposited in a polycrystalline form at low enough temperature. Subsequently, in the region where the base contact is to be placed, the a-Si emitter material and the optional backing material is ablated, preferably using a picosecond laser. Subsequently a rear passivation layer is deposited, which can be comprised of silicon dioxide or aluminum oxide. In the regions for the base contact, subsequently a phosphorus dopant source can be locally applied, such as by printing of phosphorus ink dots. In subsequent steps, the dopant for the base contact is driven in, for instance using a nanosecond laser that melts the top of the silicon and incorporates the deposited dopant into the silicon lattice. Also a picosecond laser is employed on the emitter contact side to remove the dielectric and make contact to the a-Si emitter. For metal 1 deposition, both PVD followed by ablation to define the metal layer, as well as screen printing can be employed, provided the thermal budget of both processes does not exceed the threshold for a-Si crystallization. The backplane lamination and further downstream processing with its various embodiments can then subsequently proceed in the same way that has been described for the homojunction process.

The following description provides processing methods and designs utilizing a permanent support structure (“backplane”) providing a permanent reinforcement that will not be removed after it is applied to the thin Si wafers and may be used in solar module panels together with front or back contacted thin Si solar cells. Additionally, the disclosed backplanes provide for the extraction of electrical current and power from thin solar cells with suitably low loss. The disclosed permanent support structures enable the handling and support of thin solar cells through necessary process steps including, but not limited to, edge definition or trimming, texturization and clean, as well as passivation and anti reflective coating (ARC) deposition and optional follow-on anneals, by means of thermal, microwave, or radiation such as laser energy. Additionally, the permanent support structures further support contacting schemes, such as via openings and various metallization and dielectric material application schemes including, but not limited to, deposition, printing, plating, laminating metal or metal containing or in general conductive films as well as dielectrics, including intra-cell, cell to cell and cell to module contacting.

The disclosed subject matter details novel methods and structures for reinforcing very thin Silicon (Si) solar wafers and cells to reduce breakages and to furnish contacts to emitter and base during the manufacturing process. These methods and structures are motivated by the solar cell industry's movement from standard Si solar cell thicknesses of 180 to 250 μm towards thinner cells in order to reduce Si usage and thus material costs—Si wafer production technology has advanced rapidly in reducing the wafer thickness. The fabrication of Si wafers with thicknesses less than 30 μm has been demonstrated through various methods such as layer transfer and epitaxial Si deposition. However, the industry is generally unable to manufacture Si solar cells of thickness less than about 140 μm because of the significant increase in cell breakages and lower manufacturing yields. The disclosed subject matter provides for the handling of much thinner silicon through the solar cell line with high yield, with thicknesses down to tens of microns or even less, thus reducing costs associated with breakages. Currently, the industry standard substrate thickness is greater than 180 μm. And while solar cell manufacturers have begun using Si wafers as thin as 140 μm, Si wafers less than 140 μm thick are often too fragile for usage in high volume manufacturing processes. It is anticipated that aggressive cost savings may be achieved with solar cell material less than about 50 μm thick without significant detrimental impact to cell performance as less silicon allows for a cheaper solar cell (silicon material cost constitutes a substantial fraction of total solar cell cost).

As previously noted solar cell substrates may be shaped in a variety forms including, but not limited to, standard pseudo squares, squares and hexagons. The size and the area of the substrate also varies, for example 125 mm×125 mm or ×156 mm or even much larger cells including but not limited to 210 mm×210 mm. Further, substrate material may be either mono-, poly- or multi-crystalline silicon. The disclosed subject matter is applicable to various types of substrates as distinguished by the source and the shape of the substrates. For instance, it is applicable to at least two categories:

A) Flat wafers from ingots obtained using either Czochralski (CZ) or float zone (FZ) techniques (textured or untextured) or multi-crystalline cast ingots which are obtained using techniques such as wire-sawing, polishing, lapping, etching, or ion implantation (Hydrogen or Helium) based slicing of bulk ingots.

B) Epitaxially or polycrystalline grown substrates which are produced directly using any of the precursors used for depositing silicon such as silicon tetrachloride (STC), trichlorosilane (TCS), dichlorosilane (DCS), or Silane. These substrates may or may not have the dopant diffusions as is customary in a finished solar cell such as back surface field (BSF), bulk doping, front surface field (FSF), and emitter, as part of the epitaxial growth process. The method is widely and equally applicable to any of the several combinations of doping which form a solar cell. For example: (1) n-type bulk doping using phosphorous with a boron-doped p-type emitter and (2) p-type bulk doping using boron with a phosphorous-based n-type emitter. A preference has been noted in the use of n-type doped base layers with p-type emitters as these n-type based solar cells tend to exhibit the light induced degradation effects often seen in silicon solar cell material with a boron doped p-type base.

Several embodiments of fabricating the epitaxial substrate are possible. In one embodiment the epitaxial substrate is grown on top of a sacrificial layer on a mother template and is subsequently dislodged. The mother template is then reused (for instance by residue removal, optional reconditioning by e.g. bevel or area lapping or grinding, cleaning and re-formation of the sacrificial layer) several times to grow more epitaxial substrates. The sacrificial layer has to transfer information about the crystalline structure in the mother template to the epitaxial layer and is removed selectively with respect to the substrate and the mother template. One specific embodiment of the sacrificial layer is porous silicon, whose porosity may be modulated to achieve both the aforementioned critical functions.

Within the epitaxial substrate embodiment, several possibilities distinguished by the underlying, starting, mother template are possible. Although, not limited to these, a few of these possibilities are described as examples below.

### i) Substantially Planar Epitaxial Substrate:

This has at least two distinct cases. In the first case the epitaxial layer is grown on top of a flat, untextured template which does not have a pattern. The template may be grown using standard Czochralski (CZ) growth or may be manufactured as a seeded cast quasi-monocrystalline ingot to save costs of template fabrication. A multi-crystalline template material may also be used, which in turn will yield multi-crystalline thin cells. Herein, a substantially planar substrate is referred to as an epitaxial substrate. The released epitaxial substrate is also flat without a pattern. The second case is where there is an underlying pattern or texture on the template; however, the size scale of this texture is substantially smaller than the thickness of the epitaxial substrate. Thus, the released epitaxial layer is also textured but still substantially planar. This substrate is also referred to herein as an epitaxial substrate.

### Ii) Three Dimensional Epitaxial Substrate:

Here the underlying template has been pre-patterned or pre-structured and the pattern geometries or texture is of an order substantially equivalent or greater than the thickness of the epitaxial film. Thus, when the epitaxial film is released it will have a substantially non-planar 3D geometry. Within this paradigm, several examples of pre-pattern geometries are possible, for instance, a pyramid-based cell. This substrate is also referred to herein as an epitaxial substrate.

In the above description, the release layer is comprised of porous silicon and the epitaxial layer is silicon as well. However, the disclosed subject matter is also applicable to the use of other release layer methods such as those generated by the implantation of hydrogen to form a cleave release region or the use of a laser that is focused inside the silicon to form a release or cleave region. In addition, the disclosed subject matter is also applicable to active absorber material other than silicon, including hetero-epitaxial combinations such as silicon with germanium, carbon or mixtures thereof, as well as materials from the III-V family such as gallium arsenide (GaAs), which can, for instance, be grown on top of germanium or a graded silicon germanium region which in turn is grown onto a porous silicon layer and which is designated to allow for lattice matching between GaAs and underlying silicon in order to grow good quality GaAs on essentially a silicon substrate with a release layer.

For the aforementioned substrates (flat wafers from ingots and epitaxial substrates), if the thickness of the deposited silicon is substantially thin or if the processing conditions are not compatible with the materials used for permanent reinforcement, it may be necessary to introduce a carrier to temporarily support the solar cell during processing until it is suitable for permanent reinforcement. Possibilities for temporary reinforcement include (but are not limited to) mobile carriers utilizing electrostatic, vacuum, or combination of electrostatic and vacuum methods etc. These structures will substantially strengthen and reinforce the thin substrate thus ensuring a high manufacturing yield. However, the disclosed subject matter provides a permanent reinforcement for use in solar module panels together with the front or back contacted thin Si solar cells.

Further, in the case of an epitaxial substrate formed on a template with a release layer, the disclosed subject matter provides for continuous thin substrate support during the manufacturing process. For example, in the early, preferably dry and potentially high temperature process stages using the template as reinforcement and in the later, preferably low temperature and potentially wet process stages, using backplane reinforcement structures and methods.

Thus, the disclosed subject matter entails materials, designs, structures and methods to fabricate permanent support structures that enable the manufacturing of solar cells with thin active absorber layers (“thin solar cells”) and the structures of the resulting solar cells. Further, the disclosed subject matter provides for the integration of permanent support structures within various embodiments of cell manufacturing flows—the backplane structures, materials and methods disclosed may be employed for fabrication of photovoltaic solar cells that utilize high efficiency thin film solar cell substrates.

An advantageous design for the disclosed thin film solar cell structures are back junction, back contacted cells where the reinforcement is applied onto the side that contains the back junctions and back contacts. However, cell designs with at least one polarity of the contact on the front side may also be supported using the disclosed subject matter in combination with low temperature processing, typically below 250° to 350° C., is used to manufacture the front side contact if the front side contact is manufactured after the attachment of the reinforcement. An effectively low temperature process may utilize laser annealing that only heats the front surface while keeping the back surface cold enough for the backplane material to sustain the process. Methods for front side contacting include, for example, the formation of front side lines of Al or other metals with subsequent laser annealing for contacting and optional emitter junction formation, and contacts at the front side or patterned implantation followed by laser or other substantially low temperature annealing for forming the junctions, followed by a suitable metallization scheme such as Aluminum deposition, either patterned using deposition, printing or spraying, or unpatterned with subsequent patterning.

The intent of this disclosure is to enable the reinforcement and thus high yield manufacturing of many types of thin film structures while the focus of the disclosed embodiments is on presenting solutions for the often more challenging process of manufacturing back-contacted cells. Examples for viable structures and methods for manufacturing the thin film solar substrate (TFSS) up to the point of metallization are described generally in the process flows of FIGS. 61A-C. FIGS. 61A-C are process flows showing major processing steps for the formation of a back contact solar cell including general backplane reinforcement related steps further detailed throughout this disclosure.

The process flow starts with a cleaned re-usable semiconductor wafer, called a template. A release layer, such as porous semiconductor material, is then deposited on the surface of the template. In the case of silicon wafers, this may be porous silicon. The porous silicon layer may comprise at least two zones of different porosities, where the top layer is preferably of a lower porosity than the bottom layer. The bottom layer serves as a designated weak layer while the top layer is reflowed in a subsequent bake step in an epi reactor prior to the silicon layer deposition and the reflow reconstructs the surface to provide a seed surface to enable epitaxial deposition. In the ensuing epitaxial deposition, which may be carried out at high temperature using at least one silicon containing gas such as trichlorosilane (TCS) mixed in hydrogen (H2), a thin layer of semiconductor, for instance silicon, is deposited on top of the porous layer on top of the template. This layer may serve as the thin active absorber layer, or light capturing layer, for the solar cell. Shown, the active absorber base layer is an n-type layer, formed by, for example, the addition of phosphine (PH3) during the deposition step. The PH3 may be optionally diluted in hydrogen. Graduation of PH3 flow during the deposition may be employed to achieve doping gradients in the film where desired.

After epitaxial deposition, further steps comprise the formation and structuring of the emitter layer, e.g. by atmospheric pressure chemical vapor deposition (APCVD) of borosilicate glass (BSG), and laser ablation of BSG where desired in order to make openings for base contacts. A subsequent optional step includes deposition of undoped silicate glass (USG), followed by laser ablation in order to later generate a separation zone between base contact and emitter. Then, phosphorus-silicate glass (PSG) may be deposited as a precursor to later form a highly n-doped base contact. Undoped layers may be used for separation of each layer where needed. A subsequent thermal drive-in step, optionally with oxidation in at least one step to form a good interface with the semiconductor (such as silicon), may be used to drive-in the doped diffusion profiles. A laser may then be used to ablate the dielectric in desired contact areas, which enables contacting with a subsequent metallization step. Suitable lasers for above ablation processes include picoseconds lasers and especially picoseconds UV lasers which may cause little or no subsurface damage to the underlying semiconductor.

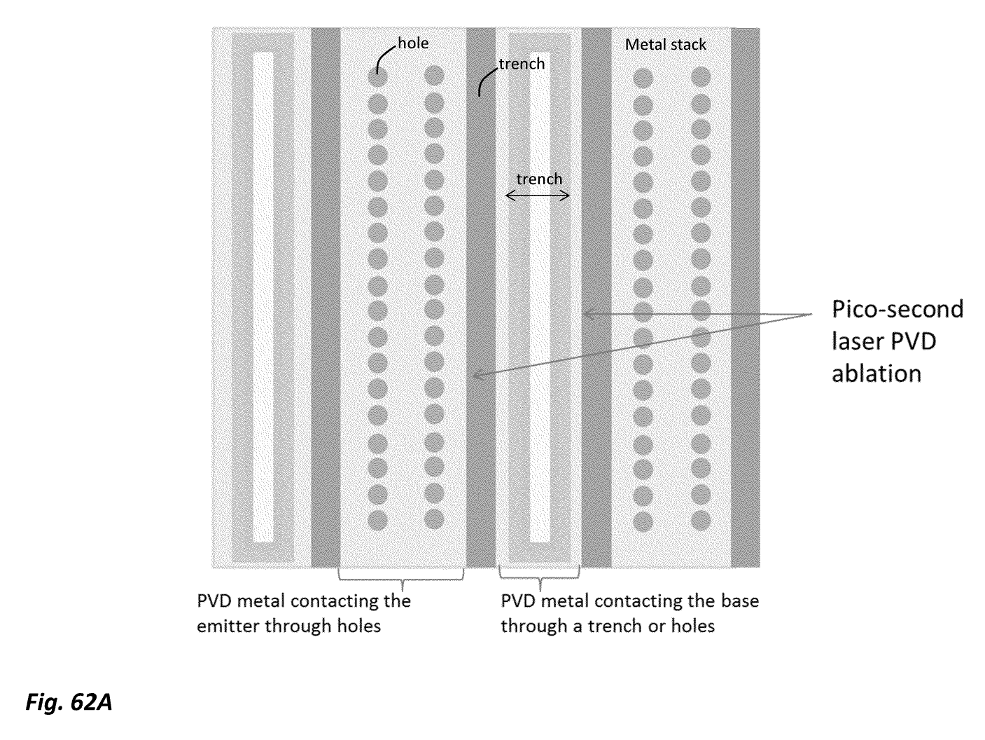

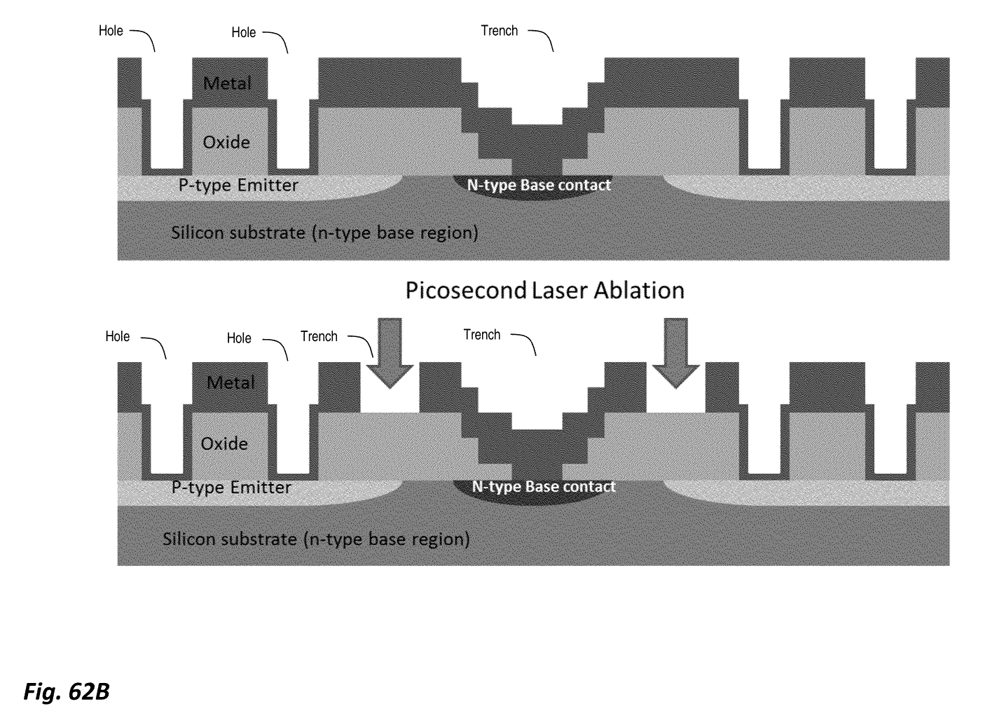

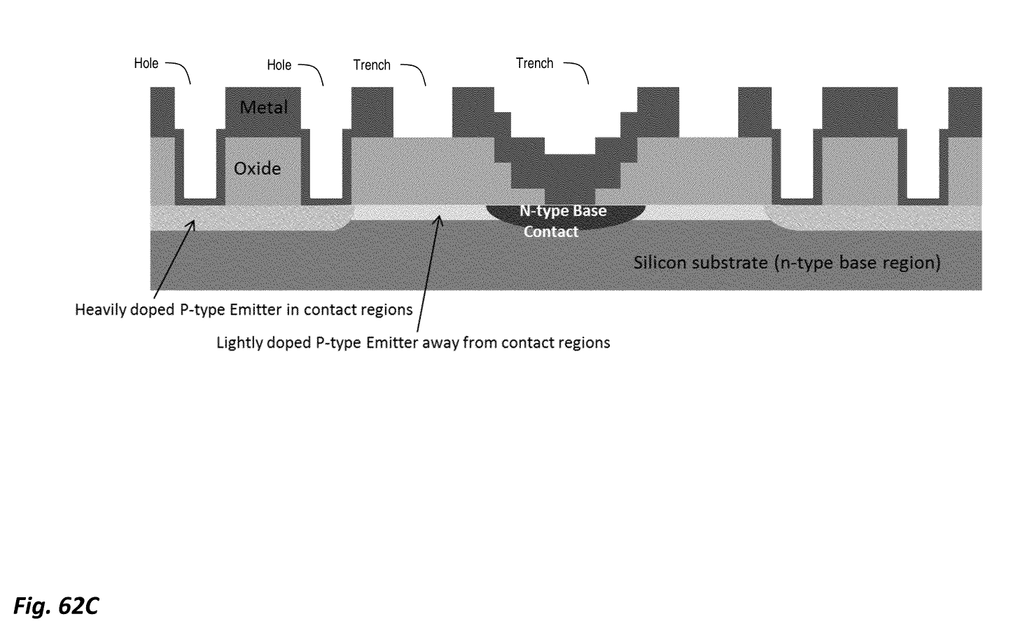

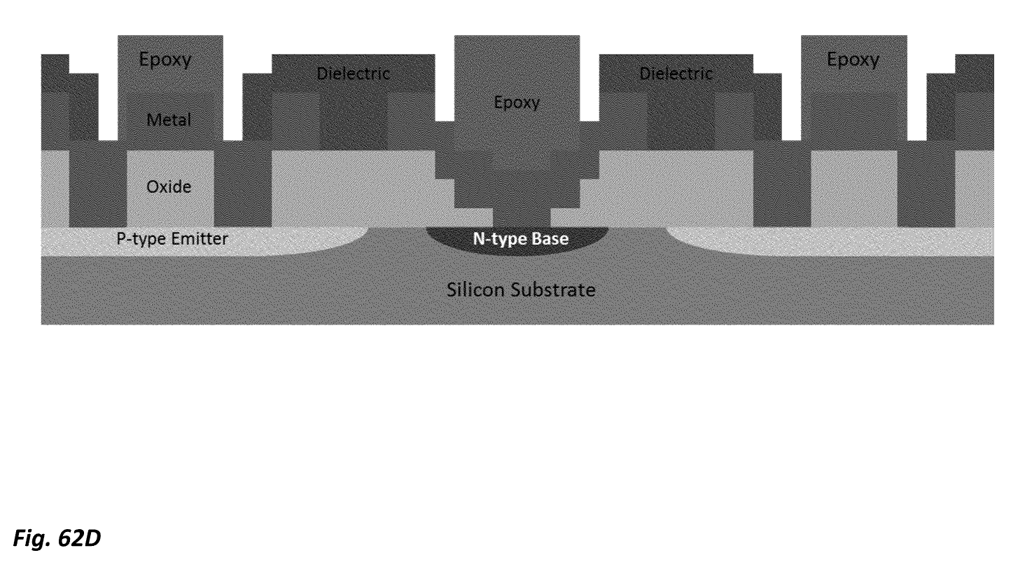

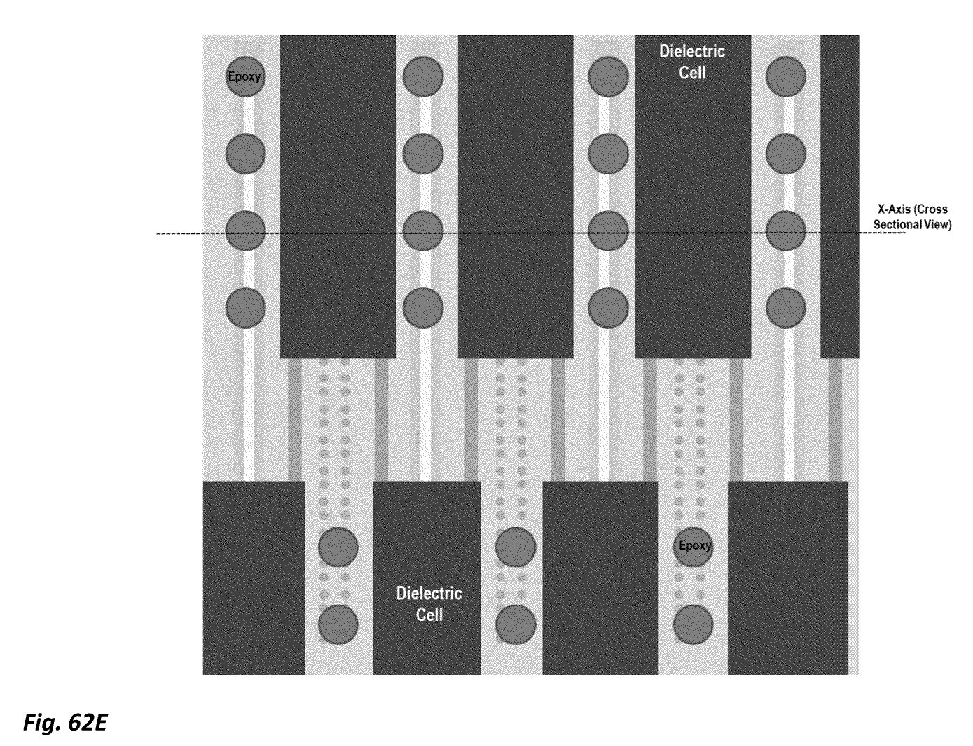

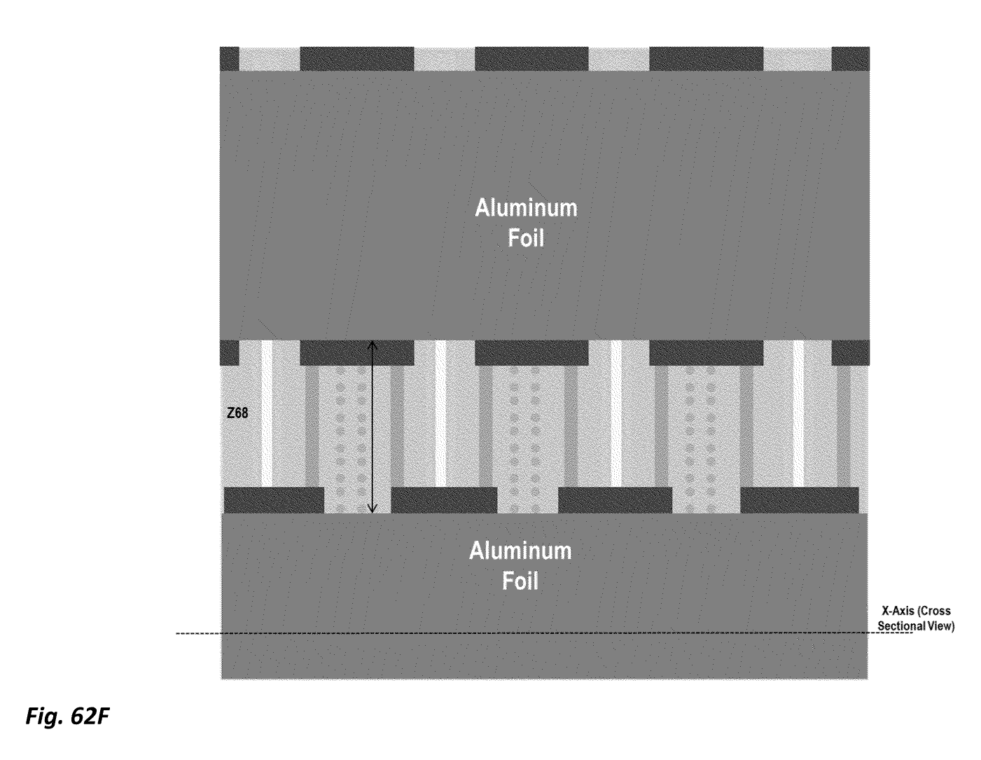

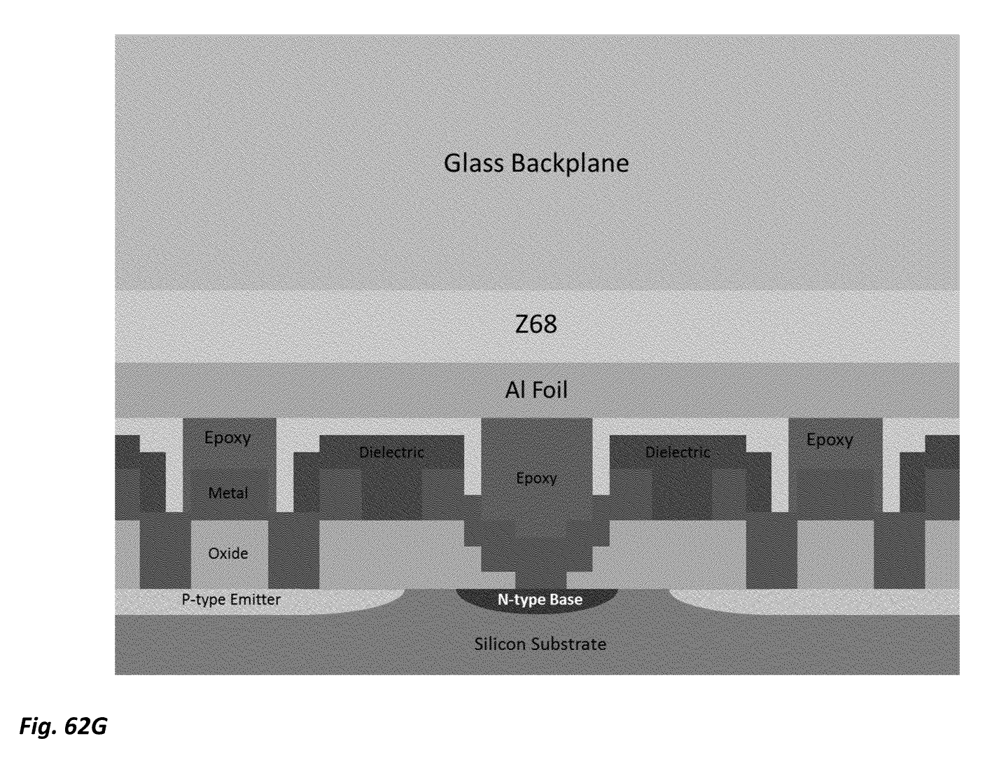

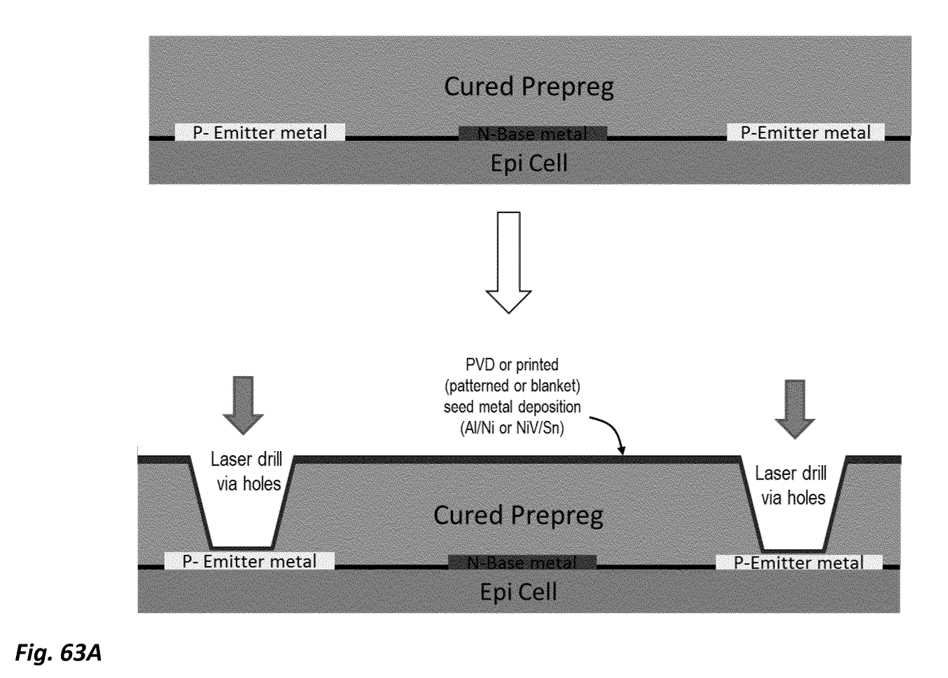

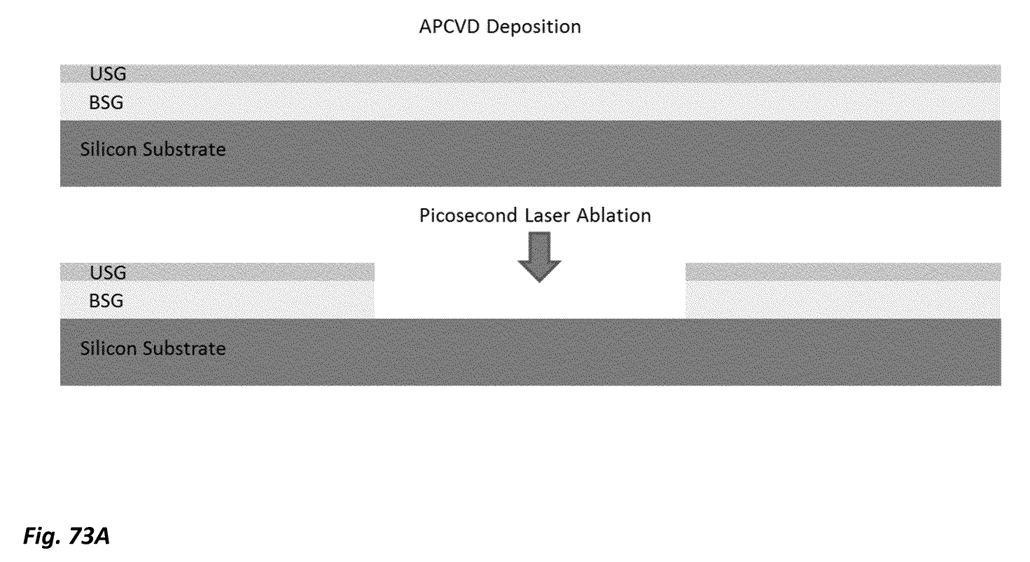

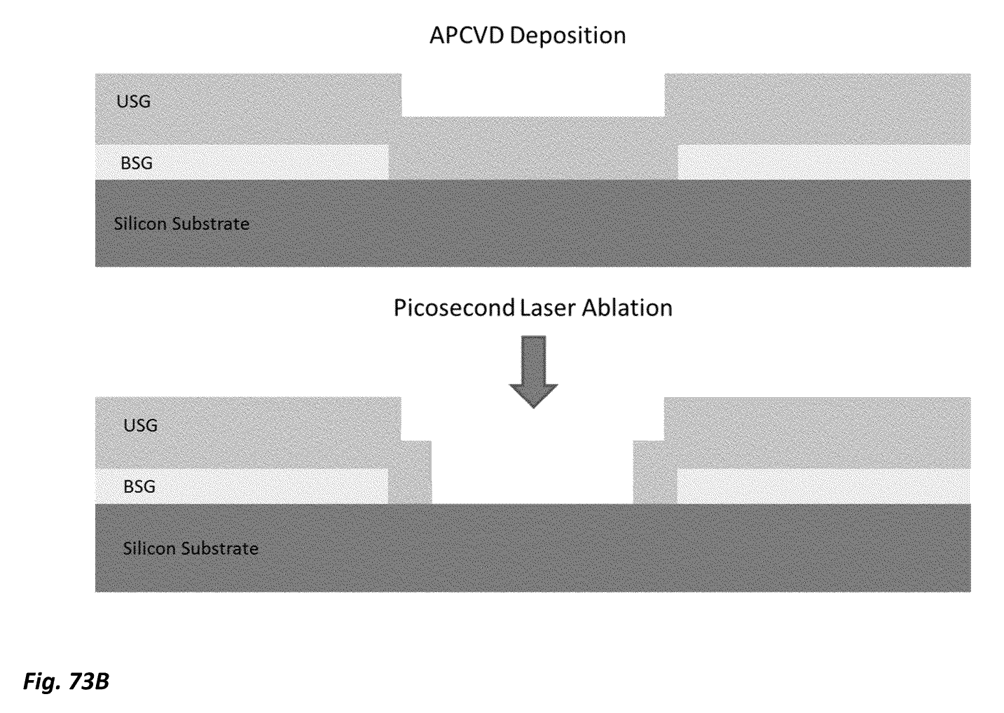

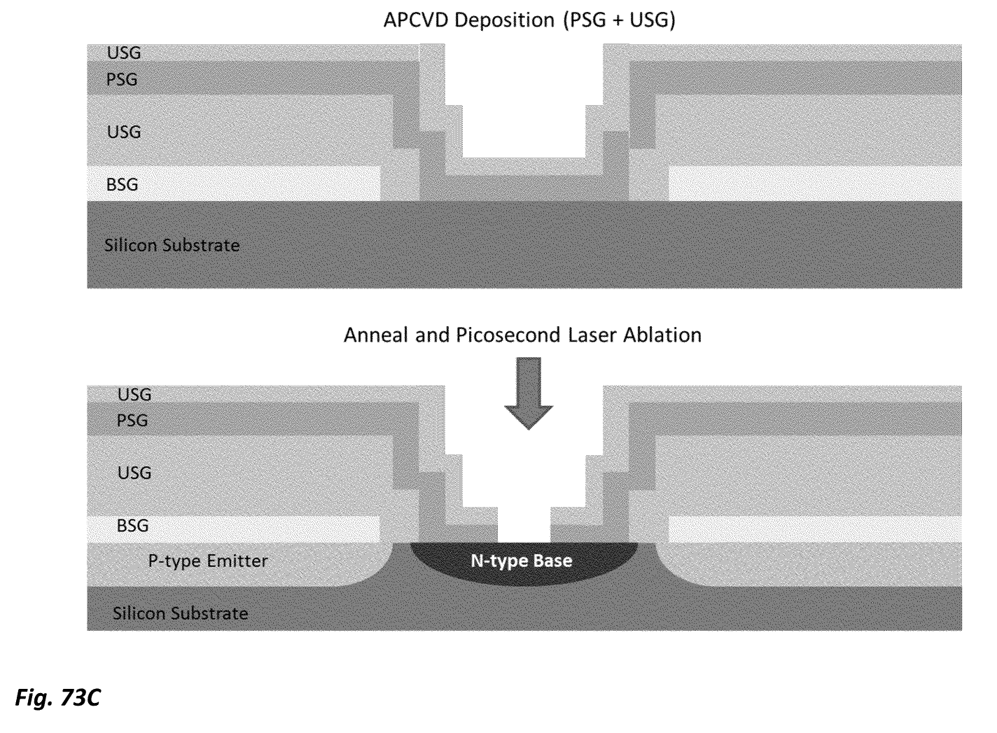

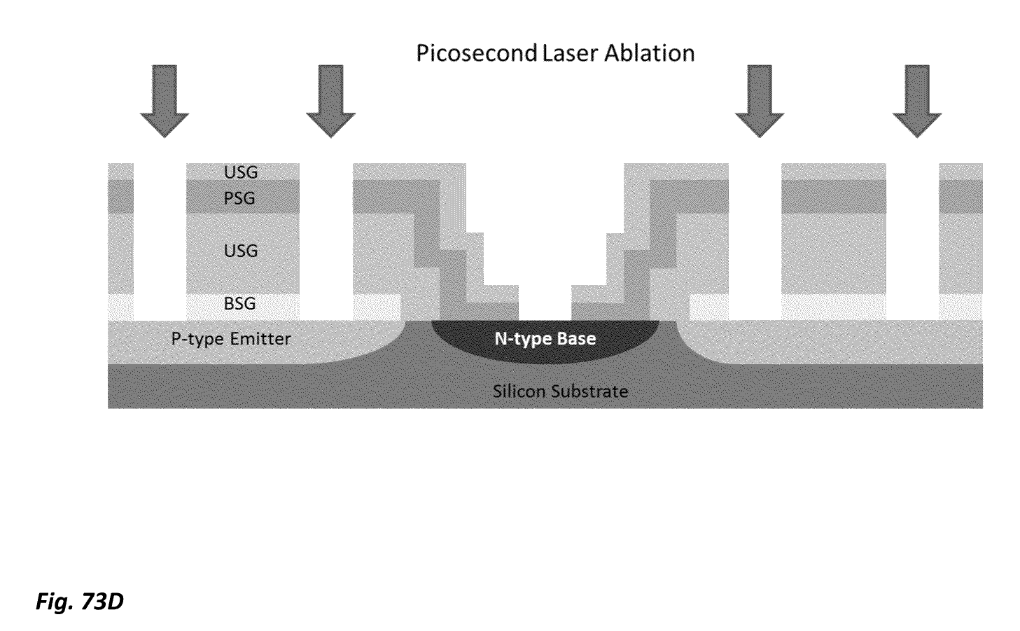

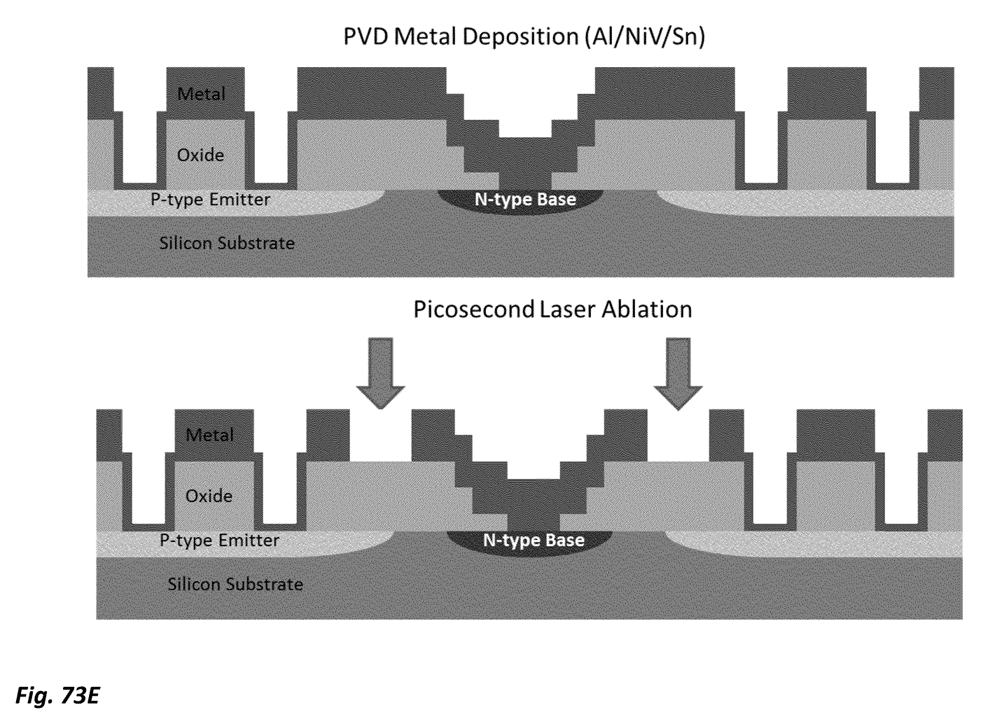

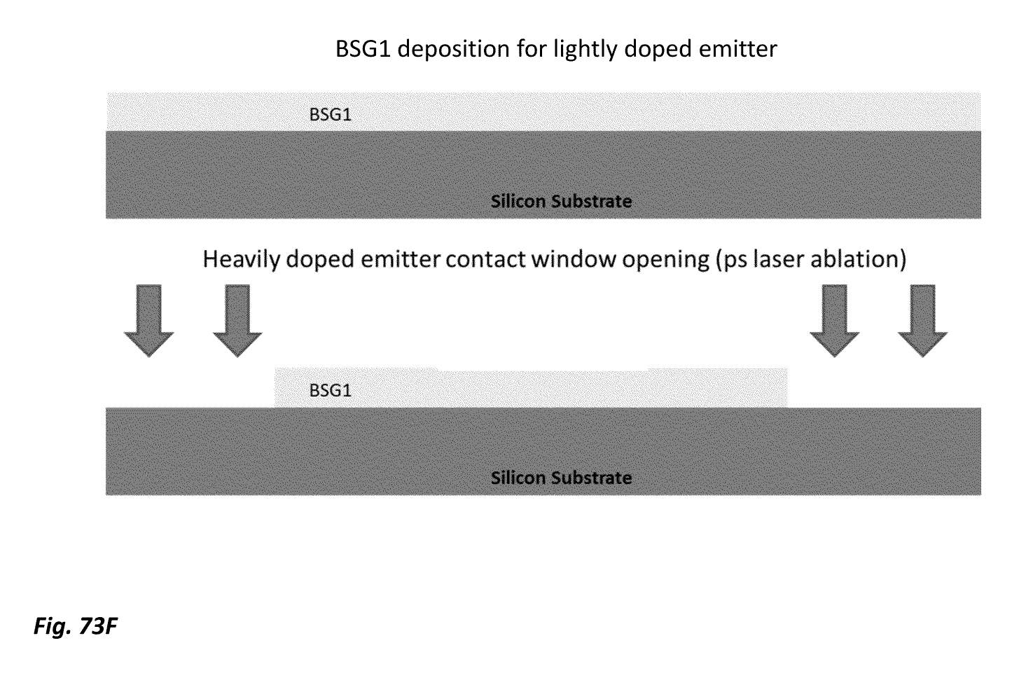

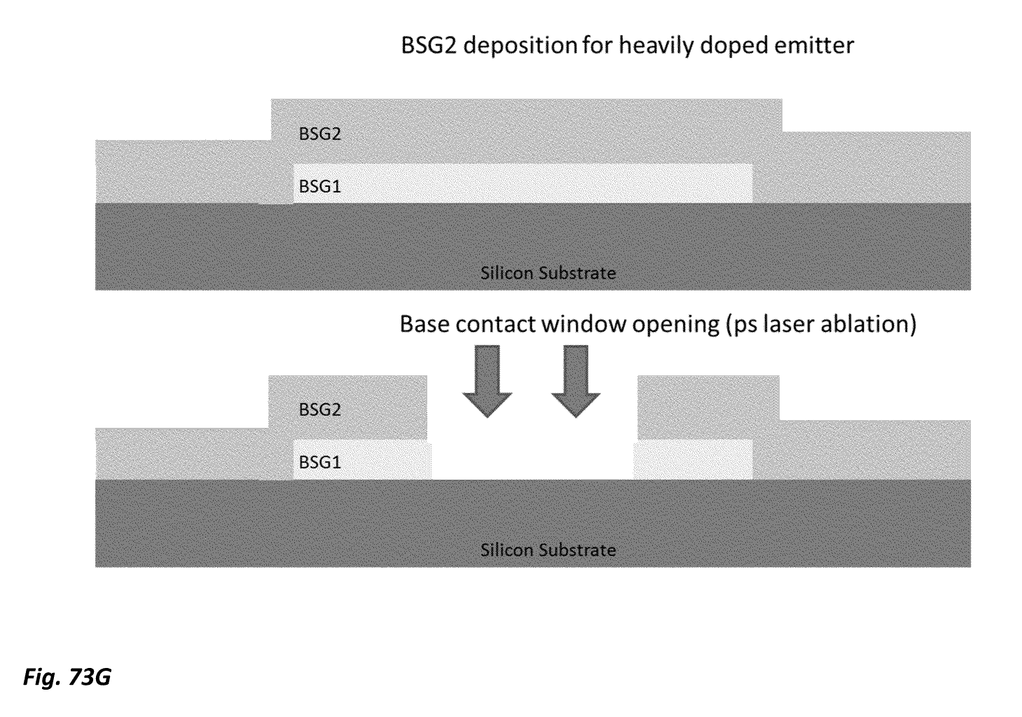

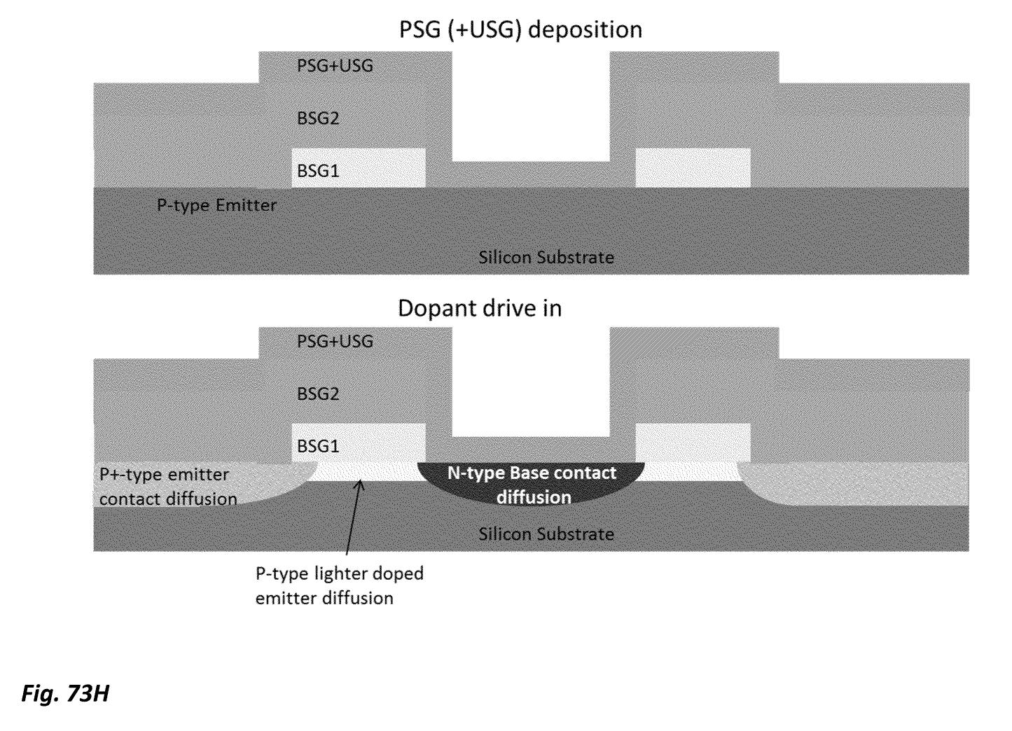

It is to be noted that after the backplane attachment and structuring processes disclosed herein, the template may be re-used after the release of the backplane reinforced structured thin film solar substrate (TFSS) from said template. This re-use requires clean-up steps to render the template ready again for the next round of porous layer formation and epitaxial deposition. FIGS. 62A-C are diagrams of structures prior to backplane reinforcement steps. FIGS. 62A and B are a top and cross-sectional views, respectively of on cell structures after PVD and metal contact openings. FIG. 62C is cross-sectional views of on cell structures after PVD and metal contact openings for a selective emitter structure. A method example on how to arrive at a selective emitter structure is detailed in FIGS. 73F through 73J.

FIG. 62D is a cross sectional diagram of the structure of FIG. 62B after dielectric layers and epoxy pillars formation. FIG. 62E is a top view of the structure of FIG. 62D after dielectric layers and epoxy pillars formation. FIG. 62F is a top view of the structure of FIG. 62E after metal fingers (metal layer 2, shown as Aluminum foil) formation. FIG. 62G is a cross sectional diagram of the encapsulated structure of FIG. 62F.
Generally, the disclosed backplane structures utilize orthogonal current extraction. In back contacted solar cells, current typically needs to travel along long distances as both contacts are on the same side—thus a large area planar electrical contact may not be easily realized. To reduce electrical shading metal finger pitch typically needs to be kept small while finger height needs to be substantial, which often results in a costly and high stress process for metal finger formation on back contacted solar cells. Such high stresses can even prevent the move to larger substrate sizes for conventional back contact cells.

The disclosed subject matter provides a solution to high cost and high stress processes associated with back contact metal finger formation through the use of orthogonal current extraction. Metal fingers on the thin solar cell are kept thin, the current is then guided up through contacting dots, which can be comprised of conductive adhesives such as, but not limited to, silver epoxy or of solder, or of deposited or printed next level metal. The remainder of the area or most of the remainder around the contacting dots is covered by a printed dielectric adhesive or by a dielectric adhesive sheet, providing electrical isolation against the backplanes. Such dielectric sheets can for instance consist of prepreg that is laminated to the thin film solar substrate (TFSS) and later has vias drilled into it in areas where contact between metal layer 1 and metal layer 2 is to be established.

Current is then extracted orthogonally where large emitter and base fingers in the backplane structure contact the respective small emitter and base fingers on the thin film solar cell substrate (TFSS). By the use of this orthogonal transfer, the individual distance that the current has to travel within the thin metal layer on the cell is minimized or kept relatively small thereby strongly reducing the electrical series resistance experienced in the structure and in turn enabling thin metal fingers on the thin solar cell.

While the first and second layer metal lines are typically orthogonal to each other, some modifications may be utilized. In the case where a bus bar is to be implemented on the cell as part of the second layer metal, in a normal completely orthogonal arrangement the area under the bus bar would suffer from substantial electrical shading, as in the region of the respective bus bar via drilling to contact the opposing first metal layer line is precluded by the presence of the bus bar and opposing carriers would not get collected or would have to travel far within the active absorber area (e.g. silicon) to be collected by the closest finger of their respective second layer metal. Here, it may be advantageous to have, underneath the bus bar, a pattern of interwoven first metal lines that connect either directly to the bus bar (the metal line having the same polarity as the bus bar) or for the other polarity to the closest fingers of the second metal layer. Using this architecture, electrical shading is reduced greatly and only the series resistance of the first metal layer contributes to additional losses compared to the situation in the bulk of the cell where the first metal layer lines and second metal layer lines are arranged orthogonally and in alternating polarity, respectively.

An explanation in broad and general terms the variations of embodiments of the various backplane flows follows disclosing typical layers, structures, materials, functions and unit processes that are associated with the backplane reinforcement flow. Importantly, not every embodiment of the backplane or processing methods requires all described layers and functionalities.

Several cell layers and structures may be associated with the disclosed backplane flows and with layers that immediately influence the backplane structures and methods. In the following, such layers and structures are listed and described in general in an order starting with the layers and structures closest to the thin film solar cell (TFSS) and ending with the layers on the backside of the cell (closest to the layers that are in contact with the module).

On the TFSS are suitably patterned dielectric layer or layers on top of the thin film solar substrate that are deposited or grown on the thin film, for example while the thin film is on the template. Underneath the dielectric or dielectrics, are zones of emitters and bases (emitter and base regions) and base contacts of the thin film substrate. One of the functions of such layers is to provide dielectric isolation between terminals and of metal lines from active areas of the thin film solar substrate, and secondly to be used as dopant sources for forming emitter and/or base contacts. Methods and embodiments providing the dielectric layers include grown or deposited dielectric layers such as undoped or doped glasses with optional subsequent dopant drive-ins, thermal anneals, and/or thermal oxidations.

The contact opening of at least one of the zones of emitter and/or base (emitter and base regions) using suitable patterning methods, such as laser ablation, etch paste, lithography, and etch is employed to provide local access to the doped zones with suitable contact areas. Contact areas need to be optimized with the parameters of best contact and shunt resistance, as well as with providing a minimized area with high recombination rate for carriers. Depending on the process flow, such contact opening may be performed later in the cell process flow, but generally is performed prior to forming first layer metallization.

Metal contacts (herein also referred to as the first metallization layer or first electrically conductive interconnect layer) are deposited on the TFSS to at least one or both of the emitter and base areas. The first metallization layer (or layers) may be patterned as metal fingers, such as interdigitated metal electrodes, on the TFSS (while attached to the template if template processing is used to form the substrate) which may deposited using PVD or other methods such as printing of patterned metal layer or layers. The base and emitter metal contact layers forming the first metallization layer are suitably isolated from each other and can be patterned using laser ablation, printing, lithography and etching, etching pastes, or other methods. A function of the first metallization layer is to provide contact to at least one of emitter and base areas of the cell and to route current from the cell terminals (emitter and base) to the next backplane layer/level; and second to provide surfaces that can give low contact resistance, such as aluminum which gives low contact resistance to both p- and highly doped n-type material in silicon whereas optional materials on top of aluminum may provide good contact resistance to the next layer/level. Third, the first metallization layer may provide a surface that can later be plated, such as a Sn or Ni or NiV or Ta coated surface, if the next level of metal is applied using plating. Fourth, the first metallization layer may provide a good stopping layer in the case that a dielectric layer deposited, such as by lamination, on top of the first metallization layer is to be drilled, using a laser drilling for example. Example methods of depositing a first metallization layer are PVD, evaporation, screen printing, ink jet printing, and aerosol jet printing. Example materials and embodiments are PVD layers or stacks such as Al itself or AlSi1%, Al with Ni or NiV, and optionally Sn or SnAg, Al with Ta or Pd or Ag. Thick Al or AlSi1%, such as layer greater than 0.5 micron thick, may serve as particularly suitable reflectors in the far infrared and thus act as stopping layers for CO2 laser based drilling of subsequent via holes in further cell processing. Other examples are PVD stacks with additional locally printed pads for better contacting with the next layer, to provide better margins to stop laser drilling, and provide mechanical locks to prevent aligned pre-drilled dielectric from shifting during lamination. Such pads may consist of pastes containing Al or Ag such as conductive epoxy. Alternatively, printed metal or metals may be used, such as printed Al or printed Al with small amounts of Si (AlSi) or combinations thereof, optionally also with local caps of Ag for better contact and better reflectance for ensuing laser drilling process. For such printed layers, the metal may be printed in fingers, interrupted fingers, or dots that are aligned to subsequent metal vias. Refractory metals such as Ti, Co or Ni that may be printed, for instance using ink jet or screen printing and which can locally form silicides when suitably heated, may also be used as first metallization layer or part of a first metallization layer. Such silicides may be optionally used underneath other metals, for example underneath printed Al or AlSi.

The next level dielectric layer (herein referred to as the second dielectric layer) acts as an adhesion layer for the TFSS and additional components of the backplane. The second dielectric layer also serves as an isolating dielectric which enables the orthogonal arrangement between metal fingers on the TFSS (the first electrically conductive interconnect layer) and the large metal fingers on top of the dielectric or within the backplane (the second electrically conductive interconnect layer). The second dielectric may also provide protection from chemical attack to the backside of the TFSS along with the first electrically conductive interconnect layer and first dielectric layer in processing embodiments where the second dielectric acts as the outermost layer of the structure at the time of wet processing, such as texturing and post-texture cleaning. The second dielectric also serves to provide mechanical stability to the backplane reinforcement for the attached active absorber layer, comprised of the thin film silicon solar cell substrate. Deposition methods for the second dielectric layer include, a pre-drilled dielectric sheet which is attached using a lamination process, a post-drilled sheet which is attached using a lamination process and is undrilled at the time of lamination and of subsequent wet processing and drilled after said wet processing steps, and a patterned dielectric adhesive which may be, for example, printed either onto the TFSS surface or on the backplane side of the TFSS-backplane structure. Example materials for the second dielectrics layer include first dielectric sheets such as prepreg, EVA, Z68 PE sheet and others which are patterned via pre-lamination or post-lamination drilling (in the case of prepreg preferably using a laser such as for example a CO2 laser). Alternatively, punching or stamping processes may be used for perforation of such sheets. Printed dielectric adhesives, such as thermo-plastic or B-stageable materials, may also be used as a second dielectric. Other example second dielectric layers include a sandwich structure of sheets of dielectrics, such as prepreg, EVA, Z68, or others, covered with a protective material such a Tedlar, Mylar, Teonex such as Q83 or other PEN or PET materials, where at least one of the layers is continuous to secure protection and at least one or all of the other layers are either continuous (in the case of post lamination drilling) or perforated in the case of pre-lamination drilling. The latter allowing for easy low contact resistance access to the underlying metal fingers. Another example second dielectric layer includes a randomly or regularly but unaligned perforated sheet, such as in the case of the immersion contact bonding structure.

It is to be noted that in the case of performing subsequent wet processing steps in an embodiment where there is no wet chemistry contact to the back side of the backplane-reinforced TFSS, a protective sheet may not be necessary during the wet processing and, also, drilling of access via holes may then be performed even at any point prior to the wet processing.

The via hole (also referred to as contact openings) in the attached dielectric provides access between the underlying first level metal fingers on the TFSS (the first electrically conductive interconnect layer) and the next level metal on the backplane (the second electrically conductive interconnect layer. Drilling the via holes after lamination or keeping the via holes covered with a protective sheet provides, as in the case of the Pluto structure described below, protection of the underlying metal on the TFSS during the texture, clean, and front surface passivation steps and thus enables immersion of the reinforced structure into wet chemical baths. Via holes (contact openings) in the dielectric may be formed by drilling, preferably using a laser as described above, or in the case of a printed dielectric adhesive leaving areas unprinted where a via hole is desired.

The next level metal routes the current through the vias and either onto the next level of metal on the backplane or directly to cell-to-cell or to module connectors depending on the backplane structure and process embodiment. Typical materials and embodiments of via filling materials are conductive epoxy or more generally conductive adhesives which may be either stencil or screen printed into the vias or applied prior to applying a pre-drilled dielectric sheet. Typical materials also include solder or solder pastes, such as those containing Ag, Cu, Sn, Bi or mixes thereof, including SnBi mix which may be particularly advantageous due to its low solder apply temperature of approximately 140° C. which is in the same range as or even lower than attractive backplane dielectric processing temperatures.

Subsequently to at least partial via filling or even omitting via filling, the next level metal deposited serves to provide large width metal fingers on top of the dielectric (herein referred to as the second electrically conductive interconnect layer or second metallization layer). For the more desirable case where no additional via filling metal is used inbetween, said second level metal directly is used to make contact to the underlying first level metal in the drilled vias. Such large metal fingers may consist of plated metal, optionally with a prior blanket PVD seed which is then covered by a patterned and later removed dielectric print for emitter metal from base metal separation. The latter print is later removed and an etchback process may be carried out to remove the blanket seed metal. For plated fingers, optionally the seed may also be printed or deposited using a shadow mask, such that it is pre-patterned. Depending on the existence of a bus bar structure, a larger amount of contacting points during the plating of the finger structure may be employed. Rather than being deposited or built up by methods such as printing, spraying or plating, the large metal fingers (the second electrically conductive interconnect layer) may also consist of preformed fingers made of for instance solderable aluminum, i.e. Al with a thin coat of Ni, NiV and optionally Sn. For structural strength, such finger lines may be interlocked or may be tiles which may also be optionally interlocked. Another example for depositing the orthogonal fingers includes sprayed metal, such as the use of flame or thermal spraying. Yet another option is a flexible printed foil which can locally be attached to the underlying vias by the solder or conductive adhesive points—such printed foils are not unlike those used for flex circuitry or flex connectors.

The metal fingers embodiments may optionally include a bus bar design. If not, then subsequent contacting through soldering or printing of conductive adhesive may connect the backplane and with it the cell to the module. It is to be noted that for some embodiments, the printing of conductive material into the holes is not required and that rather, after the optional clean-up of the drilled via holes, optionally together with a removal of native oxide on metals, the seed layer for the next level metal (the second electrically conductive interconnect layer) can be applied directly into the opened via holes.

Optional additional layers, particularly as applied to the oasis and hybrid structures described herein, include:

a. In the case the second layer metal is already on the backplane when the backplane reinforced TFSS undergoes chemical treatment such as texturing and post texture cleaning, it may be advisable to have a protective dielectric layer on top of the second level metal. This layer's function is to provide protection from the chemical, optionally to help control CTE mismatch and structure bow as well as to protect and provide areas for contacting of the cell for later testing and module interconnection. Such contact areas may be opened through this protective layer for instance after undergoing the wet processing step or steps, for instance by cutting or drilling through the sheet or layer with a laser. Example material embodiments include the use of prepreg, EVA, Z68, Tedlar, Mylar PEN (e.g. Teonex Q83). Optionally, a sandwich of two or more layers can be used for this task, where at least one of the layers provides chemical protection of the backside and the edges from chemicals.
b. In addition to the above dielectric layer a backing layer may be added which serves to supply sufficient flatness and rigidity as required for most solar cell module embodiments or to provide a predetermined shape or curvature to the structure. The latter may be used advantageously in architectural designs where non flat cells are to be employed. This curvature, however, can also be tuned to potentially sufficient extent by the use of a suitably chosen initial backplane dielectric layer or layers, such as prepreg and others, as mentioned in herein. Such a backing layer or layers may also need to be perforated in order to allow contacting through them onto the metal layer underneath so that metallic contacts can be routed through it. Optionally, the backing layer may be assigned one of the polarities of the contacts. Typical embodiments for materials are aluminum, steel, glass or other suitably rigid plates that are thin, preferably thinner than 1 or 0.5 mm.
c. In the case that a metallic or otherwise not chemically resistant material is used for the backing layer, then an additional top protective cover layer may be employed which prevents chemical attack of the backing layer and which can be perforated after the chemical exposure, for instance using mechanical cutting or laser cutting, in order to provide electrical contact access to the metal underneath the backing layer and thus enable contacting of the backplane reinforced cell to the multi-cell module. Typical material embodiments for such protective layers are prepreg, Mylar, PEN, for instance Teonex's Q83. The attachment of these protective layers to the backplane reinforced cells may be performed either through an additional adhesive underneath or through adhesive which contacts through the perforations in the backing layer and around the edge of the backing layer. The adhesives may be comprised of for instance prepreg, EVA or Z68. The backing layer will tend to be slightly undersized to allow for edge wrap-around of the underlying adhesive to the top protective cover layer. During the lamination process, it may be advantageous to have a suitably shaped cover pressing onto the backplane side of the backplane reinforced TFSS, the cover providing a means to prevent closure of areas by adhesive that flows during the lamination process. This in turn can facilitate greater ease of electrical access to the backplane contacts at a suitable point after the lamination process. In the case that glass is used as such a backing layer, then the connection can be made either through drilled holes through the glass or by wrapping the wide metal fingers around the edge of the glass and either onto the top of the glass where they are subsequently covered by a chemically resistant material, or by having the metal fingers protrude outside of the cell used directly for contacting to neighboring cells in a module. The latter may also requires the application of a chemically resistant protection layer during the wet chemical exposure of the cell.
As the applications of this disclosure allow for a multitude of embodiments, this disclosure presents several possible embodiments using different types of support structures, materials and processes. Within some of these embodiments, we point out specific structures, materials and processes with their advantages and key points to be considered. Where not explicitly stated otherwise, it is perceived as included that such key points may also hold for other embodiments where conceptually similar structures, materials and processes are described.

Also, the structures, materials and methods covered in this disclosure allow for a multitude of potential implementation variations which cannot all be explicitly described. It is the intention of this disclosure to cover all such implementations, if at least one part of the presented embodiment is implemented and utilized in a comparable fashion. In addition to final structures, specific method or process flows along with some variations to achieve the final structure may be shown for each of the cases. The process flows and structures below assume a very thin silicon needing carrier support as this case is more general. Thicker silicon not requiring carrier support is a specific case of the more general case presented here.

For descriptive purposes, the present application provides several backplane and process flow embodiments, including: the Pluto structure, the Oasis structure, the Hybrid structure, and the immersion contact bond structure. However, the backplane structural and processing elements disclosed may be used in any number of combinations and variations by one skilled in the art.

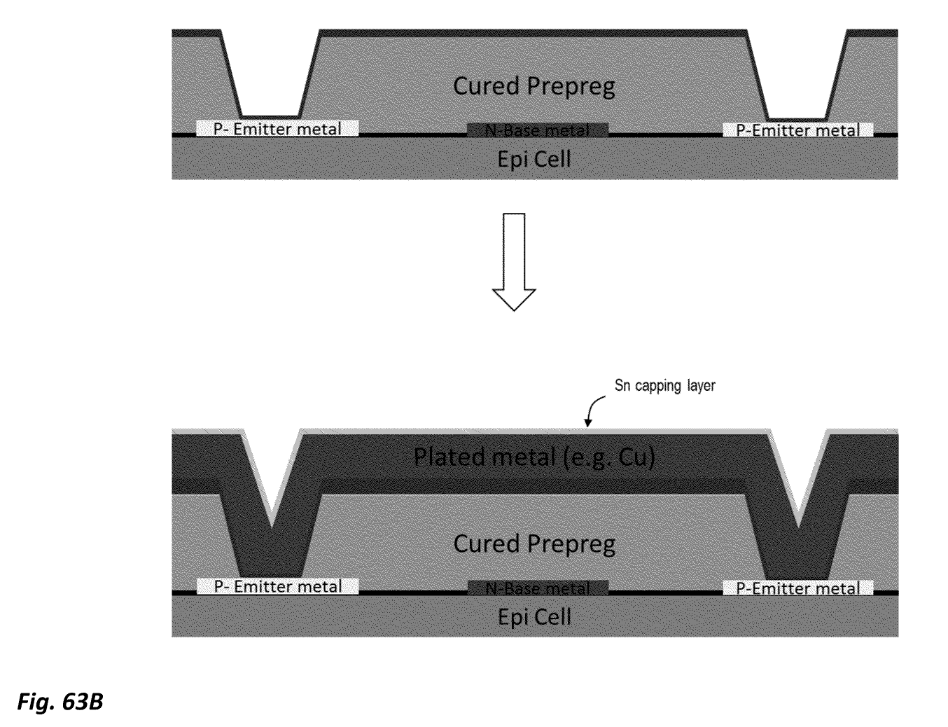

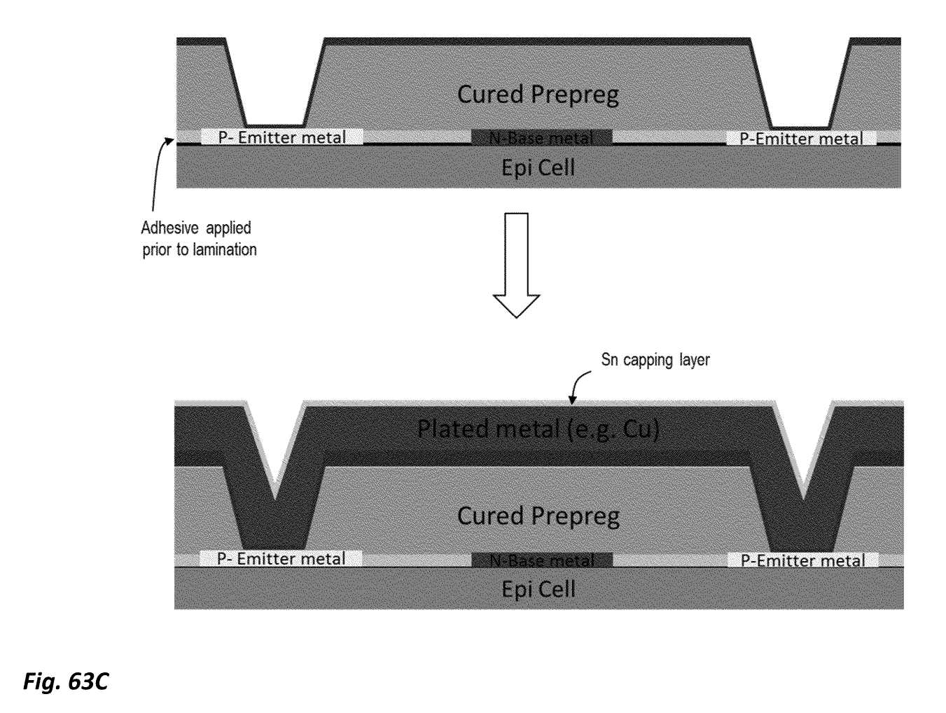

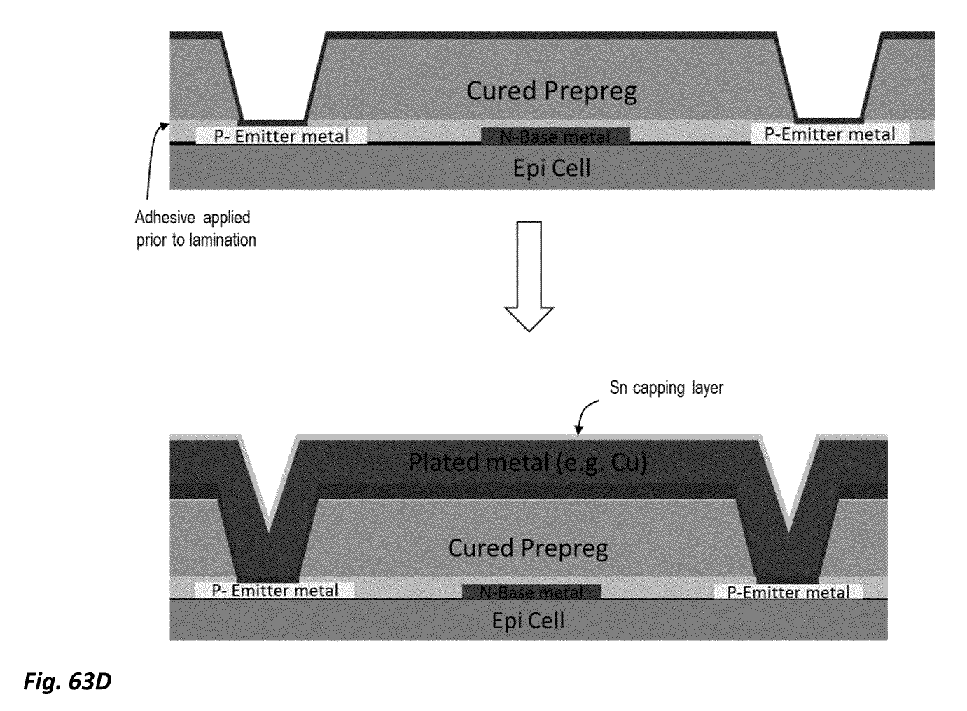

FIGS. 63A through 63D are cross-sectional diagrams of a first embodiment, hereinafter referred to as pluto, during certain processing stages. FIG. 63A shows a pluto structure after prepreg lamination, laser drilling, and PVD seed metal processing steps. As shown in FIG. 63A, a pluto structure consists of the following elements: First, the thin film solar substrate (TFSS) which consists of the active absorber layer, patterned emitter and base regions as well as patterned first layer metal, in this figure represented as deposited using PVD and subsequently patterned. Typically metal 1 fingers are lines that extend orthogonally to the metal 2 (plated Cu/Sn in the case of FIG. 3). The frontside of the TFSS (also called the sunny side) is textured and passivated. Second, Pluto comprises a prepreg or other suitable adhesive dielectric backplane forming material which is laminated to the TFSS structure and cured, optionally in the same step as lamination. The dielectric backplane material is selected to have good adhesion, good matching to the thermal coefficient of expansion of silicon which is chemically inert or optionally protected by a top cover sheet. Thermal matching allows for the drilling of vias, for instance drilled using a CO2 laser. Via drilling proceeds to the underlying metal 1 and needs to stop on top or just within the metal 1 layer. Further, the prepreg material may be comprised of one or more sheets of material with optionally different properties, such as incorporating woven or non-woven fibers (for instance glass, Kevlar, or other suitable materials as well as resin or different resins) all in optimized ratio to best match the coefficient of thermal expansion of the underlying silicon, or at the least, to reduce built-in bow and associated stress in the laminated and later released sandwich structure. It may be advantageous to balance thermal mismatch and adhesion to have an asymmetrically resin coated prepreg sheet or to laminate more than one prepreg sheet with different resin content or type.

FIGS. 63B, 63C, and 63D show a pluto structure in plating and Sn capping layer processing steps. FIGS. 63C and 63D illustrate examples where prior to lamination of the prepreg an additional adhesive is place, e.g. by screen printing, between the metal 1 structures to. Note that the adhesive applied prior to lamination in FIG. 63D covers the space between metal 1 lines and metal 1. The adhesive applied prior to lamination may either be printed only in the space between the metal 1 lines (FIG. 63C) or at least partially above the metal 1 lines (FIG. 63D) which may provide several additional process options and benefits. The adhesive may help alleviate the planarization requirements during the subsequent lamination by providing a more planar starting lamination surface. It may also provide an improved adhesion as well as a stress buffer, especially if the adhesive, when cured, has a low modulus which can in turn help decouple thermal expansion coefficient mismatch between backplane (e.g. prepreg) and the active absorber material (e.g. epitaxially grown and released silicon). Third, the above mentioned vias are filled or contacted at least partially with a metallization such as a PVD or printed seed layer or conductive paste. FIGS. 63B-D show plated copper as the example metallization both to fill the via holes as well as to provide the fingers that route the current to and from the via holes. The metal fingers (metal 2) may be arranged in an essentially orthogonal way to the on-TFSS metal fingers (metal 1) of the first layer metal.

A multitude of similar structures may be envisioned with this scheme in mind, for instance structures that consist of more than one metal to form the contact to the on-TFSS metal fingers. Common to the structures shown is a two-layer metal design where the outer, second layer metal (metal 2) is arranged essentially orthogonal to the inner, first layer metal (metal 1). Further, the dimensions of the second layer metal are much larger and easily manufactured. A second group of structural embodiments, hereinafter referred to as oasis, is defined by the following two concepts. First, at least at some point in time the structure relies on orthogonal or quasi-orthogonal current transfer, a concept that is described in the following structure attributes: Orthogonal finger design for orthogonal current extraction including: 1) interlocked fingers to provide structural integrity and keep the cell-backplane arrangement from bowing or warping, and 2) stress relief cuts in fingers; and Tile design for orthogonal current extraction including: 1) segmented fingers (tiles) to reduce the CTE mismatch related stress between the thin solar cells and the backplane material in the direction of the fingers, and 2) interlocked tiles to provide structural integrity and keep the cell-backplane arrangement from bowing or warping.

The second oasis characteristic is that at the time of the texture and passivation processes in the solar cell manufacturing process, at least one additional layer of metal next to the metal layer that makes the contact to the base and emitter in the semiconductor is already integrated into the backplane. Thus the oasis backplane is an integrated structure with two metal layers, metal 1 and metal 2.

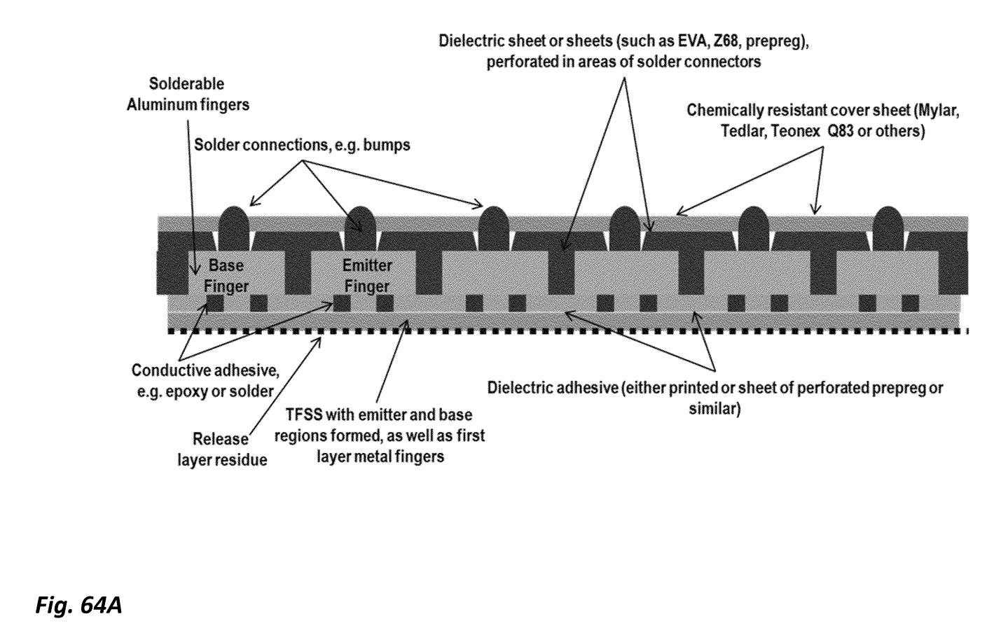

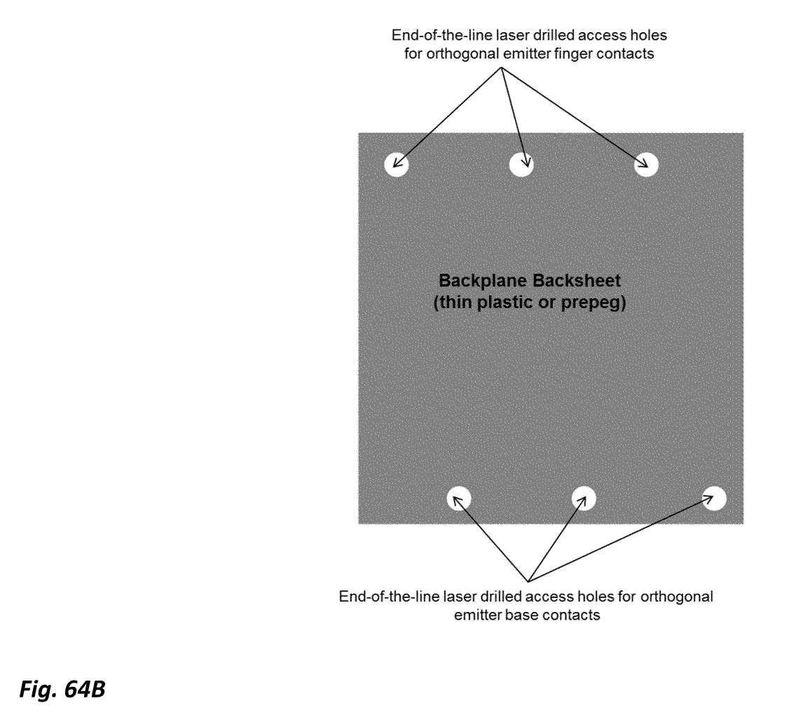

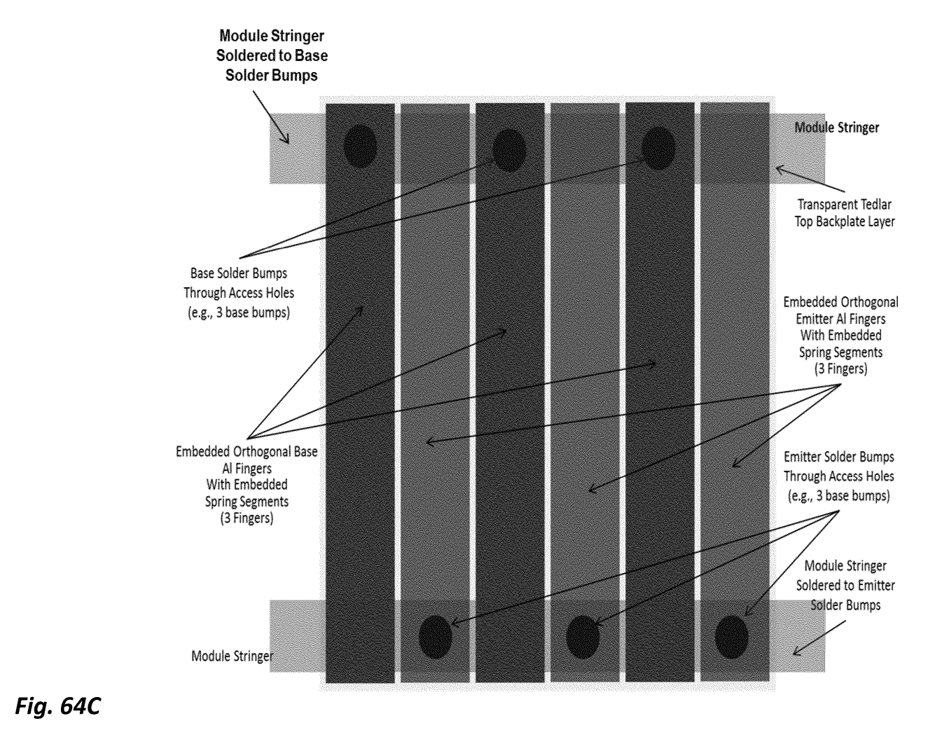

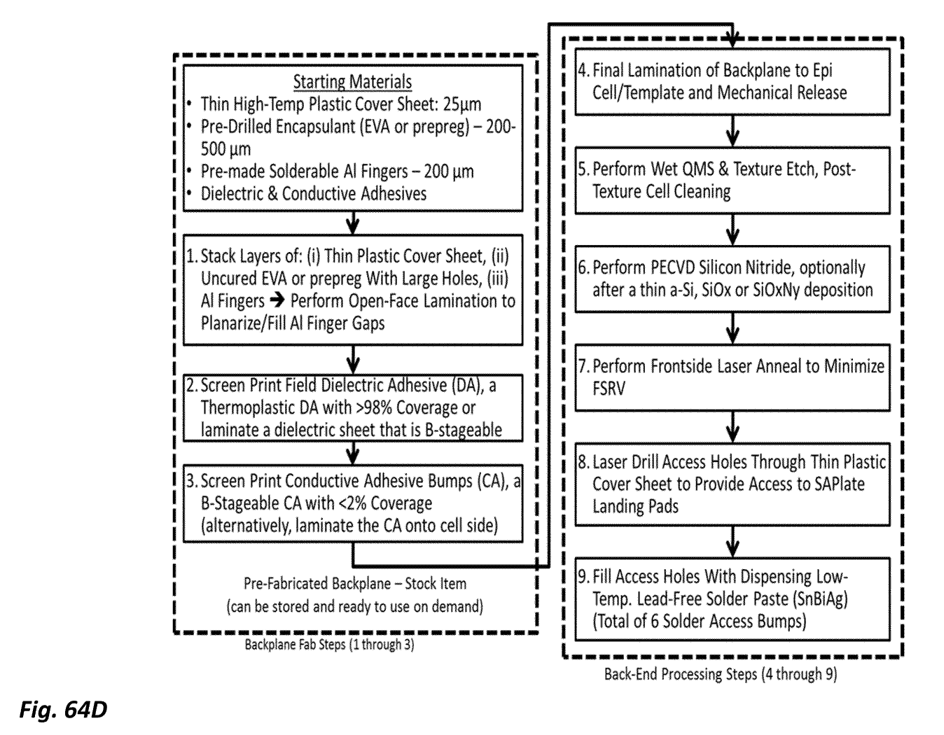

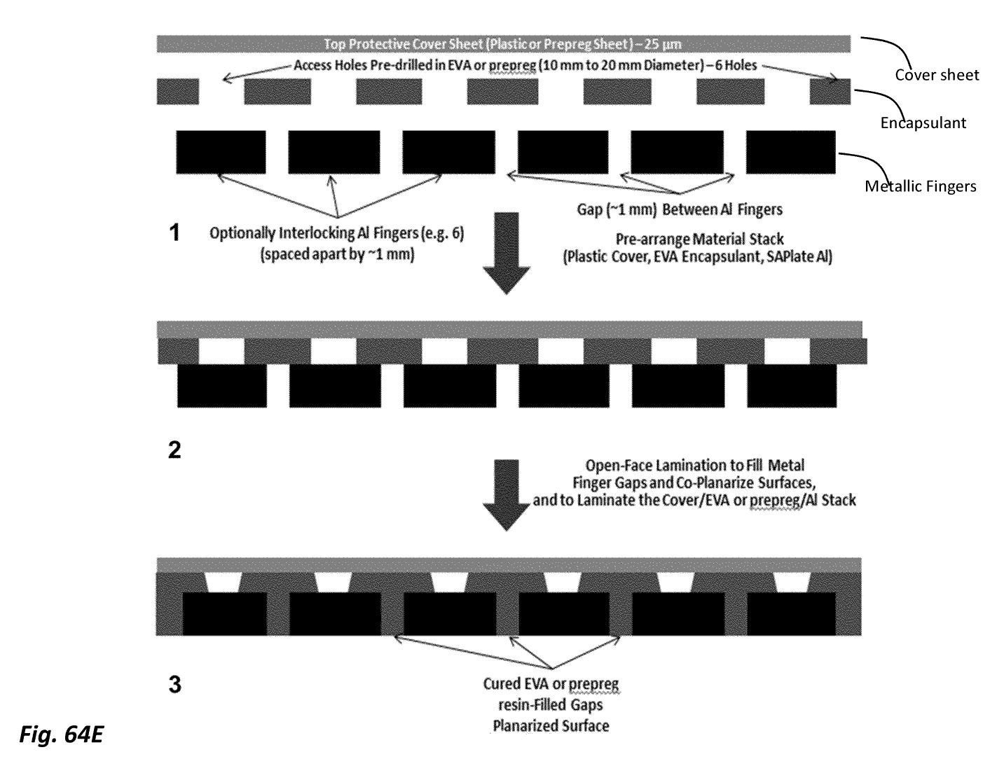

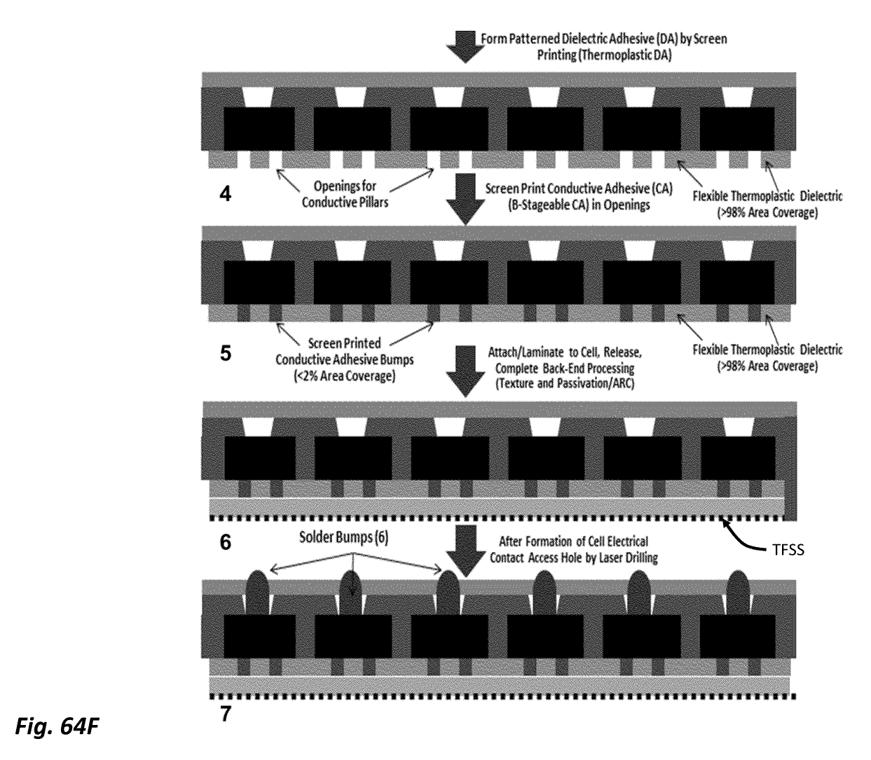

FIGS. 64A-F show various aspects of a four-layer backplane oasis structure (without a backbone) and manufacturing process flow embodiment. FIG. 64A is a cross-sectional diagram of an oasis structure after release from a template with six total metal fingers (three base/emitter pairs). The structure comprises the following elements: first, like a pluto structure, a TFSS which contains the patterned first layer metal fingers. Second, a dielectric adhesive, which is either applied in a patterned way using screen printing, or as a sheet such as a prepreg material which may be either pre-drilled or post-drilled prior to application to the TFSS. Third, an array of conductive contacts, which may be stencil or screen printed, made of materials such as conductive epoxy, such as silver epoxy. The conductive material being applied in areas where there are openings in the dielectric. Fourth, the structure contains a conductive second layer of metal fingers. The second layer of metal fingers material may be aluminum or solderable aluminum plate (SAP), for instance aluminum (Al) coated with a thin layer of Nickel (Ni), or Nickel Vanadium (NiV) and tin (Sn). The material being embedded into a further dielectric, for instance prepreg, EVA, Z68 or other compatible dielectric. This further dielectric is optionally pre-punctured to allow for contact access to the conductive second layer metal fingers. An optional chemically resistant cover sheet, for instance made of Mylar, Tedlar or other PEN or PET based materials such as Teonex, specifically Teonex Q83, may be applied to the top of the structure. Several process flow embodiments are possible to attain such a structure. The four layers of the backplane are 1) the dielectric/conductive adhesive, 2) the SAPlate fingers, 3) the next layer adhesive, and 4) the top cover sheet.

An important structural differentiation may be drawn between a single backplane lamination process where all components are laid up together and laminated at the same time, and a process where the second layer metal is laminated into a flat backplane and is embedded into the surrounding dielectric prior to a second lamination to the TFSS which, at that point, may be supported by the template by means of a release layer of suitable strength. In the latter case, the a backplane may be manufactured, stored and staged separately from the TFSS with potential benefits to cost and logistics. Also, in this case, there is an option: either one or both the dielectric adhesives that provide adhesion between the TFSS and the backplane and the conductive material that is used for the contact between the on-TFSS metal fingers and the large metal fingers that are part of the backplane may be applied either to the backplane side or to the TFSS side prior to lamination.

FIG. 64B is show a top view of the top cover sheet, e.g. 25 um plastic or prepreg material, of a backplane structure with end-of-the-line access holes formed near the backplane periphery. As shown with three emitter access holes and three base access holes. Access holes are laser (or mechanically) drilled into the thin backsheet to expose the solderable Al landing pads through the already pre-drilled EVA encapsulant sheet. The access holes may have a diameter of around 5 to 15 mm and are filled with Pb-free solder for stringer contacts, as well as module lamination and assembly. In one embodiment, one large-diameter access hole per orthogonal finger may be used (as shown six access holes for six underlying orthogonal fingers). FIG. 64C is show a top view of a backplane structure showing configuration of external access holes for external module stringer contact. Note no internal or external cell busbars are required. FIG. 64D is a process flow highlighting the major oasis backplane fabrication steps. FIGS. 64E and 64F show a structural process flow for an oasis backplane embodiment. Structure 1 of FIG. 64E shows a three layer stack, from top to bottom: 1) a thin (25 um) cover sheet, made from, for example, a transparent plastic or prepreg, 2) a thin (200 um) EVA or prepreg encapsulant pre-drilled with large access holes, made from, for example, an uncured EVA or prepreg), and 3) thin (200 um) solderable Al fingers prefabricated using laser scribe and KOH etching or stamping. In structure 2 of FIG. 64E the three layer stack is aligned to form a stack of: 1) the thin plastic cover sheet, 2) the pre-drilled EVA or prepreg, and 3) the orthogonal interlocking SAPlate Al fingers. Structure 3 of FIG. 64E shows the stack after open-faced lamination to cop-planarize and fill gaps between Al fingers and to prepare the planar backplane backbone structure. Structure 4 of FIG. 64F shows the structure after formation of field dielectric (such as a thermoplastic dielectric adhesive) by screen printing or a laser-predrilled dielectric sheet (e.g. prepreg or Z68). Structure 5 of FIG. 64F shows the structure after formation of conductive adhesive (CA) pillars, which may be b-stageable, by screen printing. Structure 6 of FIG. 64F shows the structure after attaching/laminating to cell, release, and back-end processing (also forming edge seal). Structure 7 of FIG. 64F shows the structure after final laser drilling of the top thin plastic cover sheet to form the electrical contact access holes, and after applying solder bumps to access holes for test and sort.

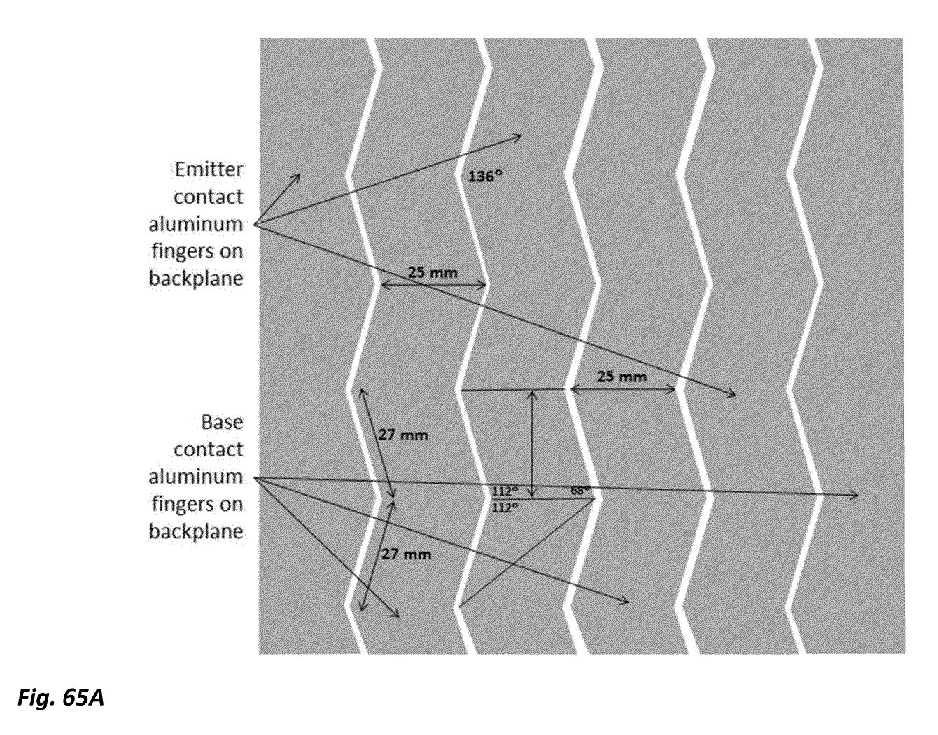

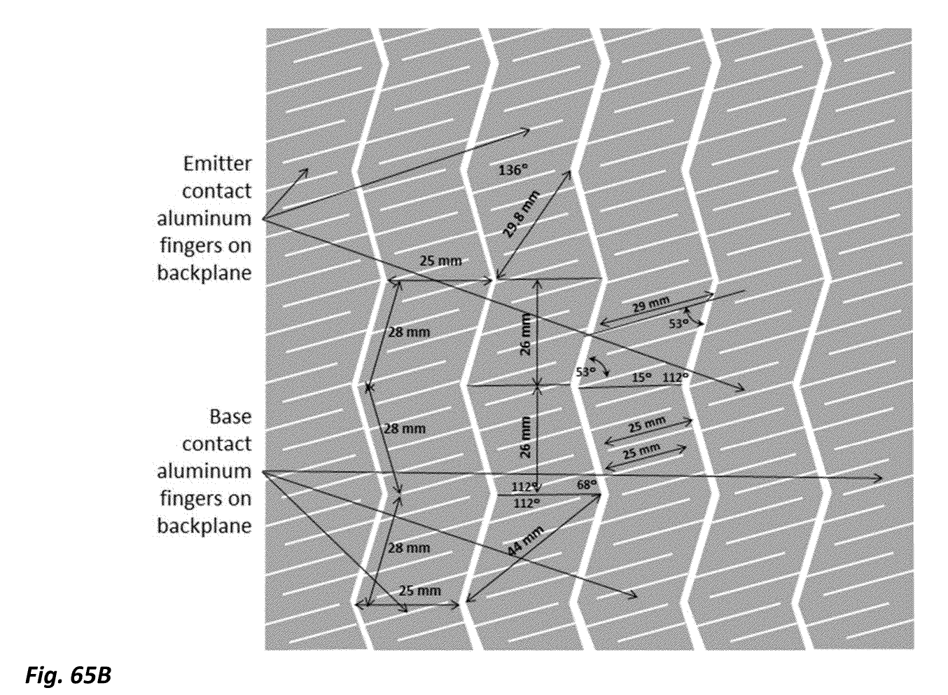

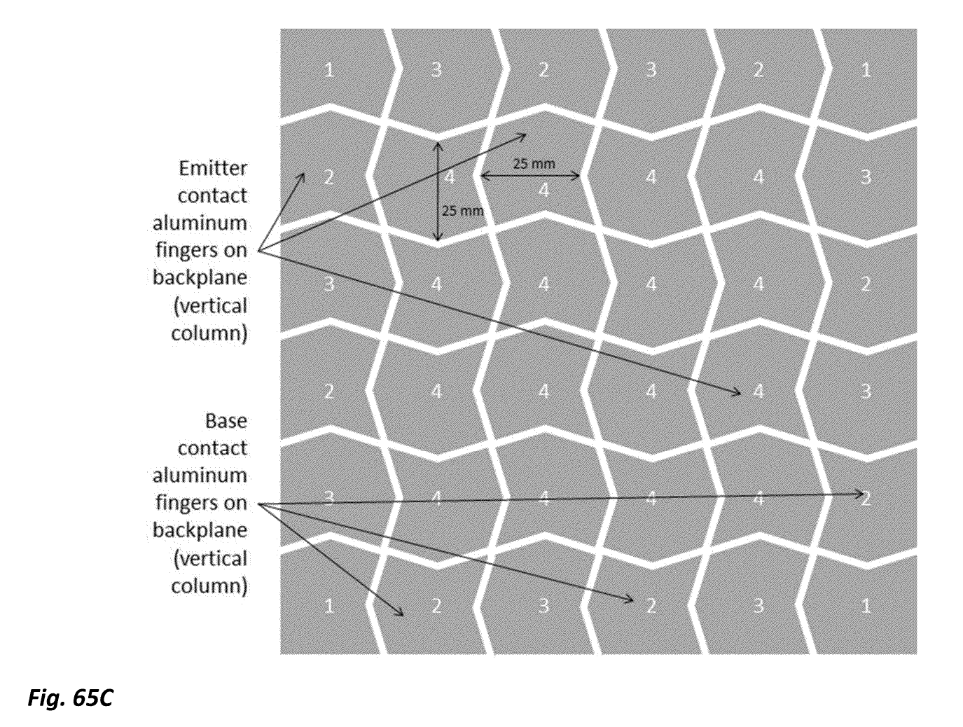

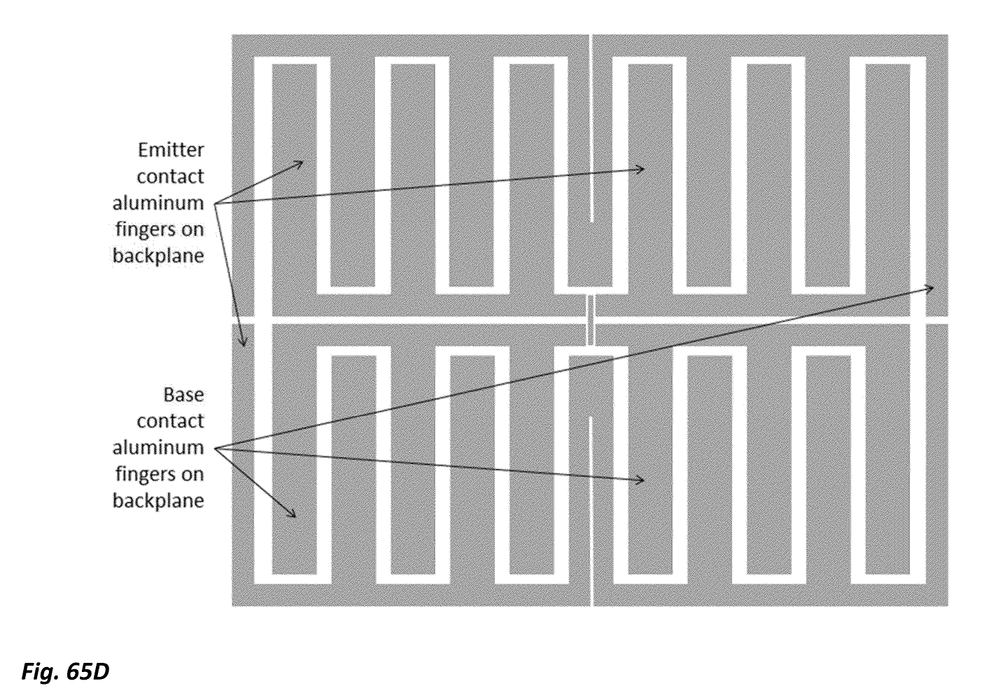

FIGS. 65A-D are top views of various embodiments illustrating potential shapes of the large metal fingers that are part of the backplane. FIG. 65A shows an interlocked pattern with six fingers, FIG. 65B shows a spring segmented balanced pattern (parallelogram) with six fingers, FIG. 65C shows a physically segmented balanced pattern with six fingers, and FIG. 65D shows an interlinked contact pattern. The fingers are in general arranged orthogonally to the on-cell first layer metal fingers. Because of the orthogonal transfer, the dimensions of second metal layer fingers may be relatively large without compromising ohmic losses due to series resistance through the metal routings. Typically, these metal fingers may be in the range from about 100 to several hundred microns thick. The main material that the backplane is to be laminated to is crystalline silicon, which has preferential mechanically weak directions along its crystal planes that act as preferential cleaving directions. Thus it may be advisable for securing the strength of the overall structure to have interleaved fingers or tiles in order to not provide preferred cleaving directions. If fingers are used (as shown FIGS. 65A and 65B), the addition of slits into the fingers can serve to provide a spring action which reduces CTE mismatch related stress along the direction of the large metal fingers. If tiles are used (as shown FIG. 65C with 36 tiles), then each column of tiles has the same polarity (emitter and base, respectively) and each tile needs to be connected later, which may require, for example, a pre-puncturing of the covering embedding dielectric sheet or alternatively opening contact holes after the cell is finished. These contact holes may be filled with a contact material such as conductive epoxy or solder and contacted to stringers as part of the module assembly fabrication. Numerous other large metal finger geometries are conceivable, for example the design depicted in FIG. 65D. The structure and geometry of FIGS. 64B and 64C show embodiments for the contacting of the cells to each other and to the module.

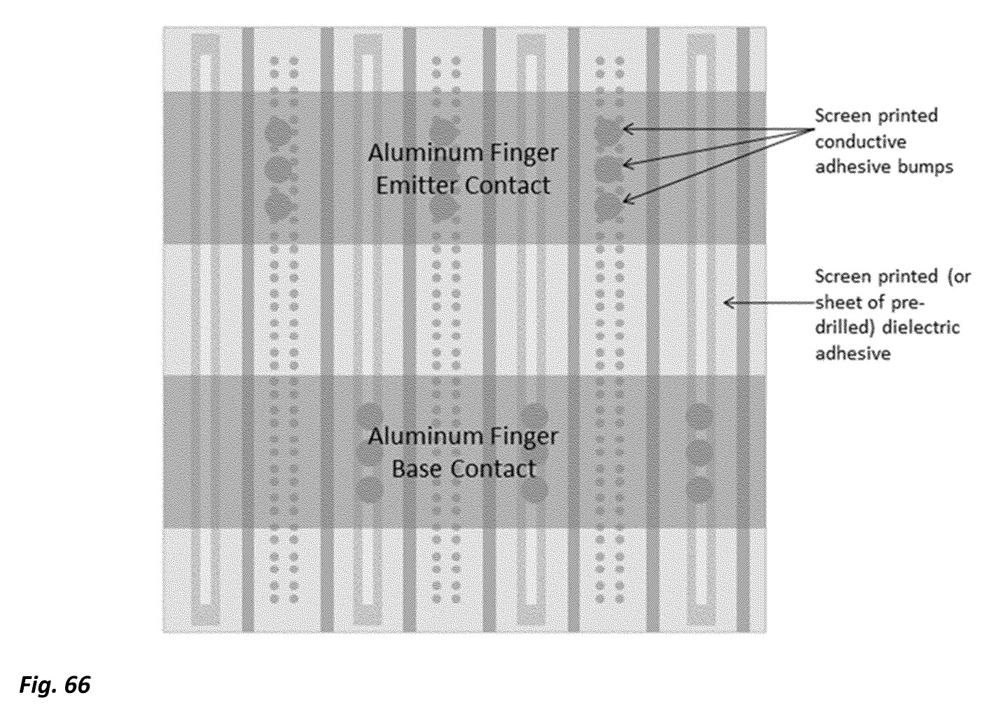

FIG. 66 is a top view of the cell backside illustrating an orthogonal oasis design. The aluminum finger emitter and base contacts are arranged orthogonally and contacted to the underlying on-cell first layer metal fingers the on-cell first layer metal fingers.

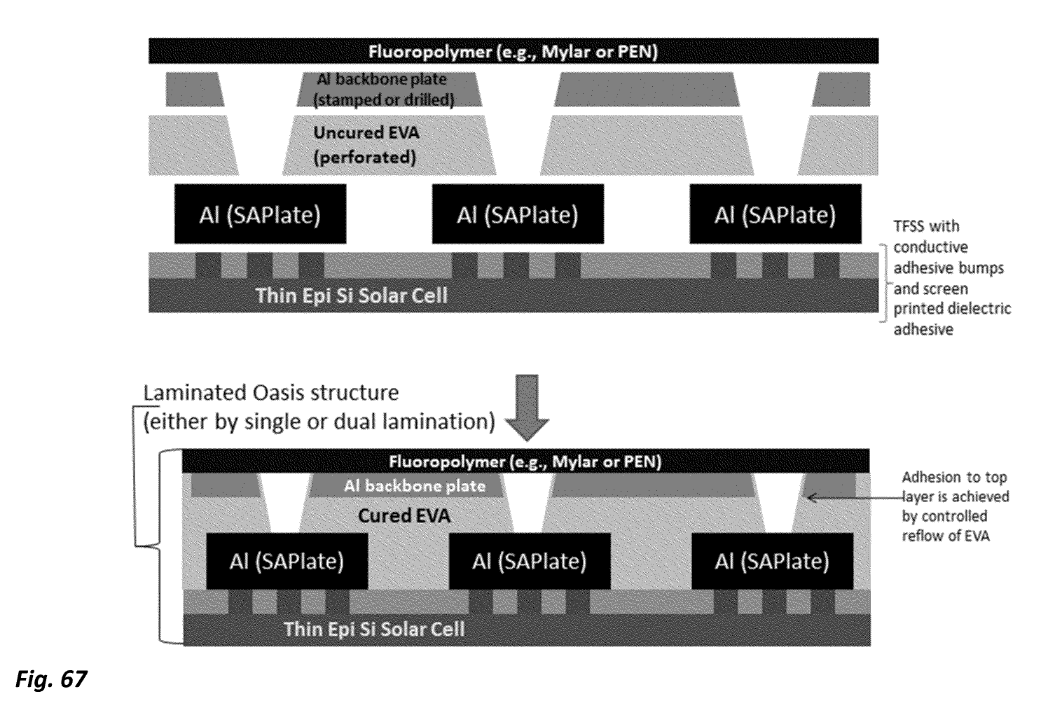

FIG. 67 are cross-sectional diagrams of an oasis structure (with backbone) embodiment, herein referred to as a five or six layer oasis structure. In comparison to the four layer oasis structure shown in FIG. 64, the structure shown in FIG. 67 contains an additional plate or plates to give the structure more rigidity, flatness and mechanical support. The support plate is pre-punctured to provide electrical contact access holes and is attached either by a dielectric adhesive sheet of its own (adding a layer and making the Oasis structure a six layer structure) or by reflowing the underlying dielectric sheet sufficiently through the pre-punctured holes and around the edges of the device for suitable adhesion and edge sealing (a five layer Oasis structure). The support plate should be a low cost material such as, for example, aluminum, steel, a suitable polymer, glass or a ceramic. Additional adhesive sheets may be comprised of the same materials as above including, prepreg, EVA and Z68, and related materials. The controlled reflow of the adhesive material to secure adhesion to the top cover sheet may be enabled by a suitably preformed fixture that is applied during the lamination process and which prevents adhesive material from closing up desired contact holes while at the same time enabling reflow of adhesive material embedded underneath the backbone layer to flow out and contact the top cover sheet layer.

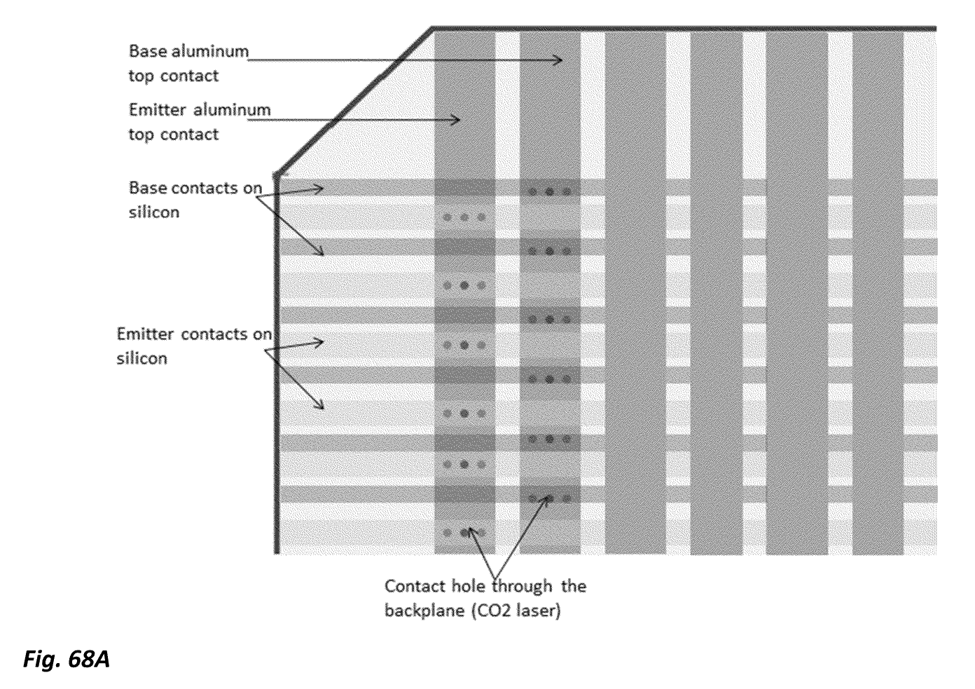

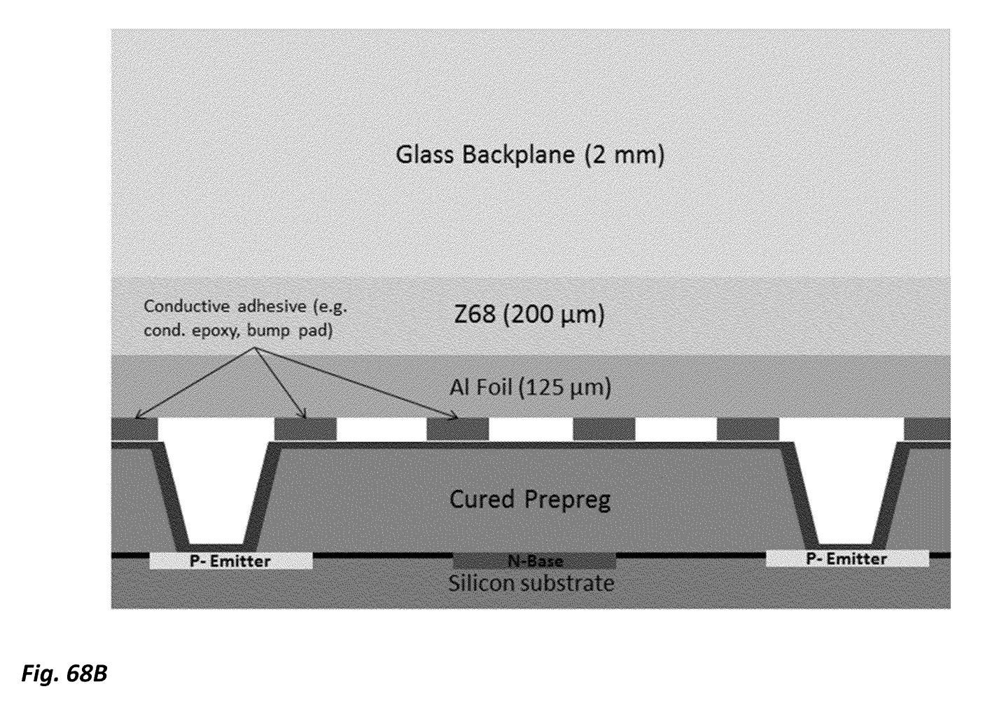

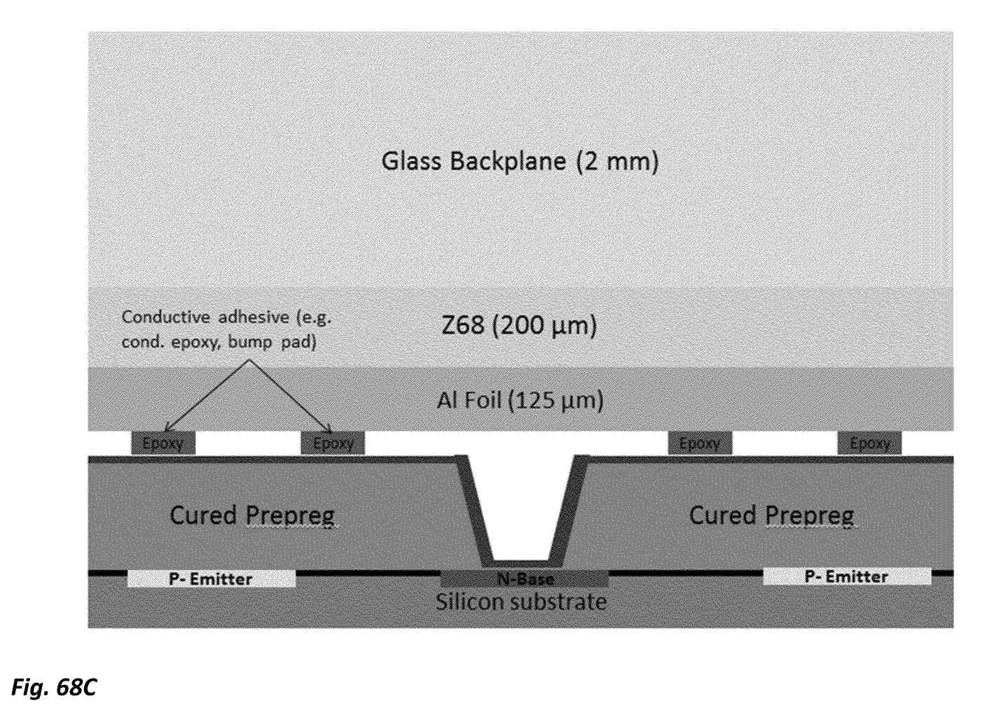

An embodiment of a third group of structural embodiments, hereinafter referred to as a hybrid structure, are depicted in the top and side views of FIGS. 68A and 68B-C, respectively. FIG. 68B is a cross-sectional view of a hybrid structure showing emitter contacts and FIG. 68C is a cross-sectional view of a hybrid structure showing base contacts. Pluto and oasis structures have substantial similarity and a multitude of intermediate/combination structures may be derived from the pluto and oasis concepts—FIGS. 68A-C illustrate one such example. The hybrid structure of FIGS. 68A-C has pluto characteristic elements such as that at the time of the wet processing and passivation the only metal components on the structure are those categorized in the process flow description below as first layer metal. The disclosed hybrid structure also has oasis characteristic elements in that it contains a large metal finger array; however, this large metal finger array is applied at a point after the texture and passivation process and thus is not integrated into the backplane structure prior to attachment to the TFSS as is characteristic of oasis structures.

The hybrid structure of FIGS. 68A-C comprises the following elements: a TFSS with the patterned first layer metal; a dielectric which may be either patterned during deposition using screen printing or using a post- or pre-lamination drilled prepreg material; a metal layer or layers that serve to route the metal from the on-cell first layer metal which is accessible through the via onto the top of the dielectric or directly to an array of large metal fingers; large metal fingers which are arranged orthogonally to the first layer metal on the TFSS and which are embedded in a dielectric, such as prepreg, EVA or Z68 with an optional backing plate (for example made of glass, polymer, ceramic or metal), and; a contact area for cell to cell and cell to module contacting which is located either on the side which may be formed by having the metal grid extend outwards and oversized compared to the cell or formed by contacting through the dielectric the large metal fingers are embedded in. Alternatively the contact may also be formed by wrapping the large metal fingers around the embedding and optional support plate material and having metal exposed directly at the very back of the cell.

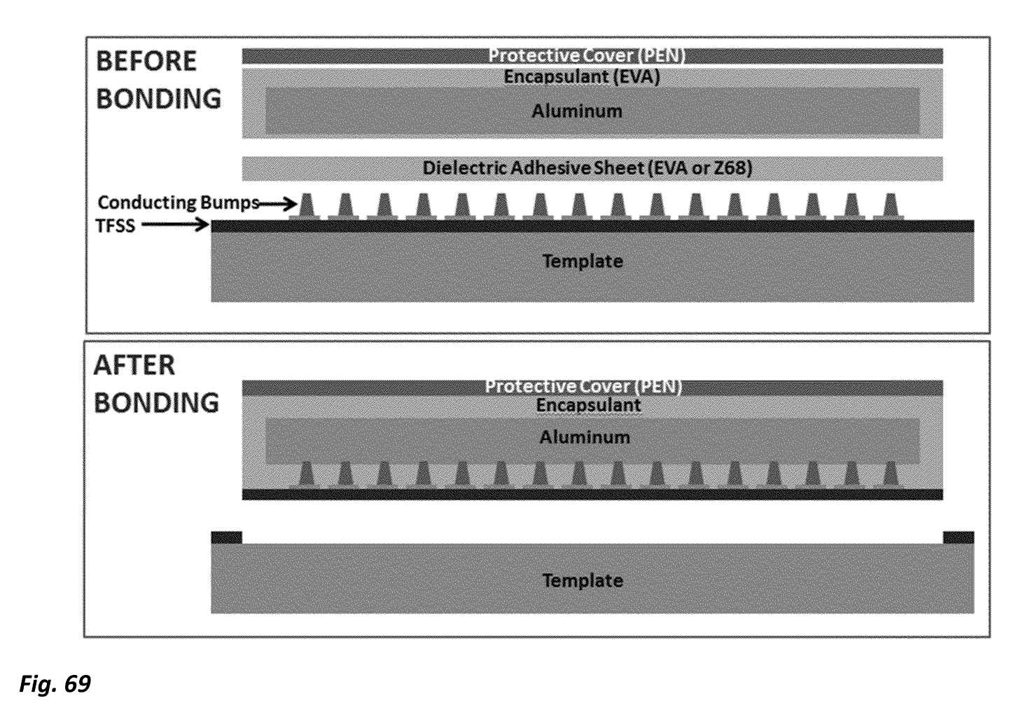

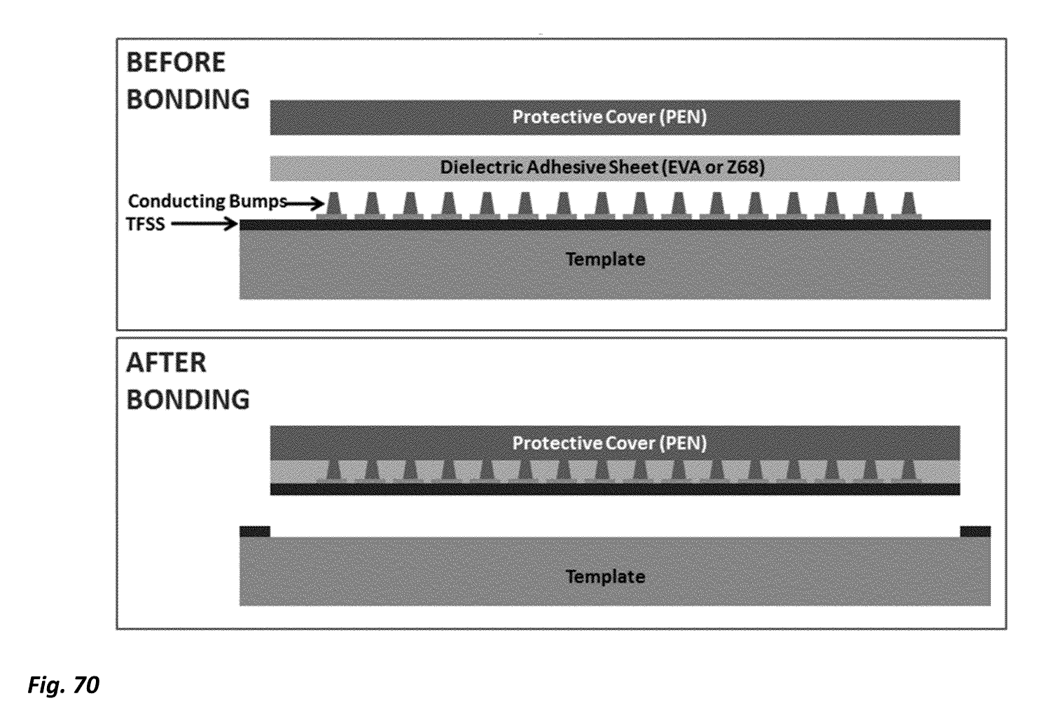

An embodiment of a fourth group structural embodiments, hereinafter referred to as an immersion contact bonding structure, are depicted in the cross-sectional diagrams of FIGS. 69 and 70. FIG. 69 is a cross sectional diagram of a immersion contact bonding structure and method using an Al oasis backplane showing the structure before and after bonding. FIG. 70 is a cross sectional diagram of an immersion contact bonding structure and method using a monolithic module array (MMA) type backplane showing the structure before and after bonding. Previously presented pluto, oasis and pluto-oasis hybrid structures have a dielectric adhesive—screen printed material or laminated prepreg sheet—that separates the first layer metal on the cell from the next layer metal and is patterned in an aligned way, such as to allow for open via holes that the contact to the next layer metal may be made through. In the immersion contact bonding structure, the dielectric adhesive is not patterned in an aligned way with respect to the contact points between first layer metal and the metal that is part of the backplane. The contact is made by an aligned, patterned array of printed conductive bumps, such as solder or conductive epoxy, which is placed in the desired contact spots and which in the process of lamination is pushed through the dielectric lamination sheet. The dielectric lamination sheet made of, for example, a material that sufficiently softens during lamination such as EVA or DNP's Z68. These materials are optionally produced as perforated sheets to provide a sufficient percentage of open area for the conductive bumps to make low resistance contact between the different metal layers.

Thus, the immersion contact bonding structure comprises: a TFSS with the patterned first layer metal; an aligned array of conducting bumps; a dielectric sheet, for instance consisting of EVA or Z68, that is either perforated in a regular or random fashion or that may be perforated as part of the bonding process; in an oasis implementation, as depicted in FIG. 69, an oasis-styled prelaminated backplane with embedded large metal fingers, and; in an direct implementation into an MMA style backplane, as depicted in FIG. 70, a protective cover that is connected to the TFSS via the dielectric adhesive sheet (made of, for example, PEN or another suitably resistant material).

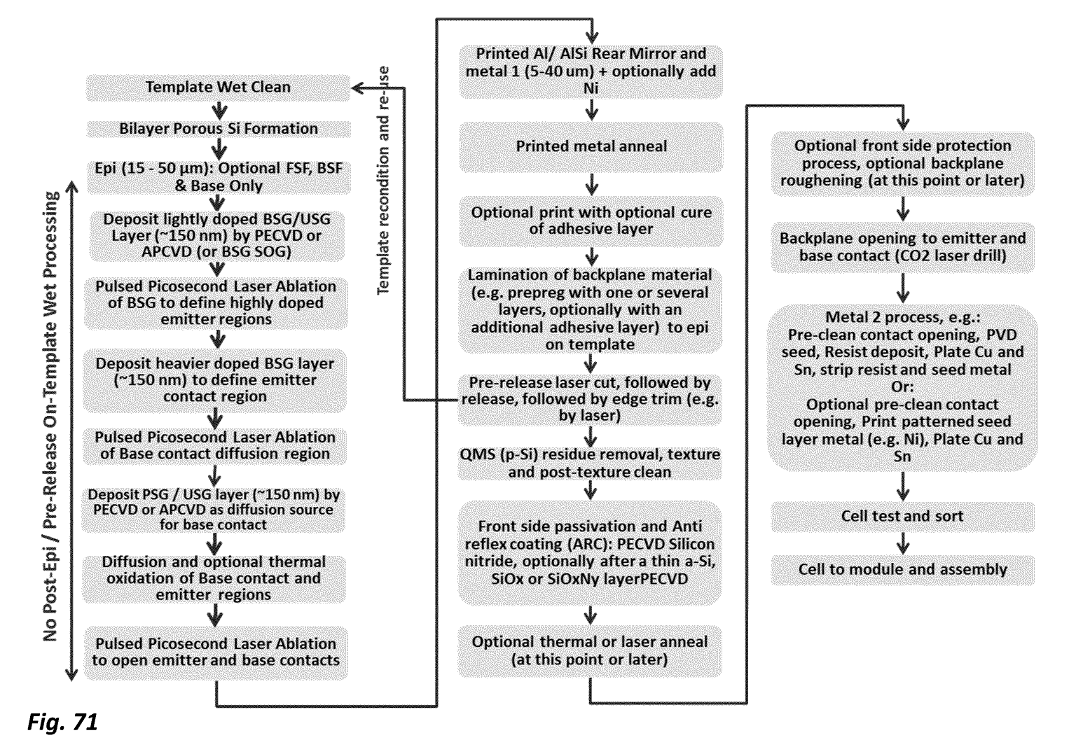

FIG. 71 is a process flow embodiment for a back contact solar cell with assembly and manufacturing of the backplane reinforcement. FIG. 73A-J illustrate front end processing such flows.

The front end of the process may begin with a wet clean of the re-used or fresh template, followed by the formation of the release layer, for example a bilayer of porous silicon with low porosity on top of high porosity. Subsequently, the active absorber cell area is deposited, for example using epitaxial deposition of silicon using trichlorosilane (TCS) gas and a dopant, for example phosphine (PH3) to generate an n-type base, in hydrogen. Optionally such a deposition may be arranged to have more than one distinct doping concentration region as a function of depth. Subsequently layers of doped glass are deposited, for example using atmospheric pressure chemical vapor deposition (APCVD), followed by patterning processes using a picoseconds laser.

In one embodiment, the first glass layer contains a lighter amount of emitter dopant (boron in boroslicate glass—BSG), optionally capped with a layer of undoped silicate glass (USG), in order to form a less heavily doped emitter, followed by ablation of the borosilicate glass in areas where a more heavily doped emitter is to be generated which in turn serves to provide a low resistance contact to the emitter metal 1. After this, a more heavily doped BSG layer (BSG2) is deposited in the region of the metal 1 contact to the emitter, optionally with a USG cap layer. Then the area for the base contact is ablated, preferably using a picosecond laser. Subsequently, the phosphosilicate glass (PSG) layer is deposited which serves as the dopant source for phosphorus which in turn is to generate the heavily N+-type doped base contact region to form a low resistance contact to the base. In a subsequent step, the profile is thermally annealed, thereby driving in the junctions. Optionally the annealing ambient may be chosen between a neutral and an oxidizing ambient, the latter to serve to form a high quality interface at the backside to enable low back surface recombination velocity. As a next step, the contact areas to emitter and base doped junctions are opened to enable contacting of the subsequently applied metal 1 layer, where metal 1 may be for example a printed layer or sequence of printed layers, for example consisting of aluminum (Al) or AlSi to form a low resistance contact of metal 1 to the junctions while avoiding spiking through the junctions. The printed metal layer or layers may optionally be thermally annealed prior to the next steps. At this point, the front end of the device may be considered completed, and backplane related steps may begin.

The next steps may comprise either single step lamination or backplane preparation, followed by lamination to thin film solar substrate on template. Such lamination is preferably carried out in a vacuum and at elevated temperatures to cure the laminate. A pressure is applied to secure uniform and reliable adhesion. Pressure can be variable throughout the thermal and vacuum cycle that the structure undergoes. Various embodiments with respect to the lamination process and tool are possible, including stacking multiple templates with laminates, separated by release sheet and pressure distributing buffer layers or having multiple templates laminated side by side in a large tray arrangement. Such large tray arrangements may themselves be stacked into commercial laminators with multiple slots (daylights) which are all heated, typically from above and below or from one side only. Hydraulic press elements may be used to apply the pressure. Sufficiently chosen thick sheets of cellulose or rubber or other suitably compliant sheets may be used to overcome pressure differentials due to local stack height variations or due to different template heights, which respectively may be caused by templates of differing age or re-use count being laminated at the same time. It is to be noted that prior to lamination of the backplane material (e.g. prepreg) it may be advantageous to apply an additional adhesive, as described earlier in the same disclosure.

The next steps involve post-lamination release of thin film solar substrate (TFSS), laminated to backplane, from the template. Either prior to the lamination or prior to the release of the TFSS it may be advised to outline the shape of the TFSS with a laser cut either through the epitaxial film outside of the backplane or through backplane and the epitaxial film. Care is to be taken to minimize template damage from cutting past the epitaxial layer and into the template. Laser based technology called thermal laser separation may be used in this cutting process in which a heating laser beam is immediately followed and traced by a cooling spot, provided by a jet of cold liquid or mist such as water or a cold gas such as helium for example. By doing so, a cleave may be initiated through the silicon which in turn terminates at the interface between the TFSS and the template, in the region of the release layer.

Next are edge preparation steps including trimming (cutting) the edges, and optionally decoupling the fragile thin film from the edge of the reinforced thin substrate. The outer edges of the device may be cut to size by mechanical trimming, such as shearing or stamping, or by laser trimming. The corners of the device may be chosen to be cut using a chamfer or otherwise suitable shape to dull the corners and make them less prone to handling damage throughout subsequent process steps.

Next are wet (or optionally dry) texturing steps followed by a post texture clean and drying. Texturing may be preceded by one or more surface preparation steps, for instance by a mechanical roughening step, such as grit blasting, to aide in the later formation of proper pyramids, or by surface treatment such as organic residue removal or forming a thin chemical oxide to aide texturing.

Next are passivation steps at low temperatures with an optional dry bake with or without vacuum assistance prior to passivation layer deposition. Example viable passivation layers for low temperature being amorphous silicon (a-Si) or silicon oxide or sub-stoichiometric silicon oxide, silicon oxy-nitride or silicon nitride. Alternatively, the passivation layer such as a chemical oxide or oxynitride may be deposited in a wet process tank.

Next are anti-reflective coating steps using materials such as silicon nitride, Al2O3, or other suitable dielectric, preferably with very low absorption in the wavelength range capable of generating carriers in silicon and with suitable built-in charge to repel the respective minority carriers. Optionally, forming gas or other thermal anneal may be used to improve the front surface passivation. Optionally, a laser anneal from the front to improve the front surface passivation and also optionally bulk quality and back surface passivation depending on the laser processing parameters and penetration depth of the chosen laser wavelength or wavelengths. The next step consists of opening contacts to the next buried layer of the cell terminals. Depending on the chosen backplane structure, the next buried layer may be, for example: the patterned metal layer on the cell that was deposited onto the cell and prior to lamination; contact pads that were deposited on said patterned metal layer only in areas where contact access is needed, or; a buried next level routing of metal, optionally essentially orthogonally arranged with respect to the original metal connectors. This contacting process may be performed using laser or mechanical hole or slit drilling into the protective/dielectric layer. Optionally, prior to this step the surface is protected by a sheet or material that prevents plating or contamination of the front side during the later plating process

Subsequently, the underlying metal is contacted through the contact opening by one of several optional means, for example: an optional surface preparation step to promote adhesion and/or platability of a seed metal; deposition of a seed metal by PVD, plating, printing including screen printing, ink jetting, aerosol jetting, stencil printing, or spraying such as flame or thermal spraying; in the case of a non-patterned deposition, a patterning step, such as printed resist, or; plating in non-resist covered areas, followed by resist removal and seed layer etchback (all of which are processes common in plating technology) Typical metallization materials include, for example, a starting layer of nickel, followed by copper and ending with tin or other solderable capping layer, and printed layers may contain suitable metals, including silver and alloys, nickel, copper, aluminum and tin. In the case of a PVD seed layer, choices include but are not limited to Sn, Ni, NiV, Al, Pd, Ta, Cu, Ag or alloys.

After optional testing and binning, contact to the solar module may be readily achieved using solderable stringer ribbons for example. The stringer ribbons may be for instance straight or dog-bone shaped and may optionally contain black or blackened areas, for instance in areas visible to the module customer, in order to retain an all-black appearance as well as to optionally serve as electrical isolation where needed. A final encapsulation is performed, for example, using common solar backside encapsulants.

The following disclosure relates to exemplary structures and process flows presented for descriptive purposes. A main difference between the pluto and the oasis structure is that at the time of wet processing or other form of texturization of the front surface of the epitaxial thin film, the pluto reinforcement structure does not contain any other metal structure except for on-cell metal emitter and base contact fingers, henceforth called first layer metal, whereas the oasis structure contains at least part of a second layer metallization.

The on-cell metal may be deposited using either a blanket deposition technique such as physical vapor deposition (PVD) or evaporation (e.g. via electron beam or thermal evaporation) with subsequent patterning using for instance laser ablation or direct patterned deposition of the metal or metal precursors using screen printing, typically with a subsequent thermal step for baking, sintering or drive-in. Importantly, the description below holds similarly for a PVD and for an evaporation based process. In the following, wherever not otherwise noted, PVD is used to represent all other large area blanket deposition type processes. Such blanket films may be deposited over the whole epitaxial cell structure on the template or a shadow mask can be implemented during the deposition to avoid deposition where not desired, for instance at the very edge of the template or outside of the active structure. Shadow masking may also be used to define the active or metal contacted area.

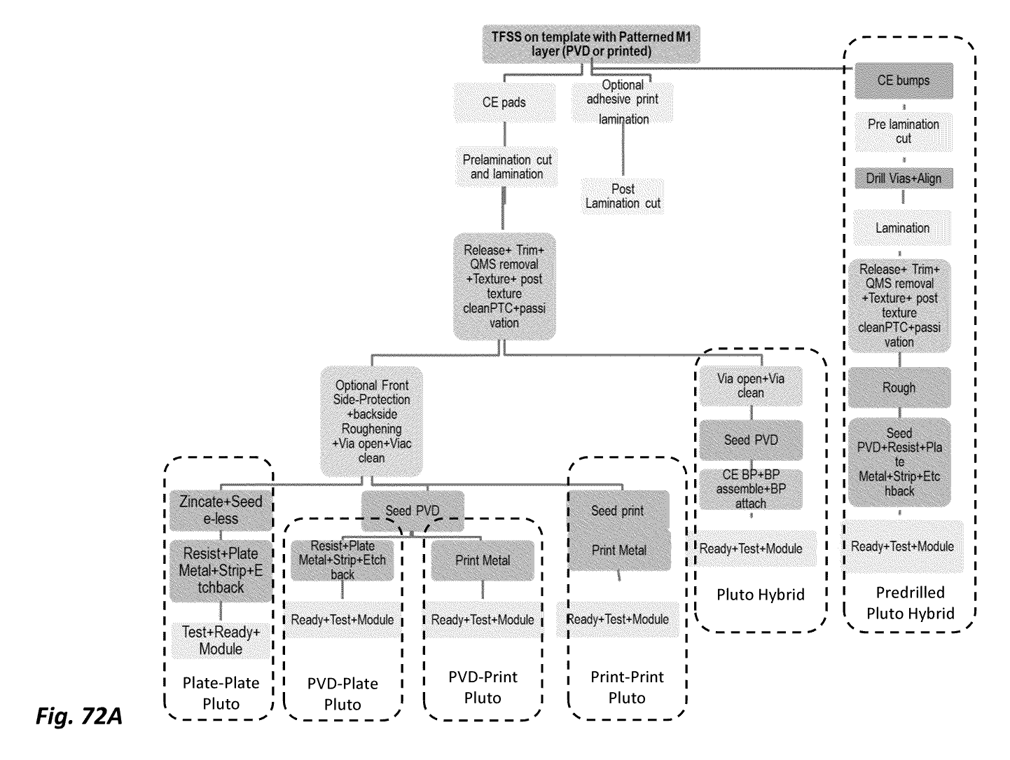

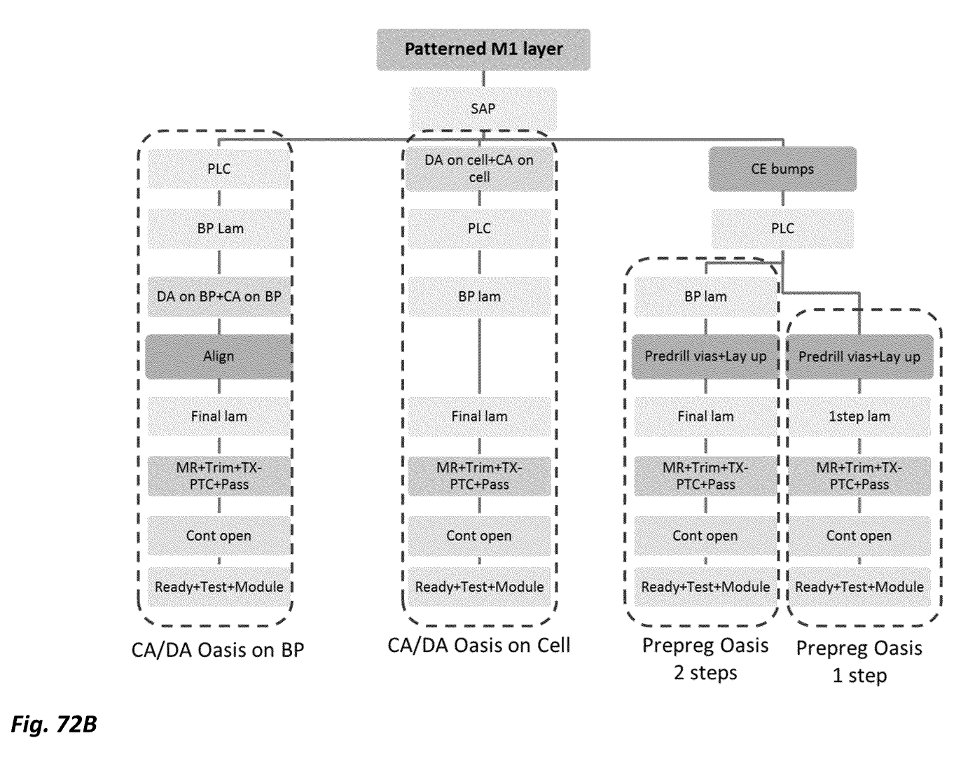

A schematic representation of examples for different embodiments of process flows of the pluto and oasis structures as well as pluto and oasis hybrid structures are depicted in FIGS. 72A and 72B. FIG. 72A are process flows relating to pluto structures and pluto hybrids. The table below defines the abbreviations used in the process flows depicted in FIG. 72A.

TABLE 1
Terms and Definitions for FIG. 72A

| TERM | DEFINITION |
|---|---|
| CE pad | Optional CE print (for enhanced process window of |
| | laser via drill) |
| CE bumps | |
| PLC | Optional pre-lamination epi laser cut (to generate |
| | suitable epi breakage lines) |
| Drill Vias | Drill vias in the prepreg sheet |
| Align | Align the components stacks prior to lamination (better |
| | than 100um) |
| Lam | Prepreg lamination (2-12 mil prepreg), 1-2 sheets |
| | (prepreg cut to suitable size, potentially oversized) |
| MR | Mechanical release (through vacuum chucking, vacuum |
| | pulsation, electrostatic chucking or optionally with the |
| | assistance of sonic or ultrasonic actuation) |
| Trim | Trimming, e.g. using laser |
| TX-PTC | Texture and post-texture clean |
| OS-TX-PTC | Texture and post texture clean in one-side tool |
| Pass | Passivation, e.g. a-Si, SiOx, SiOxNy followed by SixNy or |
| | Al2O3 in case of p-type base |
| FS-Pro | Optional front side protection |
| Rough | Optional grit blasting of exposed prepreg side or other |
| | micro-surface roughening |
| Via open | Laser via hole drilling, e.g. via CO2 laser |
| Via clean | Optional via clean-up and optional organic or native |
| | oxide removal, e.g. via peroxide clean, permanganate |
| | clean, ashing, radical plasma etching, pre-sputter |
| | etching |
| Zincate | Optional zincation if plasma clean-up is not possible |
| | and Al needs to be contacted directly |
| Seed e-less | Seed layer deposition, by plating such as electroless Ni |
| | plating |
| seed print | Seed layer deposition by printing (ink jet or screen |
| | printing), materials can be Al, Ni or NiV, Cu |
| seed PVD | Seed layer deposition by PVD |
| Resist | Resist deposition to define emitter and base region in |
| | case of plating |
| Print Metal | Plating or printing of main second layer metal, |
| | consisting of Ni, Cu, optionally with Sn at surface for |
| | solderability |
| Plate Metal | Plating or printing of main second layer metal, |
| | consisting of Ni, Cu, optionally with Sn at surface for |
| | solderability |
| Strip | Optional resist removal in case of plating |
| Etchback | Optional seed layer removal under resist, if plating is |
| | used |
| CE BP | CE print to backplane |
| BP assemble | Backplane (Al fingers, Z68, glass) |
| BP attach | Backplane attachment (laminate via CE dots to seed) |
| Ready | Cell ready for test |
| Test | Testing and sorting |
| Module | Module integration, including soldering |

FIG. 72B are process flows relating to oasis structures and oasis hybrids. The table below defines the abbreviations used in the process flows depicted in FIG. 72B.

TABLE 2
Terms and Definitions for FIG. 72B

| TERM | DEFINITION |
|---|---|
| SAP | Cut solderable Al fingers (Al with Ni/Sn surface) |
| DA on cell | print DA on cell |
| CA on cell | Print CA on cell |
| CE bumps | CE bumps print on cell |
| Pre-Drill Vias | Pre-drill vias into prepreg or other |
| PLC | Optional pre-lamination epi laser cut (to generate |
| | suitable epi breakage lines) |
| Align | Alignment of component stacks prior to lamination |
| | (~better than 100 um) |
| Lay up | Alignment of component stacks prior to lamination |
| | including predrilled prepreg sheet (~better |
| | than 100 um) |
| BP lam | Backplane lamination (SAP fingers plus adhesive |
| | (EVA or Z68 or prepreg) plus optional cover sheet |
| | (e.g. Mylar or Tedlar or Teonex - e.g. Q83) |
| DA on BP | print DA on backplane |
| CA on BP | Print CA on backplane |
| 1step lam | Laminate: cover sheet, adhesive, SAP fingers, pre-drilled |
| | prepreg, CE bumps on epi |
| Final lam | Prepreg lamination (2-12 mil prepreg), 1-2 sheets |
| | (prepreg cut to suitable size, potentially oversized) |
| MR | Mechanical release (through vacuum chucking, |
| | vacuum pulsation, electrostatic chucking or optionally |
| | with the assistance of sonic or ultrasonic actuation) |
| Trim | Trimming, e.g. using laser |
| TX-PTC | Texture and post-texture clean |
| Pass | Passivation, e.g. a-Si, SiOx, SiOxNy followed by |
| | SixNy or Al2O3 in case of p-type base |
| Cont open | Open contact access holes in cover sheet (e.g. by laser) |
| Ready | Cell ready for test |
| Test | Testing and sorting |
| Module | Module integration, including soldering |

FIGS. 73A-J show a cross-section of a cell during major fabrication steps of a process flow of a pluto structure embodiment for manufacturing a back contact solar cell.

FIGS. 73A-E show a flow based on having a physical separation between the base and emitter contact areas through the use of an undoped layer and subsequent patterning. FIG. 73A shows the cell after the BSG deposition and emitter opening steps. FIG. 73B shows the cell after the base window opening steps. FIG. 73C shows the cell after the PSG base deposition, annealing, and opening steps. FIG. 73D shows the cell after the laser contact opening steps. FIG. 73E shows the cell after the metal deposition and laser isolation steps.

FIGS. 73F-J show a flow enabling selective emitter formation by having the emitter area more lightly doped everywhere except in the regions where an emitter to metal 1 contact is to be formed, the latter benefitting from higher doping for lower contact resistance. FIG. 73F shows the cell after the lighter doped emitter precursor deposition (BSG1) and heavily doped emitter region opening steps. FIG. 73G shows the cell after the heavily doped emitter precursor deposition (BSG2) and base contact opening steps. FIG. 73F shows the cell after the metal deposition and laser isolation steps. FIG. 73H shows the cell after the PSG (+USG) deposition and dopant drive-in to form junctions steps. FIG. 73I shows the cell after the laser contact opening steps. FIG. 73H shows the cell after the PSG (+USG) deposition and dopant drive-in to form junctions steps. FIG. 73J shows the cell after the metal 1 deposition, for example printed or PVD with ablation, steps.

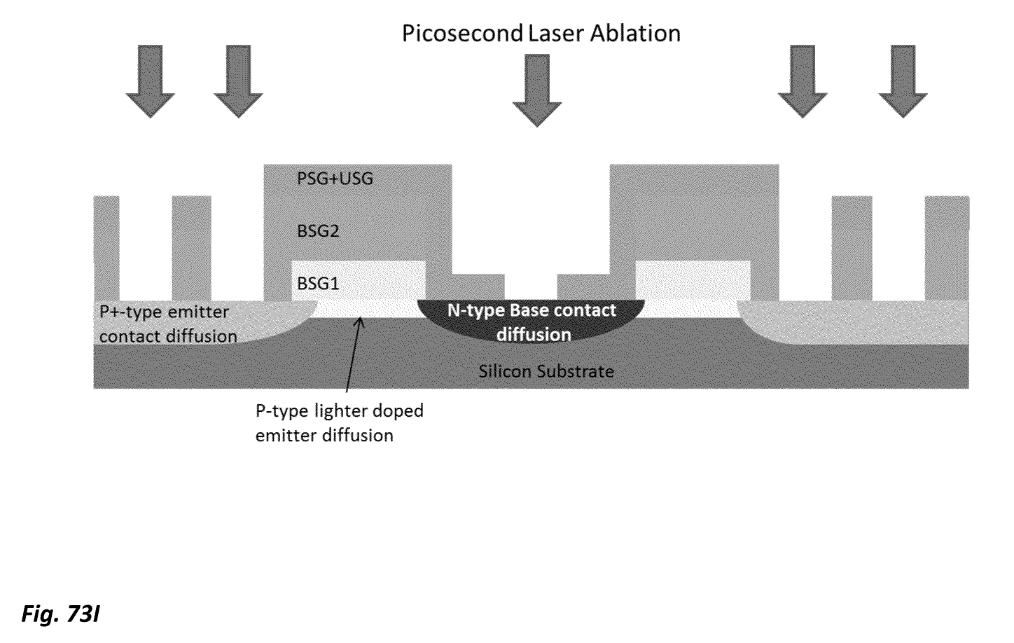

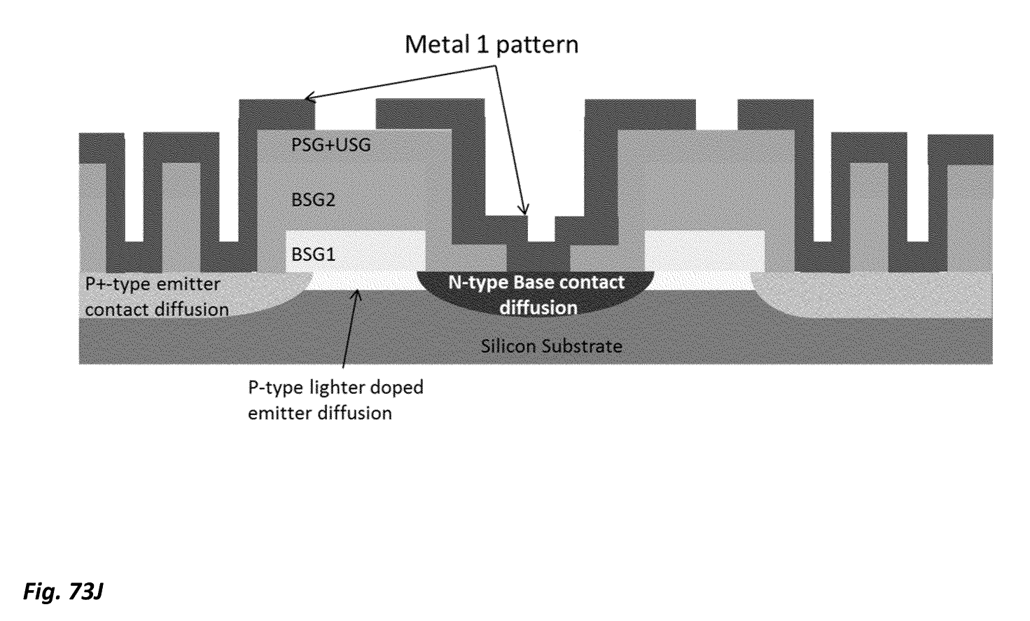

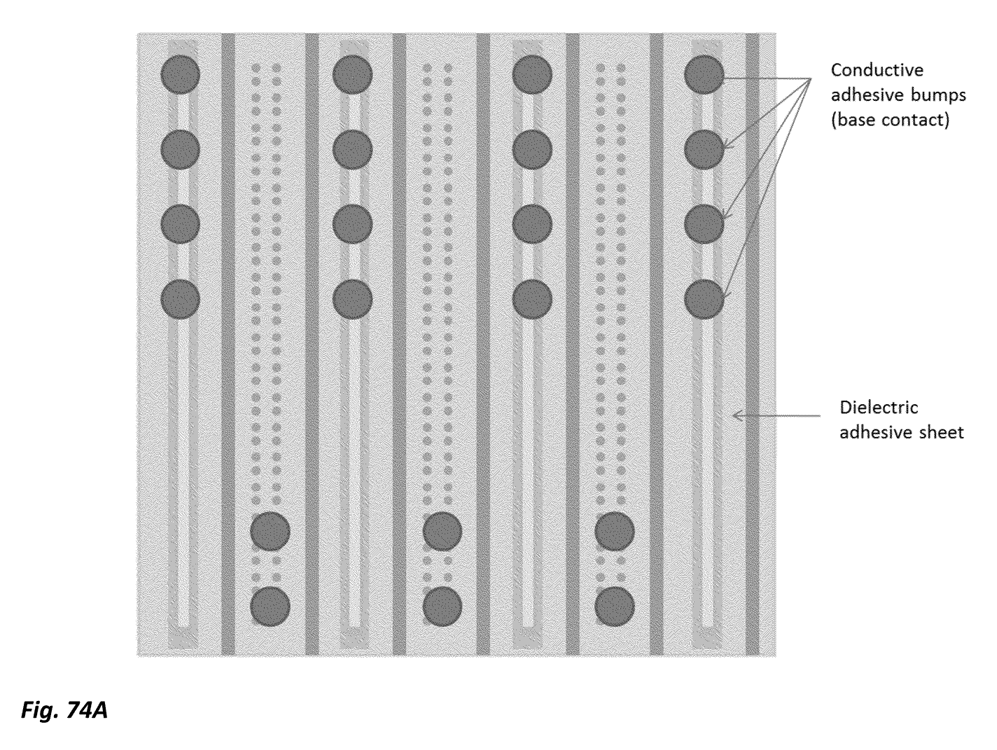

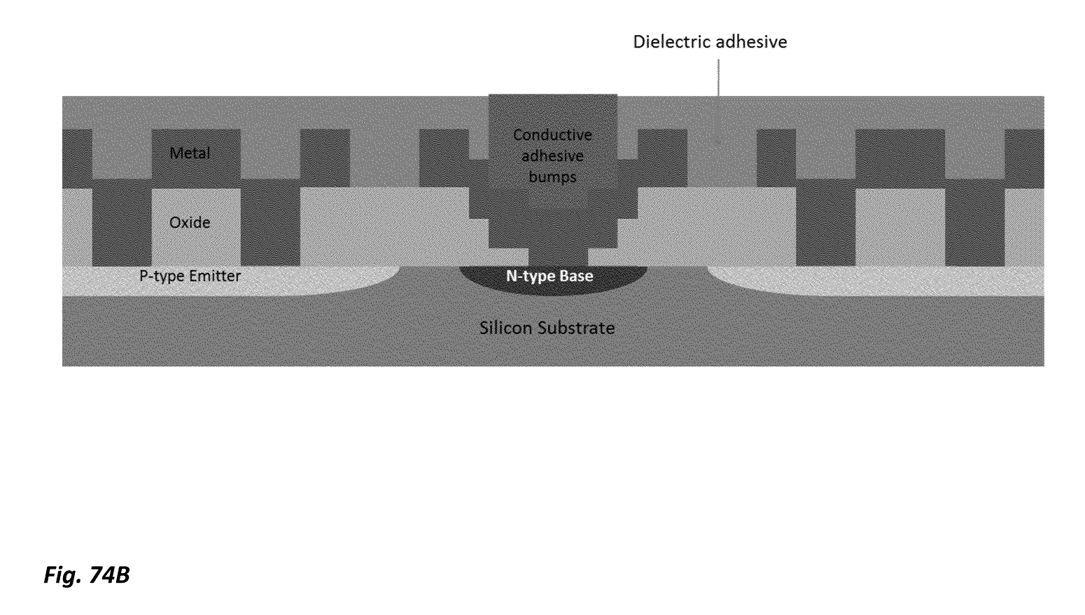

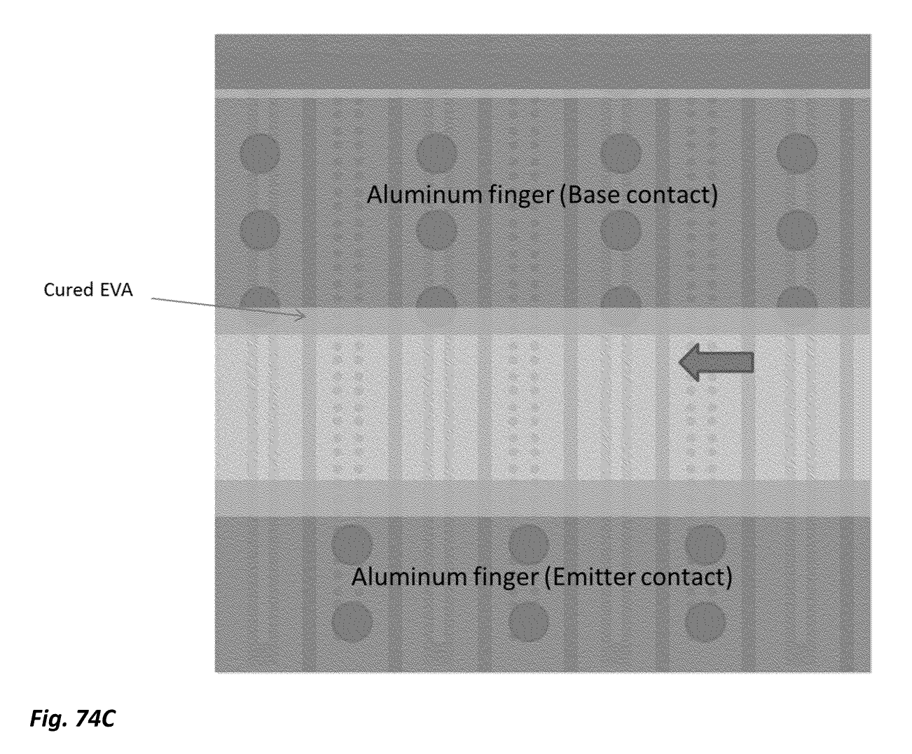

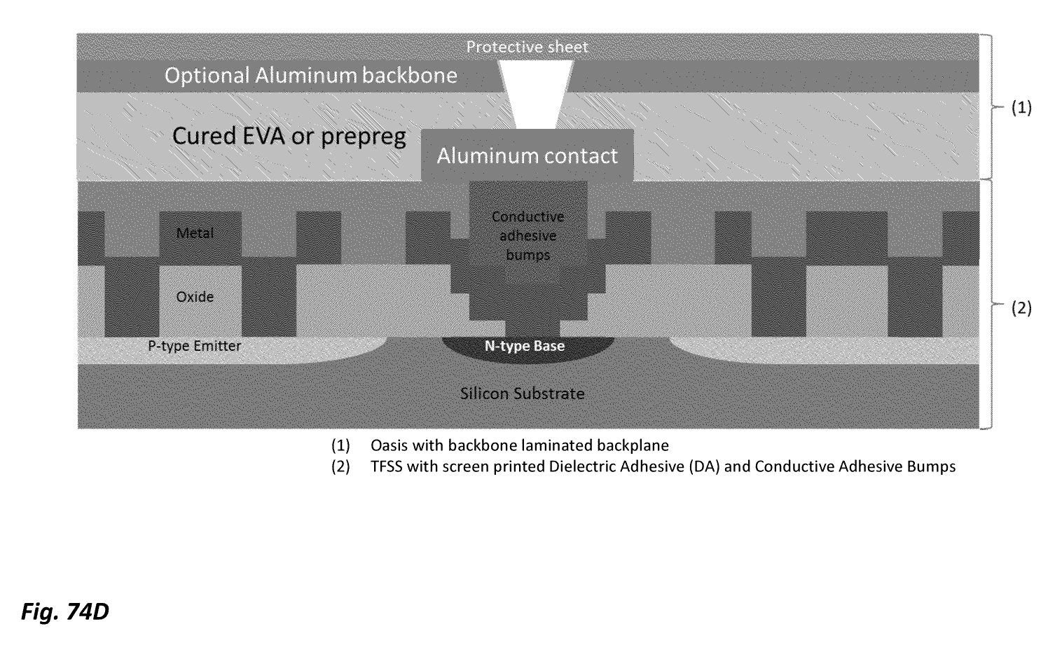

FIGS. 74A-D show a top view (FIG. 74A) and cross-sections of a cell during major fabrication steps of a process flow of an oasis structure embodiment for manufacturing a back contact solar cell. FIG. 74A is a top view of an oasis structure cell. FIG. 74B shows the cell after base contact formation steps. FIG. 74C is a top view of an oasis structure cell after backplane lamination steps. FIG. 74B shows the final oasis cell, with backbone.

For all the presented backplane embodiments, a viable processing flow and structure prior to the backplane part of the process has been disclosed herein. For example, in one starting substrate embodiment an epitaxial cell structure which is supported by the template has the contacts opened to the semiconductor areas of emitter and base. The contact to the base may have a highly doped contact area for low contact resistance, while the emitter is optionally a selective emitter with a highly doped area around the contact to the primary metal. These contacts may be opened using various techniques, as shown in the example embodiment of FIG. 73, the contacts are opened using laser ablation of the dielectric above. The contacts are best formed in an alternating line array of emitter and base contacts.

Subsequently the first layer metal is formed. This layer is referred to herein as the first layer metal even if it consists of several metals or several structures within. In one embodiment, the first metal structure is preferably aluminum or aluminum with a small amount of silicon to reduce spiking to ensure an ohmic contact to both p-type and n-type regions. If PVD is used to deposit the material, then the choice is typically that of a single material such as aluminum since the deposition is commonly performed for the whole cell area and structured later. The blanket deposited material is later patterned. Several options for patterning exist, in one example embodiment the metal is structured using laser ablation. Several options of laser ablations are possible, such as using picosecond laser ablation. The metal is preferably patterned such that alternating lines of emitter and base contact metal is formed, on top of the alternating lines of emitter and base contact openings.

If instead of PVD, a printing process is used for the first metal, such as screen printing or aerosol printing with—depending on the material—subsequent thermal processing, then aluminum or aluminum with a small amount of silicon to reduce spiking for both contacts may be used or aluminum for the p-type region contact and another metal, such as silver or others for the n-type region contact. The material of choice will also depend on its performance as a mirror. Good mirror performance (specular or Lambertian) can improve the overall light to electricity conversion, especially for the longer wavelengths which is important for cells using thin silicon. Alternatively, silicide forming refractory metals may be used as first metal layers as well for low resistance contacts; however, their mirror quality may not be adequate and the process is more complex.

Both PVD and printing processes for metal allow optionally for the deposition of stacked metal layers. In a PVD based process, aluminum deposition may be followed by an adhesion improving nickel vanadium (NiV) or nickel (Ni) layer, Ni often preferred because of the lower stress. This may be followed by a tin (Sn) layer, which allows for plating further on in the process flow. An alternative to this stack is Al, followed by tantalum (Ta). Other layer combinations are also possible. For simplicity of processing and for good performance as a mirror layer for the later introduced process of laser via opening, Al alone may be used as the first layer metal. When a plated layer is later used for the next metal layer and aluminum is the only base metal layer, then aluminum needs special surface treatment, such as zincation or double zincation.

The metal or metal stack needs to be chosen with several properties in mind, namely it needs to provide good adhesion, firstly to the underlying oxide or glass layer on the epi, secondly between the metals of a stack, and thirdly between the top metal on the stack and the backplane or, to be precise, to the adhesive component of the backplane.

For that, if aluminum is the first deposited metal and if the glass layer near the top also serves as a dopant source, for instance phosphorus silicate glass (PSG) as the n-type dopant source for the base contact, then it is typically helpful to retain the phosphorus content in the PSG at or below approximately 6% and/or cap the PSG layer with an undoped glass layer. Optional treatments of the metal during and after deposition can serve to improve subsequent adhesion. Such treatments include thermal annealing, laser annealing, surface roughening and others. For deposited materials, aluminum tends to provide good adhesion also to backplane materials presented here.

Printed metals normally require one or more thermal steps, for baking out solvents and optional sintering and/or drive-in steps. If more than one metal is printed, it is conceivable to do one thermal step for all or to have one or more thermal steps in between printing of metals. Printing of metals also allows for selective thickening of metal in areas where beneficial, such as in areas that serve as contact areas to the next layer metal at a later point in time. One method for selective thickening when using screen printed metal is to do more than one print while using different screen structures.

The surface of the deposited metal or metal stack is optimized to allow for a large process window for the metal ablation which is employed in conjunction with a PVD based process.

For both PVD and printed metals, it may be beneficial for the top metal of the metal stack (or the surface of the metal)—if only one metal is used for the first metal layer—is chosen or engineered such that it provides sufficient thickness and high reflectance to a laser beam that is employed at a later point in time to drill vias through a backplane material, where these vias have the function to provide next level metal contact to the first metal layer. For such via drilling, CO2 lasers may, for example, be used and aluminum, copper, silver and several other metals tend to provide good reflectance in the long infrared wavelength range of the CO2 lasers.

In the case of printed metals, it may be beneficial to locally thicken the metal and/or to locally add another metal print in the area of the future vias. This may serve both to increase the process window for via hole drilling as well as to provide a good metal area for the second layer metal to make contact to.

Prior to lamination, which is the next main process step after the first layer metal and its patterning and treatment, it may be advisable to provide the epitaxial layer with an oversized cut while it is on the template, so as to provide a known breakage location during the release of the backplane reinforced epitaxial cell structure.

### Process Flow for the Pluto Structure at Lamination.

The material chosen as the backplane material to be laminated to the thin film epitaxial solar cell structure (TFSS) which contains the patterned first layer metal is chosen with several important properties in mind, some of which are presented as follows: first the material has to be suitably matched with respect to its coefficient of thermal expansion with respect to silicon. Secondly the material has to either by itself, or with the help of a blanket or patterned adhesive layer, exhibit good adhesion to the TFSS and provide this adhesion throughout the temperature, pressure and humidity ranges that are required for the manufacturing of the backplane reinforced TFSS into a finished solar cell and that are required of solar cells in modules throughout their useful lifespan. Thirdly, the backplane reinforced TFSS needs to be able to withstand the chemistry, the gas environment and all handling steps throughout the manufacturing into a solar cell and into a module. Fourthly, the material needs to be cost-competitive, non-toxic and readily available.

The foregoing description focuses on the embodiments of a prepreg backplane in conjunction with silicon as the active absorber material. The same concepts apply for the use of Silicon with heterojunction materials such as Ge, SiGe, SiC, SiGeC, a-Si or a-SiGe, as well as for the use with III-V materials such as GaAs or the combination of GaAs with Si or Ge or its alloys. An attractive example material family to fulfill such requirements are prepregs that are used in similar formulations in the printed circuit board industry. Such prepregs are available with woven and non-woven fibers of different kinds, such as aramid, Kevlar or glass fibers in a matrix of resin.

Such sheets are laminated to the TFSS while it is on the template. The reinforcement can consist of a single sheet or more than one sheet, where different pretreatments or different fibers, fiber content percentage and resin type and content percentage are all employed to optimize adhesion as well as CTE mismatch.

As pointed out earlier, prior to lamination of the prepreg it may be advantageous to print an additional adhesive onto the cell. This adhesive may be thermally or UV curable and may cover either the whole area (as shown in FIG. 63D) and thus needs to be drilled through in the later via hole opening step or else is printed with openings where the via holes are to be drilled, or it can cover only the area between metal 1 lines (as shown in FIG. 63C).

Other backplane reinforcement materials options include materials similar to those used in solar module encapsulation, such as EVA or Z68. In examples below, whenever prepreg material treatment is mentioned explicitly, this should be understood to cover the use of other suitable backplane materials as well.

The materials chosen can include, depending on process flow and material formulation, the option of having very compliant or flexible cell structures, as well as enabling non-flat cell surfaces which enable further architectural solutions for applications such as non-flat solar modules.

Optionally, the prepreg area in contact with the TFSS may be covered at the time of lamination using a protective sheet which suppresses moisture or chemical uptake of the prepreg sheet during subsequent processing of the backplane reinforced TFSS such as texture and post-texture clean, as well as plating and plating surface preparation. Examples for such cover sheets are mylar or other PEN based materials which are chemically resistant.

Typical parameters to govern the lamination process itself are the use, extent and timing of pressure, temperature, temperature differential and ramping rates, resin and fiber type and content percentage, an optional pre-tacking or pre-treatment of the prepreg lamination sheet or sheets, the process time and time at temperature, the application and level of vacuum. Full curing of the prepreg through the lamination or at least prior to exposing it to water and wet chemistry may be advantageous.

After cooling down from the lamination step, the laminated TFSS on template is unloaded from the lamination tool and subsequently released from the template whether mechanically or other means such as etch. In general, the top side of the backside reinforced TFSS and the template are chucked and separated, either by the use of direct pulling, by peeling or by a pulsated pulling force, such as the force generated by the pulsated application of a vacuum on one or both sides of the structure.

The release may be optionally be assisted by the use of sonic or ultrasonic mechanical force, such as that administered by a piezo actuator that is coupled to the plates that are used to chuck the topside of the reinforced TFSS and/or the template. Also, immediately prior to the release a laser cutting step can be employed around the TFSS area to provide a preferred boundary within or along which the release takes place.

After releasing, the edges of the backplane reinforced TFSS are trimmed to a size suitable for further processing or even to the final size. In general, the trimming process may be carried out by the use of either a mechanical trim by cutting, shearing or sawing or by the use of one or more lasers, such as a CO2 laser or a pulsed YAG laser or similar, or by a combination of mechanical trimming and laser trimming.

Several options exist for aligning the trimming cut to the structure, depending on the geometry and setup of the cutting and whether the cut is initiated from the backplane side or from the TFSS side. Among the alignment options are the use of visible or infrared cameras (the latter in the case that buried alignment targets are to be used. Markings in the release layer residue may reflect the process of laser processing on the backside of the TFSS—such carried-through markings can serve as directly visible alignment targets.

Before or after the edge trimming, in any case before exposure to large capacity automated wet chemistry tools and processes and depending on the material and process chosen and the resulting flatness after releasing the backplane reinforced TFSS from the template, an optional thermal and pressure treatment of the released backplane reinforced TFSS may help provide optimized flatness of the layer which is advantageous for subsequent processes.

The backplane reinforced TFSS contains remnants of the release layer including the reflowed top of the release layer. This layer is highly defective and also acts as a gettering site. It is either removed in the following texture step or with a separate step prior to the texturing. Post texture cleaning is employed to remove metallic and optionally organic residue prior to passivation. There are several options for passivation and anti reflection coating that are compatible with the temperature range of the backplane materials and typically these steps can be restricted to temperatures below 200-250° C.

The initial passivation layer in contact with the textured surface may be an oxide, such as a silicon dioxide or a silicon-sub-oxide, i.e. a silicon oxide with a stoichiometric ratio between oxygen and silicon of less than two, where any such oxide layers are deposited or grown via chemical vapor deposition (CVD) or wet chemistry. Alternatively, the initial passivation layer can also be an oxynitride, for instance deposited via CVD or an amorphous silicon (a-Si) layer, which is intrinsic or optionally doped. This layer is for instance deposited using CVD or PVD. The anti-reflection coating may be performed using silicon nitride, even though aluminum oxide is also an option, especially for p-type base cells. This layer is for instance deposited using CVD.

After deposition of the top surface layer or layers or alternatively in between the depositions, an anneal can be employed, in order to reduce front surface recombination velocity (FSRV) and also back surface recombination velocity (BSRV). Such annealing is to be controlled in such a way that it is compatible with the thermal budget range that the device, especially the backplane allows. Suitable processes for such anneals include forming gas anneals or anneals in air or in an inert ambient as well as laser anneals that are tuned suitably to deposit their energy close enough to the surface and/or for short enough times so as to not exceed the allowable thermal budget of the backplane materials. An example for laser annealing processes for this application is pulsed laser anneals in the visible or near infrared wavelength range.

To protect the front surface during subsequent processes and for improved handling, it can be advisable to attach an optically transparent protective layer to the front surface. Such layers can be either thermoset or thermoplastic materials such as EVA or PE based materials such as a Z68 or z68 like material. The latter can later be reflowed and used for attachment of the cell to glass in the module assembly part of the process.

In order to prepare the structure for later second level metallization, an optional step may be inserted to prepare the backside surface for good adhesion. Such a step may comprised mechanical roughening of the surface with processes such as grit blasting or sanding. Alternatively, a chemical treatment or a plasma treatment of the surface can be employed which promotes adhesion. It is to be noted that such treatments can also be carried out prior to texturing, if desired.

The next set of process steps serves to establish contact to the first metal layer which is so far protected underneath the backplane material. This contact opening can be accomplished by laser based via drilling. An example laser employed for this process is a CO2 laser, although other lasers such as pulsed UV, visible or IR YAG lasers may be employed as well to ablate the backplane material. Holes can be drilled by direct pulsing at the same spot, using single or repeated pulses or by trepanning the area with multiple pulses, depending among others on the via hole size desired and the laser pulse energy available. For best selectivity of the laser drilling process to the underlying first layer metal, the underlying metal should be very reflective to the laser beam, such as for example aluminum and silver are very reflective at CO2 laser wavelengths. Depending on its absorption characteristics for CO2 laser wavelengths, it may be advantageous to have a dye in the material to be drilled (e.g. the prepreg). This dye is to serve to increase the drilling speed in the backplane (e.g. prepreg) and thereby increase the selectivity to the underlying metal. The dye may also have a visual function of providing cells with darker sidewalls for an overall dark appearance of the cells in the module.

The laser drilling process may also be combined with other processes, such as plasma etching of residue in the opened via hole, or organic cleanups of the via holes using for instance hydrogen peroxide, or changing between different types of lasers or parameter settings of lasers between onset and finish of the via drilling process.

A potential plasma etching, if employed, may be implemented immediately prior to the next level metal deposition, especially if this deposition occurs in vacuum such as when using PVD. The use of molecule radicals is also envisioned for a cleanup process immediately prior to next level metal deposition.

In this implementation of the process flow, the via holes need to be aligned to the underlying structures on the TFSS, especially to the patterned metal fingers from the first layer metal. If an additional metallic contact is printed on top of the first layer metal underneath the via, in order to increase the laser process window or to promote good adhesion and electrical contact to the next layer, then the via holes also have to be aligned to this layer.

For alignment structures or targets on the TFSS it is conceived that either during one of the on-template patterning or patterned deposition processes the alignment targets may be laid down, or else the structure itself, especially where it breaks the symmetry, such as the edges of the active area, may be employed to provide alignment without using up active area for alignment targets. Since the reinforcement material in general may not be transparent, the alignment to the targets on the TFSS for the via hole drilling process may be accomplished in several ways: First by having window cutouts in the reinforcement backplane material prior to lamination. These windows need to contain some resin that reflows into the windows during lamination and that is transparent enough to allow for visual recognition of the alignment targets. Or second, the alignment targets can be viewed using a camera with suitable sensitivity wavelength, such as an infrared camera that locates the targets either through the backplane material or through the thin silicon.

Using an infrared camera which locates the targets in the laser drilling tool by transmission infrared (IR) illumination through the TFSS has the advantage that with suitable instrumentation no movement has to occur between locating the targets and drilling the vias. After drilling and optional cleanup of the vias, the backside reinforced TFSS is now ready for second layer metal formation to contact the first layer metal.

Before describing the second layer metal formation, another closely related embodiment is described. It is to be noted it is also possible to drill the via holes into the backplane material prior to the lamination. This process is subsequently called pre-drilling of vias. Pre-drilling may be advantageous for the overall drilling process window. If the contact holes are predrilled, then the requirements to selectivity to underlying first layer metal material is removed or greatly relaxed. For pre-drilling, if more than one sheet of backplane reinforcement material such as prepreg is used, it may be advisable to tack the sheets prior to pre-drilling using a tacking lamination at suitably low temperature. Furthermore, during the via pre-drilling the laser can cause local curing at the edges of the vias. This may serve to reduce outflow of resin that tends to close the opened holes. Since the predrilled holes after lamination would not necessarily protect the underlying first layer metal suitably during the wet chemistry process for texturization and post texture clean, it may be useful to add an undrilled protective sheet of the above mentioned mylar, teonex or other PEN or PET based materials. Similarly to the above described via drilling process where the vias are drilled after drilling the area, albeit this time with a much less stringent requirement on process selectivity. Such gains in process selectivity may potentially eliminate the need of other post via drilling hole cleanup steps. As an alternative to the application of an undrilled protective sheet it is also possible to locally cover the first layer metal that is to be contacted with a suitable dielectric such as a glass or polymer which is chemically resistant enough to withstand the texture and post texture clean processes, but which may be removed prior to second layer metal contact formation to the first layer metal. In the case where the wet processing is not carried out by immersion but by single side wet chemistry application, a protective sheet may not be required when using a pre-drilled sheet.

When the predrilled reinforcement backplane is laminated to the TFSS which is at that time supported by the template, the application of the backplane sheet or sheets with the TFSS on template for the lamination has to be done with an alignment. To secure that an aligned position is retained during the lamination, the sheet or sheets can be pretacked to the surface using a laser or other local heat source. Alternatively, as part of the first layer metal formation, the area of the vias may be built up with a taller, preferably printed, metal region. Such local pillars, when dimensioned properly, may serve to secure the predrilled sheet in place during the lamination. The above mentioned optional local protective material is in that case applied on top of such pillars. Such pillars can be employed in a very sparse pattern, so as to save on material usage for said pillars.

Second Layer Metal Formation.

The second layer of metal is preferably structured in an essentially orthogonal relation to the first layer metal fingers, with the potential exception of one or more bus bar strips for each terminal. Orthogonal relation may greatly relax the requirements for patterning the second layer metal. For instance, if the patterning requirements of the first layer metal are in the hundred or hundreds of micrometers, the patterning requirements of the second layer metal are in the millimeters to centimeters range. This in turn enables the use of very economic patterning techniques such as simple shadow masks or very cheap printing, roller coating or spraying applications. Also it allows for the use of stamped out large dimension metal fingers. This relaxation is enabled by the concept that for the orthogonal relation geometry, the distance that current has to travel in each first layer metal finger is suitably short prior to reaching a via for extraction.

Various process flow options for forming the second layer metal have been disclosed including the embodiments and alternatives following. If aluminum is the contact metal to the second layer, then a zincation process, preferably a double zincation is advantageous for reliable plating on top of aluminum. If a PVD process is to follow, zincation may be circumvented by doing a pre-sputter etch cleanup.

A suitable PVD process for contacting the first layer metal may then start with a pre-sputter etch, Al, follow by Ni or NiV deposition, followed by optional Sn deposition. This PVD process may be performed using a shadow mas, thereby enabling patterned metal deposition. Alternatively, the metal may be patterned after the deposition using laser ablation, similar to the patterning for the first layer metal. The deposited metal or metal stack may optionally be annealed after deposition to tune its properties.

Alternatively the vias may be filled or partially filled first by printing, for instance stencil printing a conductive paste such as aluminum, copper, nickel or silver paste. A seed metal or metal stack can then be deposited also using PVD or screen printing, on top of the metal that is used to at least partially fill the vias. Printed pastes can be baked and/or annealed after application.

On top of this seed, the remainder of the metal may be plated. And alternatively, the whole necessary thickness of the orthogonal metal fingers of the second layer metal can be printed using a suitable paste. In the case of plating, the deposition of the seed metal may be performed in a patterned way, as described above, or as a blanket layer which is subsequently patterned using a resist structure which separates emitter from base plated areas. After plating, the resist is stripped and the seed layer is etched back in the areas that were protected using the resist. A typical sequence of plating starts with Ni, followed by copper (Cu) and ending with Sn for solderability. Alternatively and depending on the seed material, Cu can be plated directly. Sn can also be applied locally after plating, using printing, in areas where it is required for soldering. In the case of a printed seed, it is also possible, if affordable, to print up the whole second level metallization using for instance screen or ink jet printing.

The structure for the second layer metal may either have a single or multiple bus bars per terminal or it can contain only metal fingers. In case of a plating process for the second layer metal, the number of contact points required for module integration scales with the number of independent bus bars at the time of plating. Contacts in the module from cell to cell can be accomplished using dog bone shaped contact fingers. For a finger-only structure, the dog bone contact points per side need to equal the number of second layer metal fingers per terminal. Minimizing the area of the bus bar, up to the point where no bus bar is employed, serves to maximize the overall active area on the cell that current can be drawn from by in turn minimizing the area of electrical shading underneath the bus bars.

The contact metal strips between cells can consist of Cu with solder or solderable aluminum, such as Al with thin Ni and Sn or tin-bismuth (SnBi) coating. In the areas that are visible in the module, the strips can be painted in black locally to add to the all-black look of the panel. Such paint coating can act as a dielectric as well, allowing for tight arrangement of cells within a module.

Manufacturing the Oasis Structures.

FIGS. 64 and 67 show example embodiments of oasis structures. Oasis-type backplane structures may be realized either by single step lamination of more than one component onto the TFSS which is at that point supported by the template, or the oasis-type backplane may be formed separately using one or more lamination steps and then applied to the template supported TFSS. If the latter path is chosen, then there are additional options to apply some layers either to the TFSS side or to the backplane side. This holds for instance for the dielectric adhesive that provides adhesion between TFSS and the backplane and which is either applied by processes such as screen printing or by laminating a dielectric sheet such as prepreg which is pre-lamination drilled or post-lamination drilled. The same holds for conductive materials such as conductive adhesive or conductive epoxy that may be applied in the area where there is no dielectric, i.e. to provide a conductive contact through a via in a dielectric between the metal fingers on the TFSS and the next layer metal on the backplane. In these cases, it may be advantageous for at least the dielectric adhesive to be b-stageable or to be at least partially reflowable, since the dielectric has to undergo two laminations to the different sides. It is seen as advantageous to then have the thermal budget of the lamination step which connects the backplane to the TFSS to be chosen such that the dielectric is fully cured. Typical dielectric choices are sheets of prepreg material or screen printable dielectric adhesives, such as polyesters or other resins.

Oasis Formation Embodiments.

FIG. 72B illustrates options for forming an oasis structure. Embodiments include the manufacturing and attachment of the backplane in a single step or in separate step, such that the backplane can be stored and staged.

Second, for the attachment between the TFSS with the patterned first layer metal fingers and the large metal fingers of the backplane embodiments include the use of a combination of printed dielectric adhesive and conductive adhesive or epoxy versus the use of a dielectric sheet such as prepreg which may then in turn vary from being drilled prior to lamination or after lamination. In the case of pre-lamination drilling, the CA posts may be printed onto either the TFSS side of the structure or to the backplane side of the structure, if the backplane is manufactured separately. For a single step lamination using pre-drilled prepreg, the CA posts are printed onto the metal fingers on the TFSS.

Oasis Lamination Using a Dielectric Adhesive.

In a process flow embodiment, such as that depicted in FIG. 64G-F, where an oasis backplane is manufactured prior to attaching to the TFSS on template and where a printed dielectric adhesive is used to bond the TFSS to the backplane, the following starting materials may be utilized. A chemically resistant top cover sheet, preferably made of Tedlar, Mylar, Teonex or other PEN or PET materials, followed by a dielectric sheet (EVA, Z68 or prepreg) which has access holes predrilled), are arranged onto the structure of the large area metal fingers. The metal fingers in turn may be structured from planar sheets of for instance solderable aluminum, i.e. Al with a thin layer of Ni and Sn, by electrical discharge manufacturing, laser marking followed by etching (in materials such as KOH, if aluminum is used), or they can be stamped out using one or more stamping dies.

These structures are aligned and laid up on top of each other, optionally covered with release sheets or with non-sticky surfaces on both sides, and then laminated together. With the right choice of material and lamination conditions, such as suitable evacuation, temperature range, ramping and lamination pressure, the dielectric material flows and planarizes the structure. Areas where planarization is not desired, such as in the backside contact areas, may be kept open by providing suitably shaped lamination contact chucks or by pre-curing the edges of the contact holes (using for instance increased laser power during the cutting of these holes) to prevent outflow of material from the edge to close the holes.

A B-stageable or at least partially reflowable, i.e. thermoplastic, printed dielectric adhesive is used as the adhesive is then applied to the backplane or (not shown) to the TFSS. Further, a conductive adhesive may be printed on either side. Dielectric and conductive adhesive each receive suitable optional thermal treatment after printing. To keep costs low, the overall area of the conductive bumps is to be kept low, preferably below 2% of the overall cell area. Prior to lamination, the TFSS may be pre-cut in a region just outside the active area to provide a designated breakage point of the epi layer upon the release that is to occur after the lamination. After that, the backplane and the TFSS on template are laminated together. In this process, the electrical contact between the metal fingers on the TFSS and the large metal fingers on the backplane is also established. After the lamination, the structure is released by mechanical release, similar to the release described for the pluto structure. The edge of the released and backplane reinforced device may then be trimmed, also similar to the trimming described for the pluto structure. Preferably, the edges of the backplane structure where the trimming occurs are sealed by the suitably chemically resistant dielectrics. Afterwards, also similar to the pluto structure, on the sunny side of the TFSS the residue of the release layer is cleaned off, the surface is textured, post-texture cleaned and passivated. As a final process for the cell, the contact access points to the large metal fingers of the backplane are opened, for instance by laser drilling of the cover sheet material.

Conductive solder bumps may be placed, or the solder from a stringer that is used for module assembly manufacturing may be used, to establish the contact to the cell. The cell receiving its own solder bumps may have the advantage that the individual cell may be tested and passing cells may subsequently be assembled into a module; however, such testing may also be accomplished using suitable probe card arrangements.

### Lamination Using a Dielectric Sheet.

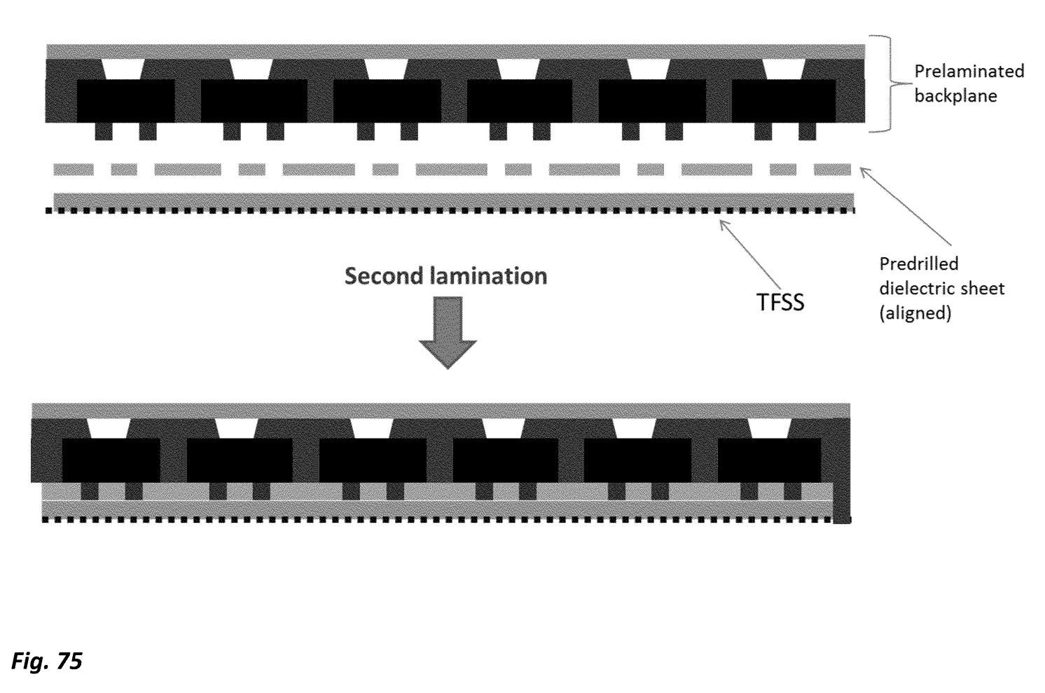

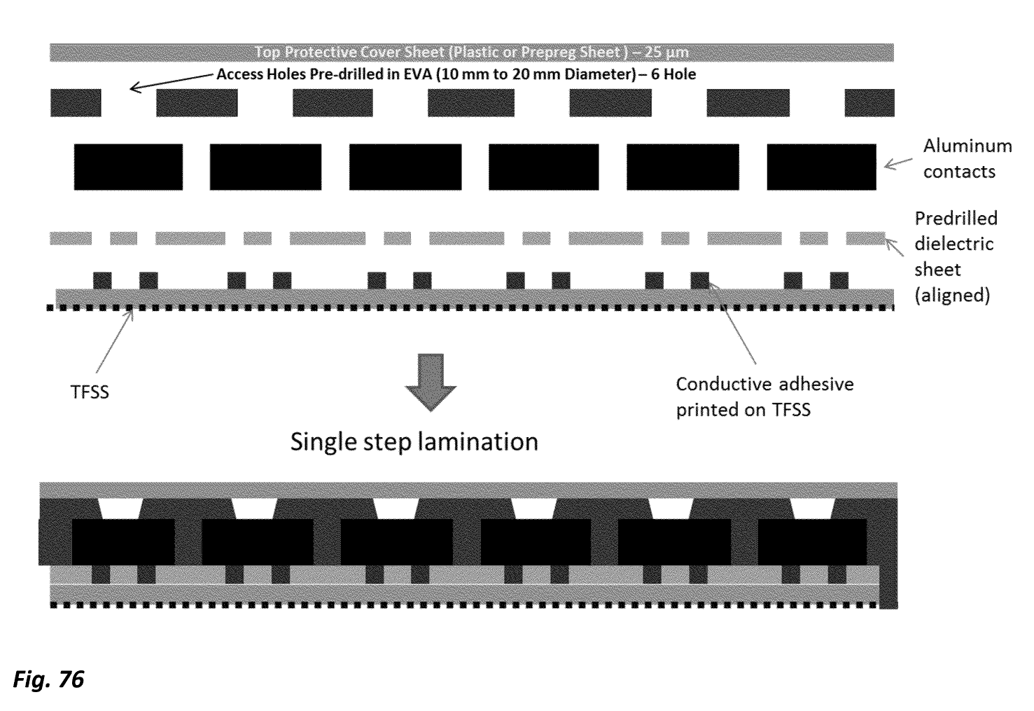

As an alternative to the lamination using a printed dielectric adhesive process described above, a dielectric sheet, for example a prepreg material, which is pre-drilled may also be used as the adhesive between large metal finger containing backplane and the TFSS. The cross-sectional diagrams of FIG. 75 illustrated an oasis flow using a predrilled dielectric sheet (with two step lamination) showing this process. Here, the conductive adhesive is printed in the desirable area and the pre-drilled dielectric sheet is laid up in an aligned way to the grid of the printed conductive adhesive. For that process, it may be desirable that the conductive adhesive be B-stageable such that it may be dried and not smear during the lay-up process but still reflow during the lamination to provide a good contact between the metal on the TFSS and the backplane metal. The remainder of the process, after lamination, is similar to the previously described case of using a printed dielectric adhesive.

Single Step Lamination Process for Oasis Structure.

With proper thermal budget and thermal sequencing during lamination it is possible to attach all components of the Oasis structure in a single step, rather than having a separate step for backplane lamination and lamination of the backplane to the TFSS on template.

The cross-sectional diagrams of FIG. 75 illustrated an oasis flow using a predrilled dielectric sheet (with single step lamination). Here, the conductive adhesive needs to be printed on the TFSS side. In a case that a dielectric adhesive is used, this adhesive is also printed onto the TFSS side, preferably prior to printing the conductive adhesive. In a case that a dielectric sheet such as prepreg sheet is used, this sheet needs to be pre-drilled for the single step lamination. In both cases above the conductive bumps are printed prior to laying up the pre-drilled dielectric sheet and the pre-drilled sheet is aligned to the pre-formed bumps. The large metal fingers of the backplane are laid up, the top perforated dielectric sheet (e.g. EVA, Z68 or prepreg) is laid up and finally the cover sheet is added. Then the lamination process is carried out, using a process profile that is adapted to the required process parameters of the materials involved—typical lamination temperatures are below 300 or even below 250 deg C. After this lamination, further processing proceeds in a like fashion to the process flows described above for the oasis structure.

Process Flow for the Pluto-Oasis Hybrid Structure.

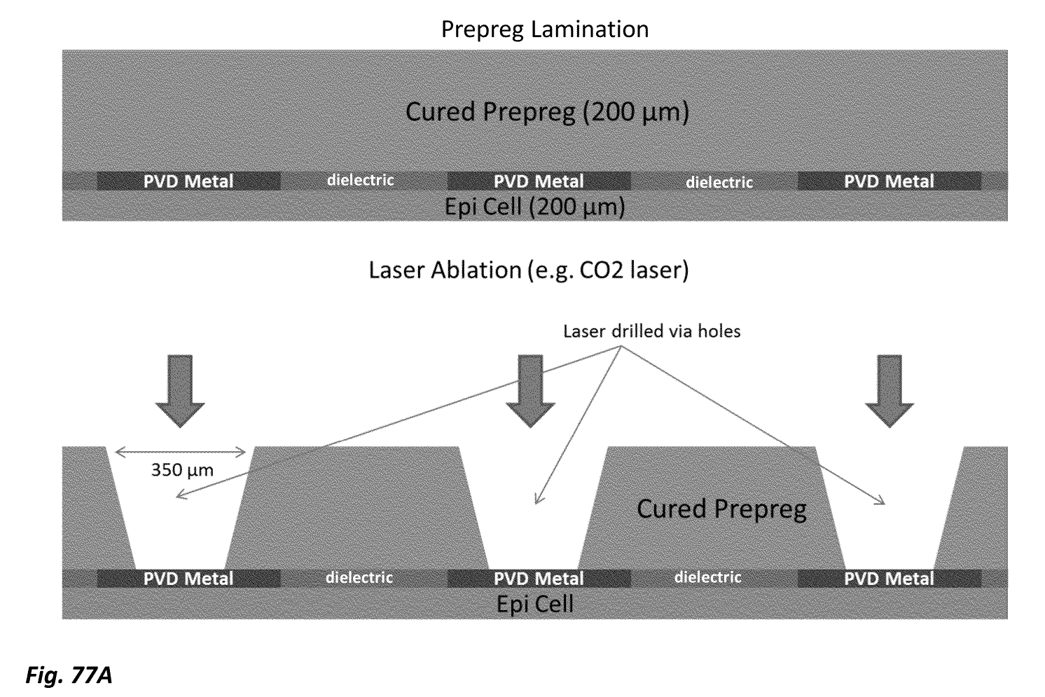

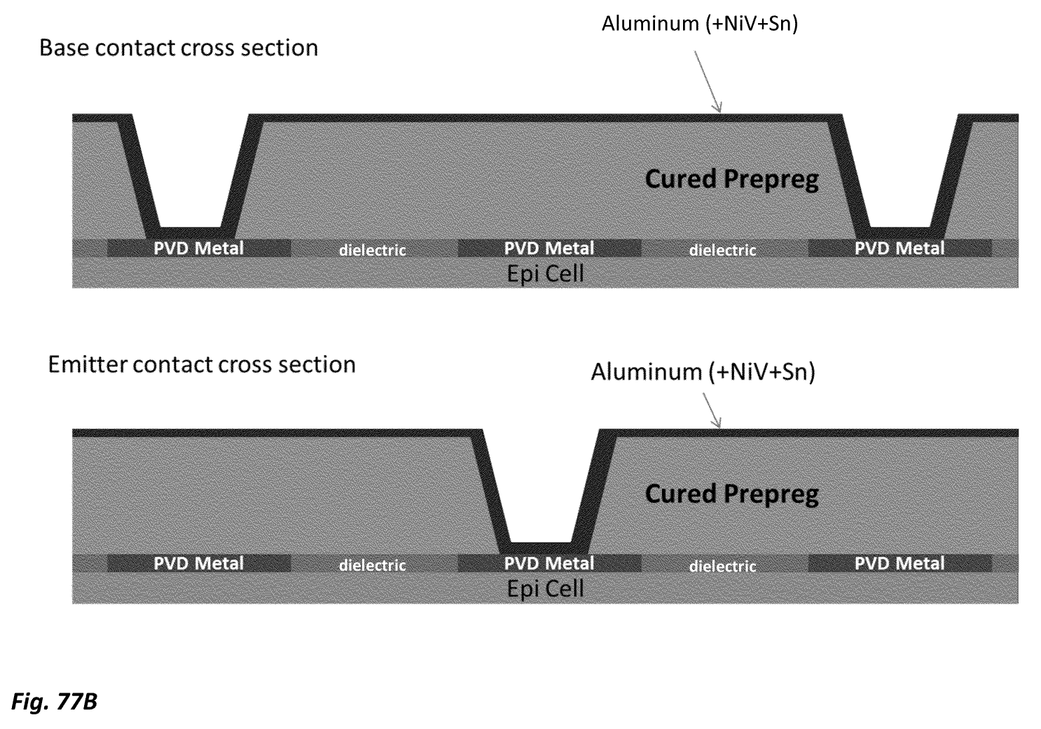

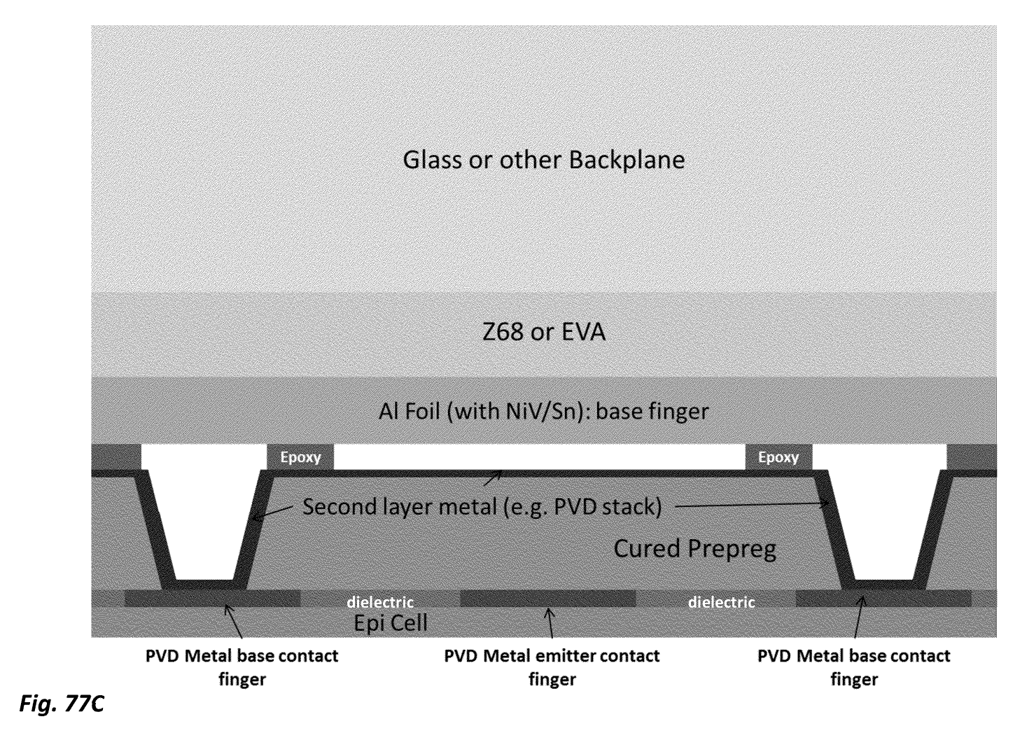

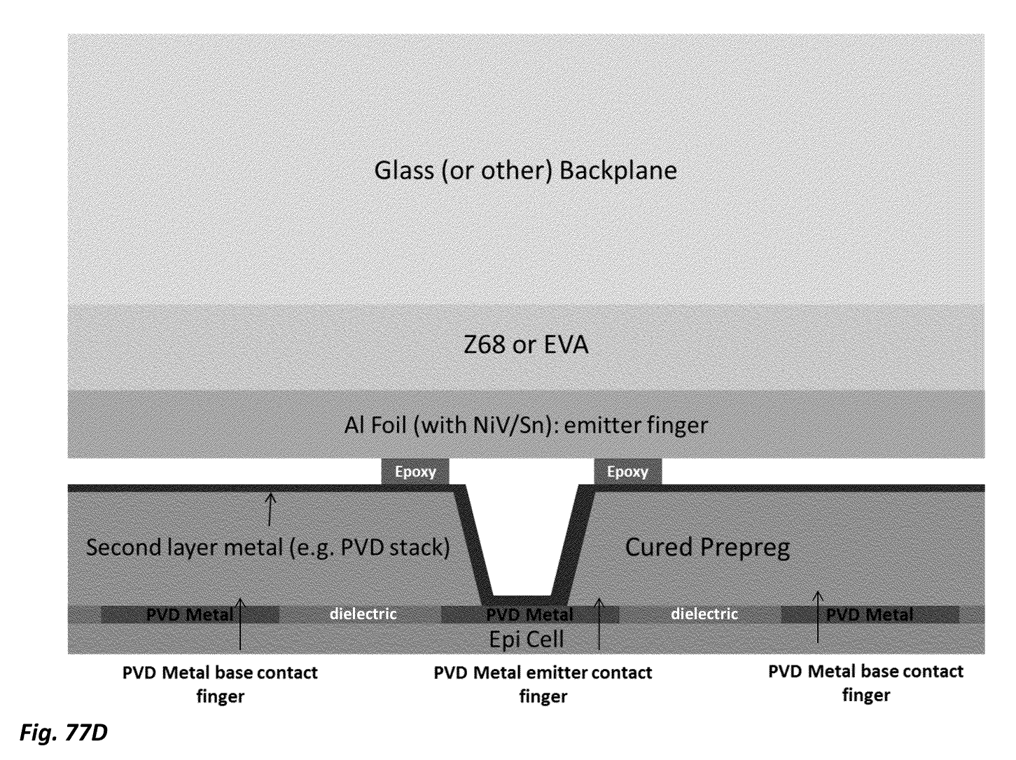

FIG. 77A-D illustrating process steps on a pluto-hybrid structure. FIG. 77A is a cross section of a pluto-hybrid structure during the prepreg via drilling processes. FIG. 77B is a cross section of a pluto-hybrid structure during the metal deposition and isolation processes—the metal isolation is parallel to the diagram and therefor not illustrated. In one embodiment, an Al (+NiV+Sn) PVD and isolation. FIG. 77C is a cross section through base contacts of a pluto-hybrid structure after conductive epoxy screen printing and backplane lamination. FIG. 77C is a cross section through emitter contacts of a pluto-hybrid structure after conductive epoxy screen printing and backplane lamination.

The process flow for the hybrid structure may be substantially equivalent to the pluto based flow up to and including the process of opening the via holes by laser drilling after the passivation and preparation of the surface, as illustrated in FIGS. 73A-E. A difference to the pluto structure and flow and with it the similarity to the oasis structure and flow is that the hybrid structure of FIG. 77 includes a structure of large metal fingers which attached to the backplane reinforced TFSS, rather than a metallization structure that is built up using a plating process. To do so, after the via cleanup as described in the pluto flow, first the metal contact is routed from the bottom of the via onto the top of the dielectric, for instance the prepreg. This may be performed in one or several steps. If several steps are used, the via is first at least partially filled using a stencil or screen printed paste. Then metal fingers are deposited for instance by PVD through a slitted shadow mask. Alternatively, if the process of routing the metal is performed in one step or sequence, then the surface of the bottom of the via can be cleaned for instance immediately prior to PVD deposition by doing a pre-sputter etching and/or ashing, in order to remove potential organic residue and native oxides, both of which can contribute to high contact resistance or poor contact reliability.

Alternatively to depositing the metal fingers through a shadow mask, which may be possible due to the rather coarse dimensional requirements for the fingers (millimeters to centimeters). The metal may also be deposited as a blanket metal and afterwards patterned, for example using laser ablation.

On top of the large width metal fingers which run orthogonally to the metal fingers on the TFSS and which contain optionally one or several bus bars per polarity, as explained for the pluto structure, an array of conductive bumps or epoxy are printed. Similar to the oasis structure, there is an additional backplane with large metal fingers, for instance made of solderable Al, for instance with a Ni and/or Sn coating, which may be either pre-manufactured and then laminated to the already reinforced TFSS, or which may be laminated in a single step. The backplane itself consists for example of large width metal fingers which are held in place by a dielectric adhesive which in turn may have a backing plate, for example of glass, polymer, ceramic or metal. For contacting the cell to other cells or in general within the module, it may be advantageous to either have holes in the layer above the large width metal fingers or to have the large width metal fingers extend beyond the edge of the cell. Such metal fingers may be generated in a similar way as for the oasis structure, for example by EDM, stamping, slit cutting or suitable etching after a definition of the etch areas using a mechanical or laser marking. From a structural point of view, it may be advantageous to retain the structure throughout the process in such a way that the area that becomes the bus bars is connected to both polarities, and only prior to cell assembly each side of the contact polarities is cut off. This is an especially straightforward process if the large width metal finger grid is chosen to be oversized compared to the cell.

As another alternative, such metal connections may also be integrated into the module assembly where then a large area of metal fingers may be processed and laminated in parallel. This is possible since the initial metal of the reinforced cell already enables testing and sorting of the cell.

It is to be noted that for the hybrid structures the orthogonal transfer of the metal lines between the on-cell thin fingers and the on-backplane wide fingers may be implemented either from the on-cell metal fingers to the second layer deposited or printed metal or from the printed metal to the backplane aluminum foil fingers. With the latter, it may be advantageous to implement another dielectric between the second layer deposited or printed metal and the aluminum foil fingers.

Process Flow for the Immersion Contact Bonding Structure.

The immersion contact bonding structure is processed similar to an oasis type structure. Main process step differences are depicted in FIGS. 69 and 70 and may be described as the following: After the patterning of the on-TFSS thin metal fingers, as described for the above structures, these fingers are covered with an array of conductive bumps. Then, similar to the oasis structure, there are essentially two alternatives. One is the bonding of the TFSS with the array of conductive bumps to a pre-fabricated backplane, second is the layup and common lamination of all components of the backplane. Both alternatives have structural and flow options as described in the oasis flow. In both cases, for the immersion contact bonding structure, the adhesive dielectric does not contain the array of via holes which is patterned complimentary to the array of conductive bumps. Rather, the dielectric is applied as a randomly or regularly perforated array to offer sufficient open area for conductive bumps to puncture through upon the softening of the dielectric during the reflow that occurs at lamination. Alternatively, the dielectric is not pre-punctured yet the conductive bumps are shaped such that with the choice of a suitably compliant dielectric, the bumps may still puncture the dielectric and form a low contact resistance contact through the dielectric and serve to establish contact between the TFSS metal fingers and the large width metal fingers on the backplane.

As described above, the disclosed subject matter relates to novel structures and methods for the metallization of solar cells, and specifically multiple (two or more) levels of metallization associated with an active semiconductor photon absorber for low-loss interconnection and efficient photo-generated electricity collection from a solar cell. In some solar cell embodiments, the semiconductor photon absorber may be crystalline silicon, including but not limited to mono-crystalline silicon solar cells with back-contact metallization architecture. Additionally, although primarily described with reference to dual layer metallization in conjunction with a supporting electrically insulating backplane, any number of metallization layers (for instance, using 2, 3, 4, or higher levels of metallization) may be utilized (even including a single metallization layer comprised of “stacked” metallization materials) on the backside (or the side opposite the sunnyside) of a solar cell comprising an electrically insulating layer (for 2-level metallization) or layers (for metallization comprising more than 2 levels of metallization) used as inter-level metallization electrical insulator in accordance with the disclosed subject matter. Further, in some embodiments the metal or electrical interconnect layer(s) on each level may be independently patterned using several available techniques, such as but not limited to blanket metal deposition (for example, by a Physical-Vapor Deposition or PVD technique such as plasma sputtering, evaporation, thermal or arc plasma spray, or ion beam deposition; or by using an electrochemical deposition process such as plating) followed by pattern formation using pulsed laser metal ablation or a combination of lithography (for instance, using screen printing of a patterned etch resist layer) and subsequent etching of metal and stripping of the resist layer. Alternatively, the metallization pattern may be formed during and by the metallization process itself (called in-situ patterning). Examples of in-situ patterning include screen printing of a metallization paste (forming the desired pattern), PVD using in-situ shadow masking, etc. The metal layers may be separated by electrically insulating dielectric layers (using one electrically insulating layer for two levels of metallization, and in general N−1 layers of electrically insulating layers for N levels of metallization, wherein N is an integer equal to or greater than 2) and connected together using specific patterns of inter-level via holes formed through the electrically insulating layer(s) (vias), either partially or fully filled with an electrically conductive material formed through the dielectric layers (hence, forming electrically conductive via plugs). The electrically conductive via plugs (connecting two adjacent metallization levels according to a pre-specified interconnection pattern) may be formed using the same metallization material and process utilized to form the higher metallization level. Each metal layer may be composed of similar or disparate metal types, such as Al, Cu, Ag, Ni, Sn, or a combination of metals—for example, low-cost high-conductivity metallization materials composed of aluminum and/or copper—and may be patterned to different dimensions. And while the following is described with reference to aluminum (Al), any electrically conductive metallization material may be a viable material choice in some instances (including copper, zinc, or even silver although silver is expensive and may be less desirable than much lower cost high conductivity material options such as aluminum and copper for solar cell metallization).

In one embodiment the metallization structure may utilize dual level metallization structure wherein the first level (or lower level) metallization closer to the solar cell absorber substrate is referred to as metal 1 or M1 and the second level (or upper level) metallization on top of M1 and, in some embodiments separated from the first level by an electrically insulating layer, is referred to as metal 2 or M2. For example, patterned M1 may be formed directly on the solar cell substrate underneath the electrically insulating layer or sheet separating M1 and M2, while M2 is formed on top of the electrically insulating layer or sheet attached to the solar cell substrate (in other words the electrically insulating layer or sheet is sandwiched between M1 and M2, and M1 is sandwiched between the solar cell substrate and the electrically insulating layer or sheet). The combination of the electrically insulating layer(s) or sheet(s) with the metallization structure above M1 may be referred to as the solar cell backplane. Advantages of a dual layer (bi-layer) metallization structure over a single metal structure for back-contact solar cells include, but are not limited to, the following:
Dual level metallization allows the M1 layer to be thinner and the M1 pattern lines to be narrower, thus allowing for the use of higher sheet resistance M1 without compromising the fill factor of the solar cell. This is because the electrical current is carried only locally (as opposed to globally) for relatively short distances on M1 (for instance, over the scale of 100's to 1000's of microns) before it is pulled up through the vias to M2, where the metallization lines may be wider, thicker, and have lower electrical resistance.
   i. A thinner M1 produces less stress on the absorber layer, which in turn provides robustness in yield and also allows for M1 scaling to larger area of the solar cells. This may be especially important as the solar industry strives toward more fragile thinner absorber layers motivated by cost reduction (and in some cases performance enhancement, such as with back-contact/back-junction crystalline silicon solar cell designs).
   ii. A narrower M1 may increase the emitter fraction in back contact/back junction solar cells which allows for reduced electrical shading and higher cell conversion efficiency.
Dual level metallization also allows flexibility in segmentation of M1 and other designs, as may be required in various and novel cell architectures.
Dual level metallization allows for a busbarless M1 that eliminates electrical shading due to elimination of M1 busbars, hence, further increasing the efficiency of the cells.
When used in conjunction with orthogonal transformation of M2 with respect to M1 (i.e., M2 fingers substantially perpendicular to M1 fingers), dual level metallization decouples the line dimensions of M2 from dimensions of M1. Orthogonal transformation allows the M2 dimensions to be generally different, and specifically more coarse, than the M1 dimensions which allows for the deposition of a thicker M2 using much more cost effective deposition strategies. This may also mean the number of M2 metal fingers can be much less than the number of M1 fingers.

Current solar cell metallization designs often use a single metallization level adjacent to and connected to the active absorber (e.g., fired paste metallization on silicon solar cells). In a traditional front contacted solar cell architecture, each side of the solar cell has metallization layer with the front side/sunnyside (solar cell side facing sunward) metal patterned (typically a screen printed silver paste metallization) to let the light through to the cell and the backside metallization/non-sunnyside (solar cell side opposite the side facing sunward) patterned or non-patterned (typically a screen printed aluminum paste metalliation). For example, a typical front-contact crystalline silicon solar cell may have one patterned emitter metallization layer (often comprising silver) on the cell sunnyside and one blanket base metallization layer (often comprising aluminum which also serves as the back-surface field or BSF layer), or screen printed aluminum with optional localized back-surface field or BSF, on the cell backside with a patterned dielectric layer. In back contacted back junction (also known as interdigitated back contact or IBC) solar cells, a single metallization layer may be patterned (e.g., as an IBC pattern) on the non-sunnyside and no sunnyside metallization—thus no sunnyside optical shading for an unobstructive and ideally maximum coupling of the sunlight. The multi-level (for example bi-layer or two-layer) metallization embodiments disclosed herein, while applicable to any solar cell architecture such as front junction/back-contact or back-contact/back junction solar cells, are described with reference to back contact/back junction (BC/BJ) crystalline silicon architecture (also known as IBC solar cells).

Multi-level metallization schemes of at least two levels of solar cell metallization, and for example designed in an orthogonal M2-M1 pattern (alternative metallization layers aligned orthogonally or the adjacent metallization levels with interconnect fingers substantially perpendicular to each other) and separated by electrically insulating layer(s), one electrically insulating layer between M1 and M2 for the two-level metallization scheme, provide numerous metallization, efficiency, and cell processing advantages over known solar cell metallization structures and manufacturing methods. For example, in a bi-layer (also known as two-level) metallization embodiment where the two metallization levels M1 and M2 are separated by one electrically insulating layer or sheet, the combination of M2 and the electrically insulating layer or sheet (also known as the solar cell backplane in this invention) may serve as a reinforcement and support structure for the semiconductor absorber, an advantage particularly applicable to ultrathin solar cell absorbers. Such backplane reinforcement and support structure may be made rigid (for instance using a non-polymeric insulator such as a glass or a ceramic layer) or pliable/flexible (for instance, using a polymeric material such as a prepreg material). Additional benefits and advantages of multi-level metallization, particularly with respect to bi-layer metallization for high-efficiency crystalline semiconductor solar cells (particularly, back-contact/back-junction solar cells), include but are not limited to:
The M1 metal may be made much thinner (e.g., in the range of 100's to 1000's of nm thick) as compared to known on absorber metallization patterns (which use 10's of microns metal thickness for back-contact/back-junction cells). Thinner M1 metallization creates less stress from M1 applied onto the silicon absorber, a very desirable advantage, particularly for ultrathin cells with absorber thickness below about 100 microns and/or large-area cells with cell area larger than 125 mm×125 mm. Larger area scaling is possible because the multi-level metallization schemes in accordance with the disclosed subject matter decouple the M1 thickness requirement from the cell area since M1 is used for contact metallization and localized areal power collection instead of global power collection. Thus, the stress reduction of a multi-level metal configuration (for example a two-level metal configuration with a thinner M1 layer on the cell—and the M1 metal thickness being essentially independent of the cell dimensions or area) may allow the silicon (or any crystalline semiconductor) substrate to be scaled to much larger cell areas (e.g., larger than 125 mm×125 mm, for instance, up to or larger than cell area of 1000 cm²) and much thinner in absorber thickness (e.g., thinner than 100 microns, and in the range of about 1 micron to about 100 microns). Multi-level metal configuration allows for a thinner M1 as the M1 layer serves as contact metallization for areal extraction of the solar cell electrical power and is not required to carry the cell current over a long distance over relatively low electrical conductivity lines. For example, the electrical current (or power) is locally pulled up vertically throughout the area of the solar cell from M1 through conductive plugs to the next upper metal level (which may be far less resistive by virtue of being much thicker and/or wider), and in one embodiment current or power is pulled from M1 to M2 through periodic via holes in a dielectric layer formed between M1 and M2 and filled (or partially filled) with conductive via plugs. Via plugs/holes along the M1 lines may be positioned with spacing such that the ohmic losses of the M1 line segments are negligible and do not have a significant detrimental impact on Fill Factor of the solar cell.
M1 be much narrower and finer. Often a large backside surface area of BC/BJ cells are covered with emitter regions with intertwined base diffusions. In one level metallization designs, to avoid cell shunting base M1 metal is usually nested inside the base diffusion to avoid cell shunting while minimum base metal resistance requirements require a wide metallization pattern. Thus, the base diffusion region is greater than the width of the base metal causing a reduction in the emitter fraction of the BC/BJ cell. A limitation in ability to increase emitter fraction results in a very high lifetime requirement to minimize electrical shading, which in turn results in higher cell manufacturing cost. Thus, the ability to utilize narrower M1 patterns, through multi-level metal design, allows significant cost saving and helps minimize electrical shading.
The multi-level metallization systems and methods disclosed herein do not require a fully connected Metal 1, thus increasing M1 design and patterning flexibility as (for example segmented/discrete M1 lines used as base and emitter lines/fingers). For example, it is possible to only connect defined small blocks of the total area on M1 to the photon absorber while providing the inter-block level connectivity on the upper M2 level. Additional advantages relating to design flexibility allow for a segmented M1 pattern and shorter length M1 line segments (as compared to known metallization patterns which span the entire area of the solar cell). These M1 designs may alleviate reliability problems arising from the temperature coefficient mismatch between metal 1 and the semiconductor and also make the solar cell structure more robust to cracks—thus providing higher yields in manufacturing and better reliability in the field. Additionally, block level isolated connectivity on M1 allows for the formation of a plurality of mini-cells within a single traditional size solar cell, each mini-cell having its own M1 pattern and connected to each through the M2 connections.
Multi-level metallization schemes (for example a two-level metal scheme with thin on-cell M1 metallization and thick M2 metallization comprising aluminum or copper) decouples the different attributes required of the metallization thus reducing the cost of Metal 2. Generally, in conventional BC/BJ cells, metallization should serve several functions including:
   i. Provide good contact resistance independently to both n and p-type diffusions (base and emitter contact regions).
   ii. Have effective infrared (IR) reflectivity to serve as a high quality back-mirror, particularly for infrared photons with wavelength at or above about 1 micron.
   iii. Have a low resistivity (for example achieved by pattern thickness or material selection) while being cost efficient for high volume manufacturing. This may lead to the selection of aluminum and/or copper while avoiding expensive high conductivity materials such as silver.
   iv. In designs that use metal types which dramatically reduce lifetime in silicon, such as Cu, the metal stack should be designed such that the silicon lifetime reducing metal is shielded by effective diffusion barrier materials such as Ti, TiW, TiN, Ta, or TaN, TiW, or Ni. Alternatively, a silicon-friendly high-conductivity, low cost metal, such as aluminum, may be used.
A multi-level metallization design, such as a two-level solar cell metallization scheme, allows M1 to be chosen specifically for attributes related to low contact resistance as well as rear mirror properties for efficient light trapping, while M2 attributes may be chosen for low cost and high electrical (and thermal) conductance.

In example embodiments of multi-level metallization for solar cells, the metallization layers on different levels may be oriented to run along the same direction or independently in different directions such as orthogonal or perpendicular to each other). For example, the thicker and higher conductivity M2 may run perpendicular to the thinner on-cell M1 or may run parallel to M1. An advantage of M2 running perpendicular to M1 (referred to as orthogonal transformation of M2 with respect to M1) is the width as well as pitch dimensions of M2 may be much coarser and larger than M1, resulting in a fewer number of M2 electrodes than the number of M1 electrodes (by a factor in the range of about 5 to 50 depending on the specific design requirements and specifications). This metallization architectural attribute, the combination of two-level cell metallization in conjunction with orthogonal interconnect transformation, may provide an advantage by decreasing the restraints of deposition and patterning of M2. The much coarser dimensions on thicker M2 opens the door to depositing M2 using relatively cheap/simple direct write techniques such as direct write thermal spray, screen and stencil printing metallic pastes such as Cu or aluminum paste, and inkjetting or depositing by aerosol printing metallic inks such as copper or nickel inks. Alternatively, M2 may be formed by a combination of formation of a seed layer by one of the above techniques (such as PVD) and electroplating of a high conductivity metal such as copper. Structural considerations for the pitch and width of the M2 may be dictated by the resistance of M1 which in-turn may dictate the spacing of vias to draw the current upward.

Cost and efficiency are important metrics when selecting a method for creating multi-level metallization in solar cell manufacturing. Several methods for forming multi-level metallization for high-efficiency, cost-effective solar cells are described below in relation to dual level metallization having a sandwiched electrically insulating or dielectric layer positioned between M1 and M2; however, these methods may also extended to multi-level metallization and are equally applicable to both conventionally thick solar cells as well as very thin silicon solar cells. The electrically insulating layer may also serve as part of the reinforcement and support structure of the solar cell. Very thin solar cells utilizing the methods and structures disclosed herein include ultrathin crystalline silicon solar cells with crystalline silicon layers in the thickness range of about one to 100 microns and which may formed by wire saw, epitaxial lift-off, proton implant and exfoliation, stress-induced peeling, laser wafering, or other thin silicon slicing techniques. And while the described metallization methods may be integrated, combined, or arranged in alternative orders, for descriptive purposes the methods for forming dual level metallization may be organized into the following four categories: (1) Methods for depositing and patterning M1; (2) Methods for forming an electrically insulating dielectric layer or sheet on top of M1 (for example by deposition, lamination, etc.); (3) Methods for forming via holes through the dielectric to connect M1 with M2 and subsequent cleaning; and (4) Methods for depositing and/or patterning M2.

For step 1 relating to methods for depositing and patterning M1, techniques such as plasma sputtering (or evaporation) followed by patterning using laser ablation or wet etching, or patterned screen printing (or stencil printing or inkjet printing or aerosol printing) may be used to deposit M1. For blanket deposition techniques such as PVD (plasma sputtering or evaporation), subsequent patterning may be performed using laser metal ablation or using standard lithography and etching techniques (such as with screen printing of a resist followed by wet or dry etching). Further, if using screen printing or inkjet printing (or stencil printing, aerosol jet printing), the M1 layer may be directly formed as a patterned metal layer using an appropriate metal paste or metal ink. It should be noted, the choice of M1 metal should be made to ensure mirror quality and low resistivity contacts to both n and p-type diffusions in silicon. For example, a metallic material for M1 comprises aluminum (or an alloy of aluminum and silicon) because of its high electrical conductivity, high IR reflectance, good ohmic contacts without shunts, and low cost. Alternatively, silver and thin nickel, followed by aluminum may be used as an M1 metal stack; however, silver is typically associated with a higher cost, for example as compared to aluminum thus aluminum may be used for fabrication lower costs and to provide good ohmic contacts to both base and emitter regions.

For step 2, related to forming an electrically insulating dielectric layer or sheet between M1 and M2, design considerations include the choice of material as well as the method of deposition or formation. Material choice considerations should include material cost as optimally the dielectric material will only be a fraction of the conventional metallization cost. For example, several plastics and polymeric materials meet these cost targets including but not limited to the prepreg materials which serve as adhesive and structural support layers in conventional printed circuit (PC) boards. Further dielectric material choice considerations and constraints may depend on which step during the process flow the dielectric material is inserted formed, and if it serves additional functions beyond serving as an electrical isolation interlayer between M1 and M2. For example, for thin silicon cells (such as crystalline silicon cells with thickness of less than 100 microns), this dielectric layer may also serve as a permanent reinforcement/support layer to handle and support thin silicon during processing of the cell as well as during the photovoltaic (PV) module lamination process and for the PV module lifespan in the field. In this example, the dielectric layer may be inserted midstream in the solar cell formation process by laminating a sheet of insulating material to the thin silicon solar cell absorber layer, which puts additional constraints on the choice of the material to ensure compatibility with downstream solace cell formation process steps as well as dexterity to support thin silicon. In another embodiment related to conventional thick silicon, constraints on the choice of dielectric material may be significantly relaxed as the dielectric layer may be formed at the end of the line after completion of the main solar cell fabrication process steps up to the metallization stage. Further, as an additional function of the dielectric material, active components and electrical components to build cell level intelligence may be positioned on the dielectric (for example a prepreg style dielectric material). In general, the electrically insulating layer may be pliable/flexible (such as prepreg or other polymeric materials) in order to produce flexible solar cells and flexible solar modules, or rigid for rigid solar cells and PV modules (such as glass or other ceramic materials).

Several methods for forming this electrically insulating layer are described herein. Formation methods include depositing the dielectric layer, for example using direct write techniques such as but not limited to thermal spray, dielectric spin-on, screen printing, or stencil printing. Alternatively, formation methods include laminating a cheap dielectric thin sheet such as a polymeric or plastic sheet (e.g., 25 microns to 200 microns thick) on the back surface of the solar cell comprising the M1 level (opposite the sunny side) for example by applying a combination of pressure and temperature whereby the electrically insulating dielectric film or laminant is reflowed to substantially conform to the M1 topography and completely encapsulate it. In a one embodiment, this laminate may be a prepreg material made of aramid fibers and resin commonly utilized as the building block layer for certain PC boards. Other prepreg materials may also be used.

For step 3, related to forming via holes connecting M2 with M1, techniques such as conventional masked and dry plasma etching may be used. Alternatively, via holes may be formed by mechanical formation such as by mechanically punching of dielectric; however, care must be taken to avoid damaging the underlying silicon, especially in the case for thin silicon cells but also for conventionally thick solar cells. In yet another embodiment, laser processing may be utilized to drill the via holes using a pulsed laser beam. For example, a cost effective and fast laser such as a CO2˜10 micron wavelength laser may drill holes through a prepreg laminant sheet at a very fast speed covering the entire cell substrate dielectric sheet in a few to tens of seconds or less. The choice of the laser and the underlying M1 metal may be made to have intrinsic compatibility, as the laser should stop at the underlying metal cleanly without punching through it. One solution uses a laser that is highly reflected by the M1 metal—thus the laser energy is not absorbed into the M1 metal—which serves as an end-point detection and self-limiting end to the drill process. In yet another embodiment, stop layer thick metal pads (for example made of aluminum and/or silver paste) may be printed before the dielectric is deposited/laminated only where the via holes are drilled. Care must be taken to ensure that the contact resistance of these metal pads to both M1 and the subsequently deposited M2 is low enough to contribute negligibly toward the total series resistance of the solar cell, for example conductive epoxy pads may be printed on top of M1 and served as the laser drill stop layer. Epoxy for the metal pads may be applied using known methods such as screen printing. In yet another embodiment, Al metal paste pads with a thickness in the range of about 10 microns to 40 microns may be used on top of Al paste metal lines (with thickness in the range of about 5 microns to 40 microns).

A fourth method for formation of the via holes utilizes direct printing of a suitable patterned electrically insulating dielectric layer by screen printing or stencil printing of a dielectric paste in which the patterned printing includes the via holes in the dielectric layer. Direct writing of the patterned dielectric layer including via holes eliminates the need for subsequent formation of holes using lithography and etch or laser drilling.

If the dielectric is polymeric or plastic based (for example formed from a range of low cost materials comprising polymers, plastics, prepreg materials, etc.), the via holes may be cleaned after drilling to ensure a clean contact with low contact resistance between M2 and M1. Various cleaning methods include but are not limited to: 1) wet organic clean; 2) dry etch clean with highly oxidizing plasma such as that produced using an oxidizing gas ambient (for example oxygen or nitrous oxide); 3) plasma sputter etch; 4) ozonated treatment; 5) a subsequent laser step to burn off the carbon; or 6) hot metal deposition to burn through the residual contaminant layer.

For step 4, relating to M2 deposition and patterning (or alternatively direct write deposition of a patterned M2 layer), conventional methods may be used such as plating on top of a seed layer formed for example by plating, inkjet printing, screen printing, or patterned PVD layer, or alternatively direct writing techniques may be used such as, but not limited to, screen printing, stencil printing, thermal (or arc or plasma) metal spray, inkjet or aerosol printing. Direct patterned metal foil attachment, or foil attachment and subsequent patterning by cut design, may also be used and particularly for an orthogonal structure, foil attachment may be preceded by depositing a conductive layer in the via holes separating M1 and M2. A metal foil M2 in an orthogonal bi-layer metallization structure provides a planar and mechanically reproducible structure due to large in-plane M2 pattern dimensions. For example, the M2 metal foil finger width may be much larger than the metal foil layer thickness (for example greater by a factor of 10).

A specific process flow embodiment is detailed below for forming dual level metallization, and although described in the context of back-contact/back-junction thin monocrystalline silicon solar cells using epitaxial silicon lift-off methods, the metallization methods and structures described herein may be applicable to solar cells of any thickness including standard crystalline silicon wafer-based cells (for example in the thickness range of 100 microns to 200 microns using CZ or FZ wafers).

A thin M1 of, for example, aluminum or an alloy comprising aluminum and silicon, is deposited on the backside solar cell substrate surface. Patterned deposition may use screen or stencil printing of Al paste, and/or a myriad other direct pattern writing techniques for metal deposition such as inkjet and aerosol printing or PVD followed by laser ablation. The thickness of the screen printed Al/Al—Si metal may range from about 5 microns to about 40 microns depending on the conductivity requirements of the solar cell design. Alternatively, Aluminum/Aluminum Silicon may be deposited as M1 using physical vapor deposition techniques such as sputtering. In the case of PVD Al or AlSi deposition for M1, post deposition the blanket metal layer may be subsequently patterned using a pulsed picosecond laser (for example with a wavelength in the near infrared range of about 1 micron wavelength) which ablates metal lines to pattern and electrically isolate the emitter and the base polarity. In one embodiment, the M1 pattern for the back-junction/back-contact monocrystalline silicon cell may be an array of straight-line (rectangular, triangular or trapezoidal) interdigitated base and emitter fingers separated by isolation regions with a relatively large metal coverage area ratio, at least 70% and up to over 90% for enhanced rear mirror IR reflectivity in conjunction with the rear dielectric layer. Importantly, there are no busbars on M1 in order to eliminate busbar induced electrical shading effects and to maximize the solar cell efficiency. In the case of patterned Al screen print to form M1, a follow up Al paste may be optional. The Al paste may be printed as a periodic pattern of pads along M1 to serve as a laser stop layer as described above. Alternatively, where the first Al paste line conductivity is not sufficient, the second print when used in the same pattern as the first print (in contrast to a second print of pads) may also serve to reduce M1 resistance and serve as a laser stop layer.

In the case PVD such as plasma sputtering is used to deposit M1, the laser ablation metal patterning may be optionally followed by optional screen printing of reflective conductive epoxy pads (for example using an aluminum and/or silver paste) where via hole drills would be positioned/land on M1. This may be required due to the lack of laser stopping ability if a small thickness of sputtered M1 is applied. Sputter deposited M1 thickness may be kept thin for lower costs and to increase ease of patterning, for example using a pico second IR laser. The Ag and/or Al based conductive epoxy provides better reflective-pad stopping power to the CO2 laser than the thin M1 layer by itself.

Subsequently, a thin polymeric (e.g., a suitable prepreg) sheet, for example having a thickness in the range of about 50 up to 500 microns (in some cases 50 microns to 200 microns) is laminated, for example using a pressure-thermal lamination process, on top of M1 and cell substrate backside (in other words the side opposite the cell sunnyside). Because the electrically insulating dielectric sheet is attached to thin silicon and is inserted midstream during cell processing (for instance, just prior to the lift-off process for epitaxial silicon cells) to also serve as a permanent reinforcement layer and carrier for thin silicon cell in this embodiment, dielectric choice may be dictated by the following additional attributes in addition to cost considerations. First, the dielectric should be a material conducive to being drilled using laser drilling such that M1 connections may be accessed and M2 may be deposited on top of the dielectric (for example prepreg). Second, it should support effective adhesion of both M1 and M2 as well as the cell isolation regions (typically covered by silicon oxide or silicon nitride and/or aluminum oxide) on the cell backside. Third, it should have a relatively well-matched Coefficient of Thermal Expansion (CTE) compared to silicon (for example a low CTE of well below 10 ppm/degree C. such as a CTE in the range of about 0 to 5 ppm/degree C.) to ensure that at lamination and subsequent solar cell processing temperatures, as well as during the long-term field operation, there is no silicon cracking due to CTE mismatch between silicon and the laminant. Fourth, in a BC/BJ architecture such as that described, the solar cell sunnyside processing steps such as texturing and front passivation may follow after the dielectric layer is formed (in one embodiment the step after laminating the dielectric layer is the lift off and release of the thin silicon/dielectric sheet laminate from the reusable template which exposes the sunnyside of the cell for completion of the cell sunnyside processing), thus the backside passivation layer may be exposed to wet chemicals used for texturing and cleaning of the front surface or cell sunnyside. In this case, the dielectric layer should serve as an effective sealant to protect the cell backside, including the M1 layer, during texturing and post-texture cleaning of the cell. Fifth, the dielectric layer must not substantially bow the solar cell due to stresses (for example the overall bowing of the cells should be limited to less than about 2 or 3 mm for a 156 mm×156 mm solar cell). Sixth, the lamination process should meet the throughput speed required for high productivity solar cell manufacturing. And finally, the dielectric material should have high thermal stability (for example up to at least 200 degrees C. and in some cases up to at least 300 degrees C.) to be able to sustain high process temperatures to ensure excellent front side passivation using PECVD passivation processes which normally utilize substrate heating in the range of 150 degrees C. up to 400 degrees C., depending on the passivation process used—a pivotal process/structure for some BC/BJ solar cell embodiments.

Subsequent to dielectric layer lamination, the solar cell may go through a number of process steps unique to this thin silicon process flow embodiment. These steps, as outlined above, may include mechanical release of a thin silicon substrate from a template along a porous sacrificial layer, frontside texture and post texture clean, frontside silicon nitride passivation, and the formation of the M2 layer. Following completion of the frontside texture and passivation process steps, via holes are drilled in the laminated dielectric sheet to connect M2 and M1 through M1-M2 conductive via plugs using laser drilling, for example using a CO2˜10 micron wavelength laser, to drill holes stopping on M1 (or alternatively, on conductive epoxy pads printed on M1). Pre-established fiducials may be used to align the via holes to the pads. Further, laser drilling holes through a dielectric laminate may create carbon residue inside the holes which may be subsequently cleaned using, for example, plasma sputter etch or directly with hot metal during the hot M2 deposition.

In a variation of this process flow for thin crystalline semiconductor (e.g., thin crystalline silicon) solar cells, the M1 layer may be screen printed (or formed by inkjet printing, aerosol printing, stencil printing) using a suitable paste, for example a paste comprising mostly aluminum and some silicon to prevent junction spiking, and fired instead of PVD deposited and laser patterned. This direct write method may provide further manufacturing cost reduction compared to PVD and patterning methods. Dual level metallization, M1 directly on the cell and M2 separated from the cell by the dielectric sheet, may also be formed as is on thicker conventional silicon solar cells. This means that the multi level metallization embodiments in accordance with the disclosed subject matter may be used with thin semiconductor absorber solar cells using thin substrates not formed by conventional wire sawing from ingots or cast bricks of silicon and also with solar cells made on standard thickness wafers formed from ingots using the wire saw process. Because BC/BJ solar cells require high electrical conductivity to reduce line resistance, and as cell area becomes larger, metallization designs have to use thicker metal layers to provide lower sheet resistance and enable higher current carrying capability. The multi-level metallization structures and methods provided are an enabling technology for scaling up the area of BC/BJ cells to 156 mm×156 mm and well beyond (for instance to cell areas up to and larger than 1000 cm²) while allowing the use of cell absorbers over a wide range of thicknesses, from about one micron up to hundreds of microns depending on the cell design and manufacturing process.

Importantly, while structures and formation methods for multi-level metallization are detailed in this disclosure, various aspects of each structure and process flow may be combined and/or altered in accordance with the disclosed subject matter.

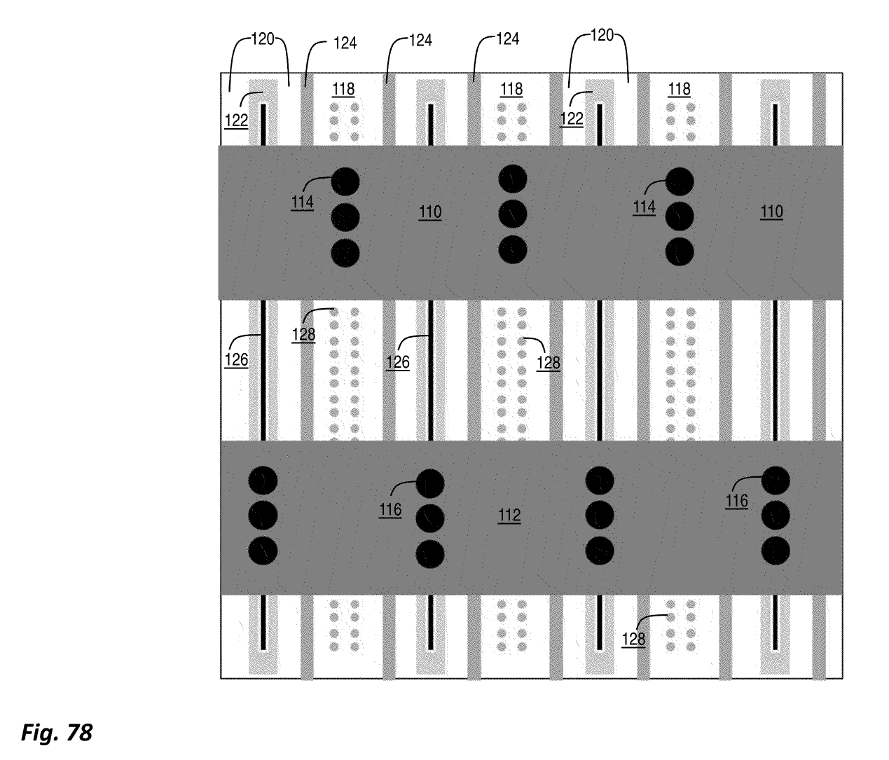

FIGS. 78 through 80 are diagrams illustrating example multi-level metallization embodiments for interdigitated back contact (IBC) solar cells. The metallization patterns of FIGS. 78 through 80 use metals or metal alloys for the first layer metal 1 (M1) as well as for the second layer metal 2 (M2) for which the design rules and feature sizes may be much more relaxed and coarser (in other words wider metallization lines and spaces). Among other formation processes, M2 or both M1 and M2 may be spray deposited (thermal or ARC spray).

FIG. 78 is a diagram showing a top view of a portion of back contact solar cell illustrating an orthogonal pattern transfer using high conductivity metal fingers spray deposited (for example in a direct write pattern to reduce mask associated costs) or plated on top of a backplane dielectric layer (backplane layer not shown to detail underlying metal 1 pattern). Metal 1 pattern comprises first level metal emitter fingers 118 (for example thermally sprayed, screen printed metal paste, or PVD deposited/laser ablated metal base fingers) and first level metal base fingers 120 (for example thermally sprayed, screen printed metal paste, or PVD deposited/laser ablated metal emitter fingers). First level metal emitter fingers 118 contact underlying solar cell emitter regions through multi-level contact openings trenches 122 and trenches 126, and first level metal base fingers 120 contact underlying solar cell base regions through holes 128. Second level metal emitter contact fingers 110 (for example plated Cu or thermally sprayed metal) contacts first level metal emitter fingers 118 through emitter holes 114 (for example drilled via holes) in the backplane positioned between the first and second metallization layers. Second level metal base contact fingers 112 (for example plated Cu or thermally sprayed metal) contacts first level metal base fingers 120 through base holes 116 (for example drilled via holes) in the backplane positioned between the first and second metallization layers.

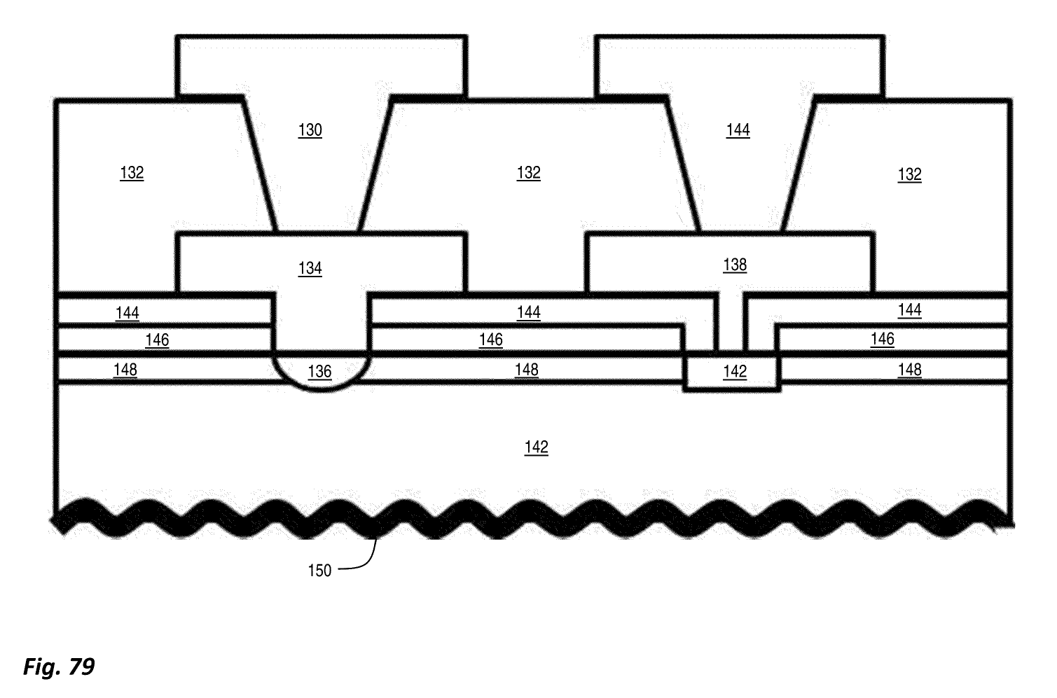

FIG. 79 is a diagram showing a cross sectional view of a back contact solar cell supported by a backplane and having parallel metallization layers. Note that this structure shows parallel metal 1 and metal 2 as opposed to the orthogonal structure shown in FIG. 78. The back contact cell of FIG. 79 comprises silicon substrate 142 (for example an epitaxial silicon substrate or a wafer formed silicon substrate), shown as an n-type base, with front surface texture passivation layer 150. Front surface texture passivation may comprise textured structures, such as randomly textured pyramids, optionally with a front surface field surface covered with a passivation layer (for example thermal oxide plus silicon nitride, or amorphous silicon (a-Si)/SiN, or amorphous silicon oxide (a-Si—O)/SiN, or intrinsic amorphous silicon (i-a-Si), or intrinsic amorphous silicon oxide (i-a-Si—O)/n-type amorphous silicon (n-a-Si)/SiN. First level metal emitter contact 134 contacts p+ emitter layer 148 at p++ emitter contact 136 and first level metal base contact 138 contacts n-type silicon substrate 142 at n+ base contact 140. Boron silicate glass layer 148 and phosphorous silicate glass layer 146 are used cell doping processing during back contact cell fabrication. Backplane 132 is formed as an electrically insulating layer between the first level metallization pattern comprising first level emitter contacts 134 and first level base contacts 138 (for example Al, AlSi, or thermally sprayed Al, AlSi, Al+Zn) and second level metallization pattern comprising second level emitter contacts 130 and second level base contacts 144 (for example thermally sprayed Al with Al/Zn). The first level metallization pattern and second level metallization pattern contacted through vias/holes formed in the backplane (for example by a laser drilling process).

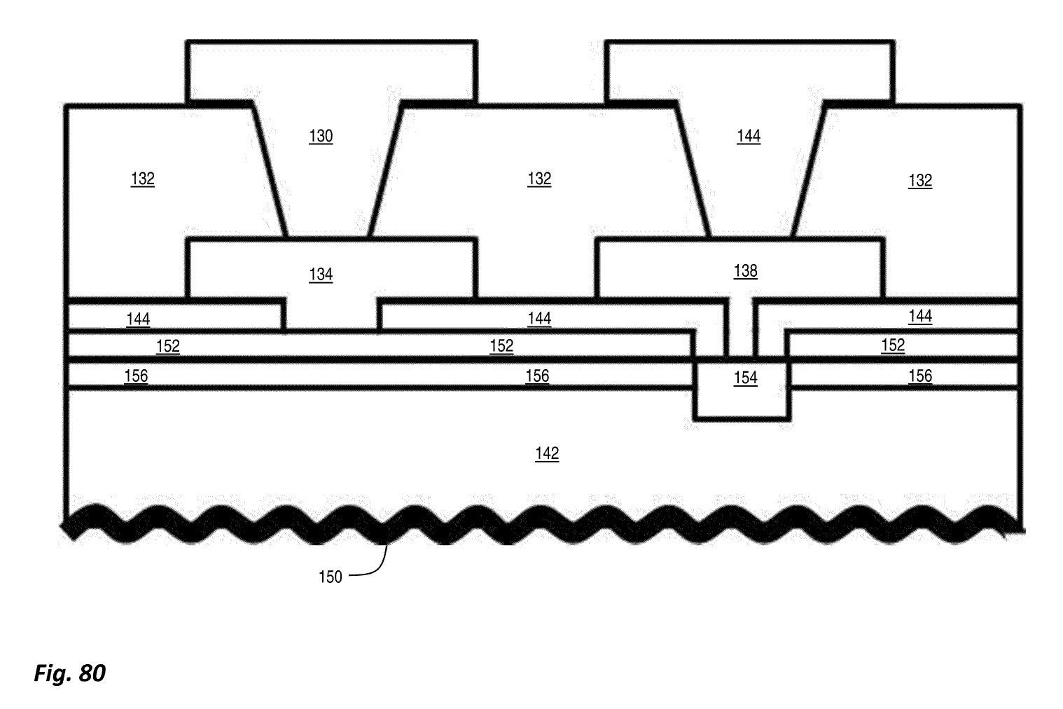

FIG. 80 is a diagram showing a cross sectional view of a back contact solar cell supported by a backplane and having parallel metallization layers similar to the homojunction cell shown in FIG. 79 except that first level metal emitter contact 134 contacts p++ emitter layer 152 (for example a poly-SiGe emitter layer) positioned on dielectric layer 156 (for example an a-Si on tunnel dielectric layer) and first level metal base contact 138 contacts n+ base contact 154 (for example laser doped).

The metallization contacts shown in FIGS. 79 and 80 may be formed in line patterns as shown in FIG. 78. The metal lines, particularly for the first level metal, may contain the same metal, alloy, or metal stack, or alloy stack for both the emitter and the base contact. However, same level emitter contact metal and base contact metal may be different. Final thermal processing after metallization as well as thermal treatment during a spray application may be used to reduce built-in stress in the resulting sprayed workpiece and thus improve metal layer adhesion and further reduce substrate bow. It may also be possible to directly write the metal lines or patterns on the substrate by writing multilayer structures (for example, a first layer of metal comprising aluminum contacting the solar cell base and emitter regions followed by top layer made of aluminum-zinc alloy for lower contact resistance with the second level metal, metal 2, through the vias).

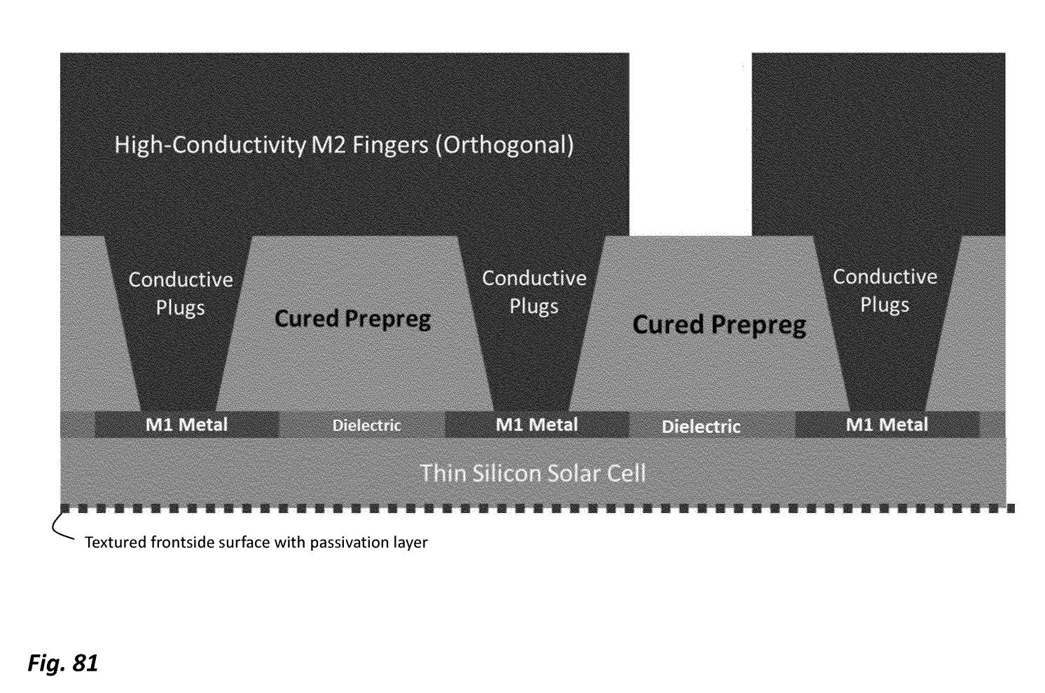

FIG. 81 is a cross sectional diagram of a back contact solar cell with a backside multi-level metallization design. M1 metal (for example aluminum) is patterned on base and emitter regions on the backside of a thin silicon solar cell. Dielectric material fills gaps and voids in the M1 metal pattern and dielectric cured prepreg provides electrical isolation between the M1 and M2 layers. Conductive plugs (for example made of the same material as M2 and formed in the same M2 formation process) provide contact from M1 to M2 orthogonal fingers pattern (for example made of aluminum or copper).

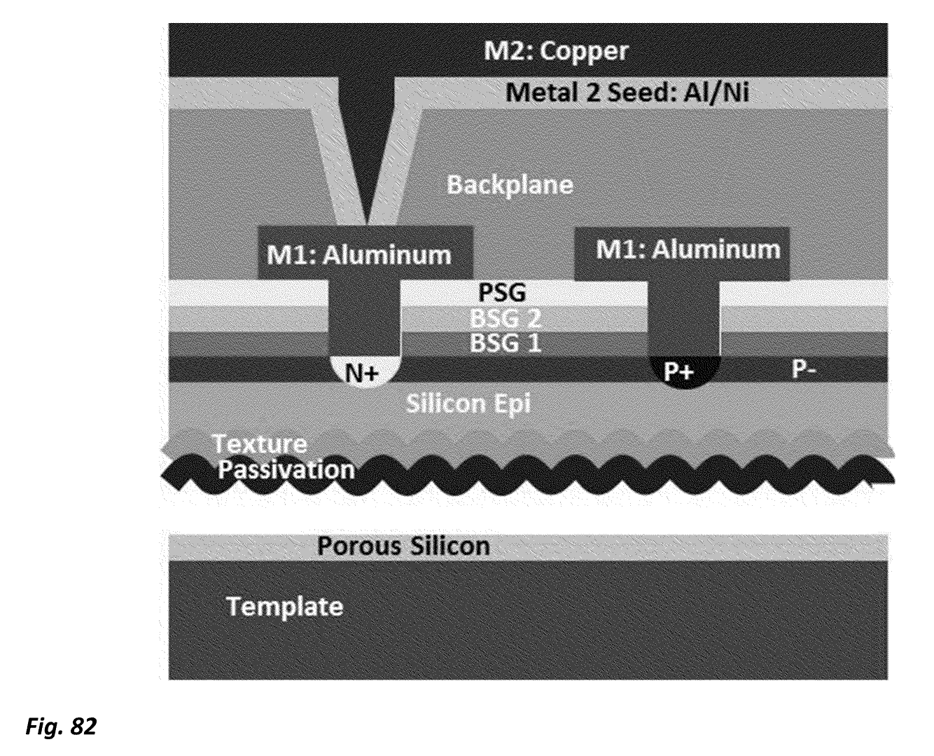

FIG. 82 is a cross sectional diagram of yet another back contact solar cell with a backside multi-level (dual level) metallization design. As shown, the back contact solar cell of FIG. 82 may be formed using an epitaxial deposition process on a reusable template. The solar cell fabrication process starts with a reusable crystalline silicon template, typically made of a p-type monocrystalline silicon wafer, into which a thin sacrificial layer of porous silicon is formed (for example a porous silicon bilayer formed by an electrochemical etch process, anodic etch, through a surface modification process in an HF/IPA wet chemistry in the presence of an electrical current). Upon formation of the sacrificial porous silicon layer, which serves both as a high-quality epitaxial seed layer as well as a subsequent separation/lift-off layer, a thin layer (for example a layer thickness in the range of a few microns up to about 100 microns, or a few microns up to about 60 microns) of in-situ-doped monocrystalline silicon is formed, also called epitaxial growth. The in-situ-doped monocrystalline silicon layer may be formed, for example, by high-productivity atmospheric-pressure epitaxy using a chemical-vapor deposition or CVD process in ambient comprising a silicon gas such as trichlorosilane or TCS and hydrogen At least one layer of borosilicate glass, or alternatively two layers of borosilicate glass (BSG 1 and BSG2 2) may then be deposited each in separate atmospheric pressure chemical vapor deposition (APCVD) processes and each APCVD process followed by a pico second laser ablation process to form openings for emitter (p+) and base contact diffusion (n+) regions in the BSG layers. A phosphosilicate glass layer (PSG) is then formed using an APCVD process followed by a thermal anneal (to form the emitter junction, base and emitter contact diffusion, and improved backside passivation) followed by a pico second laser ablation process to form contact hole openings to emitter (p+) and base (p+) regions in the dielectric stack layer. Patterned M1 is then formed on emitter (p+) and base (n+) regions for example in a screen print process (e.g., screen printing of aluminum or aluminum-silicon paste). After M1 anneal, the backplane is laminated on the backside of the solar cell for permanent cell support and reinforcement as well as to support the high-conductivity cell metallization of the solar cell.

The mostly-processed back-contact, back-junction backplane-reinforced large-area (for instance, a solar cell area of at least 125 mm×125 mm or larger up to or larger than 1000 cm²) solar cell is then separated and lifted off from the template along the mechanically-weakened sacrificial porous silicon layer (for example through a mechanical release or MR process) while the template may be re-used many times to further minimize solar cell manufacturing cost. Final cell processing may then be performed on the solar cell sunny-side which is exposed after being released from the template. Sunny-side processing may include, for instance, completing frontside texturization (for example by wet etch or laser texturing processing), passivation (for example using a PECVD process), and anti-reflection coating deposition process.

Backplane vias may then be formed in the backplane, for example using a CO2 laser, and Metal 2 seed is deposited on the backplane, for example using PVD of aluminum and nickel. Metal 2, for example tin and/or copper plating, is then formed on the backside of the solar cell.

The backplane material may be made of a thin (for instance, about 50 to 250 microns), flexible, and electrically insulating polymeric material sheet such as an inexpensive prepreg material commonly used in printed circuit boards (PCB) which meets the process integration and reliability requirements. Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temp. prepregs may be fully cured by using vacuum bag pressure alone at much lower temperatures.

The viscosity of a prepreg resin affects its properties, and it is affected by temperature: At 20° C. a prepreg resin feels like a ‘dry’ but tacky solid. Upon heating, the resin viscosity drops dramatically, allowing it to flow around fibers, giving the prepreg the necessary flexibility to conform to mold shapes. As the prepreg is heated beyond the activation temperature, its catalysts react and the cross-linking reaction of the resin molecules accelerates. The progressive polymerization increases the viscosity of the resin until it has passed a point where it will not flow. The reaction then proceeds to full cure. Thus prepreg material may be used to “flow” around and in gaps/voids in the M1 metallization pattern.

Further, PCBs are alternating layers of core and prepreg where core is a thin piece of dielectric with copper foil bonded to both sides (core dielectric is cured fiberglass-epoxy resin) and prepreg is uncured fiberglass-epoxy resin. Prepreg will cure and harden when heated and pressed. In other words, prepregs are rolls of uncured composite materials in which the fibers have been pre-impregnated (combined) with the resin. During production, the prepreg sandwich is heated to a precise temperature and time to slightly cure the resin and, therefore, slightly solidify through crosslinking. This is called B-Staging. Care must be taken to insure that the sandwich is not heated too much, as this will cause the prepreg to be too stiff and seem “boardy.” The solvent is removed during B-Staging so that resin is relatively dry of solvent. Typical thermoset resins and some thermoplastic resins are commonly used in prepregs. The most common resin is epoxy as the major markets for prepregs are in aerospace, sporting goods, and electrical circuit boards where excellent mechanical, chemical, and physical properties of epoxies are needed. Typically, prepregs have a thickness in the range of as little as about 1 mil (˜25 μm) up to a multiple of this amount.

Further, prepregs may be made of thermoplastics (not as common as thermosets). Thermoplastic prepregs are often used for their toughness, solvent resistance, or some other specialized purpose. Most of the thermoplastics used are very high performance resins, such as PEEK, PEI, and PPS which would compete with 350° F. cure epoxies in aerospace applications. Some new applications such as automotive body panels which depend up special properties, such as toughness, are using thermoplastics either alone or mixed with thermosets.

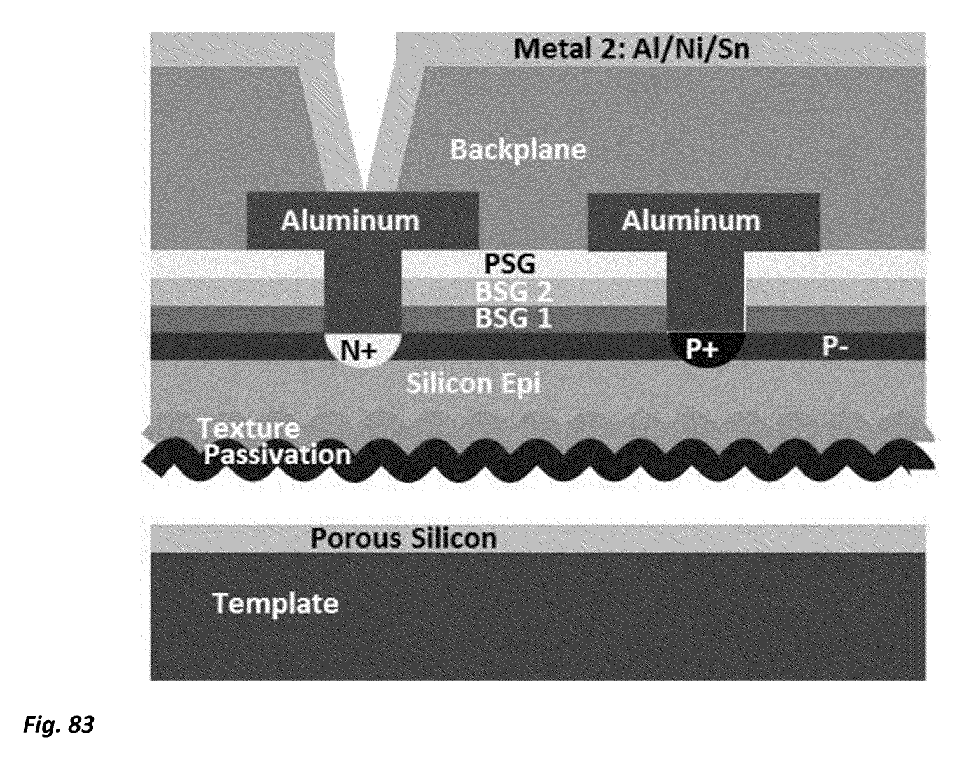

FIG. 83 is a cross sectional diagram of yet another back contact solar cell with a backside multi-level (dual level) metallization design mini-cell example. As described with reference to formation the back contact solar cell of FIG. 82, the back contact solar cell of FIG. 83 may be formed using an epitaxial deposition process on a reusable template along with similar backside and frontside processing steps except Metal 2 may be deposited using a PVD process followed by a laser patterning process (for example using a pulsed nano second laser metal ablation) to pattern and form isolated metallization regions on M2.

For example, interdigitated back contact IBC M2 metallization (metal layer 2) conductivity requirements for a dual busbar M2 metallization pattern (in other words no on-cell distributed busbars or no mini cells), for a cell such as that shown in FIG. 82 may be factored as follows: Assume 2N on-cell metal fingers and Iₘₚ=8 A for η=20% and IBC Metallization Pitch=[156/(2N)] mm. Then Ohmic Power Loss per Finger=P_{f}=(ρ/t)[(Iₘₚ²·L)/(3·W·N²)], where ρ/t is the sheet resistance of Al metal foil, Iₘₚ is the cell current at max power, L is the cell side dimension, W is the metal foil finger width (for parallel fingers), and N is the number of emitter-base finger pairs on the cell. Thus, Total Ohmic Power Loss Pₜ=2N·P_{f}=2·(ρ/t)[(Iₘₚ²·L)/(3·W·N)]. Now assume the total backplane interconnect power loss must be limited to equivalent of 0.2% in absolute efficiency loss or 1% in relative efficiency loss (this corresponds to Pₜ≦50 mW). And assume a finger width of W=0.4 mm, N=125, ρ=3 μΩ·cm, Iₘₚ=8 A, L=156 mm. To calculate the required thickness t of Al: (50×10⁻³=2·(3×10⁻⁸/t)[(8²×0.156)/(3×0.4×10⁻³×125)]. Thus, with a bulk Al resistivity of 3 μΩ·cm minimum backplane aluminum thickness t=80 μm.

In another example, interdigitated back contact IBC M2 metallization (metal layer 2) conductivity requirements for an on-cell distributed busbar M2 metallization pattern (in other words mini-cells), for a cell such as that shown in FIG. 83 may be factored as follows: Assume 2N on-cell metal finger rows and Iₘₚ=8 A for η=20%; Assume there are M columns of IBC mini-cells (M pairs of busbars); the distributed on-cell busbars create electrical-shading (higher electrical-shading for larger M); Assuming a busbar width of 0.75 mm and constraining e-shading losses to ≦0.3% absolute efficiency, the maximum allowable M is 3, M=3; Mini-cell column width=L′=L/M=156/3=52 mm, and I′ₘₚ=Iₘₚ/M; and IBC Metallization Pitch=[156/(2N)] mm. Then Ohmic Power Loss per Mini-Cell Finger=P_{f}=(ρ/t)[(I′ₘₚ²·L′)/(3·W·N²)], where ρ/t is the sheet resistance of Al metal foil, I′ₘₚ is the mini-cell current at max power, L′ is the mini-cell column width, W is the metal foil finger width (for parallel fingers), and N is the # of emitter-base columnar finger pairs on each mini-cell. Thus, total Ohmic Power Loss Pₜ=M·2N·P_{f}=2M·(ρ/t)[(I′ₘₚ²·L′)/(3·W·N)]. Now, assume the total backplane interconnect power loss must be limited to equivalent of 0.2% in absolute efficiency loss or 1% in relative efficiency loss (this corresponds to Pₜ≦50 mW). And assume a finger width of W=0.4 mm, N=125, ρ=3 μΩ·cm, I′ₘ=2.67 A, L′=52 mm. To calculate the required thickness t of Al: 50×10⁻³=2×3×(3×10⁻⁸/t)[(2.67²×0.052)/(3×0.4×10⁻³×125)]. Thus, with a bulk Al resistivity of 3 μΩ·cm minimum backplane aluminum thickness t=9 μm.

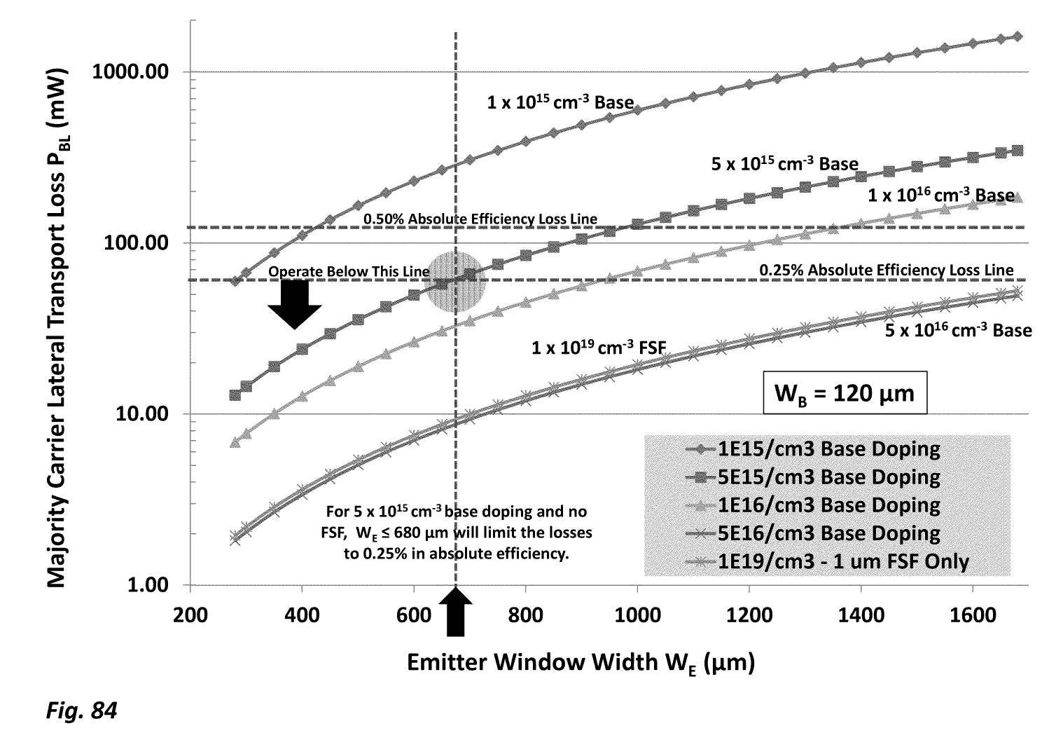

FIG. 84 is a graph showing design related calculation results for power loss as a function of metal 1 design, specifically lateral majority carrier transport ohmic losses in emitter regions for a 25 micron thick epitaxial silicon back contact solar cell.

Designing dual metallization structures using an orthogonal interconnect pattern (in other words an orthogonal transformation of M2 emitter/base fingers as compared to M1 emitter/base fingers) such as that shown in FIG. 78 may utilize analytical models to determine the minimal number of M2 orthogonal fingers required. Among other factors, minimizing M2 metallization reduces costs associated with M2 metal as well as reduces stresses induced on a semiconductor substrate by a the metallization pattern. For example, the minimum number of M2 backplane orthogonal fingers may be calculated as follows, assuming ohmic losses dominated by on-cell metallization and not the backplane Al metal foil, as is the case when on-cell backplane M1 Al metal foil thickness less than 80 μm or M2 Al metal foil thickness is greater than 200 μm. Further assumptions for building and solving an analytical model: ρ and t are the on-cell Al metal (PVD or cured ink) resistivity and thickness (ρ/t is the on-cell Al metal sheet resistance for base and emitter metallization); F is the number of orthogonal Al metal foil finger pairs in the backplane; Iₘₚ is the maximum-power current for Gen-1 cell (9.3 A); W_{BM} is the on-cell M1 base Al metal width; W_{EM} is the on-cell M1 emitter Al metal width; on-cell gap between base and emitter metal fingers is no more than ˜5% of W_{BM}+W_{EM} (or ≦40 μm for 800 μm base+emitter pitch); Cell efficiency=21% (Cell Peak Power=5.11 Wₚ), thus 0.25% absolute efficiency loss˜60 mW and 0.50% absolute efficiency loss˜120 mW; and Pₜₒₜ is the grand total ohmic losses of base and emitter.

Two sets of integral equations will be used solve the total base and emitter ohmic losses due to on-cell metal: One integral equation set for the edge base and emitter fingers and another integral equation set for the rest of the base and emitter backplane fingers (all fingers excluding the edge fingers). Total loss (Pₜₒₜ) is the sum of the above for all the base and emitter fingers, and the solution may be simplified into an analytical solution Pₜₒₜ=(ρ/t)·[(F+3)/96]·(Iₘₚ²/F³)·[(W_{BM}+W_{EM})²/(W_{BM}·W_{EM})].

Assuming an emitter/base pitch of 800 μm and a large (≧95%) M1 on-cell Al metallization area coverage (i.e., base-emitter metal gap≦40 μm), the following may be calculated:

TABLE 1

| | W_{EM} | W_{BM} + W_{EM} | | [(W_{BM} + W_{EM})²/ |
|---|---|---|---|---|
| W_{BM} (μm) | (μm) | (μm) | W_{BM}/(W_{BM} + W_{EM}) | (W_{BM}.W_{EM})] |
| 280 | 520 | 800 | 35.00% | 4.40 |
| 330 | 470 | 800 | 41.25% | 4.13 |
| 380 | 420 | 800 | 47.50% | 4.01 |
| 455 | 845 | 1,300 | 35.00% | 4.40 |
| 536 | 764 | 1,300 | 41.23% | 4.13 |
| 618 | 682 | 1,300 | 47.54% | 4.01 |

As can be seen in Table 1, for a given on-cell base metal ratio W_{BM}/(W_{BM}+W_{EM}) and metal gap ≦5% of base+emitter pitch, the loss factor [(W_{BM}+W_{EM})²/(W_{BM}·W_{EM})] is independent of pitch (e.g., same for 800 μm and 1,300 μm pitch). Further, for an on-cell base metal ratio in the range of 35.0% to 47.5%, the factor [(W_{BM}+W_{EM})²/(W_{BM}·W_{EM})] in the Pₜₒₜ solution is on the order of ˜4.0 to 4.4. The smallest factor (4.0) is obtained for on-cell base metal ratio of 50%. And a base metal ratio as small as 35% results in an acceptable small increase to 4.40. As a design rule, a base metal ratio on the order of 35% (for example W_{BM}=280 μm for 800 μm pitch) may be used.

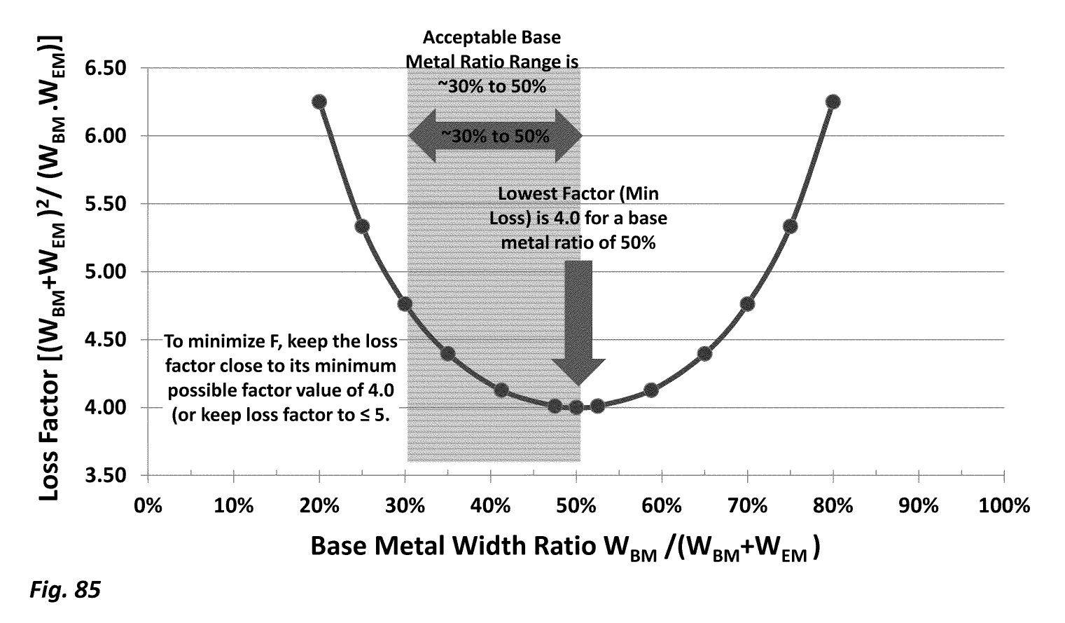

FIG. 85 is a graph based on the results calculated in Table 1 highlighting the relative sensitivity of the number of M2 backplane orthogonal fingers to metallization pitch and M1 base-to-emitter metal width ratio.

Table 2 below compares the number of backplane orthogonal Al-foil finger pairs (M2) to on-cell Al (M1) sheet resistance and thickness.

TABLE 2

| | | | | No. of Backplane | No. of Backplane |
|---|---|---|---|---|---|
| On-Cell | Thickness of | Thickness of | Thickness of | Orthogonal Aluminum | Orthogonal Aluminum |
| Aluminum | On-Cell Al for | On-Cell Al for | On-Cell Al for | Foil Fingers Pairs (F) for | Foil Fingers Pairs (F) for |
| Metal Sheet | PVD-Al | Direct-Write Al | Direct-Write Al | Cell Absolute Efficiency | Cell Absolute Efficiency |
| Resistance | Process: | Ink Process: | Ink Process: | Loss Limited to 0.25% | Loss Limited to 0.50% |
| (Ω/□) | ρ = 3 μΩ.cm | ρ = 45 μΩ.cm | ρ = 30 μΩ.cm | Tighter Loss Spec | More Relaxed Loss Spec |
| 0.30 | 0.1 μm | 1.5 μm | 1.0 μm | 5 | 4 |
| 0.15 | 0.2 μm | 3.0 μm | 2.0 μm | 4 | 3 |
| 0.06 | 0.5 μm | 7.5 μm | 5.0 μm | 3 | 2 |

The above calculations may lead to the following orthogonal backplane design conclusions:
For a specified maximum allowed cell efficiency loss (0.25% or 0.50% absolute), there is a strong correlation between the sheet resistance of on-cell Al metal and the required number of backplane Al-Foil finger pairs;
For a practical on-cell Al thickness range of either 0.20 to 0.50 μm for PVD-Al with ρ=3 μΩ·cm, or alternatively 2 to 5 μm direct-write Al ink with ρ=3 μΩ·cm, the required number of backplane Al-Metal-Foil finger pairs (F) is 3 to 4 for an absolute efficiency loss limited to 0.25%;
For the thinner range of on-cell Al thickness (e.g., 0.20 μm for PVD-Al or 2 to 3 μm for direct-write Al ink with larger cured ink resistivity of ρ=45 μΩ·cm, even F=3 pairs of backplane Al-Metal-Foil fingers will limit the absolute cell efficiency loss to 0.50%.

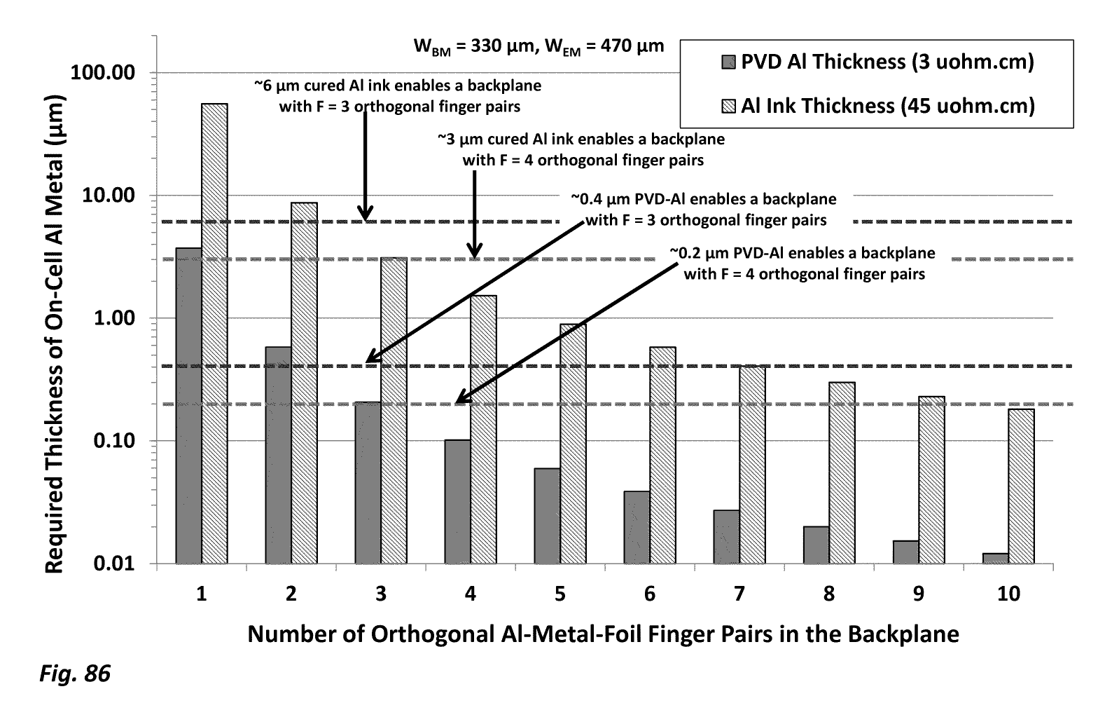

FIG. 86 is a graph showing the thickness of on-cell aluminum metal (M1) vs. the number of backplane orthogonal aluminum-metal-foil fingers pairs (M2) at absolute cell efficiency loss=0.25% (60 mW). As can be seen in the graph shown in FIG. 86, for on-cell PVD-Al with bulk Al resistivity of 3 μΩ·cm: On-cell PVD Al thickness of 0.20 μm may be used in conjunction with F=4 pairs of orthogonal Al fingers in the backplane; and on-cell PVD Al thickness of 0.40 μm may be used in conjunction with F=3 pairs of orthogonal Al fingers in the backplane. For on-cell cured Al ink with bulk Al resistivity of 45 μΩ·cm: On-cell cured Al ink thickness of 3 μm may be used in conjunction with F=4 pairs of orthogonal Al fingers in the backplane; and on-cell cured Al ink thickness of 6 μm can be used in conjunction with F=3 pairs of orthogonal Al fingers in the backplane.

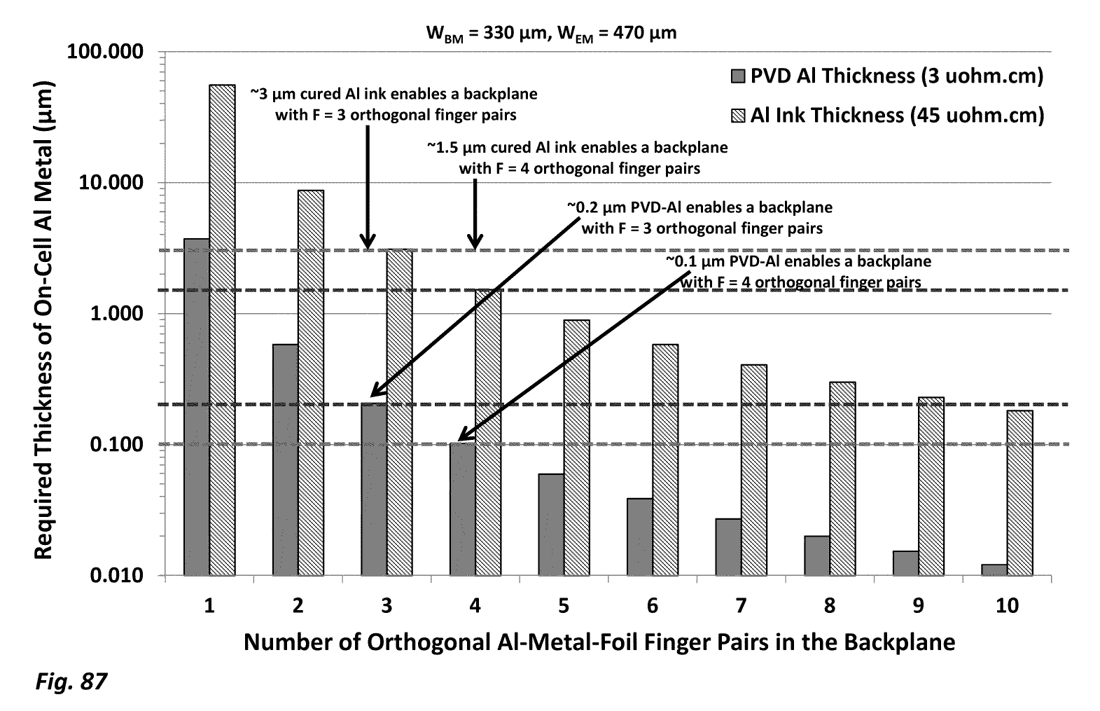

FIG. 87 is a graph showing the thickness of on-cell aluminum metal (M1) vs. the number of backplane orthogonal aluminum-metal-foil fingers pairs (M2) at absolute cell efficiency loss=0.50% (120 mW). As can be seen in the graph shown in FIG. 87, for on-cell PVD-Al with bulk Al resistivity of 3 μΩ·cm: On-cell PVD Al thickness of 0.10 μm may be used in conjunction with F=4 pairs of orthogonal Al fingers in the backplane; and on-cell PVD Al thickness of 0.20 μm may be used in conjunction with F=3 pairs of orthogonal Al fingers in the backplane. For on-cell cured Al ink with bulk Al resistivity of 45 μΩ·cm: On-cell cured Al ink thickness of 1.5 μm may be used in conjunction with F=4 pairs of orthogonal Al fingers in the backplane; and on-cell cured Al ink thickness of 3 μm can be used in conjunction with F=3 pairs of orthogonal Al fingers in the backplane.

Table 3 below summarizes results for the number of backplane orthogonal finger pairs (M2) as compared to on-cell metallization thickness (M1).

TABLE 3

| Thickness of On-Cell | | | Thickness of On-Cell |
|---|---|---|---|
| PVD Aluminum | 0.25% Absolute Cell | 0.50% Absolute Cell | Cured Aluminum Ink |
| (ρ = 3 μΩ.cm) | Efficiency Loss Limit | Efficiency Loss Limit | (ρ = 45 μΩ.cm) |
| 0.10 μm | F = 6 Pairs of | F = 4 Pairs of | 1.5 μm |
| (good process margin for | Orthogonal Fingers | Orthogonal Fingers | (excellent choice for low |
| laser metal ablation) | | | cell stress and low cost) |
| 0.20 μm | F = 4 Pairs of | F = 3 Pairs of | 3.0 μm |
| (marginal Al thickness for | Orthogonal Fingers | Orthogonal Fingers | (good choice for low cell |
| laser metal ablation) | | | stress and low cost) |
| 0.40 μm | F = 3 Pairs of | F = 3 Pairs of | 6.0 μm |
| (Al may be too thick fo | Orthogonal Fingers | Orthogonal Fingers | (increased stress risk |
| laser metal ablation) | | | and ink cost) |

As can be seen from Table 3, in one embodiment F=3 in conjunction with 3 μm cured Al ink (or 0.2 μm PVD Al) may be chosen for a less or equal to 0.50% loss and in another embodiment F=4 in conjunction with 3 μm cured Al ink (or 0.2 μm PVD Al) may be chosen for a less than or equal to 0.25% loss.

In operation, the multi-level metallization structures, for example dual level metallization comprising M1 and M2 including orthogonal and non-orthogonal transformations, disclosed herein provide the following M1/M2 design flexibility advantages relating to performance, cost, mechanical yield, and architecture:
Increase M1 design flexibility (including segmented M1 designs, for example such as those shown in FIGS. 54 and 55, and mini-cell designs) allows for thinner M1 patterns which reduce the stress and bowing associated with metal on silicon (thin silicon substrates as well as wafer based thicker silicon substrates) without compromising performance. Further, M1 may act as a support structure for thin silicon substrate in a large area back contact solar cell.
Busbarless M1 pattern—The M1 pattern may run to the edges of the solar cell and the busbar formed on M2, thus preventing electrical shading due to M1 busbars.
Larger emitter fraction due to narrower M1—a narrower M1 pattern allows for narrower base diffusion (for example in a nested design where M1 base metal is positioned inside base diffusion region), thus a larger emitter fraction and less electrical shading from base diffusion regions.
M2 may be decoupled from the silicon substrate by positioning a dielectric layer between M2 and the silicon thus reducing stress of M2 and allowing for thicker M2 designs.
An orthogonal M2 pattern allows for highly coarse M2 dimensions which may reduce the cost of forming M2 as additional metallization formation methods may be utilized. Further, and orthogonal pattern may allow for the insertion of active components such as bypass diodes and MPPT electronics components.

While the embodiments described herein have been largely explained in conjunction with back-contact/back-junction crystalline silicon solar cells using very thin (e.g., from about one micron up to about 100 microns) mono-crystalline silicon absorber layers supported on flexible or rigid backplanes, it should be understood that the aspects of the disclosed subject matter may be applied in some instances to other solar cell and module implementations by one skilled in the art, including but not limited to the following: front contact solar cells and PV modules comprising such cells; non-crystalline silicon solar cells and modules such as those made from crystalline GaAs, GaN, Ge, and/or other elemental and compound semiconductors; and, wafer-based solar cells including back-contact/front-junction, back-contact/back-junction and front-contact solar cells made from crystalline semiconductor wafers (such as crystalline silicon wafers).

As mentioned previously, silicon is currently the dominant absorber material of choice for the mainstream high efficiency solar cells. This disclosure provides solutions in the form of solar cell fabrication processing and structures, driving improvements, such as improved cost per watt, in high efficiency solar cells. Solutions include, but are not limited to: The use of significantly less silicon material. Process methods and structures providing for the use of significantly less silicon material, for example cells formed by epitaxial deposition on a re-usable template with subsequent release (or lift off separation) of epitaxial films by means of a designated sacrificial release layer or region (for example formed by porous silicon, stress induced splitting, laser cleaving, or other release methods, such as hydrogen implantation).

Second, process capabilities for high efficiency, back contacted wafer based cells are provided including: multi-level metallization comprising an affordable second layer metal structure (for example made of aluminum and/or copper formed by thermal spray and/or twin-wire arc spray) which reduces overall metallization cost, enables the use of larger cell substrates and the extraction of larger cell currents, the decoupling of higher conductivity thicker metal (metal 2) stresses from the active thin cell layer, and the use of thinner absorber cells. The use of an affordable inter-metal dielectric or electrically insulating layer positioned between a first layer metal and a second layer metal which may also serve as a permanent mechanical support is provided which may also further reduce cell substrate thickness.

Third, the use of heterojunction designs and structures as well as formation methods which may be integrated and used in conjunction with the disclosed high efficiency capable cell structures further extends the efficiency and cost per watt capabilities of back contacted, back junction cell concepts.

Fourth, aspects of the disclosed subject matter are also directly applicable to cells formed from non-silicon material—for example direct bandgap materials such as GaAs. For example, cells utilizing these materials may also benefit from a mechanically supportive backplane and an affordable release layer or cleaving region.

Fifth, the use of thermally sprayed metal (or metal deposited using low-cost atmospheric twin-wire arc spray)—for example pure Al or Al-containing metal alloy such as Al/Zn, Al/Cu, etc.—may reduce metallization fabrication equipment and processing cost. Further, the spraying of metal (for example by thermal spray and/or twin-wire arc spray) may be used for an all-dry as well as direct-write metallization process which may reduce propensity of metallization to cause contamination and absorber material lifetime reduction as compared to wet plating processing as metals (such as copper) may reach the silicon area of the solar cell (often accidentally) during or after the wet plating process.

The disclosed subject matter provides structures and processing methods for high efficiency solar cell structures, particularly back-junction back-contacted cells, embodiments including, but not limited to:
Selective emitter technology (for example utilizing dual layer borosilicate glass BSG application plus laser induced patterning of BSG layers, or by laser annealed paste);
Metallization schemes containing various embodiments, including multi-level metallization such as two-level (dual-level) metallization, which may utilize low cost metallization materials such as aluminum and/or copper and/or aluminum-zinc, or a combination thereof, formed using processing methods such as atmospheric thermal spray and/or twin-wire arc spray (TWAS);
Heterojunction application to the solar cell sunny side (front side);
Heterojunction application to the solar cell back side, including various embodiments for emitter and base contact and contact doping schemes;
Various embodiments for applying a dielectric layer separating a first and a second level metal (lamination and subsequent hole drilling versus direct print);
Multi-level metallization structures, in one embodiment comprising an orthogonal arrangement between metal level one fingers and metal level two fingers, and alternatively comprising parallel M1/M2 finger designs as well as more complex M1/M2 designs/arrangements two-level cell metallization schemes (in some instances comprising a tighter pitch M1 as compares to a looser/coarse pitch M2);
Applicability of all structures and flows to both epitaxial layer based cells and wafer based cells (as well as various thin silicon or thin semiconductor solar cells, including but not limited to thin semiconductor layers formed by epitaxial semiconductor lift off, exfoliation using stress-induced splitting, and separation by proton ion implantation).

Importantly, aspects of the described exemplary process flows and structures presented embodiments are provided as illustrative examples and are not exclusive, but rather may be combined in numerous and various manners and permutations in accordance with the disclosed subject matter. For example, heterojunction passivation on the cell front side may be combined with heterojunction application to the cell back side, as well as implementation of either frontside heterojunction passivation or backside heterojunction passivation. Further, generally the aspects of the described exemplary process flows and structures may be combined to form processes and structures for high efficiency solar cells, particularly cells utilizing thin semiconductor layers (for example cells with semiconductor layers comprising silicon and/or gallium arsenide and/or other semiconductor material layers with the active absorber layer thickness in the range of below 1 micron up to approximately 100 microns). And while the solar cells disclosed herein are described using silicon as the active light absorber material—and corresponding dopant sources and glasses suitable for silicon are detailed—aspects and concepts provided in the detailed structures and process flows are transferable to other light absorbing materials, such as compound semiconductors (for example GaAs, etc.), the use of release layers such as porous silicon, backplane reinforcements, back contact, laser ablation, and metallization schemes. Thus, the disclosed solar cell structures and fabrication methods may utilize and are applicable to alternative light absorbing materials and solar cell fabrication materials and processes.

Additionally, although the following solar cells and process flows are generally described for n-type cells having, for example, a phosphorus base, and subsequent emitter formation by borosilicate glass deposition(s) (BSG), phosphosilicate glass (PSG) deposition, and subsequent diffusion to generate emitter and base contacts, respectively, the disclosed subject matter is transferable to a p-type base cell. For example, a p-type base cell having, for example, a boron doped base, and emitter formation by PSG and BSG deposition and diffusion to generate n-type emitter and p-type base contacts to the p-type cell, respectively.

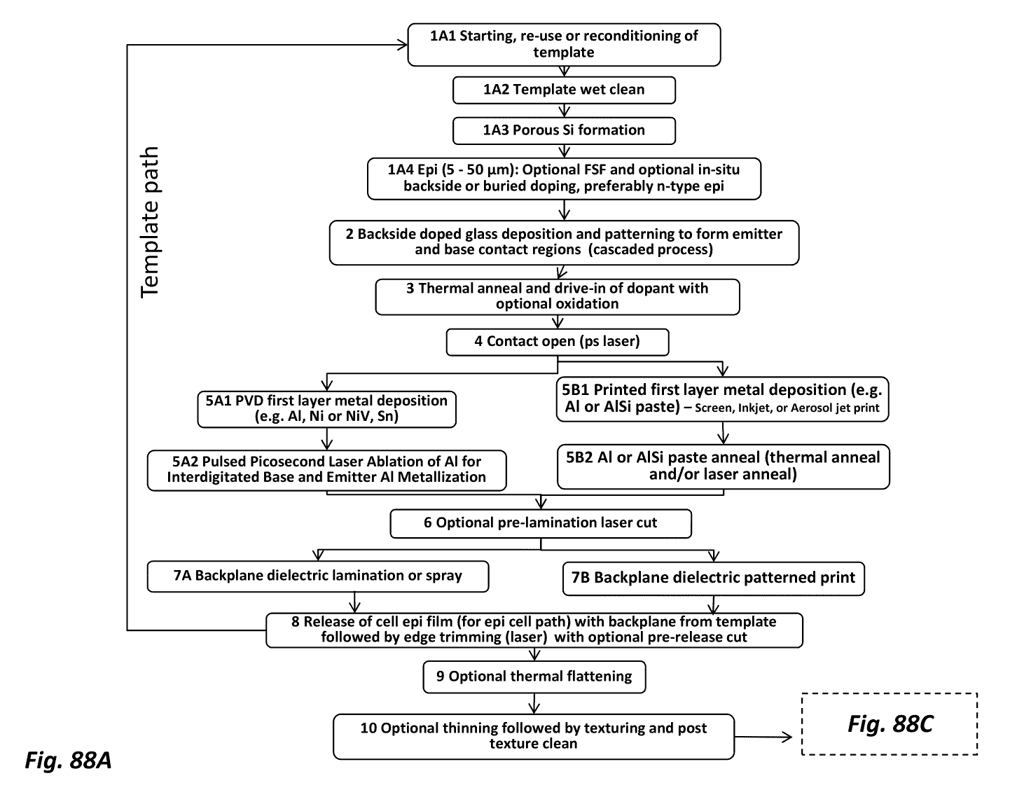

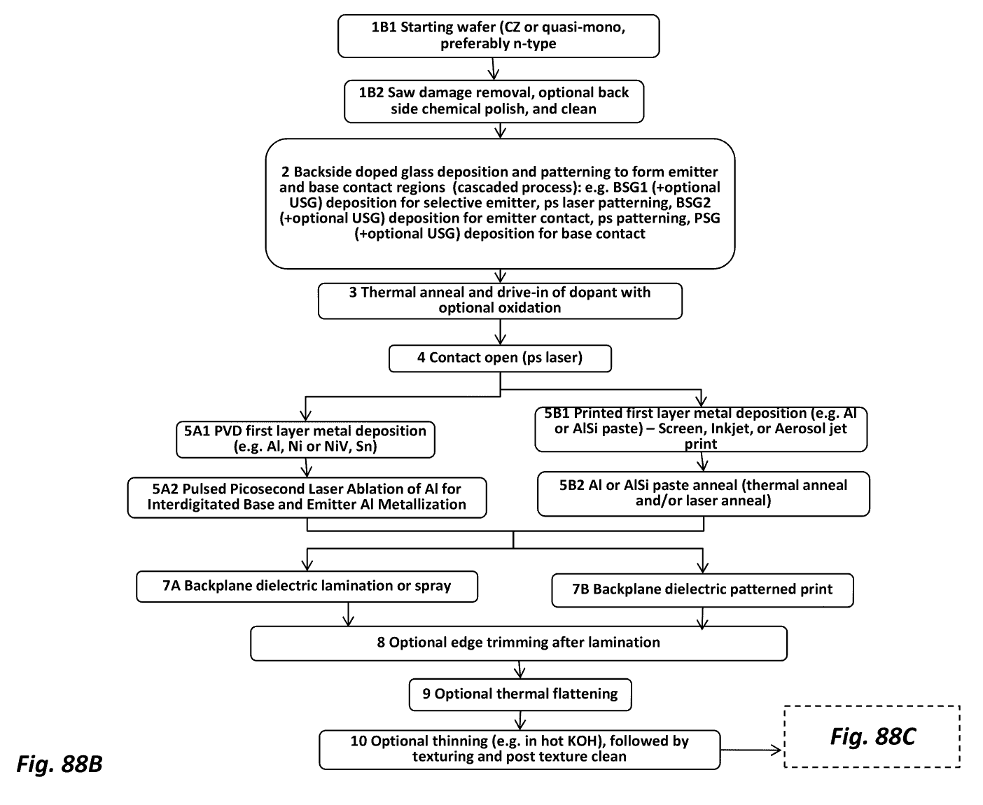

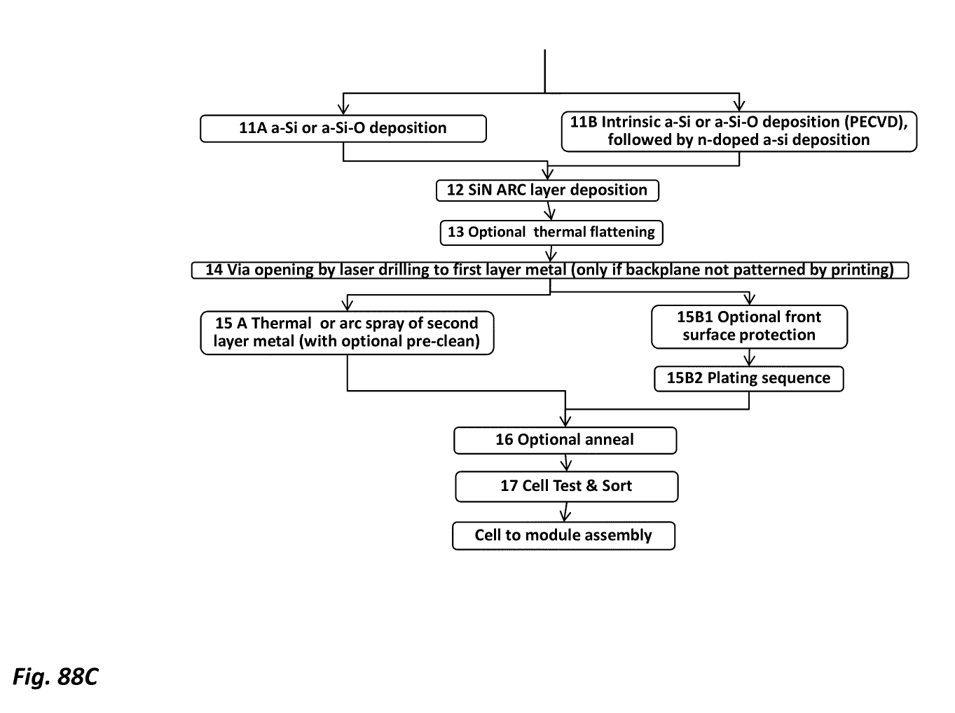

The following outlines various partial structures and processing methods for the manufacturing of a variety of solar cell structures by a variety of methods. Alternative options for the partial structures and methods may be further detailed herein. And wherever not explicitly excluded, the exemplary list of partial structure and method options provided below may be combined. Importantly, processes methods may also occur at different points in the overall solar cell fabrication process flow and this disclosure is intended to cover all such permutations. Partial structures and methods include, but are not limited to:
The use of wafer based active absorber cell materials (such as Czochralski (CZ), continuous growth CZ, FZ, seeded cast mono-crystalline, multi-crystalline or upgraded metallurgical grade silicon UMG) in some instances having lifetimes of at least several hundred microseconds. And the use of active absorber material that is based on epitaxial deposition on and later released from re-usable templates (for example crystalline silicon) which contain a release layer or layer system (for example a release layer formed by electrochemically etching the crystalline silicon template to form a porous silicon layer structure).
The formation of homogeneous emitters and the formation of selective emitters. Several embodiments of forming such emitters are outlined.
The use of physical vapor deposition (PVD) (such as sputtering or evaporation) and the use of direct printing (such as screen printing, stencil printing, ink jet printing or aerosol jet printing) of pastes or inks (for example pastes/inks containing Aluminum, or Aluminum silicon particle mixes) in order to form ohmic contacts to both doping polarities (n-type and p-type ohmic contacts) at low cost.
Backplane dielectric materials which may be laminated on the cell and later drilled to form a plurality of via holes for contact openings to interconnect and contact the first and the second metal layers and a printed (direct write) dielectric layer which may printed in a pattern inclusive of the via holes for interconnections between the two levels of metallization. The latter may be used, for example, in process flows where the dielectric material provides a barrier protecting against chemical attack of the first metal during subsequent wet processing steps (such as texturing or post texture cleaning) wherever wet processing steps are not carried out prior or in a single sided fashion (on the cell side opposite metallization) which may avoid wet chemical exposure of the backplane dielectric material.
A second layer metal which may fabricated using plating based process sequence (such as seed layer deposition by PVD such as sputtering or evaporation) or electroless deposition, inkjet deposition, or aerosol printing deposition, followed by printing of a sacrificial patterned separation dielectric defining the areas of the two polarities, followed by plating the main metal or metal stack (for example plating of copper), and finishing by stripping the dielectric and the seed layer underneath the dielectric and an optional anneal. Alternatively, the second layer metal may fabrication by applying a thermal spray or arc plasma spray (such as twin-wire arc plasma spray or TWAS). And in some instances, the use of a PVD layer or layer system to form the complete thickness of metal 2, followed by patterning by either a lithographic or screen printing step or by laser ablation to delineate and separate areas of different polarities may be used. And if the lower layer is aluminum, a capping layer such as Ni, NiV or Ni, NiV, may be added followed by Sn.
Thinning wafers by chemical etching, lapping or grinding, after application of the backplane (for example by lamination), to allow the use of comparatively lower lifetime wafers or higher lifetime wafers which may benefit from the higher open circuit voltage (Voc) capability provided by a thinner wafer as the generated carriers in thinner wafers will generally have a shorter path to the terminal. In a wafer based fabrication flow (such as that shown in FIG. 88B), the starting wafer may have a thickness in the range of approximately of 140 to as large as approximately 220 microns. After backplane lamination, the wafer may then be thin to a thickness in the range of approximately 35 to 100 microns—for example by chemical etching, lapping, or grinding—thereby shortening the path for a carrier to reach a backside emitter from the wafer frontside. Other advantages of using relatively thinner wafers include higher flexibility and bending capability of thin silicon, particularly when supported by a flexible backplane. Thinner absorber layers in combination with a flexible backplane combination provides several architectural solutions for solar cells such as fabricating non-planar modules or otherwise integrating silicon based solar cells in or onto non-planar surfaces. Further, thinned wafers—as an alternative to thin epitaxially deposited and released solar cell structures—may allow for the extension of epitaxial thin film cell capabilities to readily commercially available solar cell starting wafers.
Various frontside passivation embodiments. For example, for wafer based cell flows where texturing is performed at least prior to application of the backplane (for example by lamination, printing or spraying) and thinning is not performed from the front side after lamination, high temperature frontside passivation may be used (for example from a thermally grown oxide). In some instances, low temperature passivation may be used (for example a thin (e.g., 2 to 10 nm thick) amorphous silicon (a-Si) or oxygen containing amorphous silicon (a-Si—O), or carbon-containing amorphous silicon, which may also serve to avoid inadvertent and undesirable epitaxial alignment of the to be deposited a-Si layer with the underlying textured crystalline silicon). And in some instances, heterojunction-type front-side passivation may be used, which may use intrinsic a-Si or a-Si—O, followed by doped a-Si (for example in the case of an n-type base n-doped a-Si such as phosphorus-doped a-Si). For each of these passivation starting layers, the subsequent deposition of an anti-reflection coating (ARC), for example silicon nitride (SiN), may be employed, where the SiN may serve as an ARC layer, a reservoir of positive fixed charges, as well as a source of embedded hydrogen to effectively passivate dangling bonds in the a-Si or a-Si—Ox (or a-SiCx) and in the a-Si or a-Si—O/c-Si interface. To optimize the optical performance and further reduce light reflection, a secondary ARC layer or an ARC layer with a graded refractive index may be employed as well.
Backside passivation by deposited and subsequently densified glass, for example from an Atmospheric-Pressure Chemical-Vapor Deposition (APCVD) layer. And backside passivation using a doped or undoped Al2O3 (aluminum oxide) layer, where the doping in the Al2O3 is used in a subsequent diffusion step to form at least one of the emitter junction area (e.g., p+ emitter diffusion) or the base contact area. As well as the formation of a heterojunction backside passivation layer. Detailed embodiments for heterojunction backside passivation layer formation are provided below.
Optionally, a front surface field (FSF) and/or back-surface field (BSF), for example formed by in-situ doping during epitaxial deposition of the thin monocrystalline silicon solar cell, which serves two functions: to reflect generated minority carriers from the front surface (in the case of FSF) and enable a low front surface recombination velocity (FSRV); and to laterally carry the majority carrier current through the base (in the case of either FSF or emitter enveloping BSF), thus lowering the effective base resistance. Front surface field (FSF) containing structures are compared with non-front surface field containing structures that rely on a good surface passivation for low FSRV. In some instances, FSF structures that rely on a high temperature drive in, for example from a furnace step, may generally be limited to the wafer based approach. However, FSF structures that rely on laser annealing or laser doping or in-situ doping during thin silicon epitaxy, may be employed for both wafer based and epitaxial deposition based structures (for example in-situ doping for FSF and/or BSF with the same doping polarity as that of the base doping, such as in-situ n-type doping with phosphorus, for thin epitaxial silicon cells).
Doping with variable doping levels in the direction of the epitaxial film deposition as compared to constant/uniform doping. Variation of doping levels in the direction of the film growth may be limited to cell structures that employ the deposition-release concept. Variable doping levels or graded base doping profile may be employed for the application of an in-situ FSF, for the application of a buried high conductivity doped layer (or a BSF layer) to reduce effective base resistance, or for the application of a high electrical conductivity layer close to the surface (on the emitter side of a back-junction/back-contact epitaxial solar cell), which in turn may reduce the depletion layer width of the emitter junction that resides close to the backside of the device.

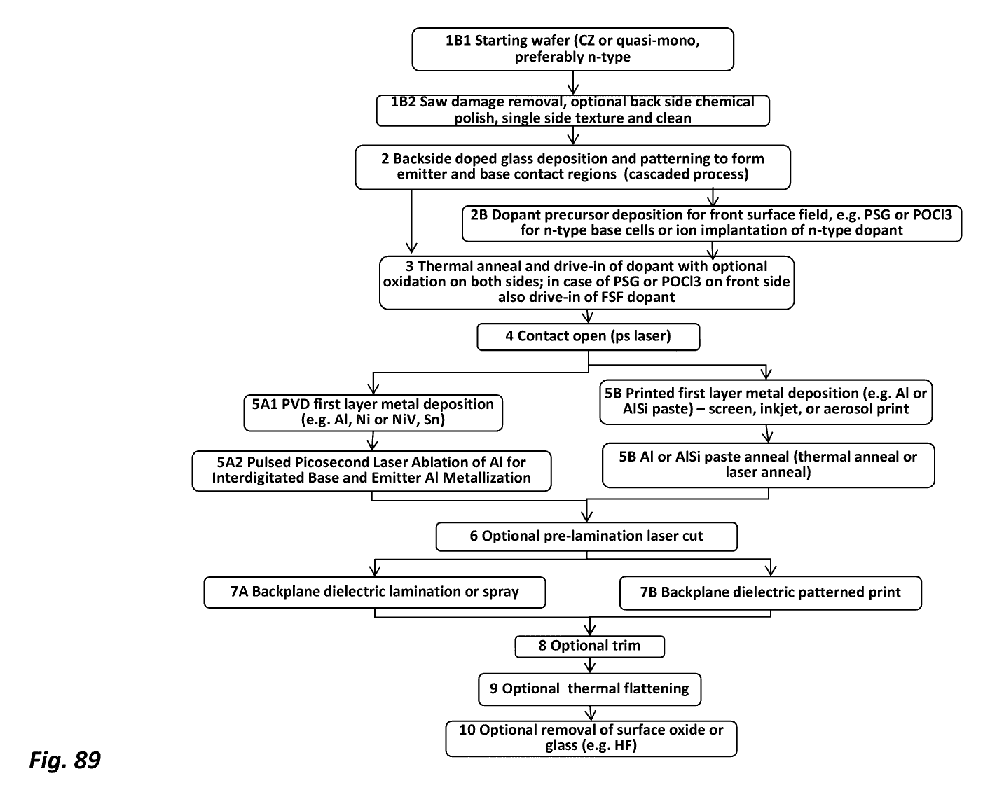

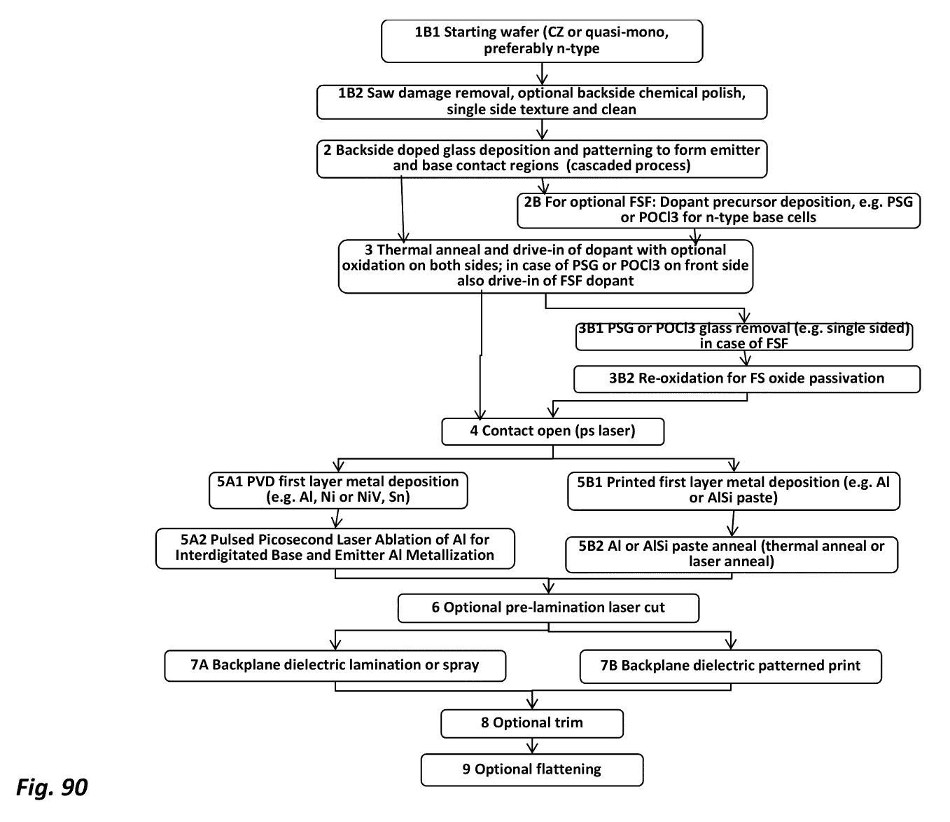

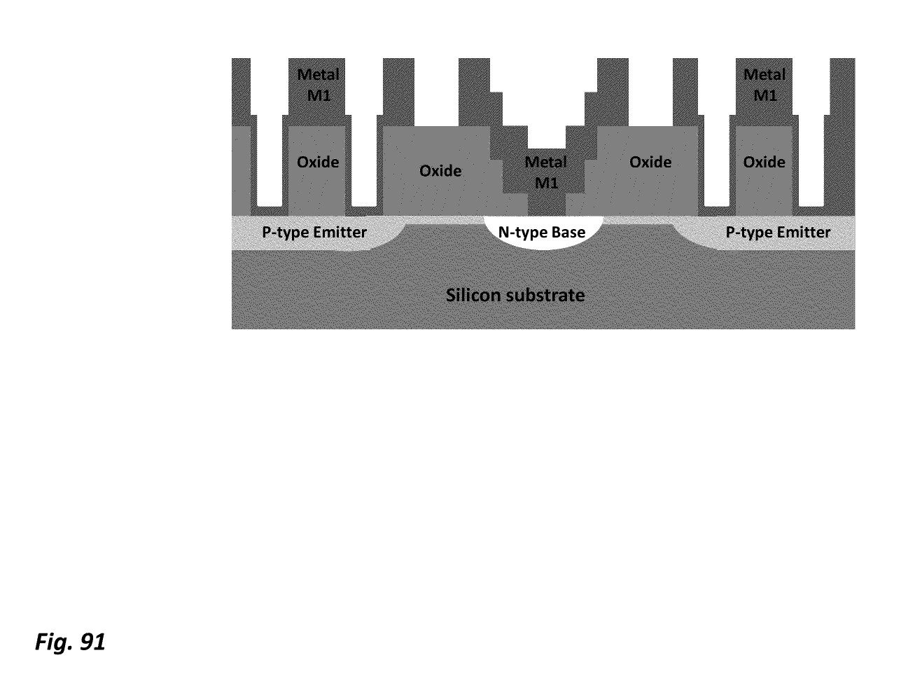

FIGS. 88A, 88B, 88C, 89, 90, 95A, 95B, 96, and 97 are process flow embodiments for the formation of high efficiency solar cells, for example thin crystalline semiconductor solar cells (including but not limited to monocrystalline silicon and gallium arsenide). The exemplary process flows are provided as detailed descriptions and permutations and combinations of various aspects of each flow are within the scope of the disclosed subject matter. Further options, including but not limited to such options where the sequence of some process steps is changed, are intended to be implicitly included. FIGS. 91 through 94 are diagrams depicting structures which may result from the processes disclosed herein. Generally, FIG. 88A describes various high efficiency flow options using epitaxy on reusable templates; FIG. 88B describes various high efficiency flow options using wafer based cells with capability of thinning after lamination; FIG. 89 describes various high efficiency flow options using wafer based cells with texturing prior to lamination; and FIG. 90 describes various high efficiency flow options using wafer based cells with thermal oxide front surface passivation.

FIG. 91 depicts a cross section of on-cell structures with patterned first layer metal and doped emitter and base contact regions. This cross section is representative for both epitaxial layer based cells as well as wafer based cells. In the case of epitaxial cell wafers, the depicted silicon substrate may attached to a silicon template via a porous silicon layer or layer stack during the backside processing part. First level metal (Metal M1)—for example printed Al, Al/Si, or PVD deposited laser ablated metal stack—electrically contacts doped emitter contact regions (selective P-type emitter regions) and doped base contact regions through contact openings formed through an oxide layer (for example picosecond laser ablated contact openings).

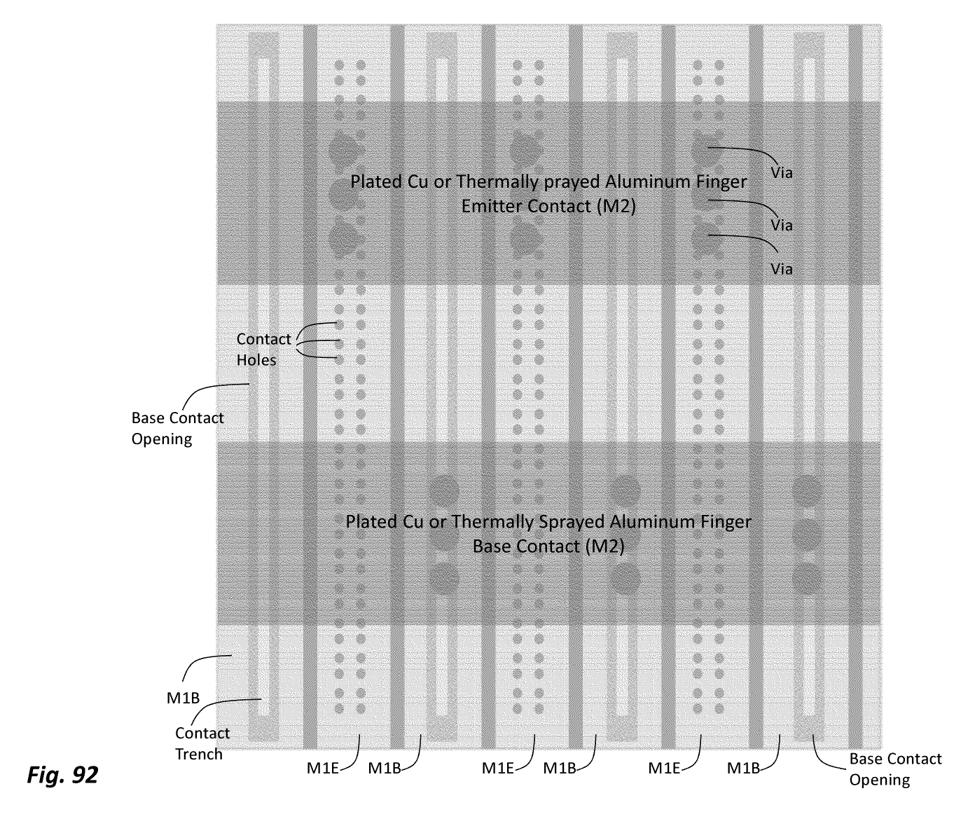

FIG. 92 is a diagram of a top view of an orthogonal M1/M2 metallization pattern (backplane not shown) to transfer the current between two levels of metal layers. High-electrical-conductivity second level meta and emitter fingers may be spray deposited (for example as a direct write pattern for lower cost), PVD deposited, or PVD deposited followed by plating on top of a backplane dielectric layer (not shown) with second level metal fingers running essentially orthogonally first level metal base (M1B in FIG. 92) and emitter fingers (M1E in FIG. 92), separated by a dielectric backplane (not shown) which acts as a dielectric layer. Contact holes (for example laser ablated contact holes) provide access for the first level metal to contact underlying cell emitter and base contact regions—shown as a contact trench/slit in laser ablated base contact openings for base contacts (M1B contact) and cylindrical contact holes for emitter contacts (M1E contact). Via holes formed/drilled in the dielectric back plane to enable/provide electrical contact between the respective emitter and base fingers of first and second level metal.

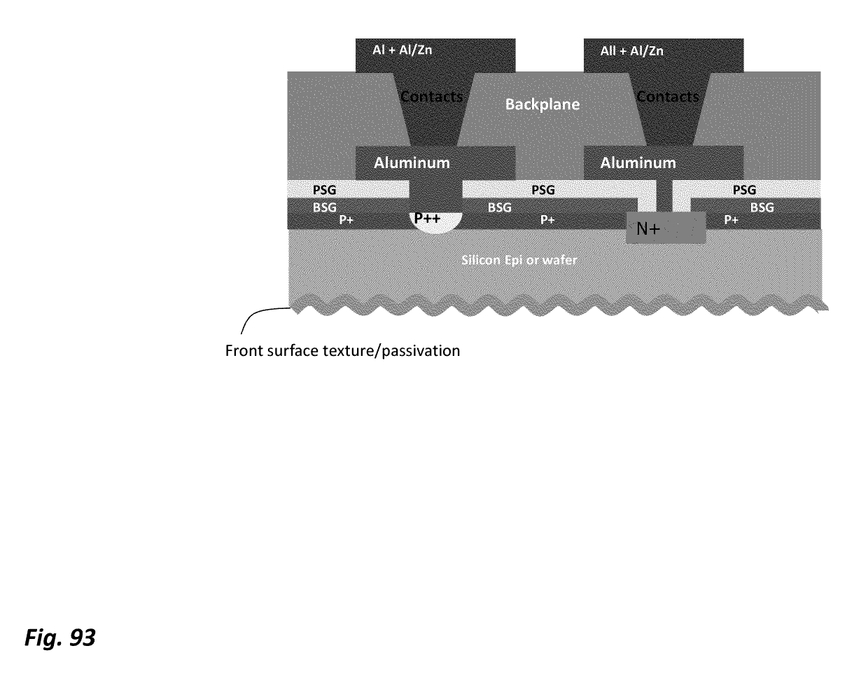

FIG. 93 is a diagram showing a cross section of a homojunction back contacted cell structure after backside pattern processing, metal 1 application, backplane lamination (and cell release in the case of epi based cell), optional thinning (in case of wafer based cells), texturization, passivation, backplane via drilling, and second layer metallization. Second level metal/M2 (for example thermally sprayed Al with Al/Zn, and shown as Al+Al/Zn in FIG. 93) contacts first level metal/M1 (for example Al or AlSi, and shown as Aluminum in FIG. 93) through laser drilled vias. M1 contacts base regions (N+) and selective emitter regions (P++) on the epitaxial layer based or wafer based cell (n-base). As shown, the cell frontside front surface texturized (for example with randomized textured pyramids) and comprises an optional front surface field (FSF). Cell frontside front surface may be covered with passivation (for example a thermal oxide (Tox) plus silicon nitride (SiN) or a-Si/SiN or a-Si—O/SiN or i-a-Si or i-a-Si—O/n-a-Si/SiN). It is also to be noted that the depicted BSG layer may be preceded or replaced by an optionally doped aluminum oxide (Al2O3) layer which may provide superior back surface passivation, for example applied using atmospheric pressure chemical vapor deposition (APCVD) or by ALD. It is to be noted that the second layer metal contacts to the M1 emitter and base may run orthogonally (as illustrated in FIG. 92).

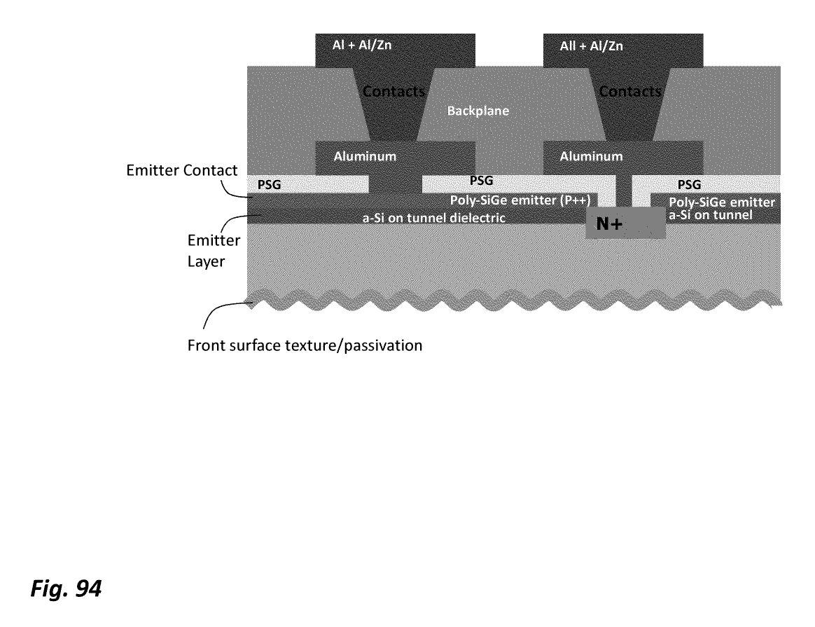

FIG. 94 is a diagram showing a cross section of a heterojunction back contacted cell structure after backside pattern processing, metal 1 application, backplane lamination (and cell release in the case of epi based cell), optional thinning (in case of wafer based cells), texturization, passivation, backplane via drilling, and second layer metallization. The cell of FIG. 94 is similar to the cell FIG. 93 except is it heterojunction back contact solar cell and M1 contacts base regions (N+)—for example laser doped N+ regions—and emitter contact layer (P++) on the epitaxial layer (a-Si on tunnel dielectric) based or wafer based cell (n-base).

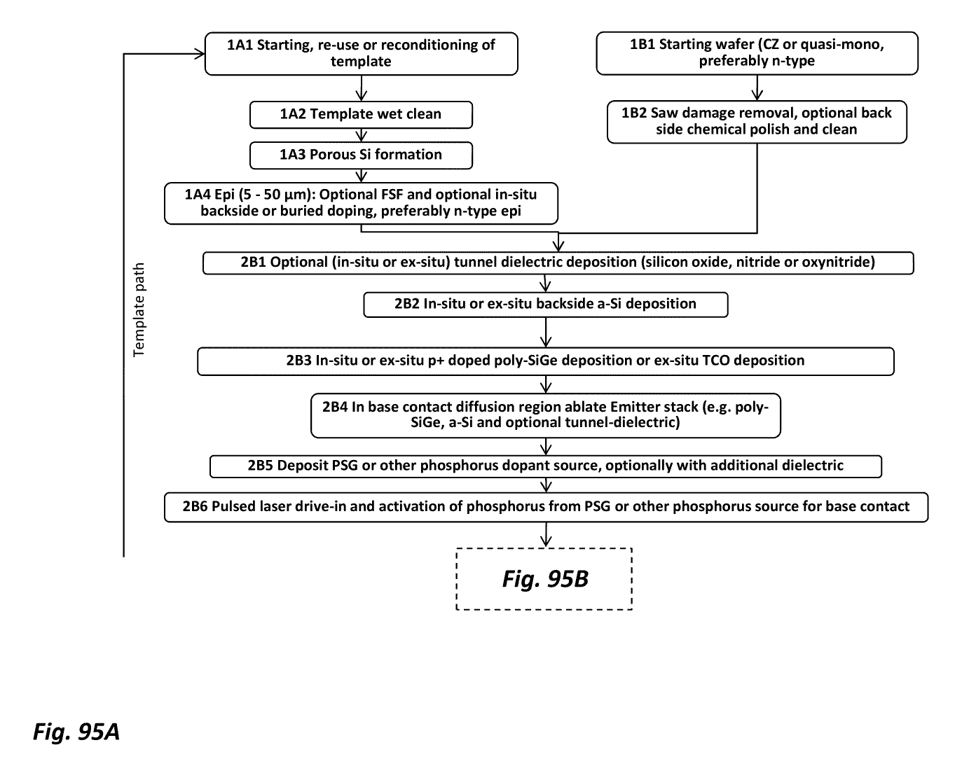

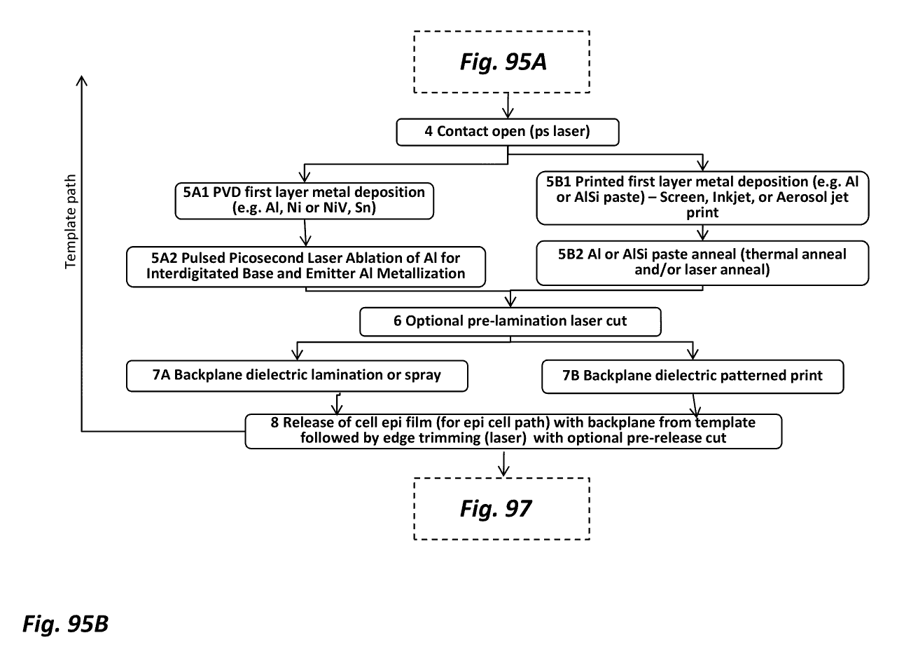

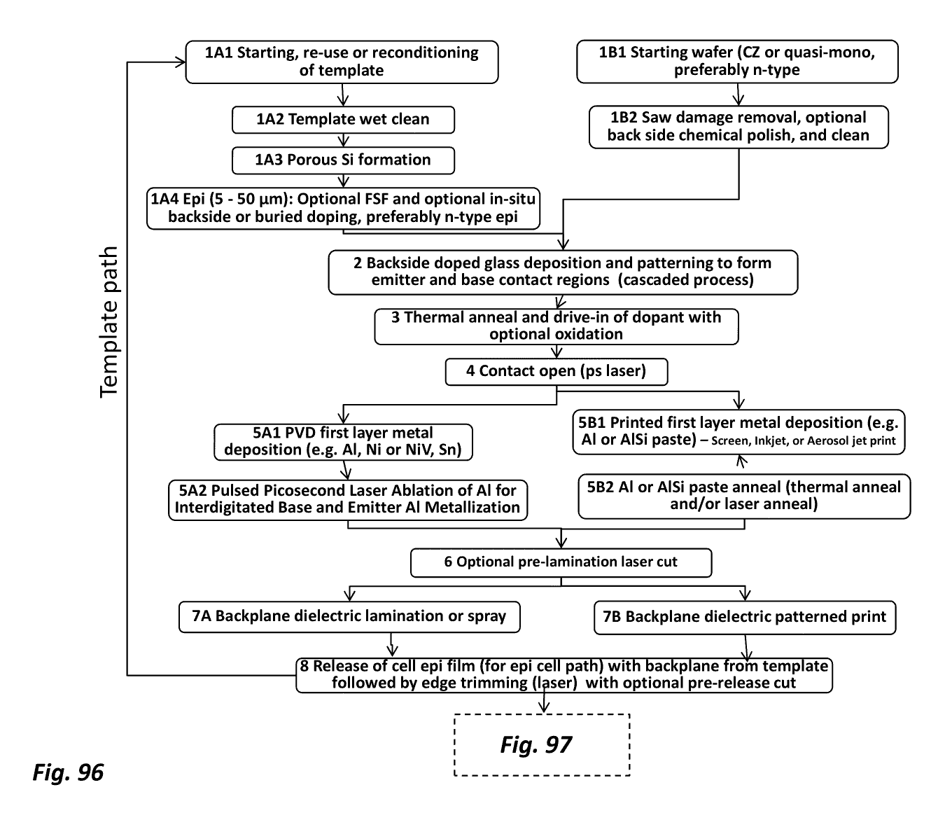

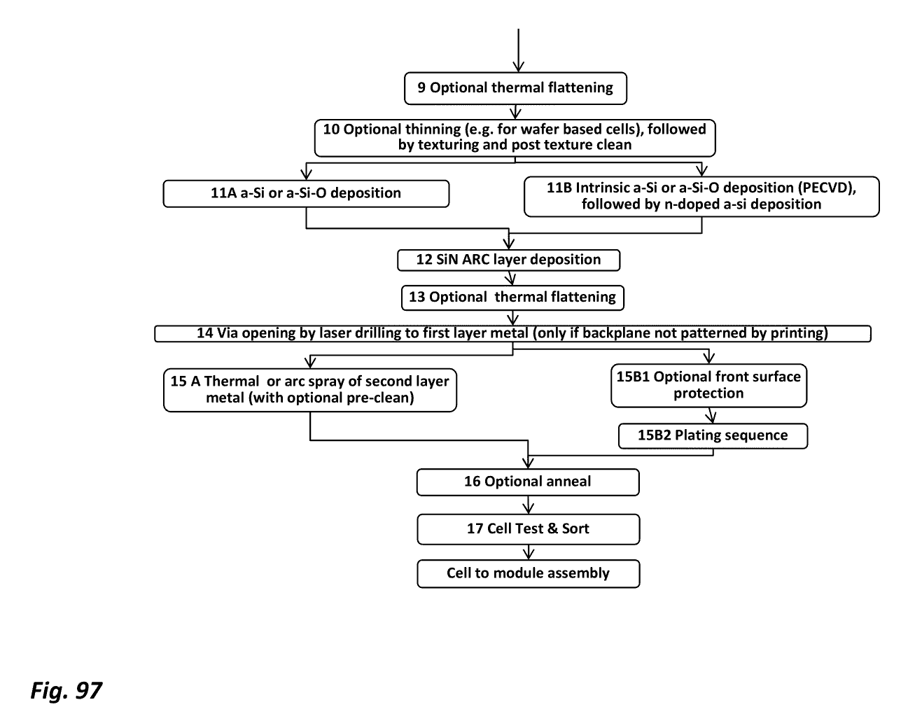

FIGS. 95A and 95B illustrate various high efficiency flow options using epitaxial layer or wafer based cells in conjunction with a heterojunction emitter. FIG. 96 illustrate various high efficiency flow options using epitaxial layer or wafer based cells in conjunction with a homojunction emitter. Relating to a heterojunction solar cell, in the case of the epitaxial layer it is envisioned that at least one layer of the optional tunnel dielectric or the a-Si emitter layer may be deposited in the same epitaxial reactor used to deposit the base layer without removing the wafers. For the wafer based cell, the distinction of in-situ or ex-situ is not applicable as no epitaxial process is applied prior to the tunnel dielectric or a-Si emitter deposition. FIG. 97 illustrates subsequent cell processing for the flows of FIGS. 95 and 96.

Relating to Steps 1A1, 1A2, 1A3, 1A4, 1B1 and 1B2 in Relation to the Process Flow Embodiments of FIGS. 88A, 88B, 88C, 89, 90, 95, 96, and 97.

1A1. In the case of epi (short for epitaxy) based cells, a reusable template (for example made of p-type silicon doped with boron) may be utilized. After cell process cycles, the starting or re-used template may receive a bevel grinding to remove deposition residue of the epitaxial layer from the bevel as well as to form a bevel which lowers the propensity of template chipping or breakage during on-template processing and subsequent reuse cycles. Further, after cell process cycles, templates may also undergo a removal step removing epitaxial layer residue on areas detrimental for subsequent processing. Example residue removal processes may used known methods as well as grinding steps, either closed to the edge, such as bevel or near bevel grinding, or area grinding or lapping, optionally followed by polishing, wherever needed, if—mainly due to defectiveness—epitaxial layer residue is found in the active area.

1A2. Subsequent template cleaning steps may include the removal of porous silicon layer residue, silicon etching, as well as the removal of metal and optionally of organic residues from the template.

1A3. A porous silicon layer structure may be formed by electrochemical etching. For example, a porous silicon layer comprising at least two zones with different porosity values may be formed, where a lower porosity zone is formed (for example having a porosity value less than approximately 35%) on which the epi layer is to be deposited on, and a high porosity zone is formed (for example having a porosity value greater than approximately 50%) in the region closer to the template to aide in epi layer release. In a pre-epitaxial deposition hydrogen bake the top porous layer (the layer having a lower porosity) then reforms to close the pores to constitute an effective starting monocrystalline seed layer for subsequent epitaxial layer formation, and the buried high porosity layer reforms to form a designated mechanically weak layer (for subsequent on-demand lift-off/release). For example, at step 8 after the backplane reinforced epitaxial film may be split from the template over the entire cell area, and processed further to complete formation of a solar cell and template may be re-used in an additional epi layer formation process after above described epitaxial residue and porous silicon residue removal (template reconditioning) and template surface cleaning. Inspection steps are implicitly included in this process loop.

The epitaxial layer deposition may be performed in an atmospheric pressure high-productivity batch or in-line epitaxial reactor using, for example, low cost and abundant silicon containing precursors such as trichlorosilane (TCS), dichlorosilane (DCS), silane (SiH4) or silicon tetrachloride (STC).

1A4. During the silicon deposition, the film may be in-situ doped, for example with phosphorus for n-type back-contact/back-junction solar cells. For an n-type base solar cell the dopant atom may be phosphorus, for example incorporated by controlled addition of PH3 during the epitaxial layer formation. Further, this addition of PH3 may be varied during the deposition process to form zones of higher and lower doping or graded doping, for instance to reduce the base resistance by incorporating one or more thin higher doped layers (for example with doping in the range of 5×10¹⁵ cm⁻³ to 5×10¹⁸ cm⁻³ in conjunction with a lower doped base region with an in-situ base doping in range of 5×10¹⁴ cm⁻³ to 5×10¹⁵ cm³). In a suitable depletion mode reactor, gas flow direction may be switched several times, for example at least once per designated doping zone, for form a designated doping profile

Doping profiles may provide several advantages, including: A higher doping level close to the sunny side of the device (in other words the first part of the epi deposition in the case of a back-contact/back-junction cell) may be used to generate an in-situ front surface field (FSF) while at the same time reducing the effective base resistance. And a higher doping level at the back side of the device (in other words the last part of the epi deposition) may be used to reduce the depletion region width of the junction by producing a back-surface field (BSF) layer. Further, a buried layer having a higher doping level (for example one or multiple layers embedded throughout the base region) may reduce the effective base resistance while allowing for a relatively low base doping and very high minority carrier bulk lifetime (over at least 100 microseconds up to over 1 ms). Both BSF and FSF layers may be used to reduce the base resistance.

1B1. In contrast to the vapor-phase epitaxial cell flow, a wafer based flow starts with a sliced wafer. Starting wafers may be any shape such as full squares, with just a minor chamfer at the edges, or pseudo-squares, having sizes in the range of 125 mm by 125 mm or 156 mm by 156 mm on a side, or as large as 210 mm by 210 mm and larger.

1B2. The starting wafer may be cleaned and saw damage removed. Saw damage removal may be performed using an acidic chemistry (such as hydrofluoric acid and nitric acid) or an alkaline chemistry (such as heated potassium hydroxide (KOH)). High temperatures and high concentrations of KOH may make the process less faceted as the KOH process gets more isotropic in these ranges. Subsequent processes may benefit if such wafers, as part of the saw damage removal, also receive a chemical polishing, such as with a concentrated mixture of hydrofluoric acid and nitric acid (HF/HNO3). In some instances, chemical polishing may applied only to the back side of the wafer at this time to consume as little silicon as possible at this time to retain the wafer mechanical stability and strength to reduce mechanical breakage yield during wafer processing. Alternatively, chemical polishing may be two sided.

HF/HNO3 saw damage removal and chemical polishing steps may be followed by KOH based removal of surface stains of porous silicon generated during this etch. After KOH application, the surface may be treated for metal removal using chemistries such as those containing HCl or mixtures of HCl with HF, or HCl with hydrogen peroxide (H2O2). In some instances for a hydrophobic layer prior subsequent processing steps, the wafer clean and saw damage removal may end by exposing the wafer surface to HF, either by immersion, spraying or application of vapor. A final rinse with ultra-dilute hot HF (for example with HF concentrations well below 1%) may also be applied at this point.

The prepared CZ or continuous growth CZ starting wafers (formed from a continuous growth ingot) may then have an essentially uniform starting base doping (for example a wafer sliced from a CZ ingot or from a seeded cast monocrystalline silicon brick). Continuous growth CZ may then be applied, for example in the case of n-type cells, to generate silicon wafers with suitably tight distribution of resistivity to enable both a high lifetime as well as a suitably low base resistance, which may be particularly applicable when the wafers are thinned as part of the overall cell process.

Where needed, it is also possible to overcome non-uniformity of doping across an ingot by applying a heavier n-doped layer to the back of the wafer in order to have comparable base resistance. Such heavier n-doped layers may be applied by using a dopant precursor such as POCl3, PSG or a phosphorus based implant with subsequent anneal. In this case, a lower bulk doping may be used which generally enables higher lifetimes.

2. After epi deposition (or after saw damage removal and optional backside chemical polishing for wafer based cells), a sequence of process steps is employed to prepare and structure the emitter junction and doped contact regions on the cell backside (for back-contact/back-junction cells). These processes are shown as steps 2, 2B and 3, 3B1 and 3B2 in FIGS. 88A, 88B, 88C, 89, 90, 95, 96, and 97 and consist of several processes and flow options.

Cells and cell processing may differ substantially depending on whether the backside structure (including emitter and base contact region) is formed by homojunctions or heterojunctions. It is to be noted in the following process flows that the thermal anneal step (icon 3) is omitted in the case of the heterojunction back contact region.

Homojunction Backside Contacts.

FIGS. 91 and 93 are cross-sectional diagrams showing examples of homojunction backside contact structure embodiments. FIG. 91 is a cross-sectional diagram of a solar cell structure after backside processing comprising the formation of an on-cell backside patterned first layer metal contacting doped emitter and base contact regions. In the case of an epitaxial cell wafer, the silicon substrate may be attached to template via a porous silicon layer on the cell frontside during backside structure processing. FIG. 93 is a cross-sectional diagram of a homojunction selective emitter solar cell structure after backside processing comprising pattern first layer metallization (M1) formation, backplane lamination (and cell release in the case of an epi based cell and optional thinning in the case of a wafer based cell), texture, passivation, via drilling, and second layer metallization (M2) formation for a homojunction back contacted solar cell. FIG. 94 is a cross-sectional diagram of a heterojunction uniform emitter solar cell structure after backside processing comprising pattern first layer metallization (M1) formation, backplane lamination (and cell release in the case of an epi based cell and optional thinning in the case of a wafer based cell), texture, passivation, via drilling, and second layer metallization (M2) formation for a heterojunction back contacted solar cell. Note that in both FIGS. 93 and 94 the second layer metal contacts to the emitter and base regions are not in the same plane/level as the second layer metal (although M2 and the M2 electrical contacts to M1 may be formed in the same processing steps and made of the same materials) and may run orthogonally to the M1 metallization fingers (as shown in FIG. 92).

Cell fabrication processing to generate the structures shown in FIGS. 93 and 94 may depend on whether the emitter is a uniform/homogeneous or a selective (for example comprising lightly doped emitter junction regions with heavily doped emitter contact regions)—in other words, a selective emitter has higher doping only in the regions comprising/proximate the emitter contacts and lower doping in the remainder of the emitter region (which in most instances comprises most of the emitter area as well as most of the cell area).

In one uniform homojunction emitter formation embodiment (which may be referred to herein as a cascaded or cascade process as the deposition alternates or cascades between glass deposition steps and laser patterning steps), boron doped silicate glass (BSG) is deposited on the cell backside to form the precursor for the boron doped emitter, and the base contact region may then be defined by laser ablation (for example using a picosecond (ps) laser) of the BSG layer above the selective base contact regions.

In a selective homojunction emitter formation embodiment, the main lightly doped emitter junction region is defined by depositing a lower boron concentration or thickness BSG glass, which then may be followed by laser ablation (for example using a ps laser) of the BSG glass and local deposition of thicker or more heavily boron doped glass, then the base contact region may be defined in a similar manner as described above for the uniform emitter. For example, base contact regions may formed as regular parallel lines, or discrete or isolated (or interrupted base) islands in various shapes in various shapes which may in some instances reduce electrical shading underneath the base contact region as carriers generated underneath the base contact regions may have on average a closer path to the emitter for collection.

After the base contact region is defined, a phosphorus doped silicate glass (PSG) may be deposited in the opened regions.

And while the process flow above are based on forming an main emitter junction region using a BSG layer (followed by laser patterning and furnace annealing), it is also possible to form the emitter region directly by in-situ boron doping (changing the doping from phosphorus for the base to boron for the emitter junction) during the final stage of silicon epitaxy (followed by laser ablation of p+ doped emitter to pattern the emitter region).

And in the case of the wafer based cells for which the silicon is not to be thinned after lamination, it is also possible to use PSG or POCl3 as a dopant on the front side for the formation of an ex-situ FSF, if previously an essentially single sided texturing step has been applied—as depicted as a process flow option in FIG. 89.

The cell may then be thermally annealed (for example in a tube furnace), which serves to drive in the dopant underneath the glass regions. Introduction of an oxidizing ambient during at least part of the anneal may generate a thin thermally grown passivation oxide at the original silicon oxide interface for high-quality backside passivation and low back surface recombination velocity (BSRV). The annealing process may also act as an impurity gettering step.

And in a case where the frontside has an FSF dopant recursor, this FSF may be driven in at the same time as the dopant.

For wafer based cells, as an alternative to the PSG or POCl3 precursors, the FSF dopant may be supplied by ion implantation of an n-type dopant (such as As, P, or Sb in the case of Si) into the textured frontside of the wafer. The implanted dopant may then be annealed and activated in the same step that drives in the junctions on the backside of the device.

Heterojunction Backside Contact Formation.

FIG. 94 is cross-sectional diagram of a heterojunction backside contact structure embodiment; FIG. 95 is a process flow for the formation of a heterojunction backside contact structure (such as the structure shown in FIG. 94); and FIG. 96 is a process flow for the formation of a homojunction backside contact structure. Thus, two alternative general process flows and a resulting structure are presented for the case of heterojunction and homojunction backside contact formation. In some instances, such as that shown in FIG. 95, the heterojunction may be deposited as at least one of several additional layers, after the epitaxial silicon deposition, in situ in the epitaxial silicon reactor. After epitaxial layer formation, an ultrathin high-quality tunnel nitride or tunnel oxide (or tunnel oxynitride) is grown (for example having a thickness in the range of approximately 5 to 30 angstroms) on top of the epi layer, for example using ammonia in case of a nitride or oxygen in case of the tunnel oxide (or other gases such as NO, N2O, etc.). Such tunnel dielectrics may be on the order of a fraction of nanometer to just less than 3 nm thick in order to not provide excessive series resistance. Subsequently, the temperature in the reactor may be lowered and amorphous Si (a-Si) or a-Si with oxygen (a-Si—O) is deposited. The optional tunnel dielectric layer may help avoid epitaxial alignment of the a-Si (or a-SiO or a-SiN or a-SiON) layer to be deposited. Subsequent to this a-Si deposition, at temperatures in the range of approximately 300 to 500 deg C., thin (several hundred to >1000 A) p+ doped SiGe with a substantial Ge content (for example greater than 10%) is deposited. Such material may be deposited in lower resistivity in-situ doped polycrystalline form at temperatures of approximately 400 to 500 deg C. where crystallization of a-Si can still be suppressed. With this configuration, a low sheet resistance emitter area of SiGe may be defined and thus eliminating the need for a more expensive sputtered TCO layer (such as an ITO layer). A subsequent laser ablation step ablates the thin SiGe and a-Si layer in regions where a base contact is to be formed. Subsequently, a PSG layer is deposited. Upon this, the phosphorus from the PSG layer is driven in and activated by pulsed laser annealing, for example using a pulsed nanosecond laser to form a local N+ doped region. In the ensuing contact opening step, a ps laser may be used to ablate both the emitter and base region through remaining phosphorus doped glass and enable contact formation to both terminal polarities.

As an alternative to depositing/growing layers of tunnel nitride or oxide (or oxynitride), as well as the a-Si and the poly-SiGe, in the epitaxial reactor, these layers (or a portion thereof such as the a-Si and doped SiGe layer) may be deposited in an atmospheric pressure chemical vapor deposition (APCVD) reactor (in one instance without breaking the controlled atmosphere between depositions). And particularly, but not exclusively, relevant for wafer based cells, such deposition/growth processes may also be performed in plasma-enhanced CVD (PECVD) or low pressure CVD (LPCVD) systems. Alternatively, the tunnel dielectric may be formed in situ and at the end of the epitaxial growth process in the silicon epitaxial reactor followed by formation of a-Si and doped SiGe layers in an APCVD reactor. With the described processes concluded, the base contact and emitter regions on the backside for the various options have been formed and the cell is ready for subsequent processing.

Relating to the patterns and the structure of the contact openings (formed, for example, using a laser processing, such as picoseconds laser) shown as step 4 in the process flows of FIGS. 88A, 88B, 88C, 89, 90, 95, 96, and 97: After the junctions have been implemented on the backside of the device, laser ablation (for example pulsed picoseconds or ps laser) is used to open up contacts to the junction contact regions. In the case of the base contacts, for example, contacts may be arranged essentially linear and aligned inside the doped base contact regions. And in the case of base doped contact regions (or emitter doped contact regions) comprising an array of isolated regions or islands, the base contacts are adapted to such geometries.

After contact opening, the first level metal may deposited (shown as steps 5A1, 5A2, 5B1 and 5B2). First level metal deposition options include, but are not limited to, physical vapor deposition (PVD) metallization (for example plasma sputtering or evaporation) of metals such as Al or Al with an Si component (to reduce junction spiking) and provide, in some instances, improved ohmic contact to both n and p-type silicon, followed by Ni or NiV and optionally Sn (or another solder material). After the first level metal deposition, the relatively thin first metal layer (for example the stack having a thickness less than approximately 2 microns and in some instances less than approximately 1 micron) may be patterned by ablation, for example using a pulsed ps laser. Optionally, after this patterning, additional metal may be locally applied, for example by screen printing of conductive epoxy, in the areas where contact to the second level metal will be made.

As an alternative to a PVD metallization scheme, the first level metal may be printed (for example by ink jet, aerosol jet, or stencil or screen printed) using a metal paste of pure Al or an alloy of Al with an Si content to reduce spiking. The paste may be dried after application, and optionally may be applied in a single or dual print step where a second layer is only printed where desired (for example in an area around the designated contacts to the second level metal). The paste may or may not contain frit, depending on whether the etching assistance of the frit is required for good contact resistance. In some instances the paste does not contain frit so a nested design is not required. For example, a nested design is a design where the extent of each polarity metal (base contact metal and emitter contact metal) does not exceed the extent of the respective base or emitter contact region. The paste final anneal to form a low series and contact resistance metal layer may optionally be performed in more than one heating step. The deposited first level metal may also be annealed using lasers, for examples using nanosecond (ns) or ps lasers, or an annealing step may combine laser and thermal anneal processing. Relating to laser annealing, different laser conditions may be utilized for different areas on the cells—for example to drive Al deeply into the silicon using a higher laser fluence in the designated emitter contact areas to form Al—Si eutectic, thus forming localized heavily doped p++ emitter contacts in conjunction with lightly doped selective emitter junction structures.

Further, first level metal designs and patterns may comprise a busbar-less pattern (to eliminate electrical shading) of interdigitated fingers (long parallel fingers of alternating contact polarity) which may different shapes (such as an interleaved multiple “H”-bar shape which allowing for a more relaxed (wider) second level metal design).

Relating to process flow steps 6, 7A and 7B: After first level metal formation is completed, the backplane may be applied (for example by lamination or thermal spraying, printing such as screen printing, or other coating method). In some instances, particularly relating to an epitaxial layer based cell flow, before backplane application an optional pre-lamination cut, for example in the peripheral areas of the device or even outside of the active device, may be performed. In the case of lamination of a backplane in sheet format, backplane materials include materials such as prepreg and fiber enforced resin sheets. For printed backplanes, materials include mixtures of resins and fillers such as small glass beads or fibers. In both cases the material mix may optimized for adhesion, Coefficient of thermal expansion (CTE) matching, and chemical and thermal resilience. Further, in the case of a printed backplane material (such as a screen printable dielectric paste) the backplane pattern may be directly printed with via holes open or partially open for contact between the first metal level and a subsequent second level metal. Direct backplane pattern printing may be especially applicable when front side texture is performed prior to backplane lamination—such as when using a pre-textured template which transmits texturization to the conformally deposited eip layer. However, if needed single sided texturization may be performed using a single sided texturing machine. And for unpatterned backplane material embodiments (laminated or otherwise applied), the backplane itself may acts as a protection layer during subsequent texturing.

Relating to step 8 in the disclosed process flows: After the lamination, in the case epitaxial wafer based cells, the backplane reinforced epitaxial cell structure is released and lifted off from the template. The template may then returned to the beginning of the template reuse cycle for the fabrication of multiple cells. The backplane reinforced epitaxial cell structure, also called thin film solar substrate (TFSS), may then be trimmed (for example by laser) around the edges to define cells outer periphery geometric outline.

Importantly, alternatively to the use of porous silicon as a designated release layer, the active cell area may be cleaved or released from a template or carrier wafer utilizing alternative cleaving mechanisms or separation methods which may be readily integrated with the described fundamental process flows and structures. For example, the formation of a mechanically weak layer using the implantation of hydrogen ions (or proton implantation) to a controlled depth in order to release the structure along the line defined by the implant depth. Alternatively, laser processing may be used to cleave/separate a controlled thickness from a source wafer. For example, one or a plurality of closely focused laser beams (focus in the um range) are scanned across the wafer from the side opposite of the backplane material. These laser beams are focused at a depth that defines the thickness of the layer to be cleaved off. Similar to the use of porous silicon as the release layer, after this release cleaving step the source wafer may undergo a re-use process sequence and the released backplane reinforced cell structure is processed further. Other release/separation methods include stress-induced splitting and exfoliation of the thin semiconductor layer from a reusable wafer using a thick metal layer to produce a controlled stress field.

Relating to step 9 in the disclosed process flows: in the case of excessive cell bow after lamination (and after cell release), and particularly relevant to cells that utilize releasing from a reusable template or are based on a source wafer, a flattening step (for example a thermally assisted flattening step) may be employed to flatten the TFSS and reduce cell bow for improved handling through high volume, high throughput subsequent process tools.

In subsequent texture and post texture cleaning steps, shown as step 10 in the disclosed process flows, the epitaxial cell based TFSS may undergo selective wet removal of the remnants/residue of the porous silicon layers, namely any remnant of the high porosity layer and the quasi monocrystalline silicon (QMS) layer which has formed after the reflow bake of the porous silicon prior to the epitaxial deposition. For monocrystalline semiconductor material, alkaline texturing process will remove the reside layers and also may result in randomized pyramidal texture formation resulting in improved solar cell light trapping and reduction of the optical reflection losses. Alternatively, a designated etch-back step may be employed to remove the QMS layer and part of the starting epitaxial layer which is then followed by a texturing process. Alternatively, dry texturing steps such as laser texturing or plasma texturing (with or without a final post-texture wet cleaning step to remove any residual dry texture damage) may be employed. Before and after the texturing organic residue may be removed from the cell surface, for example using chemistries such as mixtures of potassium hydroxide (KOH) and hydrogen peroxide (H2O2). After the texturization and prior passivation, a metal removal step may be performed to remove metal contamination from the surface, for example utilizing hydrochloric acid (HCl). Further, in some instances prior to passivation it may be desired to leave the surface hydrophobic. In the case of crystalline silicon based cells, this be accomplished by various implementations of hydrofluoric acid (HF) application, such as a dip, an ultra-dilute dip, a combination with HCl, a vapor-HF step or a drying using ultra-dilute HF.

Wafer based cells also may undergo texturing and subsequent clean at this point in the fabrication process (unless performed earlier in the process flow as shown in steps 1B2 of FIGS. 89 and 90), particularly relevant in the case of wafers that contain a front surface field. When wafer based cells undergo texturing at this point in the process (after the lamination), the texturization may be proceeded by a silicon thinning, for example using an etching (using KOH or hot KOH at a temperature of approximately 90 degrees C. or higher), lapping or backgrinding step, for form a controlled thin silicon layer for which the bulk lifetime requirements of the material are lower as compared to a thicker silicon cell. In some instances, silicon thinning (after backplane lamination) may be desirable as in a thinner silicon device, on average, a generated minority carrier (hole in n-type material) will have a shorter path to travel to the terminal and thus the material lifetime requirement (which is measure of the starting material quality and cost) may be loosened. As the wafer is thinned, wafer structure is weakened making the wafer brittle for subsequent cell processing. However, thinning the wafer thinning after attachment/lamination of a supportive backplane allows such cells to be transported through high volume processing equipment at high mechanical yield.

Optionally, and as shown in step 10 in FIG. 89, in the case of wafer based cells that do not undergo a thinning processing step but are pre-textured, surface oxide or glass may be removed prior to subsequent processing steps.

After texture and post texture clean steps, front surface passivation steps may be performed—shown as steps 11A, 11B and 12 in the disclosed process flows. For both a wafer based cell and an epitaxial layer based cell, passivation steps may comprise the deposition of thin intrinsic amorphous silicon (a-Si), or a-Si with sub-stoichiometric oxygen content (a-Si—O), or a-Si with sub-stoichiometric nitrogen content (a-Si—N), or a-Si with sub-stoichiometric carbon content (a-Si—C), or a or a-Si with sub-stoichiometric oxygen and/or nitrogen and/or carbon content (a-Si—ONC). This deposition may be optionally followed by an n-doped a-Si layer forming a heterojunction front side passivation and generating a minority carrier repelling field. The total thickness of the amorphous silicon frontside passivation layer may be less than 100 angstroms. In either case, a subsequent (for example in the same tool) silicon nitride layer may deposited which may serve as donor of hydrogen for further passivation and provide fixed positive charges to repel minority carriers (holes) from the surface, as well as forming and anti-reflective coat (ARC) to help couple light into the cell (reduce optical reflection losses). Alternatively to silicon nitride, other combinations, such as SiCxNy, may also be used as an ARC.

An optional flattening step, shown as step 13 in the disclosed process flows, combined with a thermal anneal may be employed after ARC layer deposition (or alternatively after any subsequent process step). Vias in the backplane providing contact to the first layer metal may then be formed by drilling vias through the backplane material (as shown in step 14). Patterned vias may drilled by ablating backplane material using lasers (for example CO2 lasers) to expose the underlying first level metals.

After exposure of the first level metal (for example via drilling through the backplane) process, a second level metallization may be formed. A two-level metal architecture formed in conjunction with a backplane supported thin cell enables the fabrication of low-cost, large-area, high-efficiency solar cells. Second level metal formation is shown as steps 15A and 15B1 and 15B2 in the disclosed process flows. The second level metal, for example an interdigitated pattern of rectangular or tapered fingers may be patterned orthogonally to the first level metallization—in other words the interdigitated fingers of M1 and M2 are positioned substantially perpendicular—which allows for a substantially less number of conductor fingers on the second metal level and relaxed design rules for the second level metal (millimeters or centimeters versus hundred(s) of micron for the first level metal). FIG. 92 is a top view of the backside of a solar cell illustrated an orthogonal M1/M2 metallization arrangement. Alternatively, if the first level metal is patterned using a “multi-H-shaped pattern” the second level metal design rules may be relaxed without being essentially orthogonal to the first level metal. Several geometrical designs are possible to achieve a relaxed dimension for the second level metal.

Relating to the second level metallization: The second level metal may be formed using a metal plating sequence comprising a seed layer deposition (for example using PVD or electroless plating) and an optional pre-PVD surface clean etch to clean the surface of the first level metal exposed at the bottom of the via hole. For example, a PVD layer stack may comprise Al followed by NiV and Sn. After seed layer deposition, the areas to be plated may be defined using for example screen printing of a sacrificial resist. In subsequent plating, metal (for example copper Cu) followed by Sn may deposited by electroplating. To protect the front (sunny) side of the cell during plating, the front side may be covered with a temporary strippable or permanent transparent protection layer which is removed/stripped off after the plating. Alternatively, cell fixturing protecting the cell active side from plating chemistry exposure may be employed during plating. In some instances, a second level metal pattern retracted from the edge further than the first level metal may be advantageous for such fixturing. Dual layer (multi-layer) metallization allow for both fabrication process flexibility and cell mechanical flexibility. Following the electroplating process, the resist, the optional front side protection layer, and subsequently the exposed seed layer metal are stripped, and after an optional anneal the cell may then be ready for electrical testing and module integration.

As an alternative to a PVD seed for plating, the seed may also be prepared by a screen or ink jet printed metal paste or ink. With suitable fixturing, the screen print patterning for the plating may be circumvented, if the seed layer is applied in a patterned form. Alternatively, the second level metal may be formed as a thermally sprayed metal, for example using a direct write metallization process, to further reduce manufacturing costs by using a low capital and consumable cost approach.

Backplane reinforcement in conjunction with back contact architecture allows for comparatively relaxed second level metallization requirements in terms of pattern design and fabrication processing. Thus, the equipment required for second level metallization, and particularly when used in conjunction with the relaxed geometries, may have a relatively low level of complexity. M2 metallization materials, to transport/carry the cell currents, include, but are not limited to aluminum or a material containing a high percentage of aluminum—thus resulting in a relatively low cost versus conductivity ratio. Alternative M2 metallization materials include, for example, copper, layers of aluminum with copper, and/or zinc or alloys of aluminum with copper and/or zinc.

Prior to thermally spraying (using flame spray and/or arc spray) the second layer metal, an optional cleanup and surface preparation step may be employed that prepares the bottom of the drilled via for a low resistance contact. Such surface preparation may include plasma steps (such as plasmas of oxygen and/or hydrogen) to remove carbon residue from the backplane material, as well as hydrogen or forming gas plasma (for example at atmospheric pressures) to remove native oxides, such as those found on Al paste or Al with Si or other metals after CO2 laser drilling. Oxide removal may be performed using lasers such as pulsed nanosecond or picosecond lasers. Alternatively wet chemical dips or chemical vapors may be employed to remove such oxides. In some instances, oxide removal may performed in an integrated tool without breaking the controlled atmosphere an ensuing flame spray deposition is carried out in. Metals materials to be thermally sprayed include, for example Al and alloys and/or layered stacks of Al and Zn (or Al and Cu or Al and Cu and Zn) to allow subsequent contacting (particularly at the module level). Pre-cleaning in a hydrogen plasma may be combined with metal spray deposition. In addition, the deposition may begin with one metal, for instance pure Al being sprayed by a twin or two wire ARC spray (TWAS), and using the same machine an additional metal or alloy may be deposited using a simpler single wire fed spray.

Second level metallization patterns include, for example, alternating/interdigitated linear parallel strips of metal with or without bus bar connections on the edges of the wafer. If the second level metal is without bus bar connections on the wafer, then the bus connection may be part of the module stringing or each strip segment may connected one by one to the neighbor cell in the module.

Thermally sprayed patterning embodiments include, for example: blanket metal deposition with subsequent masking and etching to generate the metallization pattern. Alternatively and in some instances reducing manufacturing cost, the second level metal may be deposited through a shadow mask comprising the metallization pattern information. In this case, the mask may be cleaned of deposited metal residue after every or several depositions or may consist of a disposable low cost material (for example a thermally and chemically resistant paper or film).

In certain second level metallization patterns having relaxed pattern geometries (in the range of several mm to cm range) the metallization pattern may be formed be direct write—for example using a plurality of nozzles or by using a scanning mechanism for either the nozzle or the cell to be coated.

In some instances, for example when pure Al is sprayed onto the cell, an optional second level metallization step may comprise localized printing or spraying of solderable contacts, such as copper and/or Ni and/or Sn and/or Zn or other metals or alloys, for example deposited in the same tool or without breaking the controlled atmosphere. For instance, in one embodiment Al (or an alloy of Al with another element such as Zn or Cu) may be used as the main metal 2 structure and a thin layer of Cu or Sn may be deposited on top for solderability.

A controlled atmosphere for thermal or arc plasma spray process or processes include oxygen reduced or oxygen free atmosphere, such as nitrogen, forming gas, hydrogen, or an inert ambient such as argon or helium (with closed loop capture and recovery of the gas if desired). After an optional final anneal to optimize especially the front side passivation as well as the second level metal layer and contact, shown as step 16 in the disclosed process flows, the cells may then be ready for test the sort, shown as step 17 in the disclosed process flows. Alternatively, a final anneal may be employed where needed at any time after the passivation layer has been applied.

Thermal Spray Integration Schemes for High Efficiency Solar Cell Manufacture.

The following relates directly to the concept of thermal or arc plasma spraying on back contacted solar cells, particularly used in conjunction with integral second level metal. Thermal spray or arc plasma spray (flame, arc or twin arc) has been demonstrated for front sided crystalline, multi-crystalline and polycrystalline solar cells where the molten species of metal is directly deposited onto the silicon cell and utilized as an ohmic contact, or as a diffusion source, and the dopant may be the metal species itself or a metal alloy where the incorporated species is the dopant. However, thermal spraying suffers from challenges when applied to silicon solar cell manufacture and particularly back contact solar cells, including: 1) Thermal spray directly onto Si may not offer a controlled heat zone and hence does not offer a controlled intentional or unintentional diffusion front; and 2) Patterning of metal on front sided silicon solar cells requires fine geometries in order to reach high efficiency by reducing reflective areas and hence optical shading. Utilizing metal masks or direct write with fine thermal sprays soon reaches the limit of the critical dimensions required to support such fine geometries.

Recent progress on high efficiency solar cells requires further improvement of reducing metal coverage on the front surface to zero metal (with back contact metal only). Other areas for high efficiency include reducing the thickness of crystalline silicon, to allow lower tolerances on material lifetime and advanced surfaces, minimizing surface recombination and maximizing anti reflection coatings. Back contact metallization, thinner silicon absorber thickness and especially two-level metal cell architecture open up new possibilities for thermal spray metallization. The rear two-level metal scheme relaxes the critical dimensions for metal printing. Thin silicon requires mechanical support provided, as disclosed herein, by bonded low cost substrates—thus the thermal sprayed material may be predominantly located on the support material, buffering the Si from the deposition heat zone.

High efficiency solar cells, which offer peak currents around 10 A for 156×156 mm square cells, require low contact resistance and high conductivity metallization to transport large currents to the remaining cells in the module. In some instances, the application of pure aluminum, zinc, copper and tin and their corresponding alloys, often utilizes PVD and plating which may be considered expensive for solar cell manufacturing. And in some instances, the use of pastes, where glass frits provide etching through oxide layers, may lead to good contact resistance but may be compromised by poor bulk conductivity.

The back/rear contacted silicon cells as disclosed herein allow for relaxed metallization geometries and patterns—particularly relating to the second level metal. For example the two-level metallization scheme with backplane reinforcement material of the thin cell also serving as the inter-metal dielectric and the orthogonal metal 1 metal 2 pattern transformation. This structure enables a coarse metal 2 pattern which in turn allows the use of thermal or arc plasma spray through metal masks for direct write metallization, or using conformal coating followed by etch back methods. And while described with reference to a crystalline silicon solar cell, the structures and processing methods disclosed herein are not limited to this material set or state. Importantly, this scheme may be applied to different crystalline states of silicon, including multi and poly-crystalline as well as semiconductor systems such as GaAs, CIGS and CdTe. Further, the two-level metallization scheme may be applied to any silicon absorber thickness including a standard thickness silicon (120-160 um or thicker) or thin, supported silicon (5 to 50 microns).

For thicker, unsupported silicon the thermal spray material may sit on top of thermal or deposited oxide and electrically contact silicon through open windows in the oxide or via paste pillars. Further, standard thickness silicon may also benefit from having a backplane which enables a second layer metal at relaxed pitch. The cell cross sectional and top view diagrams of FIGS. 91 through 94 depict structures that may, in addition or alternatively to utilizing metallization methods such as printing or PVD, utilize thermally sprayed (for example by low-cost atmospheric flame spray and/or arc plasma spray) metal (for example comprising aluminum and/or copper, in pure or alloy forms together or with other suitable low-cost metals such as zinc) as a second metal level M2. This second level metal may be patterned during deposition for direct write metal 2 pattern formation (to reduce costs) utilizing a solid mask with openings that image the location of the desired metal pattern or may be patterned after a conformal coating of the thermal spray followed by resist based or metal based masking and subsequent wet or dry etching. The deposition of a metal mask may utilize standard screen print technology already in use in the industry.

For backplane supported thin silicon, the backplane acts as a dielectric. Vias/holes are formed in the dielectric to gain access either directly to or to the underlying metal 1 layer and the deposited second level metal M2 may be patterned on the top surface of the backplane. The first metal pattern M1 under the dielectric (which may be orthogonal or parallel) to a thermally sprayed second level metallization M2 pattern deposited on top of the dielectric.

As mentioned above, following disclosure relates generally to the field of solar photovoltaics as well as semiconductor microelectronics, Micro-Electro-Mechanical Systems (MEMS), and optoelectronics devices, and more particularly to high-yield manufacturing methods and structures for large-area (for example, substrate areas of at least 100 cm² up to several thousand cm², or having linear side or diagonal dimensions from about 10 cm up to 10's of cm) thin-film solar cells and other semiconductor devices using thin films of crystalline semiconductor devices, including but not limited to thin films of monocrystalline silicon and compound semiconductors used as the active semiconductor layer (such as GaAs for example), in the semiconductor thickness range of approximately from a fraction of 1 micron up to approximately 100 microns. The semiconductor thin films (in the thickness range of approximately a fraction of 1 micron up to approximately 100 microns, and in some embodiments in the thickness range of a fraction of 1 micron up to about 50 microns) may be formed by repeated deposition processes on a reusable semiconductor template (and their subsequent separation from the template at some stage after each thin film deposition process and at least one additional on-template processing step) or by repeated slicing of a reusable semiconductor template (again with the slicing performed after performing at least one additional on-template processing step). And while the representative embodiments of this disclosure are provided for reduced-cost, high-efficiency thin-film mono-crystalline silicon solar cells, they are also applicable to manufacturing other semiconductor thin-film devices such as semiconductor microelectronics, optoelectronics, and MEMS devices.

As noted previously, crystalline silicon solar photovoltaics (PV) modules account for majority of the solar PV market and PV system installations (with a current market share of over 85%). For crystalline silicon PV manufacturers, the cost of the starting crystalline silicon (monocrystalline or multicrystalline silicon) wafers may account for about half of the overall all-in manufacturing cost of crystalline silicon solar PV modules. Crystalline silicon wafers used for manufacturing of solar cells as well as other microelectronic and optoelectronic devices are often produced using a costly and energy-intensive sequence of polysilicon feedstock production, silicon ingot growth, slicing the monocrystalline ingot (or cast Multicrystalline brick) into wafers using wire saw, and saw damage removal.

In order to reduce the cost of solar PV cells, a current industry trend is to reduce the thickness (and also the related slicing kerf losses) of the crystalline silicon wafers used to manufacture solar cells, with the solar cell crystalline silicon wafer thicknesses now being on the order of approximately 140 microns to over 200 microns. However, a reduction of the crystalline silicon wafer thickness may also result in a substantial increase in the wafer breakage rate during the solar cell manufacturing process (since the wafer strength roughly scales with the cube of thickness). Another significant waste and cost factor in crystalline silicon solar cells and other microelectronics devices is caused by wire-saw-induced kerf losses. In practice, the kerf losses due to wafer slicing wire saw and the thin wafer mechanical breakage constraints (or breakage-induced yield loss) place a practical limit on the ability to reduce the cost of starting wafers for manufacturing of low-cost solar PV cells and modules as well as other semiconductor microelectronics, optoelectronics, and MEMS devices.

The use of thin crystalline silicon (silicon films in the thickness range of approximately a fraction of 1 micron up to about 100 microns, and in some embodiments in the range of a fraction of 1 micron up to about 50 microns) formed by high-yield separation, cleaving, exfoliation, or lift-off from a reusable crystalline silicon template in conjunction with fully-supported thin-silicon processing techniques will enable a disruptive reduction of the manufacturing cost of solar cells and other semiconductor microelectronics devices. Various embodiments of this disclosure fully enable achieving such important objective for high-performance, low-cost solar PV cells and other semiconductor microelectronics devices.

Despite major cost advantages of using ultrathin (from a fraction of 1 micron up to about 100 microns in thickness) crystalline semiconductor films, including but not limited to monocrystalline silicon films, for production of large-area (particularly with areas equal to or larger than approximately 100 cm², or alternatively with side dimensions equal to or larger than about 100 mm×100 mm for square-shaped substrates or about 100-mm in diameter or diagonal dimension for circular or polygonal shapes) solar PV and microelectronics devices, the use of such ultrathin crystalline semiconductor (including monocrystalline silicon) films in crystalline semiconductor solar cell and semiconductor device manufacturing has not been implemented because processing and handling of such large-area ultrathin semiconductor layers through multiple manufacturing tools without breakage and yield losses has not been possible.

Thus, various structure embodiments and representative high-yield manufacturing process flow methods for cost-reduced, large-area (at least approximately 100 cm² in thin semiconductor area), high-efficiency solar PV cells using thin-film (i.e., thickness ranging from a fraction of 1 micron up to about 100 microns, and in some embodiments from a fraction of 1 micron up to about 50 microns) crystalline semiconductor, in general, and silicon, in particular, devices based on complete support and reinforcement of the thin crystalline silicon layers at all times both during and after the device fabrication process are provided. Specific embodiments are also disclosed for manufacturing of various designs and architectures of thin-film crystalline silicon solar cells, including: (i) back (emitter)-junction/back-contact thin-film solar cells, (ii) back (emitter)-junction/front-contact (base) thin-film solar cells, (iii) front (emitter)-junction/front-contact (base) thin-film solar cells. And while the specific embodiments are described with reference for monocrystalline silicon solar cells, such embodiments may be also extended and applied to other crystalline semiconductors such as gallium arsenide, III-V semiconductor materials, as well as to fabrication of microelectronics and optoelectronics devices.

Methods for manufacturing large area, very thin crystalline (fractions of micron thick up to about 100 μm thick) semiconductor devices are detailed herein. The disclosed methods and structures are versatile enough for manufacturing, in general, a spectrum of semiconductor devices such as solar cells, MEMS, photonics and others on both silicon and non-silicon (such as GaAs and other compound semiconductor based) devices, and may be adapted as such for specific applications by those skilled in the art. In the current disclosure the primary focus is in reference specific embodiments related to 1) crystalline Silicon and 2) solar cells.

Additionally solar cell structures using thin silicon are provided. The structures are enabled by the use of thin semiconductor layers (such as thin crystalline silicon). These structures along with more conventional solar cell structures may be combined within the framework of the generic thin crystalline semiconductor device manufacturing method described herein.

A general method of manufacturing thin crystalline semiconductor devices in accordance with the disclosed subject matter may comprise:
1. Starting with a relatively thick (for instance, at least about 200 microns in thickness) semiconductor, in general, and silicon, as a specific embodiment, which is substantially thick to support processing of the device with very high mechanical yield. The thick semiconductor material (henceforth, referred to as template) may be used repeatedly to amortize its cost as each template may yield numerous thin semiconductor devices. The template may be used to form a thin semiconductor device by using: 1) a process step(s) designed to facilitate the detachment of the template top layer with a predetermined and controlled thickness, or 2) the template has additional thin semiconductor layer(s) joined to it by a sacrificial layer(s) on at least one of its faces. The purpose of the sacrificial layer(s) is to facilitate the detachment of the thin semiconductor layer from the thick supporting semiconductor layer, at the desired stage in the process flow.
2. Performing at least one or more device fabrication steps on the face of the template which is to become the thin detached layer or in the case where there is an additional thin semiconductor layer, on the side supporting the thin semiconductor layer(s).
3. Attaching a support material, referred to as the backplane, which serves as at least a carrier and mechanically supports the thin semiconductor layer when it is detached from the template and goes through any remaining solar cell processing. In addition to being a carrier, the backplane may also serve other functions, for example it may comprise embedded metal lines for device interconnection and metallization and it may facilitate integration of discrete active components. This material, in a specific embodiment may be a prepreg material with a B-stageable resin, which can be laminated on to the thin semiconductor layer (or alternatively it may comprise a PET or PEN or another polymeric or composite material applied as a thin sheet or applied as a printed paste and subsequently cured). In general, this material may be any material, and particularly those materials which are substantially cheaper than silicon, are a strong mechanical carrier for the thin semiconductor, meet specific constraints dictated by the downstream process flow and device reliability, and do not interfere with electrical performance of the device. Specific material choices are discussed in specific context below.
4. A detachment process, by which the thin semiconductor device layer having at least one process step performed on it is separated from the template.
5. Subsequent processing to finish the formation of the device either on the face of the thin semiconductor layer which was just detached (the cell light receiving side/sunnyside/frontside), or on the face which has the backplane on it (the cell backside), or on both faces in any order, when needed.
6. Processing the template to restore its original condition or a condition conducive to facilitate the processing and release of the next cycle of thin semiconductor devices.

More specific embodiments of the aforementioned general process sequence to manufacture thin crystalline semiconductor devices are disclosed. The detailed focus is on: 1) silicon templates supporting the thin silicon layers; 2) thin crystalline silicon; and 3) solar photovoltaic devices. However, those skilled in the art may easily extend the aforementioned generic process sequence to 1) other semiconductor thin devices, on 2) Silicon or non-silicon crystalline semiconductor thin device layer, using 3) silicon or other semiconductor templates.

Two specific embodiments are discussed in the context of crystalline silicon template supporting thin crystalline silicon solar cells: the first uses porous silicon/epitaxy and the second uses cleaving. Further, components from each process flow may be combined or altered outside of the specific embodiments disclosed. And in a more specific embodiment, the device processing on top of the template may entail at least one process step utilizing pico second laser processing which is equally applicable to both the cleavage as well as porous silicon/epitaxy approach.

In the Porous Silicon/Epitaxy Embodiment,

a porous silicon layer is electrochemically etched to a thickness in the range of a fraction of one micron to a few microns on the surface of thick silicon template using an anodic etch process (for instance, comprising a mixture of HF and IPA). The doping can be either p or n-type for the template, however, its magnitude must be conducive to ensure sufficiently uniform and repeatable porous silicon formation. The porosity may be graded or stepped, such as bi-layered, to ensure both a controlled release when it is needed as well as the growth of a good quality, high minority carrier lifetime, thin crystalline silicon solar cell layer on its top. Subsequently, a thin (thickness ranging from fraction of one micron up to about 100 μm) crystalline silicon layer is epitaxially grown on top of the lower porosity porous silicon (if the porous layer is graded or layered the higher porosity layer is proximate the template and the lower porosity layer is proximate the epitaxially grown layer). In several variations, the epitaxially grown silicon may have various and multiple doping regions, grown in situ, depending on the electrical needs of the device. This includes both n and p-type base of a solar cell, and for each doping the doping may be graded to ensure a conducive built-in electric field for enhanced carrier mobility, or both types of doping (p and n) may be simultaneously put in with different thicknesses to achieve both base and emitter regions of a solar cell. This is followed by subsequent cell processing on the epitaxially grown thin silicon. The cell processing may specifically involve furnace or other high temperature steps as well as laser processing and dopant-containing material (such as doped silicon oxide) layer deposition. Once this sequence of cell processing is completed, a backplane is laminated to (or deposited on) the epitaxially grown thin silicon backside. In a specific embodiment the backplane may have a resin which flows at relatively low temperatures (˜200 C) and adheres to the silicon. The backplane may also be relatively thermally (Coefficient of Thermal Expansion or CTE) matched with silicon so as not to crack the silicon during lamination or other downstream higher temperature processing steps. The backplane may also be resistant to chemicals in fabrication methods where chemistry is used in the downstream process (such as texturization and post-texture cleaning chemistries used for making back-contact back junction solar cells) and seals/protects the structures/patterns which have already been created. Where applicable, the backplane is also capable of supporting temperatures required for subsequent processing, in some embodiments up to about 200° C. to 300° C. Downstream high temperature processing steps include, for example, formation of the front surface passivation layer for a back contact, back junction solar cell.

With the backplane in place, the template and the thin crystalline silicon layer are separated along their weakest interface, which is the high porosity porous silicon layer. In one embodiment, this separation occurs by vacuum chucking the template and deploying a pick-and-place robot arm on thin crystalline layer. This separation process has been shown to produce a very high and consistent lift-off release yield or auto release for large area substrates (156 mm×156 mm) after laser trim (by the residual stress of the backplane on the thin silicon substrate). Alternative separation methods include using ultrasound assisted release.

Following the release of the thin, large area, crystalline solar cells, the residual porous silicon is cleaned off from both the template and the thin solar cell. The template is restored to its original state (through reconditioning and cleaning as needed), while remaining downstream processes on both the front and the back side of the thin solar cells are completed in accordance with the specific solar cell architecture (back contact or front contact cells).

In the Cleaving Embodiment

for the general fabrication process of large area thin crystalline Si Solar cells manufactured using a crystalline silicon template as described previously, instead of using an additive crystalline layer joined by the sacrificial porous silicon, a cleaving layer is formed on the template using a precision hydrogen ion (or proton) implant at the desired layer depth. An MeV hydrogen implant creates a mechanically weakened defective layer, which is used to facilitate the separation of the template into the thin crystalline device layer and the remaining template. This layer is controlled to a depth such that when separated, the top thin crystalline silicon is of the desired thickness (in the range of approximately a fraction of one micron up to about 50 μm).

The MeV hydrogen implant process may be followed by subsequent cell processing steps. Cell processing may comprise furnace or other high temperature steps as needed, as well as laser processing and doping layer deposition. Once this sequence of cell processing is completed, a backplane is laminated to (or deposited on) the cell backside on top of the template. The backplane may be comprised of a resin which flows at relatively low temperatures (˜200 C) and adheres to the silicon. The backplane may also be relatively CTE matched with silicon so as not to crack the silicon during lamination and other downstream higher temperature processing steps. The backplane may also be resistant to chemicals where chemistry is used in downstream solar cell processing (such as a back contact back junction solar cell) and is used to seal/protect the structures/patterns which have already been created. The backplane may also be formed by screen printing or stencil printing of a dielectric paste or another direct deposition method such as a thermal spray method.

With the backplane on the cell, the large area, thin crystalline silicon solar cell is released from the template from the weakest interface, which is the cleavage layer. Subsequent to release, the template may be cleaned to be ready for subsequent reuse. The released thin crystalline silicon layer may cleaned and processing on both frontside (in other words the sunnyside or light receiving side) and the backside (where backplane is attached) faces of the cells are completed.

Back Contact Back Junction Large Area Thin Silicon Solar Cells Using Epitaxy and Cleaving.

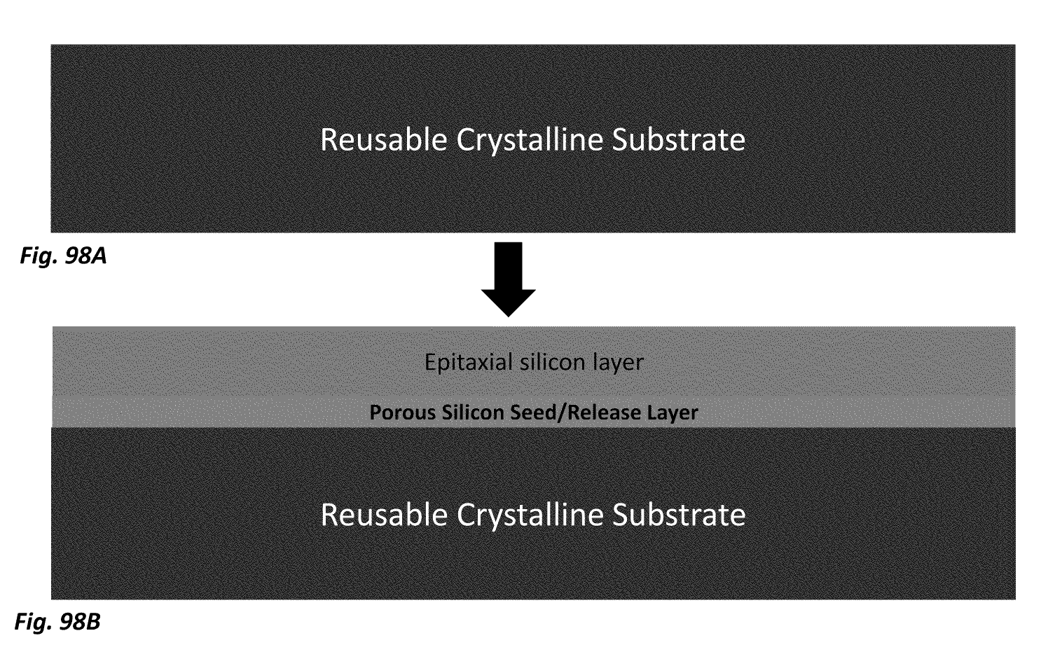

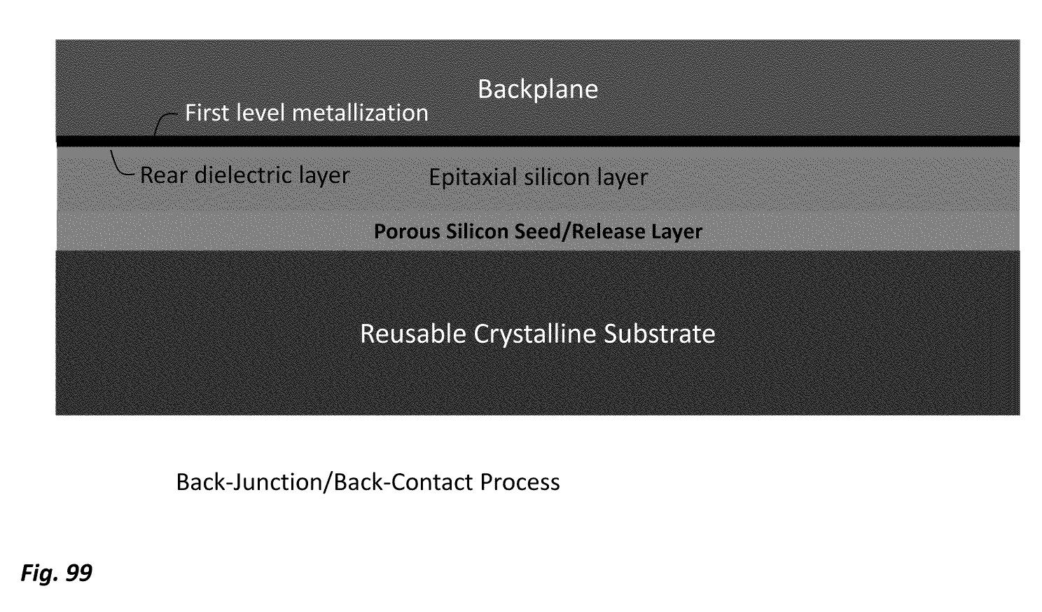

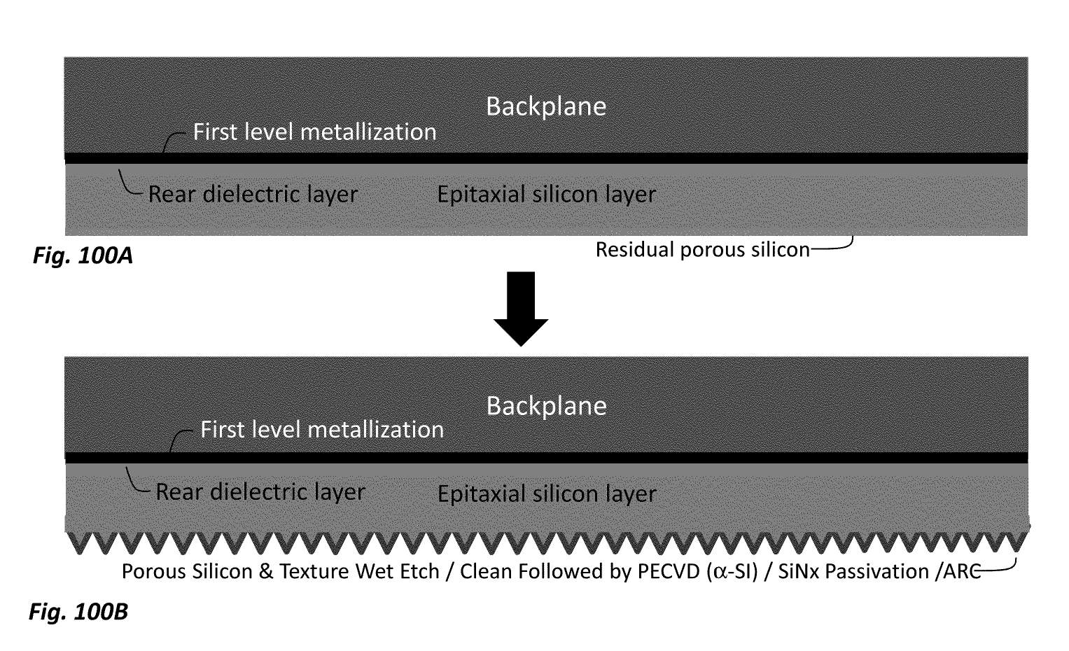

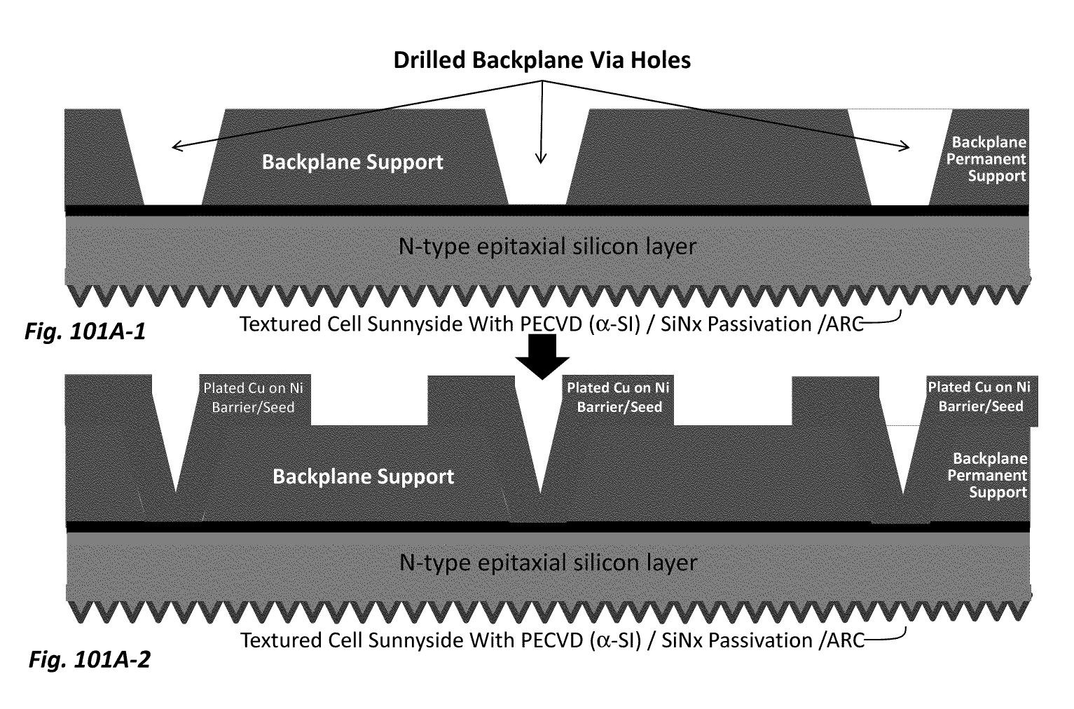

FIGS. 98A through 101B2 are cross-sectional diagrams showing a large-area thin-film semiconductor device (such as a solar cell) formation in accordance with the aforementioned manufacturing process using porous silicon seed and release layer followed by epitaxial silicon growth for a back contact back junction solar cell embodiment. FIG. 98A shows a reusable crystalline substrate (for example having a size in the range of approximately 100 to 1000 cm²) used as a first thin-film substrate support plate during some thin-film processing. The reusable crystalline silicon substrate may be a p+ monocrystalline silicon wafer having a thickness in the range of approximately 0.2 mm to 5 mm. FIG. 98B shows the formation of a porous silicon seed/release layer (for example having a thickness in the range of approximately 0.25 microns to 5 microns) and an N-type epitaxial silicon layer (for example having a thickness in the range of approximately 1 micron to 80 microns). FIG. 99 shows the formation/attachment of a backplane (for example having a size in the range of approximately 100 to 1000 cm²) to be used as a second thin film substrate support plate—and in some cases may act as a permanent thin-film solar cell support plate if needed—after the release of the thin film substrate from the reusable crystalline substrate. A rear dielectric layer may be formed on the epitaxial silicon layer on which a first level metallization layer may be formed. Importantly, the first level metallization contacts cell base and emitter regions through openings in the rear dielectric layer providing access to the cell base and emitter regions—for figure clarity these access opening are not shown in the Figures. The backplane may be a single layer or multi-layer laminate having a thickness in the range of approximately 50 microns to 500 microns. FIG. 100A shows the release of the epitaxial silicon layer from the reusable crystalline substrate along the porous silicon layer. Any residual porous silicon on the cell frontside may then be selectively etched off. FIG. 100B shows the cell after frontside processing including porous silicon and texture etch/clean followed by PECVD (α-SI)/SiNx Passivation/ARC. FIG. 101A-1 shows the cell after the formation of backplane via holes (for example by laser drilling) and FIG. 101A-2 shows the cell after high-conductivity cell plating metallization (for example plated Cu on Ni barrier/seed). FIGS. 101B-1 and 101B-2 show an alternative access hole opening and metallization embodiment as compared to FIGS. 101A-1 and 101A-2. In the structure and flow represented in FIGS. 101A-1 and 101A-2 the second layer metal (plated) is deposited and located outside of the backplane (on the very back of the cell, whereas in the structure and flow represented in FIGS. 101B-1 and 101B-2 the second layer metal—which can for instance be comprised of slices or pieces of solderable aluminum plate—is embedded within the dielectric backplane material. FIG. 101B-1 shows the cell after the formation/attachment of backplane with embedded solderable metallization and FIG. 101B-2 shows the cell after the formation of metallization access holes (for example by laser drilling).

FIGS. 98A through 101B2 show an n-type epi (n-type base) back contact, back junction solar cell embodiment. Post epitaxial growth, on template cell processing may comprise Atmospheric-Pressure Chemical-Vapor Deposition or APCVD, picosecond laser ablation, high temperature furnace dopant drive and back surface passivation, and metallization. A prepreg (with resin) backplane may be a single sheet or multiple sheets or it may be a printed or deposited electrically insulating layer. Post release from the template, the thin epitaxial solar cell may be processed in texture chemistry (such as an alkaline texture chemistry), which in addition to creating texture also cleans residual porous silicon. This may be followed by front surface passivation which may be performed at a temperature lower than the maximum allowable temperature of the backplane (for instance, at a temperature not to exceed about 250° C.) using ultrathin amorphous silicon (a-Si) passivation covered by a top layer of silicon nitride, both deposited using PECVD. Finally, the backside processing is finished on the backplane side to access the metallization through the backplane. Periodic holes (vias) are drilled in the backplane material using any number of techniques such as laser drilling, mechanical drilling, chemical etching etc. However, in one scheme, a CO2 laser may be used to drill these holes at a very high speed, stopping on the underlying metallization.

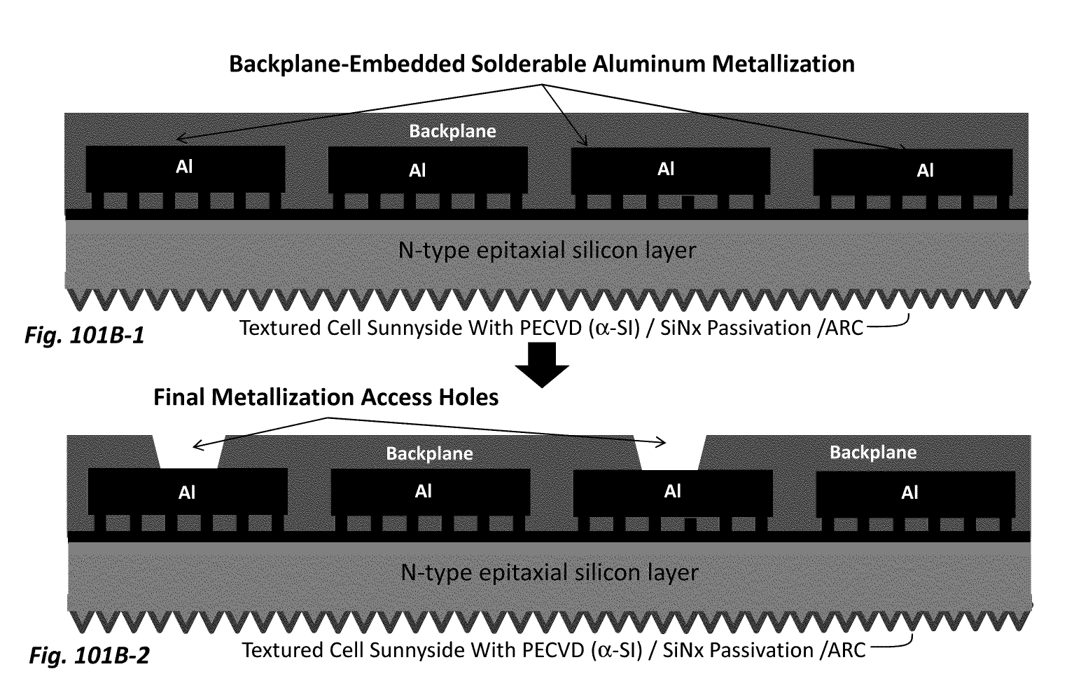

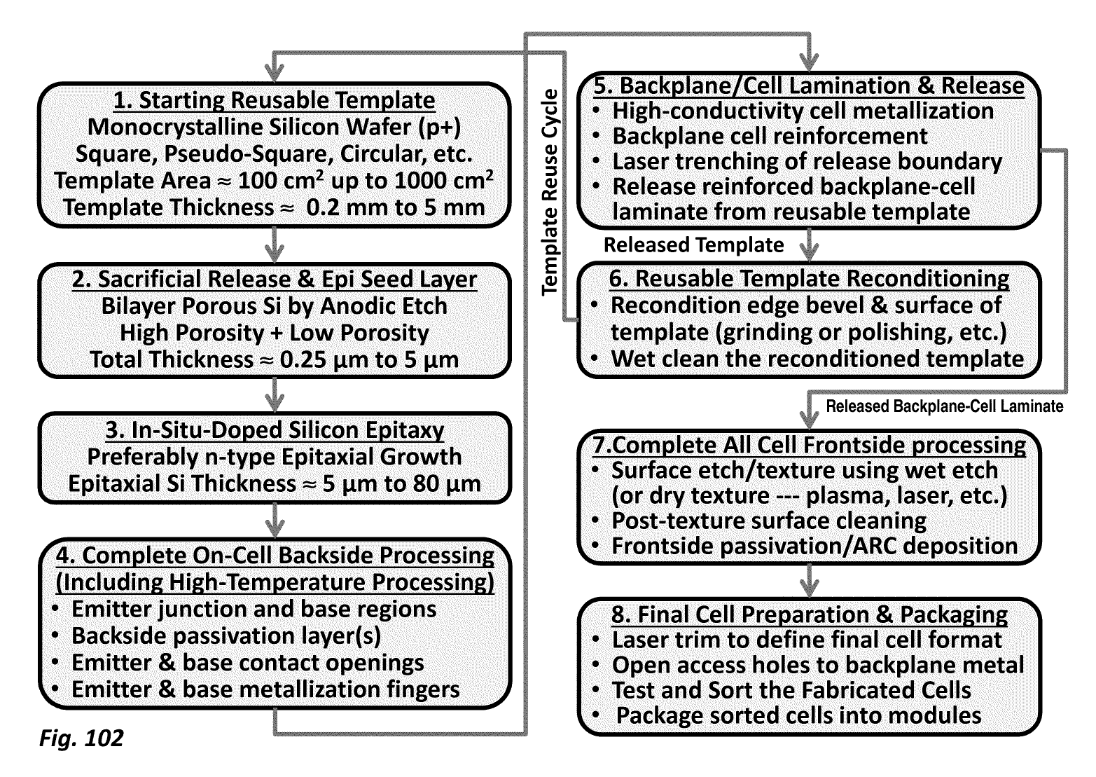

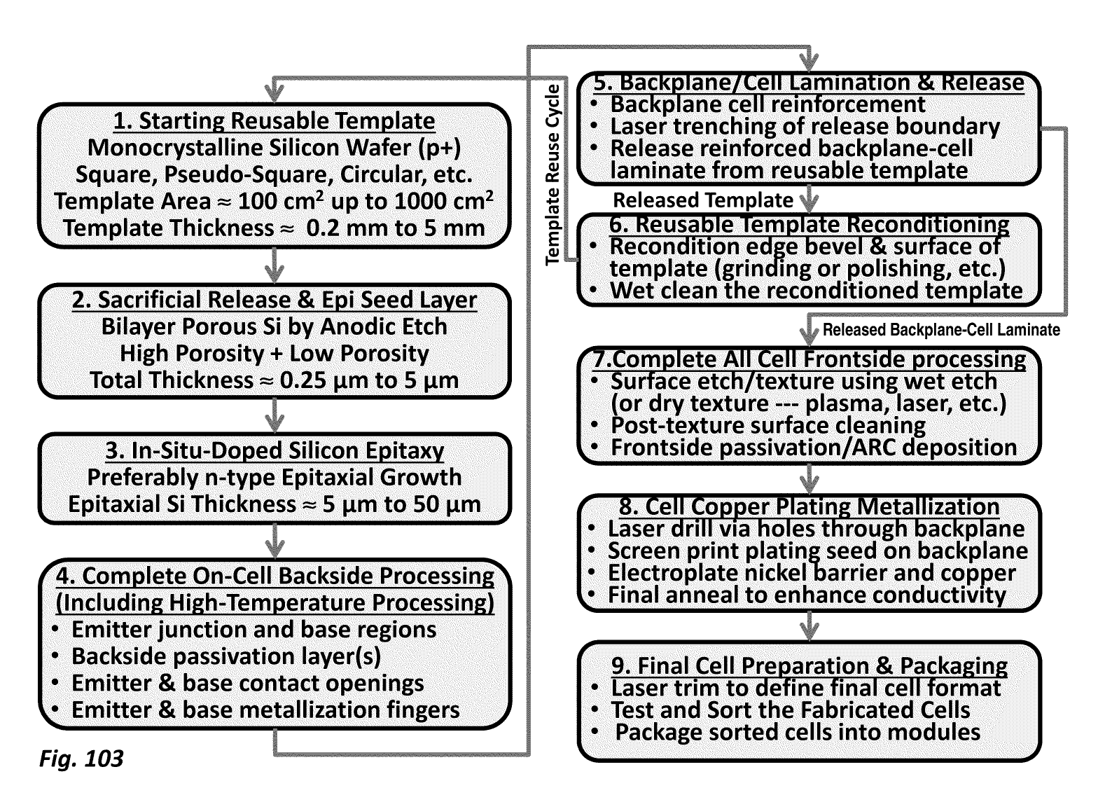

Alternative metallization methods include, for example, pre-drilling the holes in the backplane, followed by lamination while protecting the holes from chemistry during texture steps, using temporary protection. Again, FIGS. 101A and 101B depict two specific variations of this access scheme. In FIG. 101A, post hole drilling a screen printed seed layer is deposited. This is followed by electroplating on top of the seed layer. In FIG. 101B, the attached backplane already has embedded solderable Aluminum metallization. Opening of the vias through the prepreg exposes this solderable layer, which may subsequently be soldered to. FIGS. 102 and 103 are process flows showing steps to create the on-cell processes and provide other details corresponding to FIGS. 101A and 101B, respectively. FIG. 102 is a process flow for the formation of a large-area thin-film semiconductor device, specifically a back-junction back-contact monocrystalline silicon solar cell using epitaxy and with back-plane embedded metallization (for example Al foil). FIG. 103 is a process flow for the formation of a large-area thin-film semiconductor device, specifically a back-junction back-contact monocrystalline silicon solar cell using epitaxy and with end-of-the-line plating metallization (for example Cu.

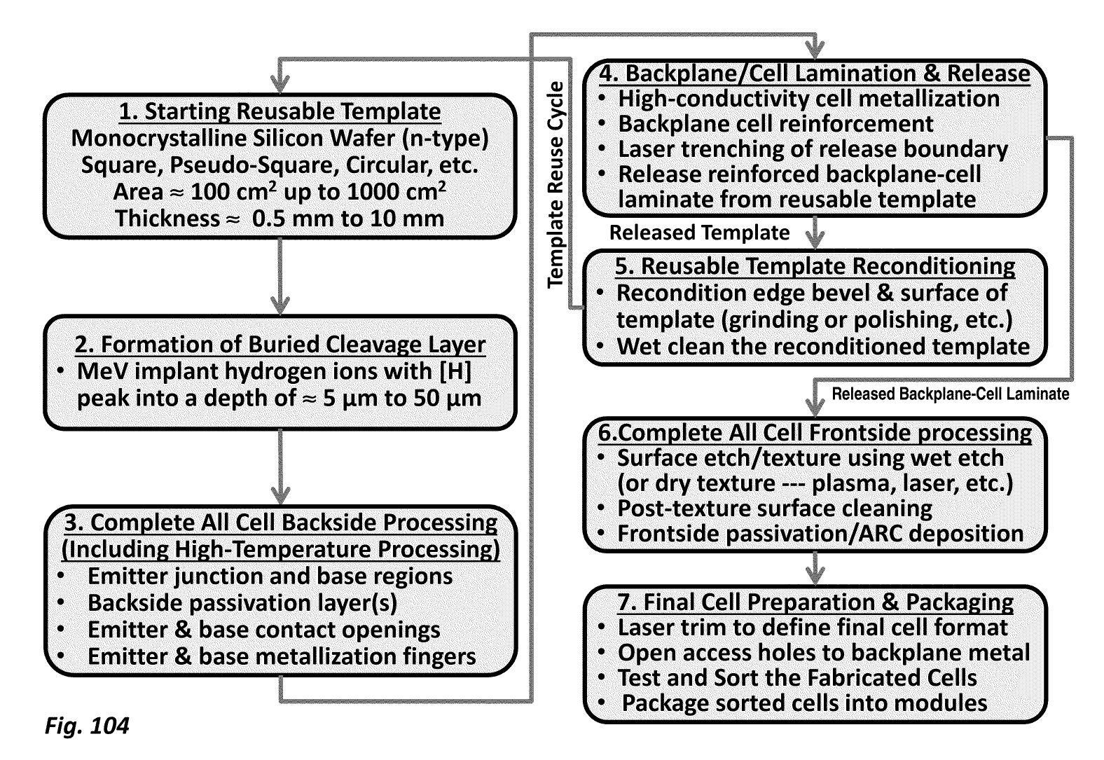

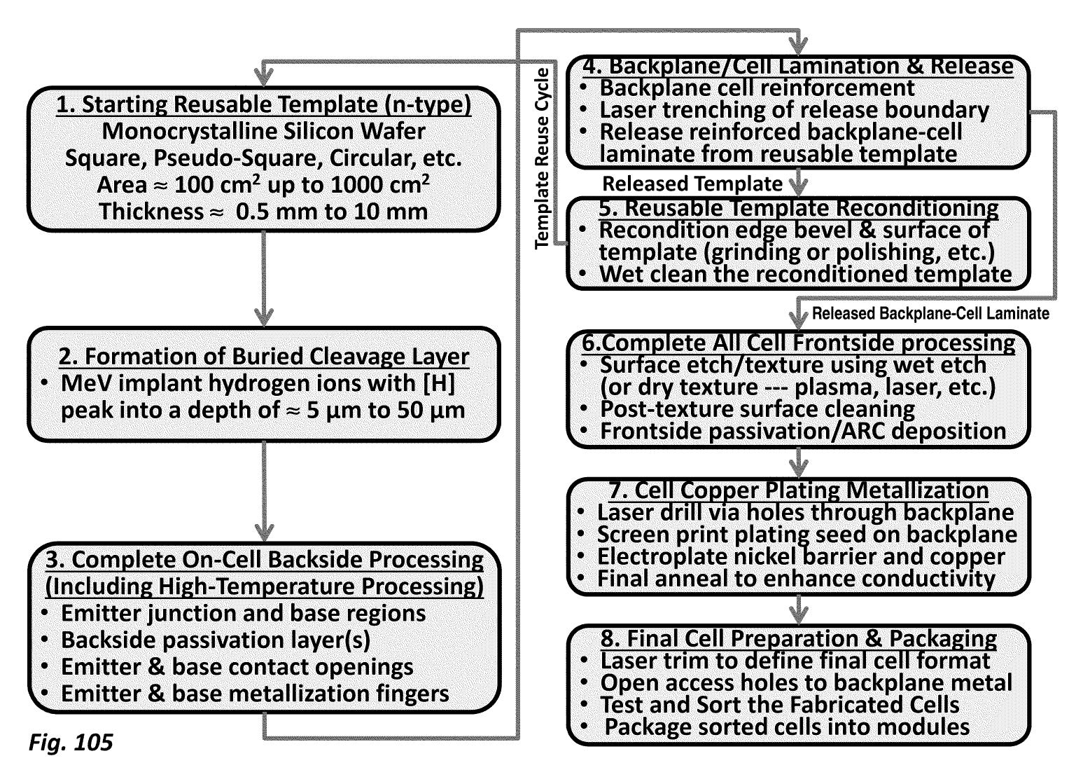

FIGS. 104 and 105 are specific process flows for back contact back junction solar cells using the cleaving technique coupled with a backplane. FIGS. 104 and 105 correspond to FIGS. 102 and 103, respectively, which use porous silicon and epitaxy. FIG. 104 uses backplane embedded metallization, where a solderable metal layer (for example Al) is embedded with the backplane and is accessed by drilling the hole in the backplane. Whereas FIG. 105 shows the same process sequence as FIG. 104 except at the last step (end-of-the-line) metallization is performed by screen printing followed by plating (for example using Cu).

Comparing the porous silicon and the cleavage approach following inferences may be drawn, among others. The porous silicon and epitaxy approach may have the following advantages: it does not incur the relatively large capital expenditure of an implant tool; it allows modulation doping and ability to cater and spatially vary the doping profile to use it to gain performance increases; and it does not require a high quality (i.e., high minority carrier lifetime) starting template. On the other hand, the cleaving approach may have the following advantages: it more readily enables wet processing on template; there is less conditioning of the template required to bring the template back to its original shape; and there is no additional cost of the porous silicon and epi tools. On the other side, the capital cost of both porous silicon and epi combined may be cheaper than the cost of the implant tool that is needed to enable the cleaving approach, and not using wet processing on template in the case of the porous silicon with epitaxy based flow may require a more efficient and cheap, dry cell process using picoseconds laser. The cleaving approach, however, may still incur the cost of a thick, high lifetime starting wafer and may have an effectively high kerf loss since only a fraction of the starting template are utilized for final cell material. Hence it still goes through polysilicon and ingot formation, only saving the cost of wafering. The porous silicon epi approach goes directly from gas to crystalline silicon hence saving the cost of both ingot and wafering.

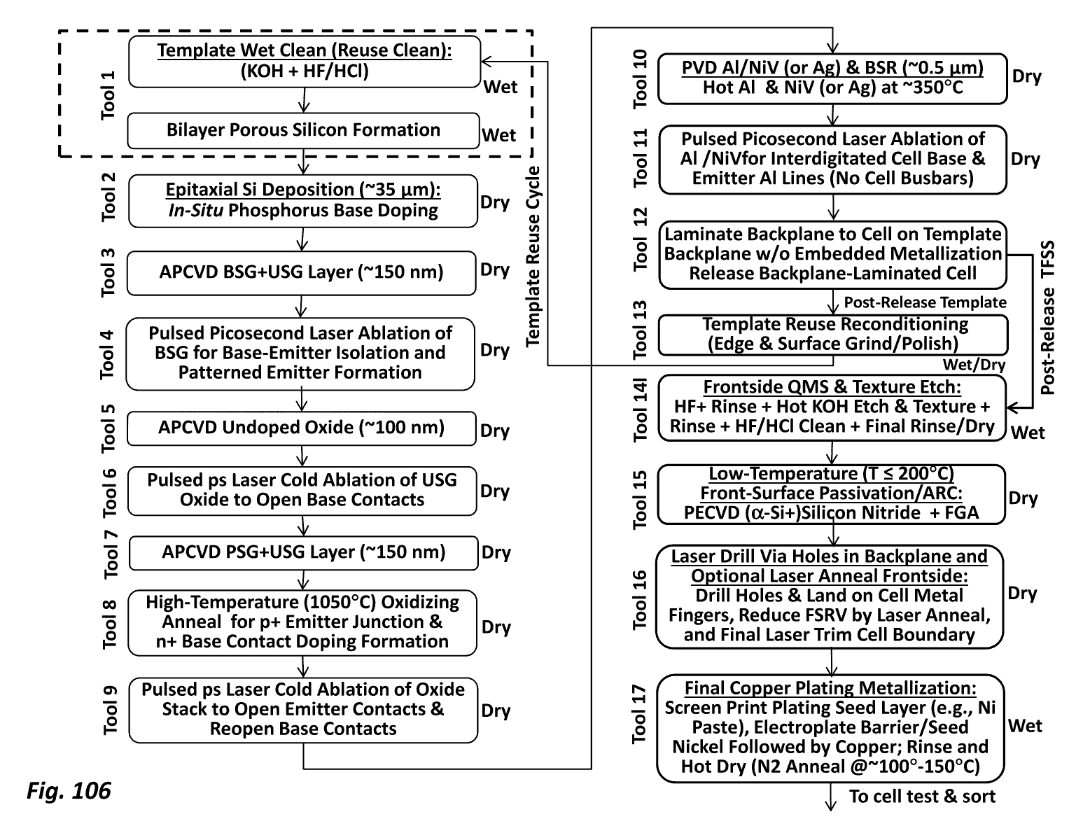

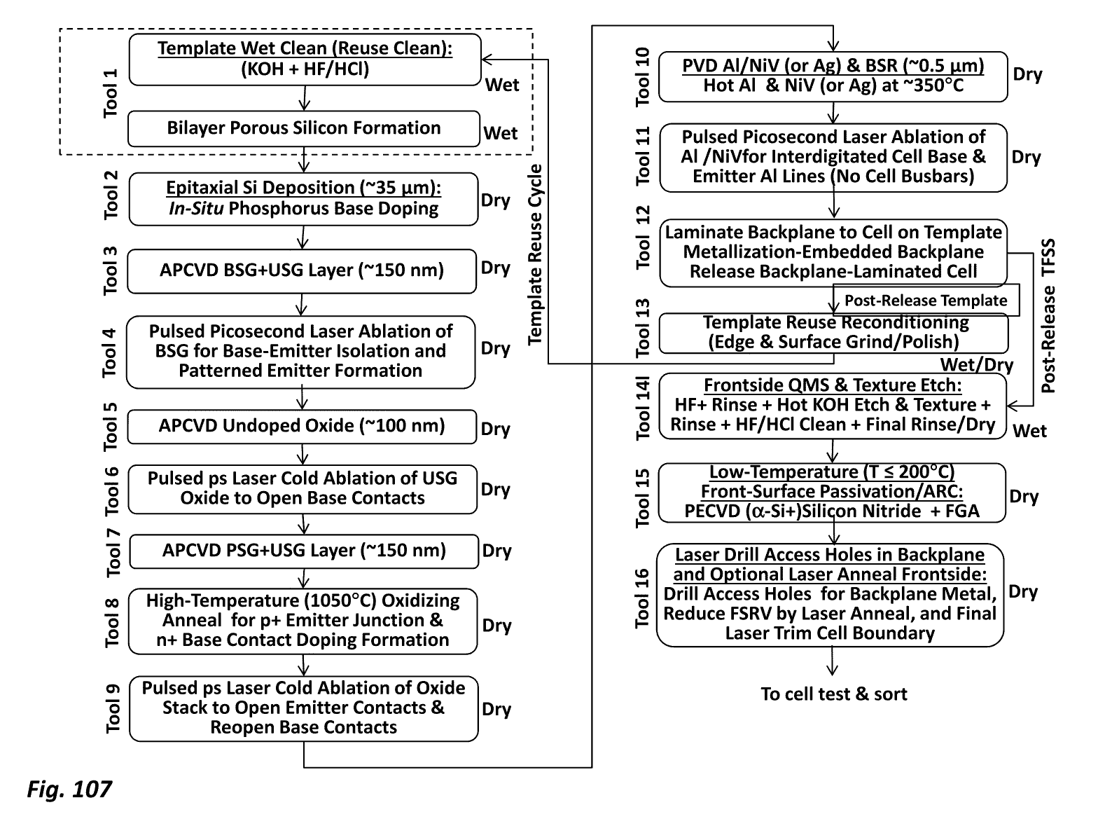

FIGS. 106 and 107 are representative process flows for manufacturing large area thin crystalline silicon, back contact/back junction solar cells using porous silicon and epitaxial growth in accordance with the general manufacturing methods discussed above. FIG. 106 is a representative embodiment of a back-contact/back-junction Epi cell process flow using end-of-the-line plating metallization. FIG. 107 is a representative embodiment of a back-contact/back-junction Epi cell process flow using backplane embedded metallization.

### Back Junction Front Contact, Large Area Thin Silicon Solar Cells Using Epitaxy and Cleaving

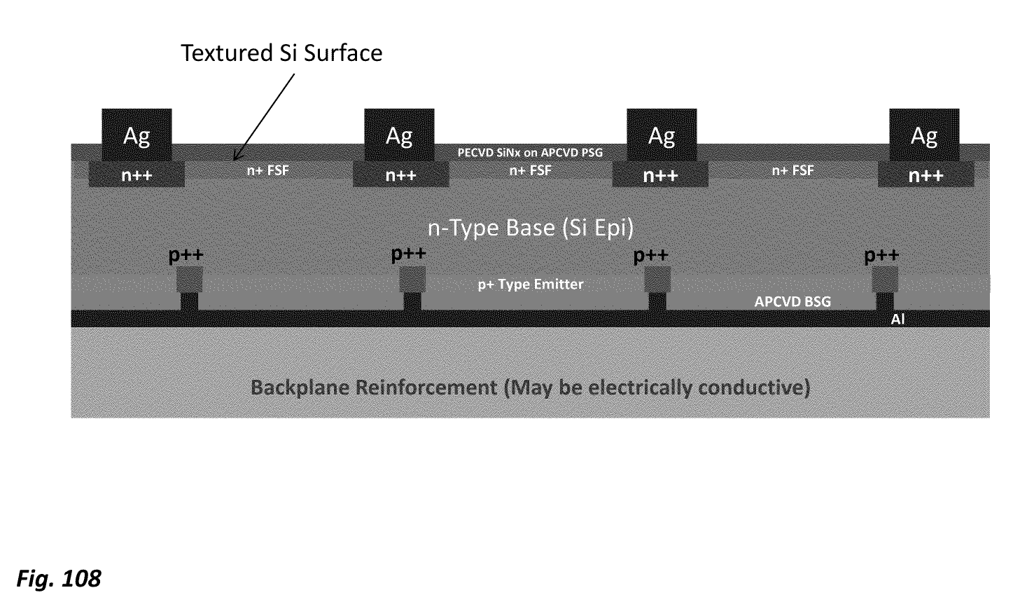

FIG. 108 is a cross-sectional diagram showing the schematic of a solar cell which has the emitter in the back (and hence is a back junction solar cell) but has the base contact in the front. Specifically, FIG. 108 shows an Epi cell design with n-Type Base, front-contact base and back-junction/back-contact emitter and having an Al disk backplane on the thin Epi. Importantly, the backplane in this structure may be electrically conductive (as opposed to a dielectric backplane). This structure is different from conventional solar cell structures such as back junction/back contact, or Front junction/back contact, and front junction front contact solar cells. Further, this structure is highly conducive for thinner solar cells because the emitter is in the back and the carrier diffusion length must be much larger than the thickness of the silicon. When the silicon is thinner, the minority carrier lifetime requirement for the substrate may be more relaxed to get the same efficiency performance. Compared to a back junction back contact cell, this structure suffers from metal shading loss. However, managing shunt resistances may be relatively easier in this structure as compared to a back contact back junction cell as the base and emitter metals are on different sides of the solar cells. Also, the amount of metal shading may be minimized down to <4% shading without compromising Fill Factor. For this structure, the substrate doping may advantageously be n-type so as to ensure higher lifetime. And there is enormous flexibility in the choice of the backplane as it may be either conductive or an insulator. In addition, the number of process steps may be reduced compared to the back junction back contact solar cells.

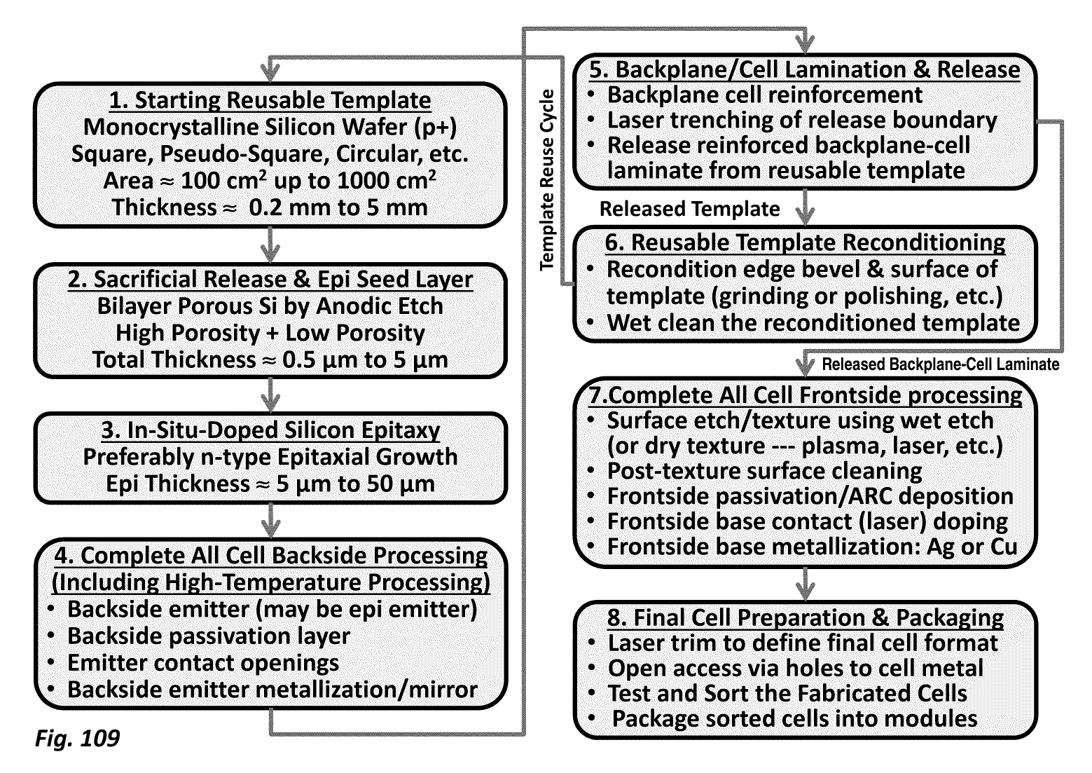

Embodiments of the aforementioned general manufacturing methods for large are thin crystalline Silicon solar cells using crystalline silicon template may be used to manufacture back junction, front contact solar cells. As above, both the porous silicon as well as the cleaving embodiments are discussed. This cell structure is well suited both for thin silicon from thin epitaxial deposition and lift-off or from a thin cleaved layer of silicon. In addition, the back contact embedded metal disk may be manufactured at a particularly low cost, as it only represents one contact polarity and thus does not need to be patterned. This opens the possibility for very low cost backside metal sheets, such as thin solderable aluminum plate (aluminum manufactured as large sheets with thin layers of solderable material such as tin or tin on thin nickel on one or on both sides). FIG. 109 is a process flow for the formation of a large-area thin-film semiconductor device, specifically a back-junction front-contact monocrystalline silicon solar cell using epitaxy. FIG. 109 shows the process flow using the porous silicon and epitaxy. Porous silicon anodic process is followed by epitaxial process. N-type epitaxy (e.g., in-situ-doped with phosphorus) may be followed by an in-situ p-type (doped with boron) emitter toward the end. As another option, a light Front Surface Field (FSF) may also be deposited in-situ as part of the epitaxial growth. The epi is followed by a backside passivation layer. In a specific case, this can be a thermal oxide or a combination of APCVD and thermal oxide. Passivation is followed by contact opening to emitter. In some embodiments, this can be achieved using a pico-second laser. The emitter contact open is followed by metallization. In some embodiments this may be performed using Al paste or using PVD Al or any metal stack which makes good contact to the p-type silicon.

Subsequently, a backplane is attached. In some instances, the backplane material choices and design for back junction, front contact solar cells may have more flexibility than the backplane for a back contact back junction architecture. For a back junction, front contact solar cell structure, the backplane may be a conductive backplane as there is no requirement to keep the base and emitter metal isolated for this structure. Post backplane attachment and releasing of the thin silicon, the cell frontside may be textured and a passivation and ARC layer or layer stack is deposited. A laser may be used to drive in the p-type dopants for contacts to the base metal. This is followed by a low temperature base metallization. This may be either Ag or Cu.

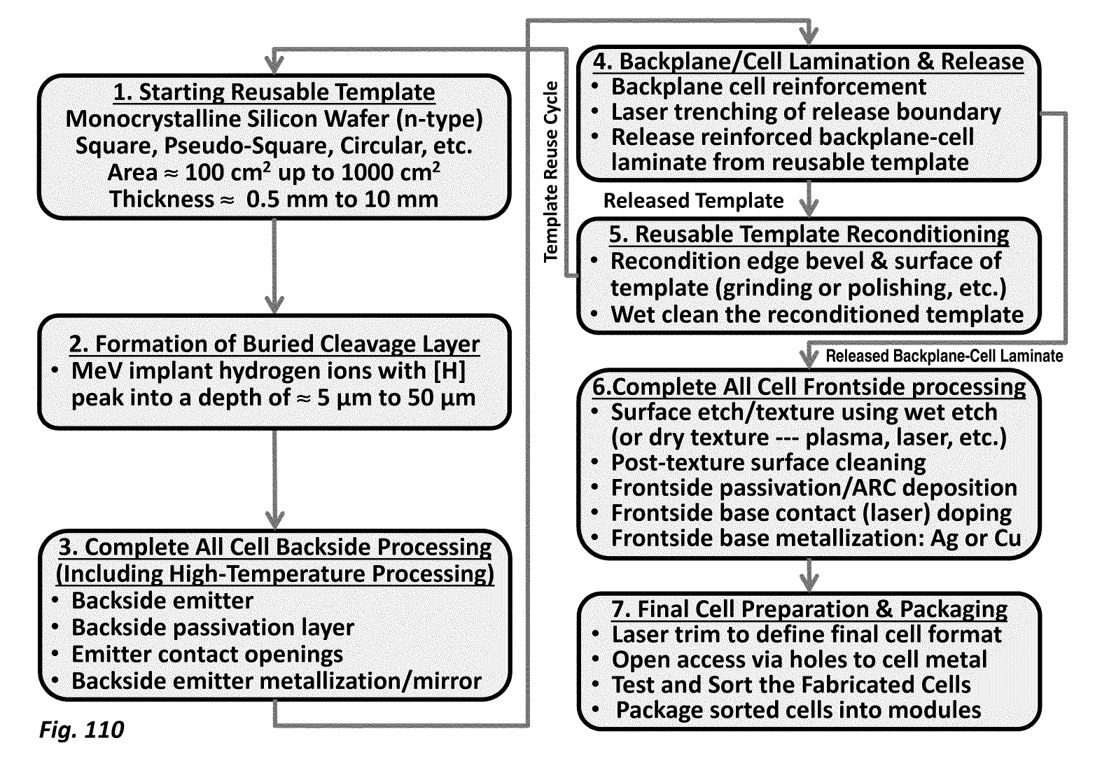

FIG. 110 is a process flow for the formation of a large-area thin-film semiconductor device, specifically a back-junction front-contact monocrystalline silicon solar cell using cleavage. FIG. 110 is a cleaving embodiment process flow for a back junction, front contact solar cell. The process of FIG. 110 is similar to that of FIG. 109 for manufacturing thin crystalline silicon solar cell; however, the process of FIG. 110 uses MeV hydrogen implant to create a cleaving layer. The starting template in this case may be a high lifetime n-type template as the solar cells are formed of the same material.

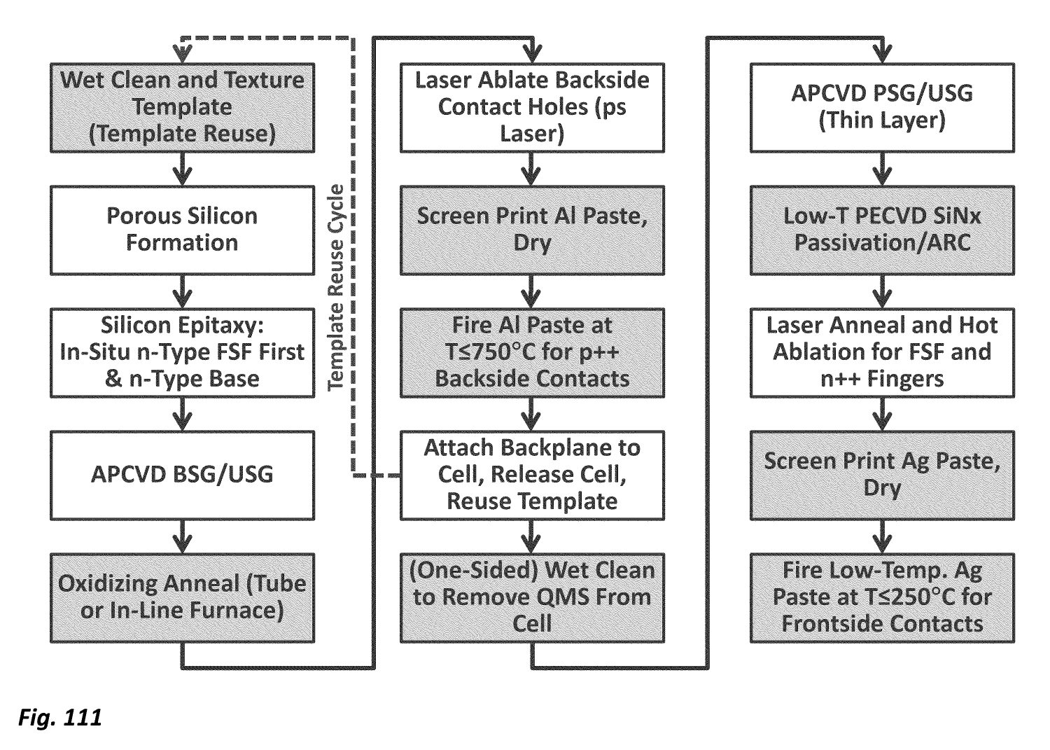

And although there are many variations of the process flows disclosed within the general paradigm described for manufacturing a back junction front contact solar cell, three additional representative process flows pertaining to the porous silicon and epitaxial embodiments are provided in FIGS. 111 through 113. FIG. 111 is an process flow for an epi cell with front-contact base and back-junction/back-contact emitter, and specifically having an n-type base, textured template, thin epi.

FIG. 111 highlights a process flow where the template is pretextured. In this scenario, the Front surface field (FSF) may be grown in-situ in the epitaxial reactor, the emitter is shown to be deposited and driven in using a BSG APCVD layer (boron doped silicon dioxide). In a variation this may also be part of the epitaxial growth. Because the epitaxial solar cell will conform to the pre-textured template, explicit texturing is not necessary for this process. Thus, after release, a relatively milder removal of the residual porous silicon (also known as quasi mono crystalline or QMS layer) is required. Other attributes of this flow include a laser anneal for the front n++ doping and a low temperature Ag paste to contact the base.

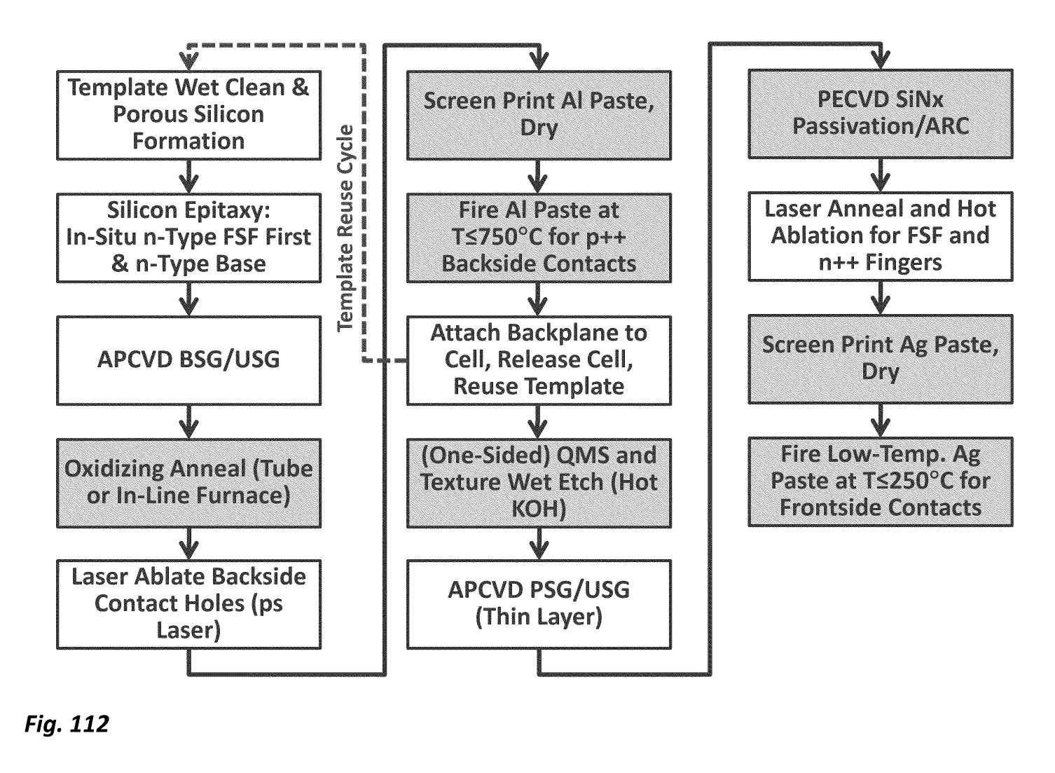

FIG. 112 is a process flow for an epi cell with front-contact base and back-junction/back-contact emitter, and specifically having an n-type base, un-textured template, thin epi. FIG. 112 shows a variant of the flow shown in FIG. 111. Again, these flows are only meant to be specific examples and should not be taken as the only possibilities within the general paradigm of manufacturing method as disclosed herein. A key difference in the flow of FIG. 112 as compared to FIG. 111 is that the starting template is non-textured. Hence, post release, in addition to the QMS removal, texturing may also be required (as shown in FIG. 112). Other process steps remain the same.

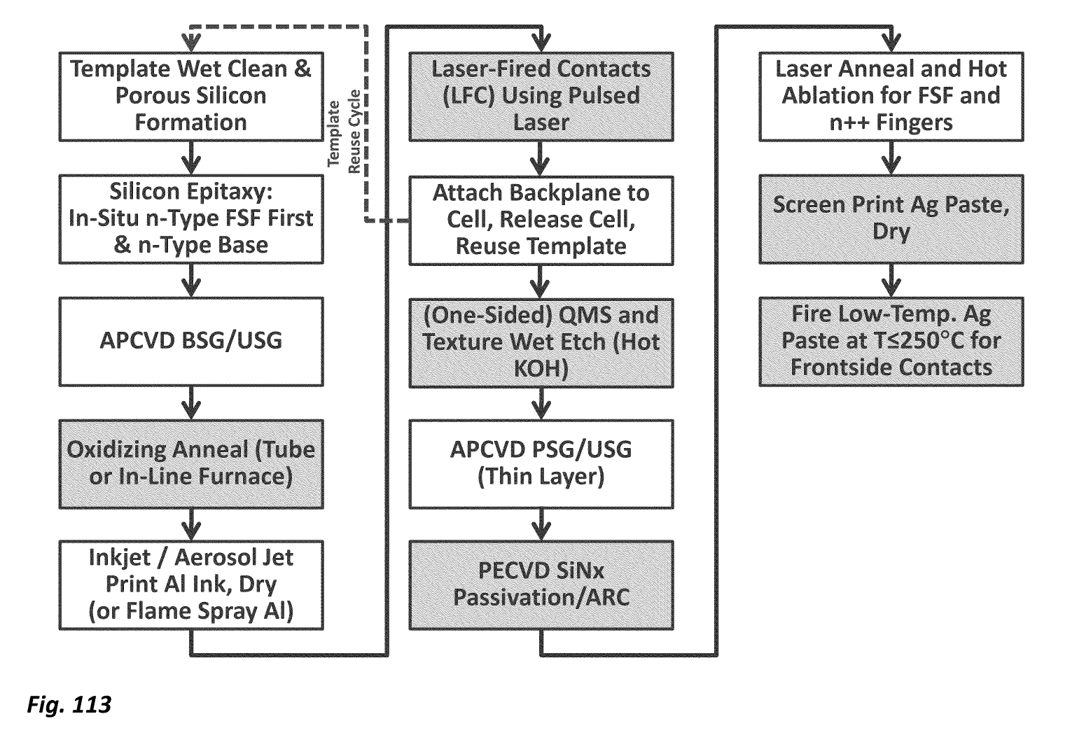

FIG. 113 is a process flow for an epi cell with front-contact base and back-junction/back-contact emitter, and specifically having an n-type base, un-textured template, thin epi, and LFC flow. FIG. 113 shows yet another variant and a specific embodiment of the general process flow paradigm disclosed herein. This flow is similar to the flow in FIG. 112 except the contacts to the emitter are achieved using laser fired contacts (LFC). Other process steps remain the same. Although, not shown explicitly, it should be understood that the any and all combinations of these variations are also viable process flows to manufacture this device. Importantly, these processes may be adopted for the cleaving scheme as well.

### Front Junction, Front Contact, Large Area Thin Silicon Solar Cells Using Epitaxy and Cleaving

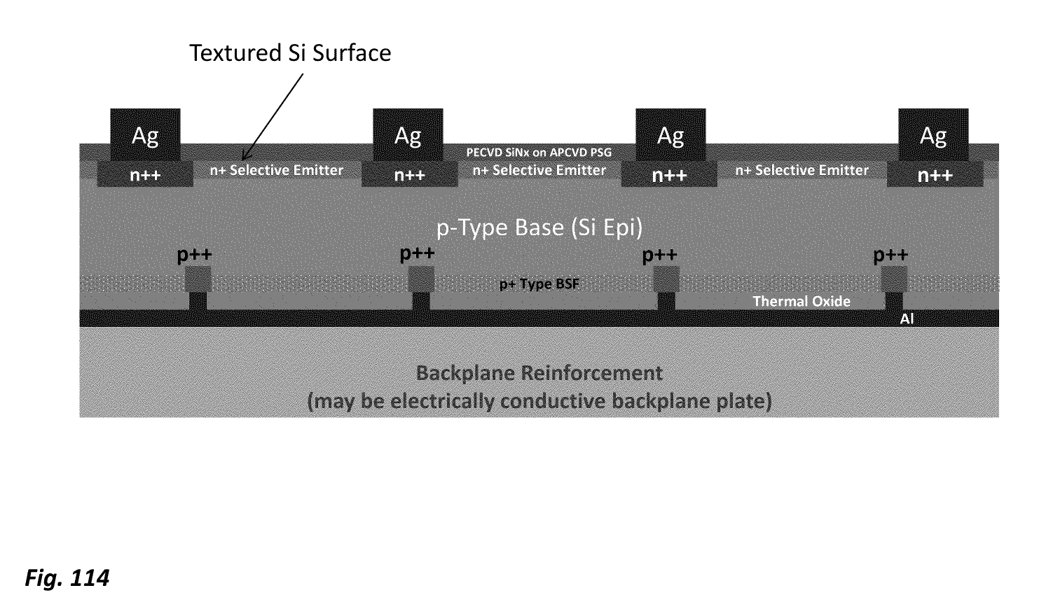

A third solar cell architecture having front junction and front contact may also be manufactured within the disclosed paradigms for manufacturing thin crystalline silicon cells using crystalline silicon template. FIG. 114 is a cross-sectional diagram of a front junction and front contact solar cell. FIG. 114 shows an epi cell design with a p-type base and front-junction/front-contact emitter. As described herein, the front junction and front contact solar cell use a p-type base (such as a thin boron doped epi layer for a p-type base), APCVD PSG (phosphorus doped silicon dioxide) and laser doping for emitter, and a QMS layer on the cell sunnyside (as QMS etch and texture may be performed simultaneously).

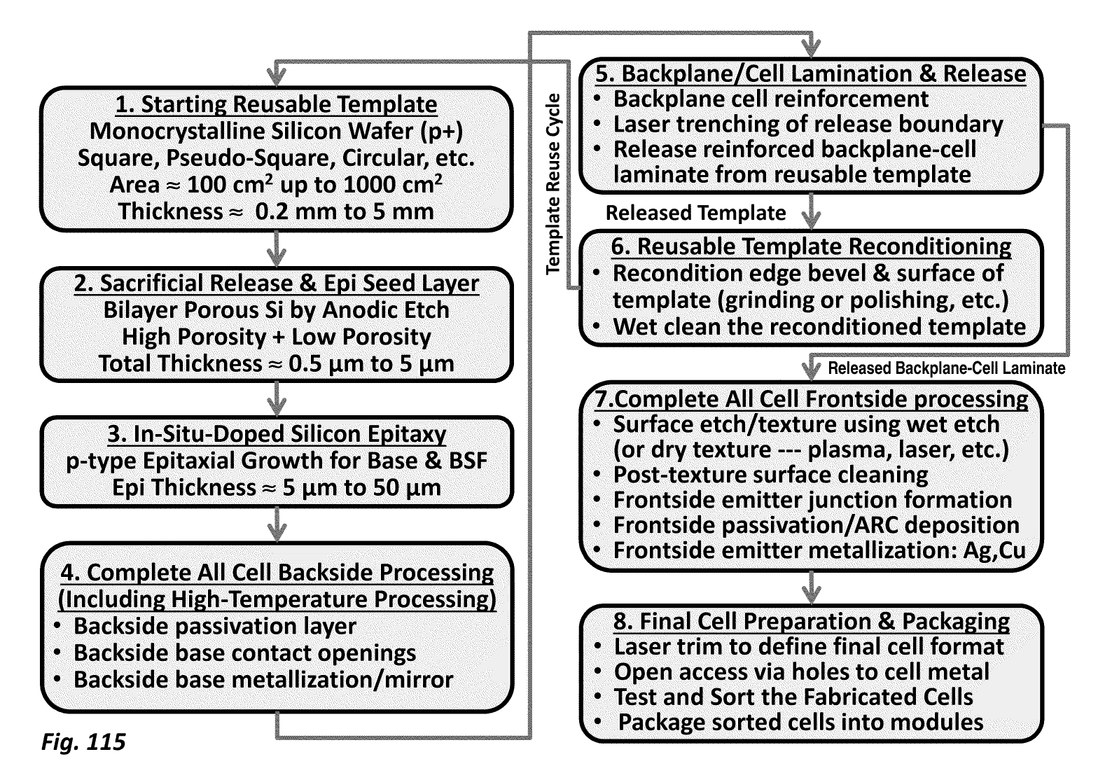

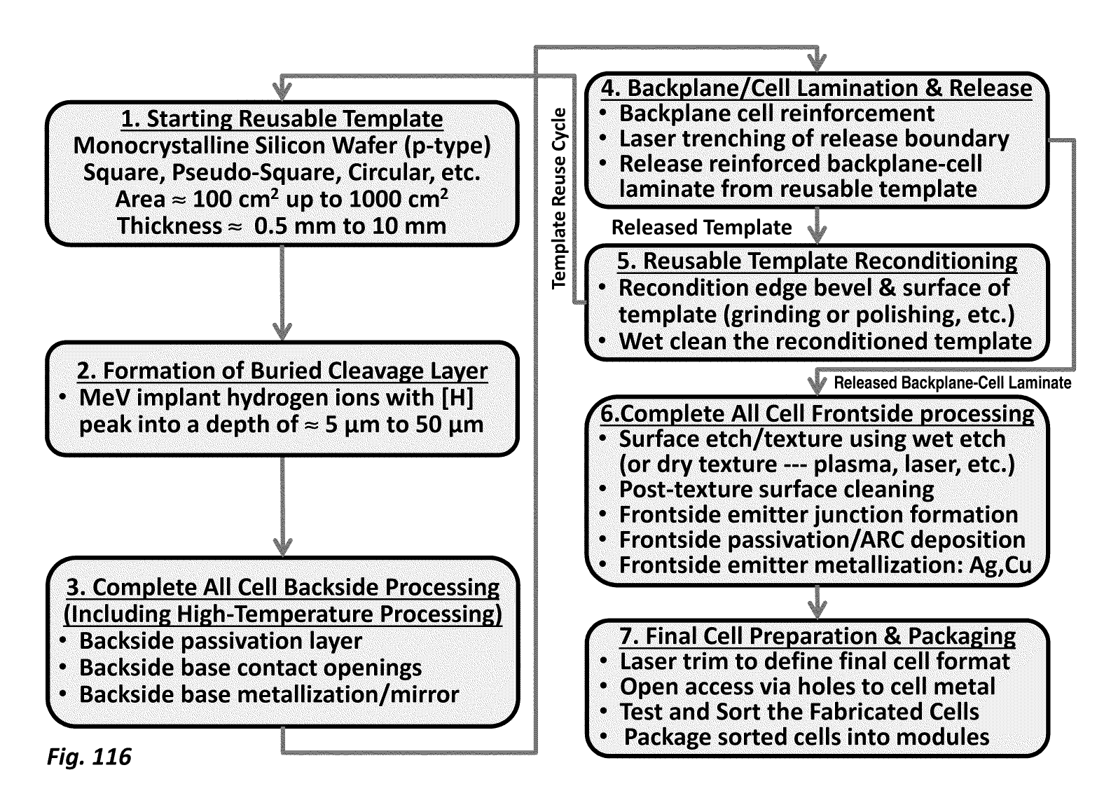

FIGS. 115 and 116 are process flows for the formation of large-area thin-film semiconductor devices, specifically front-junction, front-contact monocrystalline silicon solar cells using epitaxy (FIG. 115) or cleaving (FIG. 116). In other words, FIGS. 115 and 116 are process flow embodiments for the formation of front junction, front contact solar cells. FIG. 115 shows a porous silicon and epi approach and FIG. 116 shows cleaving using a high energy implant.

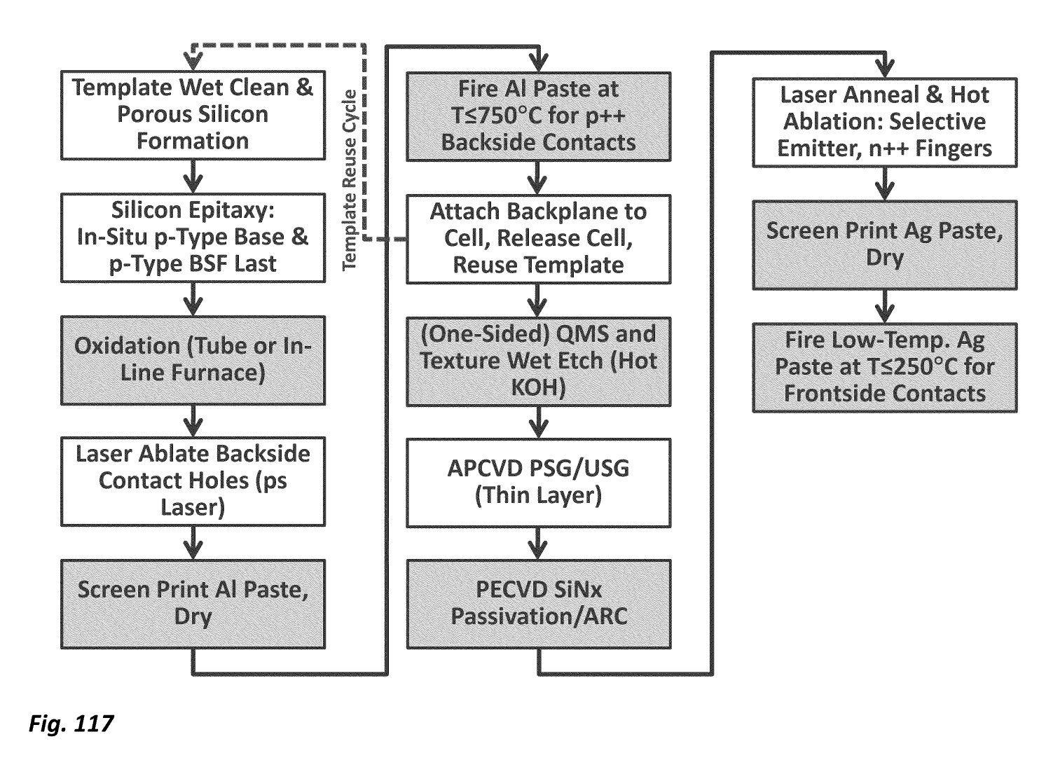

FIG. 117 is a process flow for an epi cell with front-contact emitters, and specifically having a p-type base, untextured template, and thin epi. In other words, FIG. 117 shows a more specific embodiment of the porous silicon/Epi flow highlighted in FIG. 115.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein. And it is intended that all such additional systems, methods, features, and advantages that are included within this description be within the scope of the claims.

What is claimed is:

1. A back contact crystalline semiconductor solar cell structure, comprising:
a crystalline semiconductor substrate, said substrate comprising a light receiving frontside surface covered with a frontside passivation layer and a backside surface comprising patterned doped emitter and base regions and a backside passivation layer;
a first electrically conductive metallization layer having an interdigitated pattern of emitter electrodes and base electrodes on said backside surface of said crystalline substrate;
an electrically insulating layer attached to said backside surface of said crystalline substrate, said electrically insulating layer comprising an embedded patterned metallization sheet contacting said first electrically conductive layer at specified locations, said electrically insulating layer electrically isolating said first metallization layer from a second electrically conductive metallization layer; and
a second electrically conductive metallization layer providing high-conductivity cell interconnections to said embedded metallization sheet of said electrically insulating layer.

2. The solar cell structure of claim 1 wherein said first electrically conductive metallization layer comprises aluminum.

3. The solar cell structure of claim 1 wherein said embedded patterned metallization sheet comprises aluminum.

4. A method for forming a back contact solar cell, comprising:
forming a first layer of electrically conductive metal having an interdigitated pattern of base electrodes and emitter electrodes on the backside surface of a crystalline semiconductor substrate, said substrate comprising a light receiving frontside surface and a backside surface for forming patterned emitter and base contacts silicon layer;
forming an electrically insulating layer on said first layer of electrically conductive metal, said electrically insulating layer comprising an embedded patterned metallization sheet contacting said first electrically conductive layer at specified locations, said electrically insulating layer providing electrical isolation between said first layer of electrically conductive metal and a second layer of electrically conductive metal;
forming holes in said electrically insulating layer, said holes providing access to said embedded metallization sheet contacting said first electrically conductive layer; and
forming a second electrically conductive metallization layer on said electrically insulating layer, said second electrically conductive metallization layer contacting said embedded metallization sheet contacting said first electrically conductive layer through said holes.

5. A back contact crystalline semiconductor solar cell structure, comprising:
a crystalline semiconductor substrate, said substrate comprising a light receiving frontside surface covered with a frontside passivation layer for forming patterned base regions and a backside surface comprising patterned doped emitter regions and a backside passivation layer;
a frontside electrically conductive metallization layer having a pattern of base electrodes on said frontside surface of said crystalline substrate;
a backside electrically conductive metallization layer having a pattern of emitter electrodes on said backside surface of said crystalline substrate;
a backplane layer attached to said backside surface of said crystalline substrate, said backplane layer comprising an embedded metallization sheet contacting said backside electrically conductive layer.
